(19) United States
(12) Patent Application Publication
(10) Pub. No.: US 2026/0056472 A1
(43) Pub. Date: Feb. 26, 2026

(54) LAMINATE, PROCESS FOR MANUFACTURING LAMINATE, AND PATTERNING PROCESS

(71) Applicant: SHIN-ETSU CHEMICAL CO., LTD., Tokyo (JP)

(72) Inventors: Shun KIKUCHI, Joetsu-shi (JP); Ryo MITSUI, Joetsu-shi (JP); Satoshi KUSAMA, Joetsu-shi (JP); Kousuke OHYAMA, Joetsu-shi (JP); Ryo NISHIKAWA, Joetsu-shi (JP); Masaki OHASHI, Joetsu-shi (JP)

(73) Assignee: SHIN-ETSU CHEMICAL CO., LTD., Tokyo (JP)

(21) Appl. No.: 19/304,359

(22) Filed: Aug. 19, 2025

(30) Foreign Application Priority Data
Aug. 22, 2024 (JP) 2024-140813

(51) Int. Cl. G03F 7/09; G03F 7/039; G03F 7/075; G03F 7/20

(52) U.S. Cl. CPC G03F 7/094; G03F 7/0392; G03F 7/0757; G03F 7/2002

(57) ABSTRACT

A laminate including a substrate, a silicon-containing resist underlayer film obtained from a silicon-containing resist underlayer film composition that contains a thermally crosslinkable polysiloxane containing any one or more from repeating units represented by formulae (1) to (3) and any one or more from repeating units represented by formulae (4) to (6), and a resist film obtained from a resist composition that contains at least one hypervalent iodine compound selected from a hypervalent iodine compound represented by formula (7), a hypervalent iodine compound represented by formula (8) and a hypervalent iodine compound represented by formula (9), a carboxy group-containing compound, and a solvent, in the listed order. This can provide a laminate that can satisfy both high sensitivity and high resolvability and allow for formation of a fine pattern in photolithography with a high energy line, a process for manufacturing such a laminate, and such a patterning process.

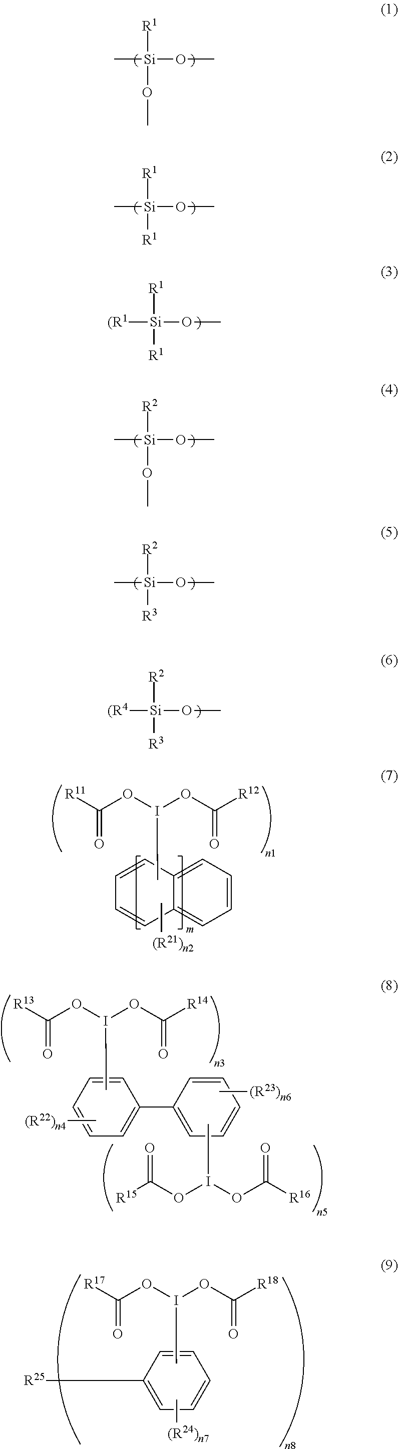

### TECHNICAL FIELD

The present invention relates to a laminate, a process for manufacturing a laminate, and a patterning process.

### BACKGROUND ART

Along with the expansion of the IoT market, LSIs are further required to have higher degree of integration, higher speed and lower power consumption, and the miniaturization of pattern rules are in rapid progress. In particular, logic devices lead the miniaturization. State-of-art miniaturization techniques carried out include volume manufacturing of 10-nm node devices by double patterning, triple patterning and quadruple patterning with ArF immersion lithography, and furthermore there are advanced studies about 7-nm node devices with next-generation extreme-ultraviolet (EUV) lithography at a wavelength of 13.5 nm.

With the progression of miniaturization, image blurs due to acid diffusion are problematic (Non Patent Document 1). In order to ensure the resolvability in fine patterns with a processing dimension of 45 nm or less, there is proposed the importance of not only an enhancement in dissolution contrast, which has been conventionally proposed, but also control of acid diffusion (Non Patent Document 2). However, chemically amplified resist compositions are increased in sensitivity and contrast by acid diffusion, and therefore, if acid diffusion is tried to be suppressed as much as possible by a reduction in post-exposure bake (PEB) temperature or a decrease in PEB time, such sensitivity and contrast remarkably deteriorate.

It is effective to suppress acid diffusion by addition of acid generators that generate bulky acids. There is then proposed copolymerization of acid generators of onium salts having polymerizable olefins, with polymers. However, patterning on resist films with a processing dimension of 16 nm or less is considered not to be able to be achieved with chemically amplified resist compositions from the viewpoint of acid diffusion, and non-chemically amplified resist compositions are demanded to be developed.

Examples of materials for non-chemically amplified resist compositions include polymethyl methacrylate (PMMA). PMMA is a positive type resist material that is enhanced in solubility in a developer of an organic solvent due to cleavage of a backbone by EUV irradiation and thus a reduction in molecular weight.

Hydrogen silsesquioxane (HSQ) is a negative type resist material that is made insoluble in an alkali developer due to crosslinking by a condensation reaction of silanol generated by EUV irradiation. Chlorine-substituted calixarene also serves as a negative type resist material. These negative type resist materials are small in molecular size before crosslinking and do not cause any blurs due to acid diffusion, therefore are small in edge roughness and very high in resolvability to allow the resolving limit of an exposure apparatus to be exhibited, and therefore are used as pattern transfer materials. However, these materials are insufficient in sensitivity and are required to be further improved.

Examples of factors making material development for EUV lithography difficult include a small number of photons in EUV exposure. The energy of EUV is much higher than that of ArF excimer laser light, and the number of photons in EUV exposure is one-fourteenth that of ArF exposure. Furthermore, the dimension of patterns formed in EUV exposure is less than half that in ArF exposure. Therefore, EUV exposure is easily affected by the variation in number of photons. The variation in number of photons in the region of radiation light at extremely short wavelengths is shot noise as a physical phenomenon, and the influence of this shot noise cannot be eliminated. Therefore, so-called probability theory (Stochastics) attracts attention. Although the influence of shot noise cannot be eliminated, how to reduce this influence is discussed. There is observed a phenomenon in which the influence of shot noise leads to not only increases in dimension uniformity (CDU) and line width roughness (LWR), but also blocking of holes at a probability of one several millionth. Such blocking of holes causes electric conduction failure not to allow for transistor operations, and therefore adversely affects the performance of the entire device. In a case where practical sensitivity is considered, resist compositions mainly containing PMMA or HSQ are largely affected by Stochastics, and cannot achieve the desired resolving performance.

With respect to methods for reducing the influence of shot noise by resists, introduction of elements with large absorption of EUV light attracts attention. Patent Document 1 proposes a chemically amplified resist composition containing an iodine atom with large absorption of EUV light. However, as described above, chemically amplified resist compositions cannot realize excellent resolving performance in EUV lithography in which processing dimensions will be hereafter increasingly miniaturized. In particular, in the case of line-and-space patterns, as pattern dimensions are smaller, collapse of the patterns or disconnecting is remarkably increased, and therefore reductions in such collapse and disconnecting lead to an improvement in limit resolvability.

Patent Document 2 proposes a negative type resist composition in which a tin compound is used. This composition mainly contains a tin element with large absorption of EUV light, and therefore Stochastics can be improved and high sensitivity/high resolvability can be realized. However, so-called such metal resists have many problems such as insufficient solubility in solvents for resists, storage stability, and defects due to residues after etching. Furthermore, metal resists are mainly negative type resists that are made insoluble in developers by formation of exposed sections into metal oxides, and, when applied to patterning of contact holes, require additional reverse process steps and also have concerns about cost.

### CITATION LIST

### Patent Literature

Patent Document 1: JP 2018-5224 A
Patent Document 2: JP 2021-503482 A

### Non Patent Literature

Non Patent Document 1: SPIE Vol. 5039 p1 (2003)
Non Patent Document 2: SPIE Vol. 6520 p65203L-1 (2007)

### SUMMARY OF INVENTION

### Technical Problem

The present invention has been made in view of the above circumstances, and an object thereof is to provide a laminate including a resist film obtained from a non-chemically amplified resist composition and a silicon-containing resist underlayer film located under the resist film, which is applicable to photolithography with a high energy line, in particular, electron beam (EB) lithography and EUV lithography and which is excellent in sensitivity and limit resolvability, as well as a patterning process on an upper layer of the laminate.

### Solution to Problem

In order to solve the above problems, the present invention provides a laminate including:
a substrate;
a silicon-containing resist underlayer film obtained from a silicon-containing resist underlayer film composition that contains a thermally crosslinkable polysiloxane containing any one or more from repeating units represented by the following general formulae (1) to (3) and any one or more from repeating units represented by the following general formulae (4) to (6); and
a resist film obtained from a resist composition that contains at least one hypervalent iodine compound selected from a hypervalent iodine compound represented by the following formula (7), a hypervalent iodine compound represented by the following formula (8) and a hypervalent iodine compound represented by the following formula (9), a carboxy group-containing compound, and a solvent;
in the listed order:

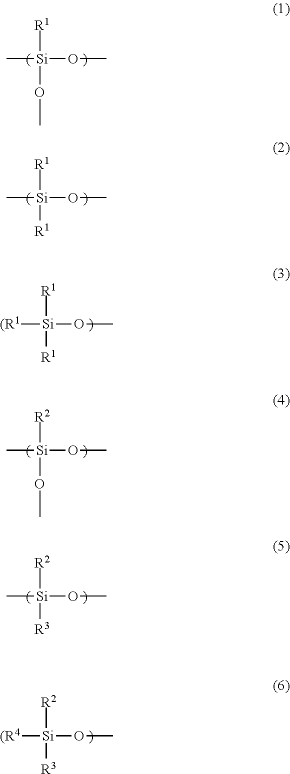

wherein R¹ is an organic group having a carboxy group or an organic group having a carboxyl group substituted with an acid-labile group, and R², R³ and R⁴ are the same as or different from each other, and are each a monovalent organic group having 1 to 30 carbon atoms;

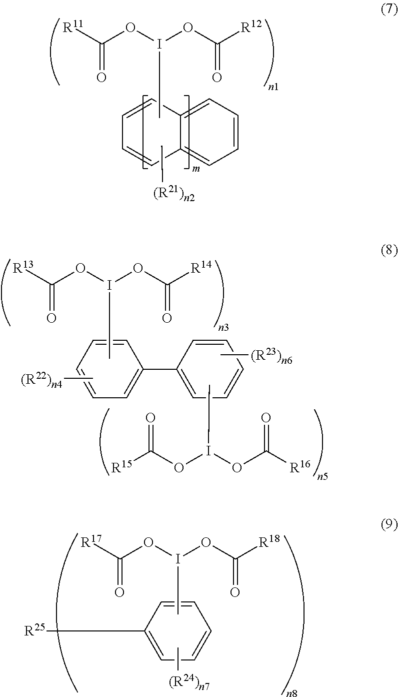

wherein m is 0, 1 or 2; when m is 0, n1 is 1, 2 or 3, n2 is 0, 1, 2, 3, 4 or 5, and 1≤n1+n2≤6 is satisfied; when m is 1, n1 is 1, 2 or 3, n2 is 0, 1, 2, 3, 4, 5, 6 or 7, and 1≤n1+n2≤8 is satisfied; when m is 2, n1 is 1, 2 or 3, n2 is 0, 1, 2, 3, 4, 5, 6, 7, 8 or 9, and 1≤n1+n2≤10 is satisfied; n3 is 1 or 2; n4 is 0, 1, 2, 3 or 4; provided that 1≤n3+n4≤5 is satisfied; n5 is 1 or 2; n6 is 0, 1, 2, 3 or 4; provided that 1≤n5+n6≤5 is satisfied; n7 is 0, 1, 2, 3 or 4; and n8 is 1, 2, 3 or 4;
R¹¹ to R¹⁸ are each independently a halogen atom, or a hydrocarbyl group having 1 to 10 carbon atoms and optionally containing a heteroatom; and R¹¹ and R¹², R¹³ and R¹⁴, R¹⁵ and R¹⁶, or R¹⁷ and R¹⁸ are optionally bound to each other to form a ring together with carbon atoms to which these are bound and an atom between the carbon atoms;
R²¹ to R²⁴ are each independently a halogen atom, or a hydrocarbyl group having 1 to 40 carbon atoms and optionally containing a heteroatom; when n2 is 2 or more, R²¹s are the same as or different from each other, and plural R²¹s are optionally bound to each other to form a ring together with carbon atoms in an aromatic ring to which these are bound; when n4 is 2 or more, R²²s are the same as or different from each other, and plural R²²s are optionally bound to each other to form a ring together with carbon atoms in an aromatic ring to which these are bound; when n6 is 2 or more, R²³s are the same as or different from each other, and plural R²³s are optionally bound to each other to form a ring together with carbon atoms in an aromatic ring to which these are bound; and when n7 is 2 or more, R²⁴s are the same as or different from each other, and plural R²⁴s are optionally bound to each other to form a ring together with carbon atoms in an aromatic ring to which these are bound; and
R²⁵ is an (n8)-valent hydrocarbon group having 1 to 40 carbon atoms or an (n8)-valent heterocyclic group having 2 to 40 carbon atoms, and when n8 is 2, R²⁵ is optionally an ether bond, a carbonyl group, an azo group, a thioether bond, a carbonate bond, a carbamate bond, a sulfinyl group, a sulfonyl group or a thioketone bond; and some or all of hydrogen atoms in the (n8)-valent hydrocarbon group or the (n8)-valent heterocyclic group are each optionally substituted by a group containing a heteroatom, some of —CH₂— in the (n8)-valent hydrocarbon group are each optionally substituted by a group containing a heteroatom, and R²⁴ and R²⁵ are optionally bound to each other to form a ring together with carbon atoms to which these are bound and an atom between the carbon atoms.

Such a laminate is applicable to photolithography with a high energy line, in particular, electron beam (EB) lithography and EUV lithography, and is excellent in sensitivity and limit resolvability. The resist composition of the present invention has an iodine atom with high absorbability of EUV light, and can allow shot noise to be reduced and allow higher resolvability and lower LWR to be achieved, in particular, in EUV lithography.

In this case, the laminate preferably includes a resist underlayer film between the substrate and the silicon-containing resist underlayer film.

Such a laminate is extremely effective for microfabrication involving precise transfer of a pattern on a resist film with excellent resolution, to a substrate.

The silicon-containing resist underlayer film composition preferably contains a crosslinking catalyst for siloxane polymerization (Xc), an alcohol-based organic solvent, and water.

Such a silicon-containing resist underlayer film composition is a silicon-containing resist underlayer film composition that is stable and excellent in handleability, in addition, it is suitable in terms of pattern formability and strength of a silicon-containing resist underlayer film produced, as a resist film.

The carboxy group-containing compound in the resist composition is preferably a polymer containing a repeating unit represented by the following formula (10) or a compound represented by the following formula (11):

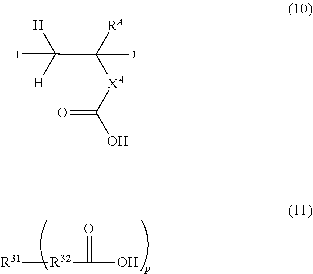

wherein R^{A} is a hydrogen atom, a halogen atom, a methyl group or a trifluoromethyl group;
X^{A} is a single bond, a phenylene group, a naphthylene group or *—C(═O)—O—X^{A1}—; X^{A1} is a saturated hydrocarbylene group having 1 to 10 carbon atoms, a phenylene group or a naphthylene group, and the saturated hydrocarbylene group optionally contains a hydroxy group, an ether bond, an ester bond or a lactone ring; and * represents a point of attachment to a carbon atom in a backbone;
p is 1, 2, 3 or 4;
R³¹ is a p-valent hydrocarbon group having 1 to 40 carbon atoms or a p-valent heterocyclic group having 2 to 40 carbon atoms, and when p is 2, R³¹ is optionally an ether bond, a carbonyl group, an azo group, a thioether bond, a carbonate bond, a carbamate bond, a sulfinyl group or a sulfonyl group; and some or all of hydrogen atoms in the p-valent hydrocarbon group or the p-valent heterocyclic group are each optionally substituted by a group containing a heteroatom, and some of —CH₂— in the p-valent hydrocarbon group are each optionally substituted by a group containing a heteroatom; and
R³² is a single bond or a hydrocarbylene group having 1 to 10 carbon atoms, some or all of hydrogen atoms in the hydrocarbylene group are each optionally substituted by a group containing a heteroatom, and some of —CH₂— in the hydrocarbylene group are each optionally substituted by a group containing a heteroatom; and when p is 2 to 4, R³²s are the same as or different from each other.

As long as the carboxy group-containing compound has such a structure, it is high in solubility in a solvent to easily be made to a composition, and has a rigid skeleton and therefore can allow high etching resistance to be achieved.

Next, the present invention provides a process for manufacturing a laminate, including the steps of:
forming a resist underlayer film on a substrate;
forming a silicon-containing resist underlayer film from a silicon-containing resist underlayer film composition that contains a thermally crosslinkable polysiloxane containing any one or more from repeating units represented by the following general formulae (1) to (3) and any one or more from repeating units represented by the following general formulae (4) to (6) on the resist underlayer film; and
applying a resist composition containing at least one hypervalent iodine compound selected from a hypervalent iodine compound represented by the following formula (7), a hypervalent iodine compound represented by the following formula (8) and a hypervalent iodine compound represented by the following formula (9), a carboxy group-containing compound, and a solvent, to the silicon-containing resist underlayer film, and performing a heating treatment, to form a resist film:

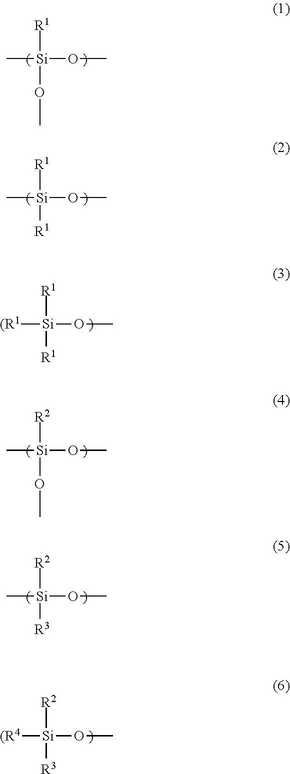

wherein R¹ is an organic group having a carboxy group or an organic group having a carboxyl group substituted with an acid-labile group, and R², R³ and R⁴ are the same as or different from each other, and are each a monovalent organic group having 1 to 30 carbon atoms;

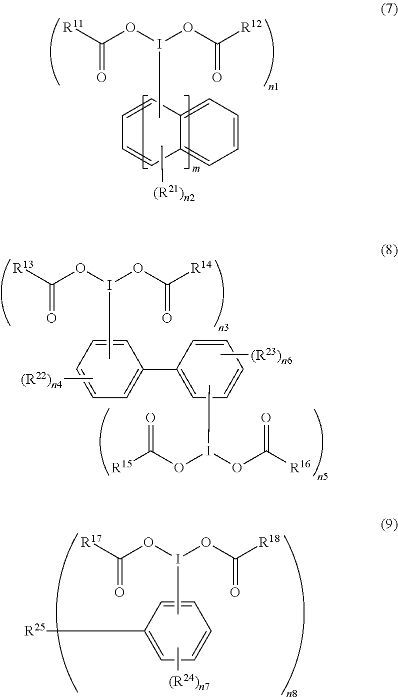

wherein m is 0, 1 or 2; when m is 0, n1 is 1, 2 or 3, n2 is 0, 1, 2, 3, 4 or 5, and 1≤n1+n2≤6 is satisfied; when m is 1, n1 is 1, 2 or 3, n2 is 0, 1, 2, 3, 4, 5, 6 or 7, and 1≤n1+n2≤8 is satisfied; when m is 2, n1 is 1, 2 or 3, n2 is 0, 1, 2, 3, 4, 5, 6, 7, 8 or 9, and 1≤n1+n2≤10 is satisfied; n3 is 1 or 2; n4 is 0, 1, 2, 3 or 4; provided that 1≤n3+n4≤5 is satisfied; n5 is 1 or 2; n6 is 0, 1, 2, 3 or 4; provided that 1≤n5+n6≤5 is satisfied; n7 is 0, 1, 2, 3 or 4; and n8 is 1, 2, 3 or 4;
R¹¹ to R¹⁸ are each independently a halogen atom, or a hydrocarbyl group having 1 to 10 carbon atoms and optionally containing a heteroatom; and R¹¹ and R¹², R¹³ and R¹⁴, R¹⁵ and R¹⁶, or R¹⁷ and R¹⁸ are optionally bound to each other to form a ring together with carbon atoms to which these are bound and an atom between the carbon atoms;
R²¹ to R²⁴ are each independently a halogen atom, or a hydrocarbyl group having 1 to 40 carbon atoms and optionally containing a heteroatom; when n2 is 2 or more, R²¹s are the same as or different from each other, and plural R²¹s are optionally bound to each other to form a ring together with carbon atoms in an aromatic ring to which these are bound; when n4 is 2 or more, R²²s are the same as or different from each other, and plural R²²s are optionally bound to each other to form a ring together with carbon atoms in an aromatic ring to which these are bound; when n6 is 2 or more, R²³s are the same as or different from each other, and plural R²³s are optionally bound to each other to form a ring together with carbon atoms in an aromatic ring to which these are bound; and when n7 is 2 or more, R²⁴s are the same as or different from each other, and plural R²⁴s are optionally bound to each other to form a ring together with carbon atoms in an aromatic ring to which these are bound; and
R²⁵ is an (n8)-valent hydrocarbon group having 1 to 40 carbon atoms or an (n8)-valent heterocyclic group having 2 to 40 carbon atoms, and when n8 is 2, R²⁵ is optionally an ether bond, a carbonyl group, an azo group, a thioether bond, a carbonate bond, a carbamate bond, a sulfinyl group, a sulfonyl group or a thioketone bond; and some or all of hydrogen atoms in the (n8)-valent hydrocarbon group or the (n8)-valent heterocyclic group are each optionally substituted by a group containing a heteroatom, some of —CH₂— in the (n8)-valent hydrocarbon group are each optionally substituted by a group containing a heteroatom, and R²⁴ and R²⁵ are optionally bound to each other to form a ring together with carbon atoms to which these are bound and an atom between the carbon atoms.

Thus, a resist film with excellent resolution can be formed by forming a silicon-containing resist underlayer film and forming thereon a resist film obtained from a resist composition mainly containing a hypervalent iodine compound and a carboxy group-containing compound, and thus a laminate extremely effective for precise microfabrication can be produced.

In this case, the resist underlayer film can be formed by applying an underlayer film-forming material to the substrate and performing a heating treatment.

The resist underlayer film can also be formed by a CVD process or an ALD process.

Furthermore, the carboxy group-containing compound can be a polymer containing a repeating unit represented by the following formula (10) or a compound represented by the following formula (11):

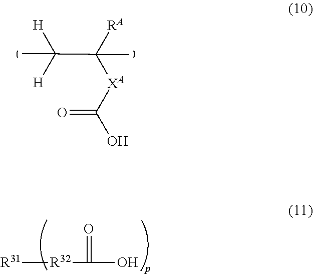

wherein R^{A} is a hydrogen atom, a halogen atom, a methyl group or a trifluoromethyl group;
X^{A} is a single bond, a phenylene group, a naphthylene group or *—C(═O)—O—X^{A1}—; X^{A1} is a saturated hydrocarbylene group having 1 to 10 carbon atoms, a phenylene group or a naphthylene group, and the saturated hydrocarbylene group optionally contains a hydroxy group, an ether bond, an ester bond or a lactone ring; and * represents a point of attachment to a carbon atom in a backbone;
p is 1, 2, 3 or 4;
R³¹ is a p-valent hydrocarbon group having 1 to 40 carbon atoms or a p-valent heterocyclic group having 2 to 40 carbon atoms, and when p is 2, R³¹ is optionally an ether bond, a carbonyl group, an azo group, a thioether bond, a carbonate bond, a carbamate bond, a sulfinyl group or a sulfonyl group; and some or all of hydrogen atoms in the p-valent hydrocarbon group or the p-valent heterocyclic group are each optionally substituted by a group containing a heteroatom, and some of —CH₂— in the p-valent hydrocarbon group are each optionally substituted by a group containing a heteroatom; and
R³² is a single bond or a hydrocarbylene group having 1 to 10 carbon atoms, some or all of hydrogen atoms in the hydrocarbylene group are each optionally substituted by a group containing a heteroatom, and some of —CH₂— in the hydrocarbylene group are each optionally substituted by a group containing a heteroatom; and when p is 2 to 4, R³²s are the same as or different from each other.

Such a manufacturing process in which a composition containing a carboxy group-containing compound of a specified structure is used can preferably manufacture a laminated product of which the composition is stable and which has high etching resistance.

The present invention provides a patterning process including the steps of: exposing the resist film of the laminate, to an i-line, a KrF excimer laser, an ArF excimer laser, an electron beam or an extreme-ultraviolet ray; and developing the exposed resist film with a developer.

In the present invention, a fine pattern high in sensitivity and high in resolution can be formed by exposurring with a high energy line and developing with a developer to a resist film.

The developer can be an organic solvent.

The resist film in the present invention is a stiff film by the effects of the hypervalent iodine compound and the carboxylic acid compound and is excellent in etching resistance and developer resistance to a solvent developer, and therefore is suitably used in a patterning process involving performing development with a developer in which an organic solvent is used.

### Advantageous Effects of Invention

The laminate of the present invention exhibits both high sensitivity and high resolvability, in particular, in an i-line, a KrF excimer laser, an ArF excimer laser, EB lithography, and EUV lithography, and is extremely effective for formation of a fine pattern.

### DESCRIPTION OF EMBODIMENTS

As described above, there has been a demand for development of a material for application to lithography forming a fine pattern which is excellent in dimension uniformity (CDU), which is small in line width roughness (LWR), which hardly causes a phenomenon of blocking of fine holes, and which is high in sensitivity and highly resolved.

In order to achieve the above objects, there have been made intensive studies, and as a result, it has been found that a resist film exhibiting excellent resolving power is provided by laying a desired silicon-containing resist underlayer film, under a resist film obtained from a resist composition mainly containing predetermined hypervalent iodine compound and carboxy group-containing compound, and this film is extremely effective for precise microfabrication, and thus the present invention has been completed.

The laminate of the present invention is extremely useful as a laminate for multilayer resist processes including a three-layer resist process in which a resist underlayer film and a silicon-containing resist underlayer film are used.

Hereinafter, the present invention is described in detail, but the present invention is not limited thereto.

Specifically, the present invention relates to a laminate including a substrate, a silicon-containing resist underlayer film, and a resist film in the listed order.

### [Laminate]

The laminate of the present invention includes:
a substrate;
a silicon-containing resist underlayer film obtained from a silicon-containing resist underlayer film composition that contains a thermally crosslinkable polysiloxane containing any one or more from repeating units represented by the following general formulae (1) to (3) and any one or more from repeating units represented by the following general formulae (4) to (6); and
a resist film obtained from a resist composition that contains at least one hypervalent iodine compound selected from a hypervalent iodine compound represented by the following formula (7), a hypervalent iodine compound represented by the following formula (8) and a hypervalent iodine compound represented by the following formula (9), a carboxy group-containing compound, and a solvent;
in the listed order:

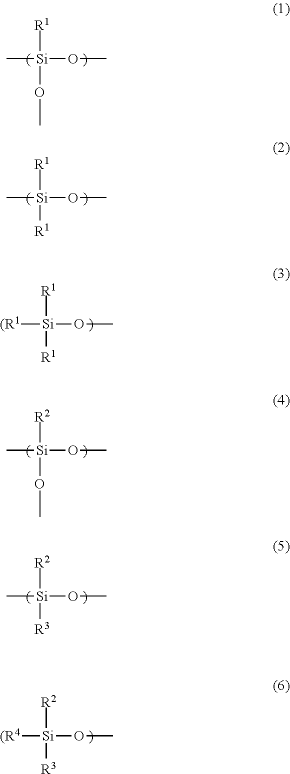

wherein R¹ is an organic group having a carboxy group or an organic group having a carboxyl group substituted with an acid-labile group, and R², R³ and R⁴ are the same as or different from each other, and are each a monovalent organic group having 1 to 30 carbon atoms;

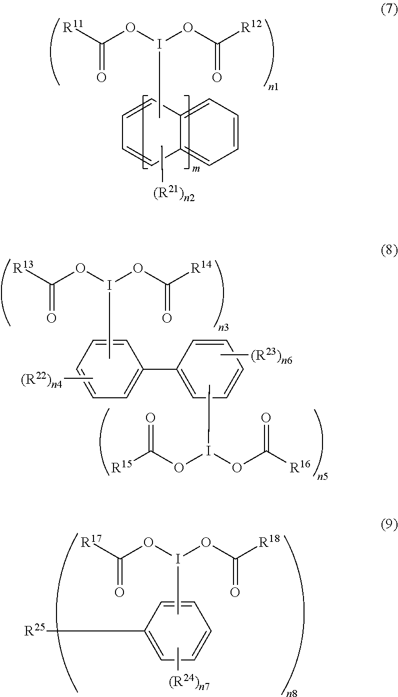

wherein m is 0, 1 or 2; when m is 0, n1 is 1, 2 or 3, n2 is 0, 1, 2, 3, 4 or 5, and 1≤n1+n2≤6 is satisfied; when m is 1, n1 is 1, 2 or 3, n2 is 0, 1, 2, 3, 4, 5, 6 or 7, and 1≤n1+n2≤8 is satisfied; when m is 2, n1 is 1, 2 or 3, n2 is 0, 1, 2, 3, 4, 5, 6, 7, 8 or 9, and 1≤n1+n2≤10 is satisfied; n3 is 1 or 2; n4 is 0, 1, 2, 3 or 4; provided that 1≤n3+n4≤5 is satisfied; n5 is 1 or 2; n6 is 0, 1, 2, 3 or 4; provided that 1≤n5+n6≤5 is satisfied; n7 is 0, 1, 2, 3 or 4; and n8 is 1, 2, 3 or 4;
R¹¹ to R¹⁸ are each independently a halogen atom, or a hydrocarbyl group having 1 to 10 carbon atoms and optionally containing a heteroatom; and R¹¹ and R¹², R¹³ and R¹⁴, R¹⁵ and R¹⁶, or R¹⁷ and R¹⁸ are optionally bound to each other to form a ring together with carbon atoms to which these are bound and an atom between the carbon atoms;
R²¹ to R²⁴ are each independently a halogen atom, or a hydrocarbyl group having 1 to 40 carbon atoms and optionally containing a heteroatom; when n2 is 2 or more, R²¹s are the same as or different from each other, and plural R²¹s are optionally bound to each other to form a ring together with carbon atoms in an aromatic ring to which these are bound; when n4 is 2 or more, R²²s are the same as or different from each other, and plural R²²s are optionally bound to each other to form a ring together with carbon atoms in an aromatic ring to which these are bound; when n6 is 2 or more, R²³s are the same as or different from each other, and plural R²³s are optionally bound to each other to form a ring together with carbon atoms in an aromatic ring to which these are bound; and when n7 is 2 or more, R²⁴s are the same as or different from each other, and plural R²⁴s are optionally bound to each other to form a ring together with carbon atoms in an aromatic ring to which these are bound; and
R²⁵ is an (n8)-valent hydrocarbon group having 1 to 40 carbon atoms or an (n8)-valent heterocyclic group having 2 to 40 carbon atoms, and when n8 is 2, R²⁵ is optionally an ether bond, a carbonyl group, an azo group, a thioether bond, a carbonate bond, a carbamate bond, a sulfinyl group, a sulfonyl group or a thioketone bond; and some or all of hydrogen atoms in the (n8)-valent hydrocarbon group or the (n8)-valent heterocyclic group are each optionally substituted by a group containing a heteroatom, some of —CH₂— in the (n8)-valent hydrocarbon group are each optionally substituted by a group containing a heteroatom, and R²⁴ and R²⁵ are optionally bound to each other to form a ring together with carbon atoms to which these are bound and an atom between the carbon atoms.

Hereinafter, the substrate, the silicon-containing resist underlayer film, and the resist film are described in the listed order.

### [Substrate]

The substrate is preferably a substrate (Si, SiO₂, SiN, SiON, TiN, WSi, BPSG, SOG, or the like) for integrated circuit manufacturing, or a substrate (Cr, CrO, CrON, MoSi₂, SiO₂, or the like) for mask circuit manufacturing.

[Silicon-containing resist underlayer film]

The silicon-containing resist underlayer film is obtained from a silicon-containing resist underlayer film composition containing a thermally crosslinkable polysiloxane of a specified structure described below.

[Thermally crosslinkable polysiloxane]

The thermally crosslinkable polysiloxane in the present invention is described below.

The thermally crosslinkable polysiloxane in the present invention is a thermally crosslinkable polysiloxane containing any one or more from repeating units represented by the following general formulae (1) to (3), and any one or more from repeating units represented by the following general formulae (4) to (6):

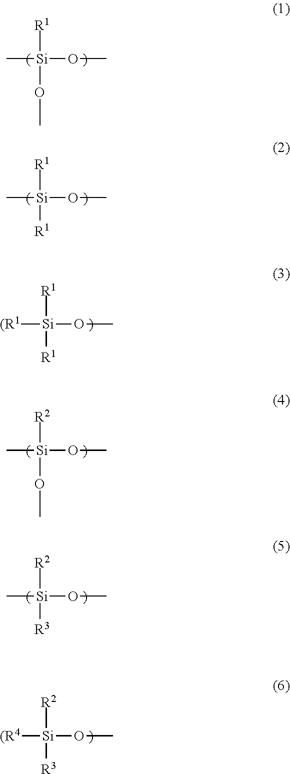

wherein R¹ is an organic group having a carboxy group or an organic group having a carboxyl group substituted with an acid-labile group, and R², R³ and R⁴ are the same as or different from each other, and are each a monovalent organic group having 1 to 30 carbon atoms.

Examples of R¹ in the general formulae (1) to (3) include the following, but not limited thereto. In the following formulae, (Si) is designated in order to indicate a binding position with Si.

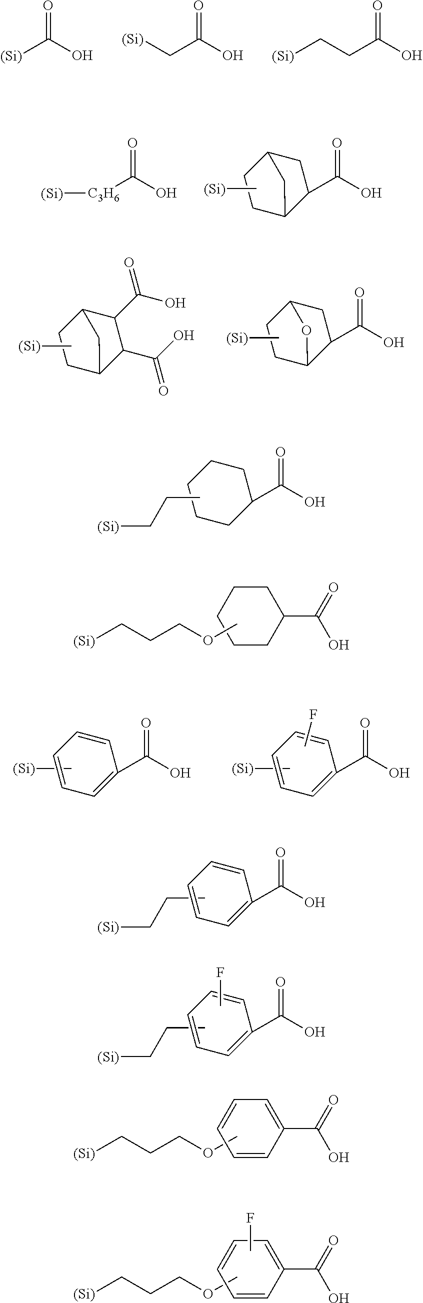

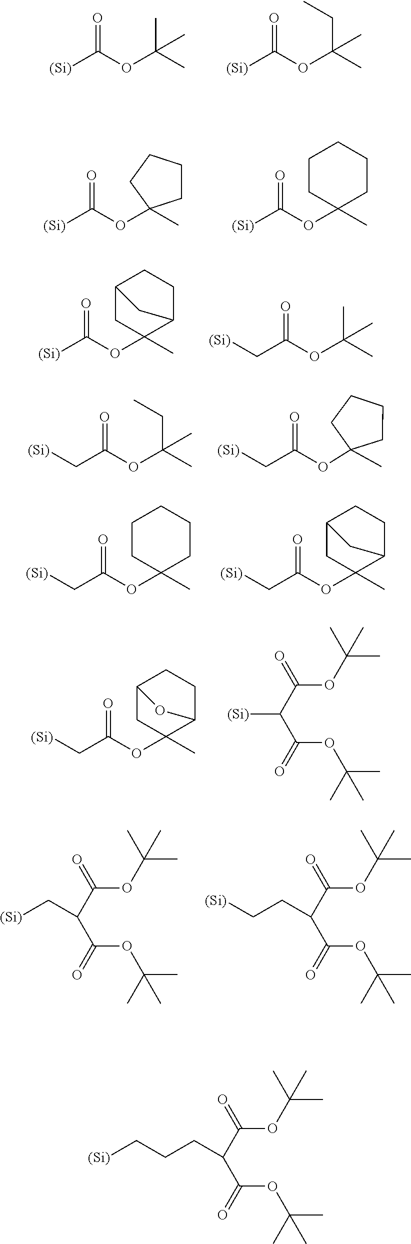

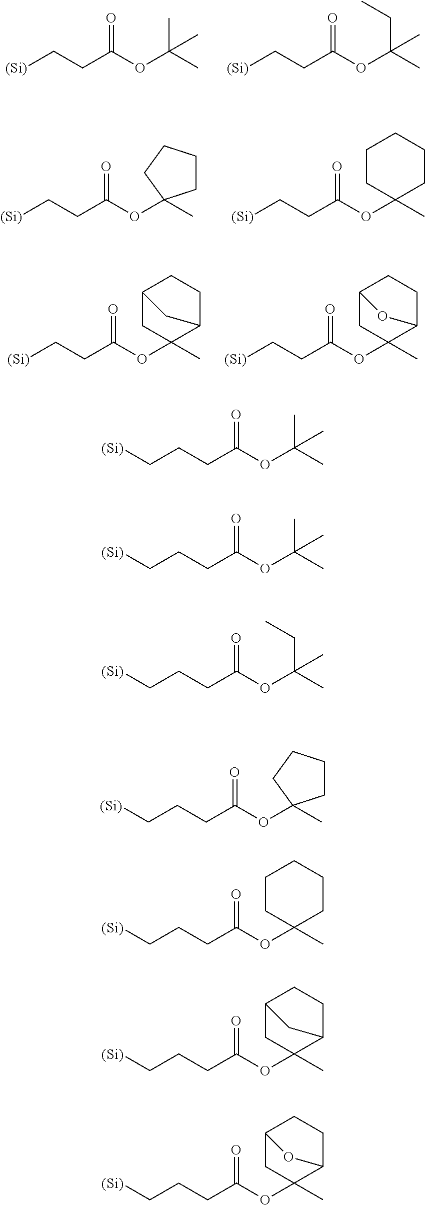

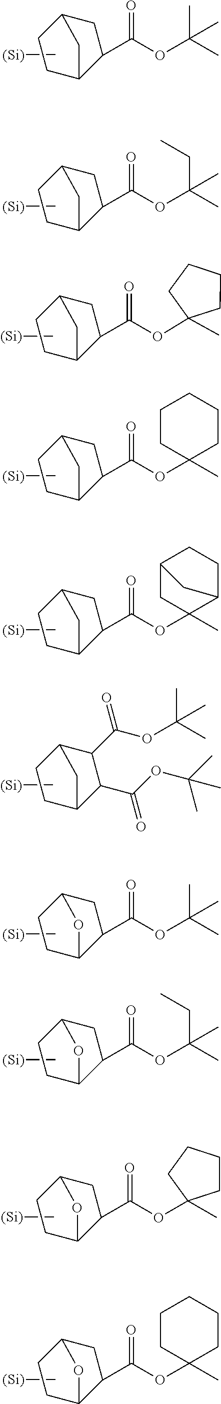

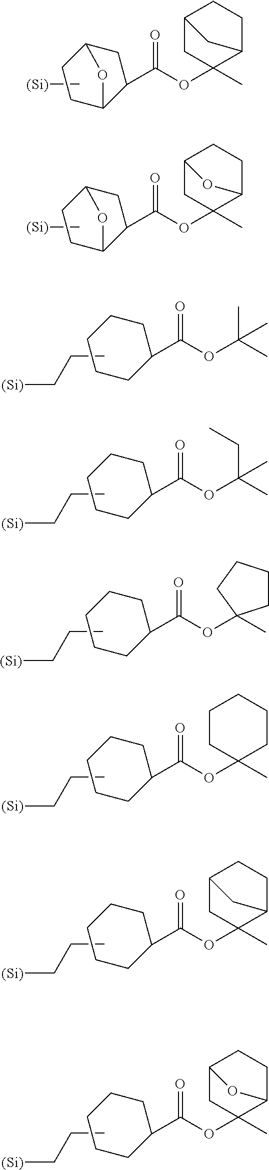

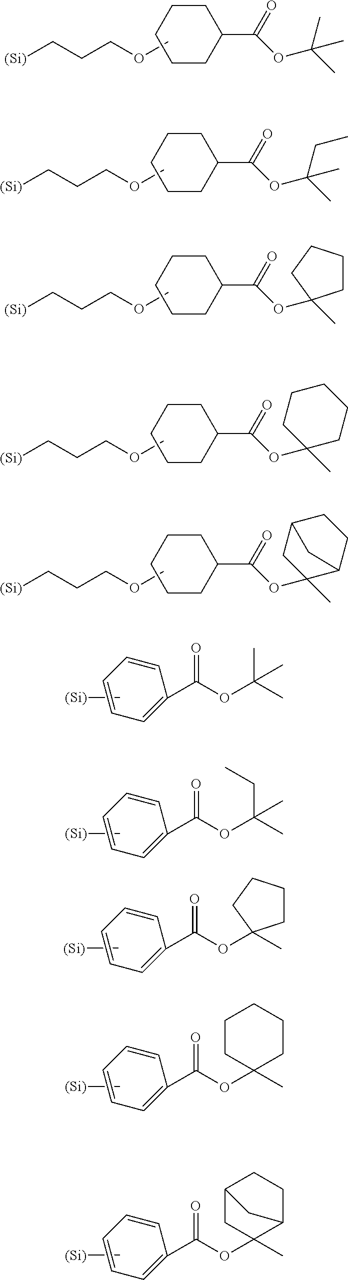

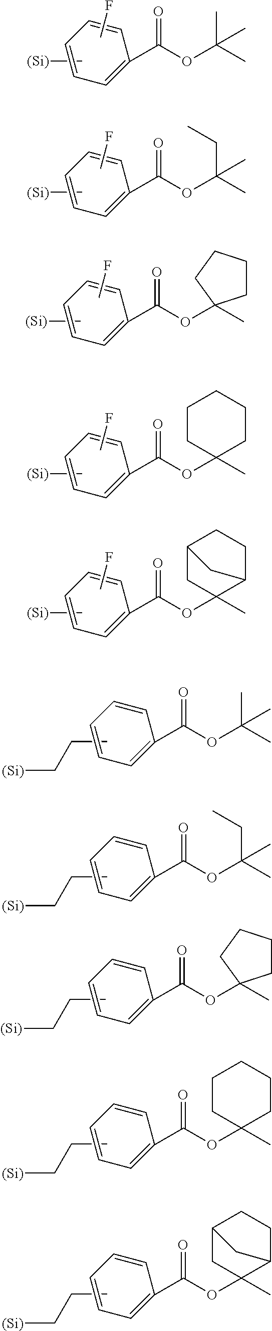

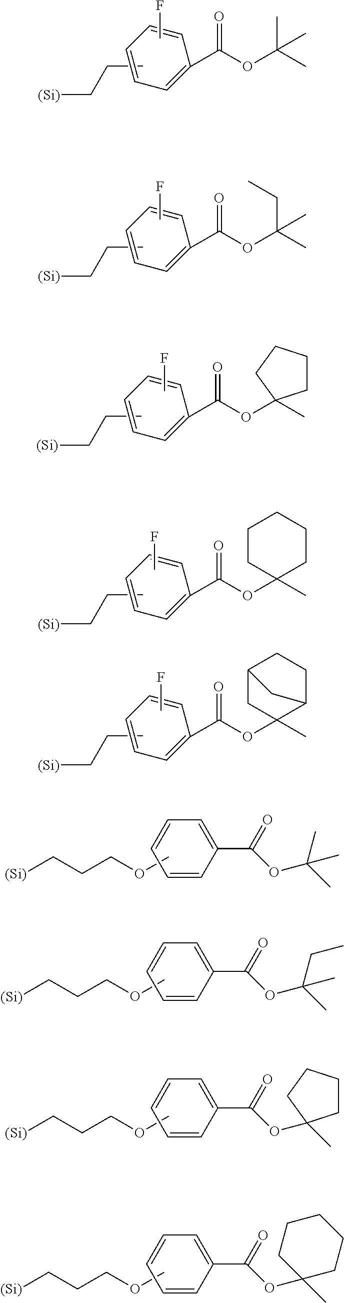

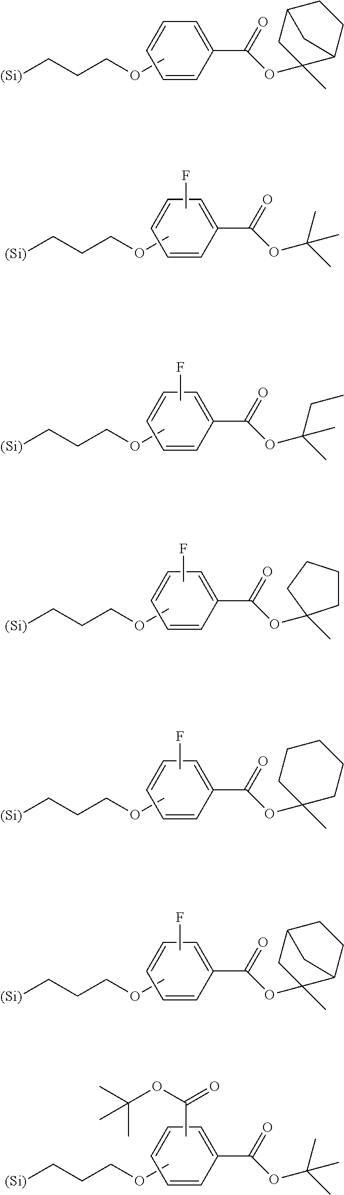

In the formulae, R², R³ and R⁴ are the same as or different from each other, and are each a monovalent organic group having 1 to 30 carbon atoms. R² and R³ are each preferably a saturated or unsaturated organic group having 1 to 20 carbon atoms and optionally having a substituent. Examples of the organic group include a substituted or non-substituted linear, branched or cyclic alkyl group having 1 to 20 carbon atoms, a substituted or non-substituted linear, branched or cyclic alkenyl group having 2 to 20 carbon atoms, and a substituted or non-substituted aryl group having 6 to 20 carbon atoms. Specific examples thereof include a methyl group, an ethyl group, a n-propyl group, an i-propyl group, a n-butyl group, an i-butyl group, a sec-butyl group, a t-butyl group, a n-pentyl group, and a n-hexyl group; a vinyl group, an allyl group, and a propenyl group; and a phenyl group and a tolyl group.

Other examples of the organic group represented by R², R³, and R⁴ can include an organic group having one or more carbon-oxygen single bonds or carbon-oxygen double bonds. Specifically, an organic group is exemplified which has one or more groups selected from an ether bond, an ester bond, an alkoxy group, a hydroxy group, and the like, excluding a carboxy group. Examples of this can include a group represented by the following general formula (Sm—R).

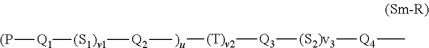

(In the general formula (Sm—R), P is a hydrogen atom, a cyclic ether group, a hydroxy group, an alkoxy group having 1 to 4 carbon atoms, an alkylcarbonyloxy group having 2 to 6 carbon atoms, or an alkyl carbonyl group having 2 to 6 carbon atoms, Q₁, Q₂, Q₃, and Q₄ are each independently—CqH(2q-p)Pp- (wherein P is the same as described above, p is an integer of 0 to 3, and q is an integer of 0 to 10 (wherein q=0 means a single bond.).), u is an integer of 0 to 3, and Si and S₂ each independently represent —O—, —CO—, —OCO—, —COO— or —OCOO—. v1, v2, and v3 each independently represent 0 or 1. T is a divalent group including a divalent atom other than carbon, an alicyclic ring, an aromatic ring or a heterocycle.)

Examples of an alicyclic ring, aromatic ring or heterocycle optionally containing a heteroatom such as an oxygen atom, as T, are shown below. The position of binding with Q₂ and Q₃ in T is not particularly limited, and can be appropriately selected in consideration of reactivity due to a steric factor, availability of a commercially available reagent used for reaction, and/or the like.

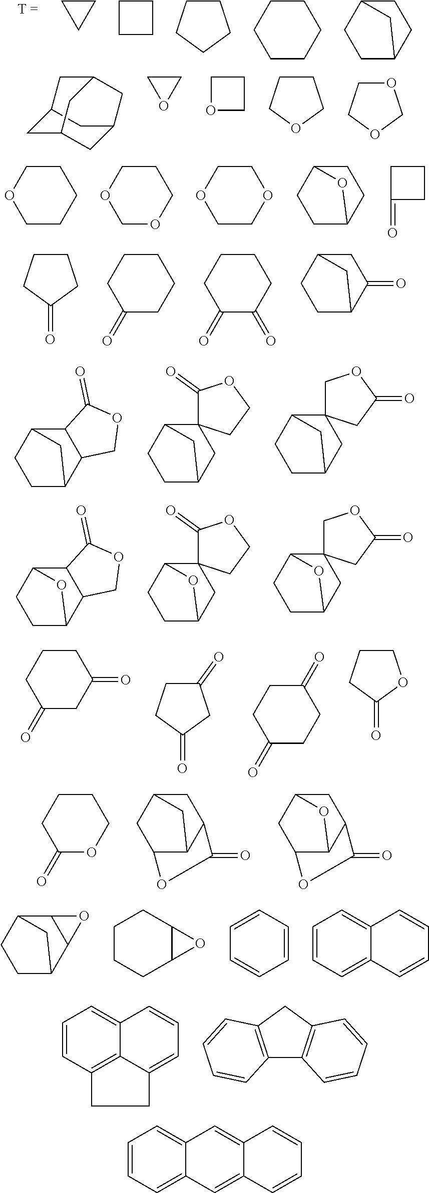

Preferred examples of the organic group having one or more carbon-oxygen single bonds or carbon-oxygen double bonds in the general formula (Sm—R) include the following groups. In the following formulae, (Si) is designated in order to indicate a binding position with Si.

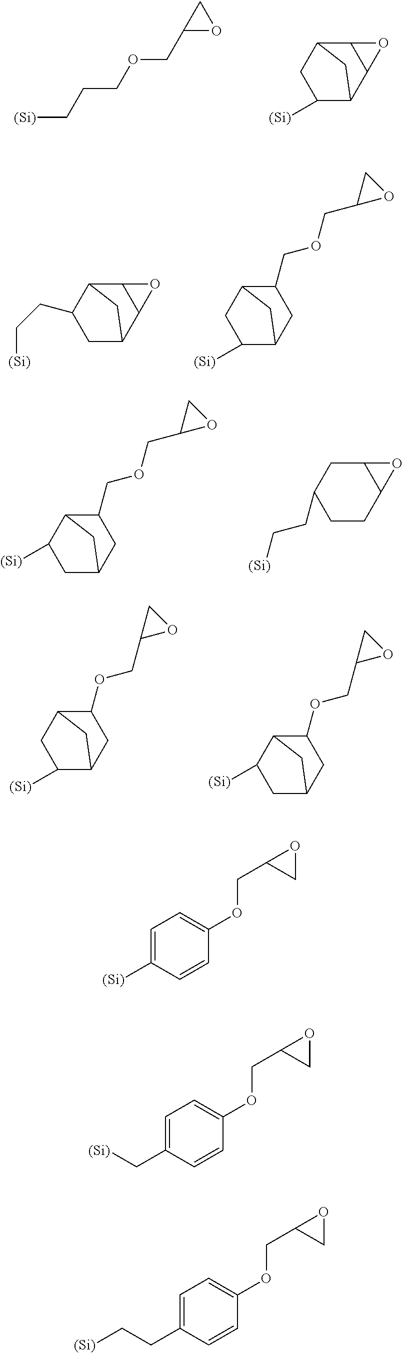

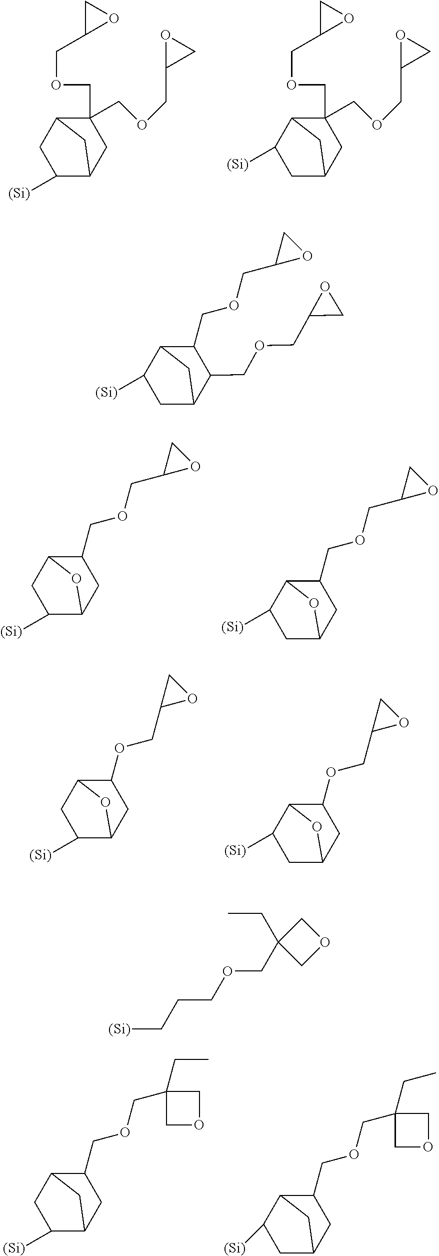

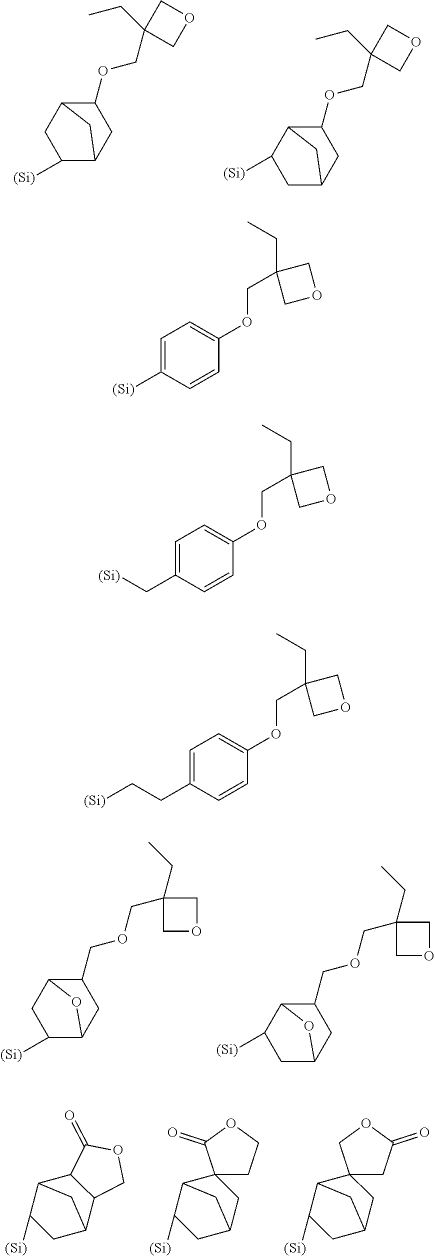

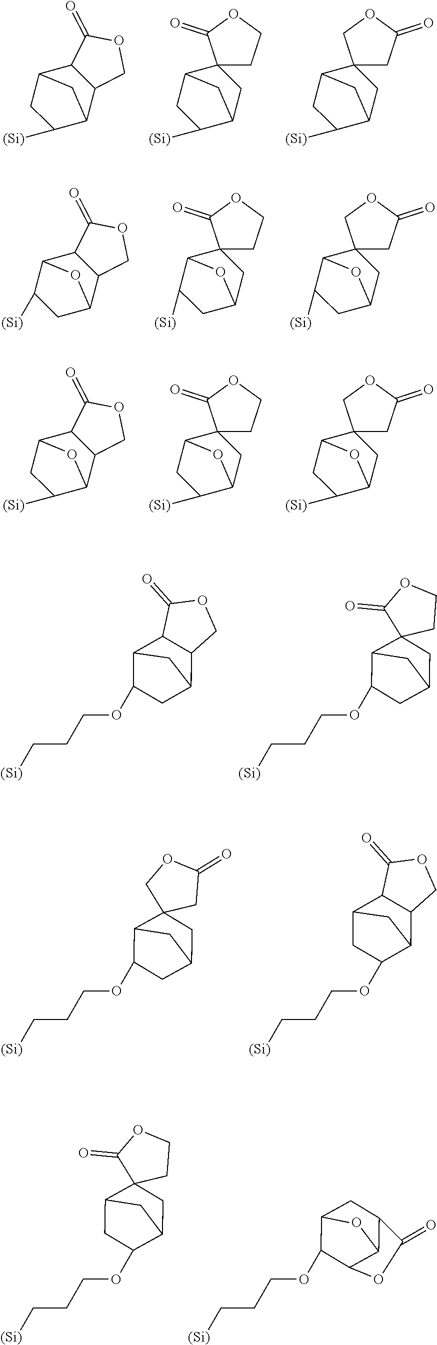

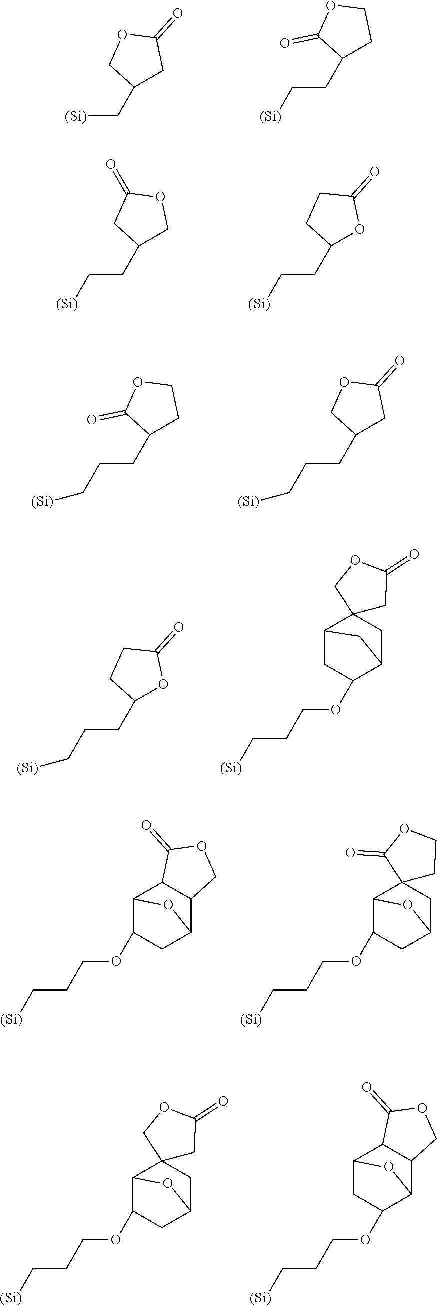

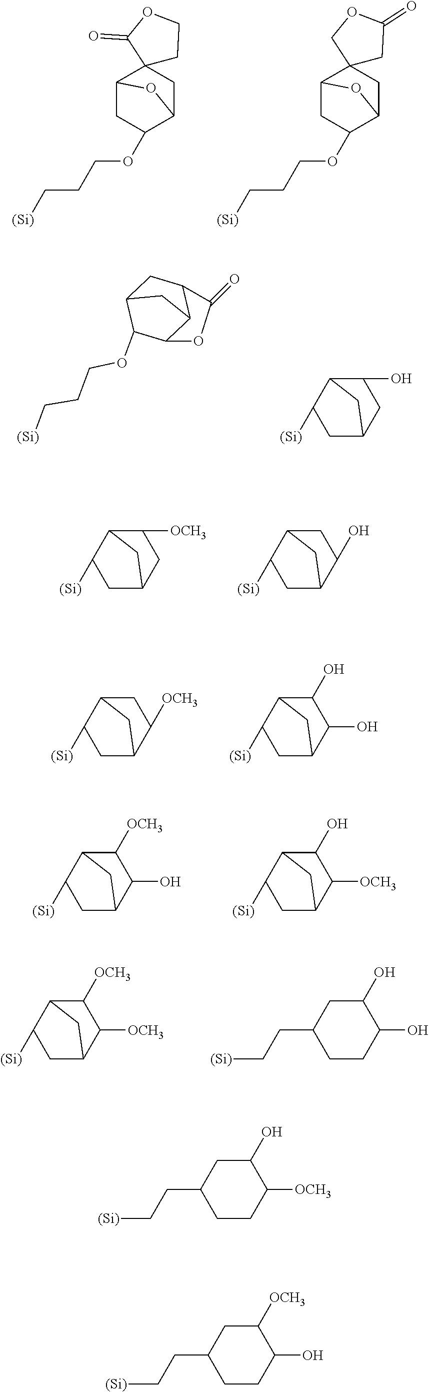

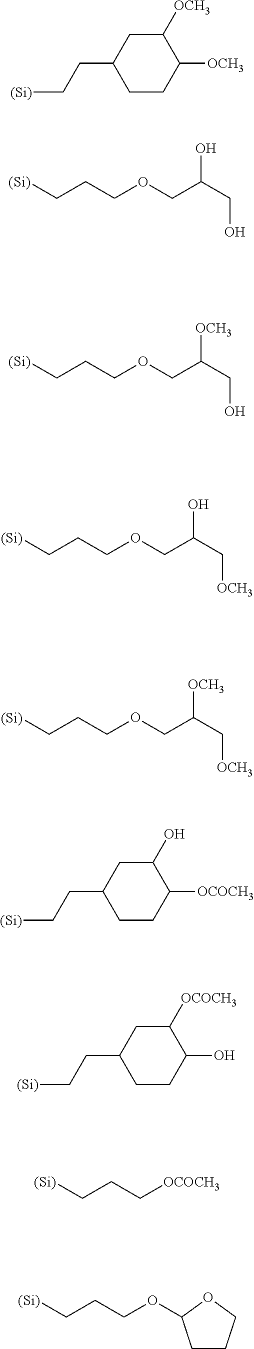

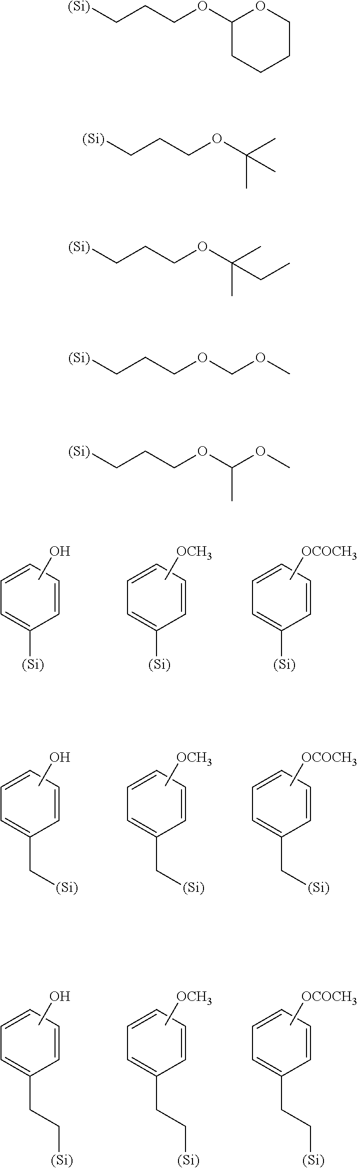

An organic group containing a silicon-silicon bond can also be used as an example of the organic group of R², R³, and R⁴. Specifically, the following can be exemplified.

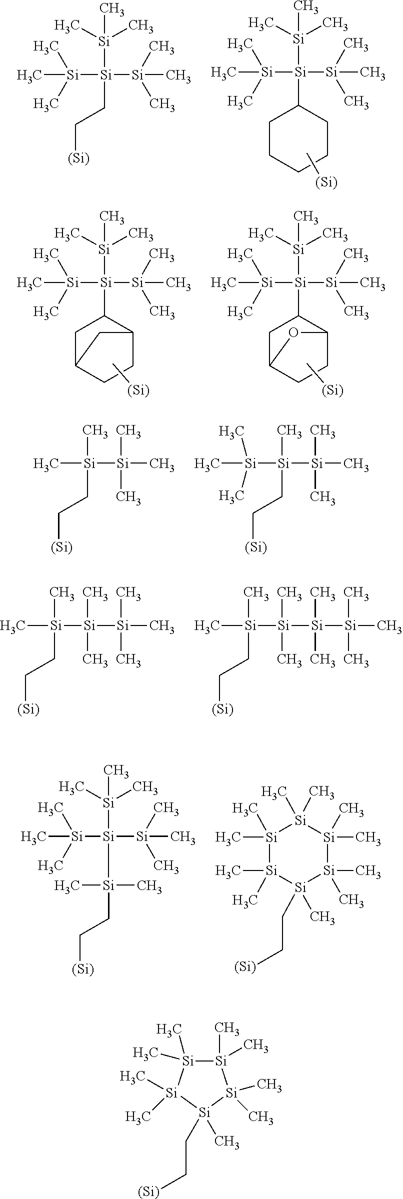

Furthermore, an organic group having a fluorine atom can also be used as an example of the organic group of R², R³, and R⁴. Specific examples can include organic groups obtained from silicon compounds shown in paragraph (0059) to paragraph (0065) in JP 2012-53253 A.

In the hydrolyzable monomer (Sm), one, two or three chlorine atoms, bromine atoms, iodine atoms, acetoxy groups, methoxy groups, ethoxy groups, propoxy groups, butoxy groups or the like are bounded to silicon atm pointed as (Si) in the above partial structure, as hydrolyzable group(s).

[Synthesis method of thermally crosslinkable polysiloxane (raw material)]

The thermally crosslinkable polysiloxane in the formulae (4) to (6) can be produced by, for example, hydrolytic condensation of the following hydrolyzable monomer (Sm).

Specific examples of the hydrolyzable monomer (Sm) can include tetramethoxysilane, tetraethoxysilane, tetrapropoxysilane, tetraisopropoxysilane, trimethoxysilane, triethoxysilane, tripropoxysilane, triisopropoxysilane, methyltrimethoxysilane, methyltriethoxysilane, methyltripropoxysilane, methyltriisopropoxysilane, ethyltrimethoxysilane, ethyltriethoxysilane, ethyltripropoxysilane, ethyltriisopropoxysilane, vinyltrimethoxysilane, vinyltriethoxysilane, vinyltripropoxysilane, vinyltriisopropoxysilane, propyltrimethoxysilane, propyltriethoxysilane, propyltripropoxysilane, propyltriisopropoxysilane, isopropyltrimethoxysilane, isopropyltriethoxysilane, isopropyltripropoxysilane, isopropyltriisopropoxysilane, butyltrimethoxysilane, butyltriethoxysilane, butyltripropoxysilane, butyltriisopropoxysilane, isobutyltrimethoxysilane, isobutyltriethoxysilane, isobutyltripropoxysilane, isobutyltriisopropoxysilane, sec-butyltrimethoxysilane, sec-butyltriethoxysilane, sec-butyltripropoxysilane, sec-butyltriisopropoxysilane, t-butyltrimethoxysilane, t-butyltriethoxysilane, t-butyltripropoxysilane, t-butyltriisopropoxysilane, allyltrimethoxysilane, allyltriethoxysilane, allyltripropoxysilane, allyltriisopropoxysilane, cyclopropyltrimethoxysilane, cyclopropyltriethoxysilane, cyclopropyltripropoxysilane, cyclopropyltriisopropoxysilane, cyclobutyltrimethoxysilane, cyclobutyltriethoxysilane, cyclobutyltripropoxysilane, cyclobutyltriisopropoxysilane, cyclopentyltrimethoxysilane, cyclopentyltriethoxysilane, cyclopentyltripropoxysilane, cyclopentyltriisopropoxysilane, cyclohexyltrimethoxysilane, cyclohexyltriethoxysilane, cyclohexyltripropoxysilane, cyclohexyltriisopropoxysilane, cyclohexenyltrimethoxysilane, cyclohexenyltriethoxysilane, cyclohexenyltripropoxysilane, cyclohexenyltriisopropoxysilane, cyclohexenylethyltrimethoxysilane, cyclohexenylethyltriethoxysilane, cyclohexenylethyltripropoxysilane, cyclohexenylethyltriisopropoxysilane, cyclooctyltrimethoxysilane, cyclooctyltriethoxysilane, cyclooctyltripropoxysilane, cyclooctyltriisopropoxysilane, cyclopentadienylpropyltrimethoxysilane, cyclopentadienylpropyltriethoxysilane, cyclopentadienylpropyltripropoxysilane, cyclopentadienylpropyltriisopropoxysilane, bicycloheptenyltrimethoxysilane, bicycloheptenyltriethoxysilane, bicycloheptenyltripropoxysilane, bicycloheptenyltriisopropoxysilane, bicycloheptyltrimethoxysilane, bicycloheptyltriethoxysilane, bicycloheptyltripropoxysilane, bicycloheptyltriisopropoxysilane, adamantyltrimethoxysilane, adamantyltriethoxysilane, adamantyltripropoxysilane, adamantyltriisopropoxysilane, phenyltrimethoxysilane, phenyltriethoxysilane, phenyltripropoxysilane, phenyltriisopropoxysilane, benzyltrimethoxysilane, benzyltriethoxysilane, benzyltripropoxysilane, benzyltriisopropoxysilane, anisyltrimethoxysilane, anisyltriethoxysilane, anisyltripropoxysilane, anisyltriisopropoxysilane, tolyltrimethoxysilane, tolyltriethoxysilane, tolyltripropoxysilane, tolyltriisopropoxysilane, phenethyltrimethoxysilane, phenethyltriethoxysilane, phenethyltripropoxysilane, phenethyltriisopropoxysilane, naphthyltrimethoxysilane, naphthyltriethoxysilane, naphthyltripropoxysilane, naphthyltriisopropoxysilane, dimethyldimethoxysilane, dimethyldiethoxysilane, methylethyldimethoxysilane, methylethyldiethoxysilane, dimethyldipropoxysilane, dimethyldiisopropoxysilane, diethyldimethoxysilane, diethyldiethoxysilane, diethyldipropoxysilane, diethyldiisopropoxysilane, dipropyldimethoxysilane, dipropyldiethoxysilane, dipropyldipropoxysilane, dipropyldiisopropoxysilane, diisopropyldimethoxysilane, diisopropyldiethoxysilane, diisopropyldipropoxysilane, diisopropyldiisopropoxysilane, dibutyldimethoxysilane, dibutyldiethoxysilane, dibutyldipropoxysilane, dibutyldiisopropoxysilane, di-sec-butyldimethoxysilane, di-sec-butyldiethoxysilane, di-sec-butyldipropoxysilane, di-sec-butyldiisopropoxysilane, di-t-butyldimethoxysilane, di-t-butyldiethoxysilane, di-t-butyldipropoxysilane, di-t-butyldiisopropoxysilane, dicyclopropyldimethoxysilane, dicyclopropyldiethoxysilane, dicyclopropyldipropoxysilane, dicyclopropyldiisopropoxysilane, dicyclobutyldimethoxysilane, dicyclobutyldiethoxysilane, dicyclobutyldipropoxysilane, dicyclobutyldiisopropoxysilane, dicyclopentyldimethoxysilane, dicyclopentyldiethoxysilane, dicyclopentyldipropoxysilane, dicyclopentyldiisopropoxysilane, dicyclohexyldimethoxysilane, dicyclohexyldiethoxysilane, dicyclohexyldipropoxysilane, dicyclohexyldiisopropoxysilane, dicyclohexenyldimethoxysilane, dicyclohexenyldiethoxysilane, dicyclohexenyldipropoxysilane, dicyclohexenyldiisopropoxysilane, dicyclohexenylethyldimethoxysilane, dicyclohexenylethyldiethoxysilane, dicyclohexenylethyldipropoxysilane, dicyclohexenylethyldiisopropoxysilane, dicyclooctyldimethoxysilane, dicyclooctyldiethoxysilane, dicyclooctyldipropoxysilane, dicyclooctyldiisopropoxysilane, dicyclopentadienylpropyldimethoxysilane, dicyclopentadienylpropyldiethoxysilane, dicyclopentadienylpropyldipropoxysilane, dicyclopentadienylpropyldiisopropoxysilane, bis(bicycloheptenyl)dimethoxysilane, bis(bicycloheptenyl)diethoxysilane, bis(bicycloheptenyl)dipropoxysilane, bis(bicycloheptenyl)diisopropoxysilane, bis(bicycloheptyl)dimethoxysilane, bis(bicycloheptyl)diethoxysilane, bis(bicycloheptyl)dipropoxysilane, bis(bicycloheptyl)diisopropoxysilane, diadamantyldimethoxysilane, diadamantyldiethoxysilane, diadamantyldipropoxysilane, diadamantyldiisopropoxysilane, diphenyldimethoxysilane, diphenyldiethoxysilane, methylphenyldimethoxysilane, methylphenyldiethoxysilane, diphenyldipropoxysilane, diphenyldiisopropoxysilane, trimethylmethoxysilane, trimethylethoxysilane, dimethylethylmethoxysilane, dimethylethylethoxysilane, dimethylphenylmethoxysilane, dimethylphenylethoxysilane, dimethylbenzylmethoxysilane, dimethylbenzylethoxysilane, dimethylphenethylmethoxysilane, and dimethylphenethylethoxysilane.

Examples of the compound can preferably include tetramethoxysilane, tetraethoxysilane, methyltrimethoxysilane, methyltriethoxysilane, ethyltrimethoxysilane, ethyltriethoxysilane, vinyltrimethoxysilane, vinyltriethoxysilane, propyltrimethoxysilane, propyltriethoxysilane, isopropyltrimethoxysilane, isopropyltriethoxysilane, butyltrimethoxysilane, butyltriethoxysilane, isobutyltrimethoxysilane, isobutyltriethoxysilane, allyltrimethoxysilane, allyltriethoxysilane, cyclopentyltrimethoxysilane, cyclopentyltriethoxysilane, cyclohexyltrimethoxysilane, cyclohexyltriethoxysilane, cyclohexenyltrimethoxysilane, cyclohexenyltriethoxysilane, phenyltrimethoxysilane, phenyltriethoxysilane, benzyltrimethoxysilane, benzyltriethoxysilane, phenethyltrimethoxysilane, phenethyltriethoxysilane, dimethyldimethoxysilane, dimethyldiethoxysilane, diethyldimethoxysilane, diethyldiethoxysilane, methylethyldimethoxysilane, methylethyldiethoxysilane, dipropyldimethoxysilane, dibutyldimethoxysilane, methylphenyldimethoxysilane, methylphenyldiethoxysilane, trimethylmethoxysilane, dimethylethylmethoxysilane, dimethylphenylmethoxysilane, dimethylbenzylmethoxysilane, and dimethylphenethylmethoxysilane.

[Synthesis method of thermally crosslinkable polysiloxane (reaction)]
(Synthesis method 1: acid catalyst)

The thermally crosslinkable polysiloxane used in the present invention can be produced by hydrolytic condensation of one kind of the hydrolyzable monomer (Sm) or a mixture of two or more kinds thereof in the presence of an acid catalyst.

Examples of the acid catalyst used here can include organic acids such as formic acid, acetic acid, oxalic acid, maleic acid, methanesulfonic acid, benzenesulfonic acid, and toluenesulfonic acid, and hydrofluoric acid, hydrochloric acid, hydrobromic acid, sulfuric acid, nitric acid, perchloric acid, and phosphoric acid. The amount of the catalyst used is preferably 1×10⁻⁶ to 10 mol, more preferably 1×10⁻⁵ to 5 mol, further preferably 1×10⁻⁴ to 1 mol per 1 mol of the monomer.

When the thermally crosslinkable polysiloxane is obtained from such a monomer by hydrolytic condensation, the amount of water added is preferably 0.01 to 100 mol, more preferably 0.05 to 50 mol, further preferably 0.1 to 30 mol per 1 mol of a hydrolyzable substituent bound to the monomer. If the amount is 100 mol or less, an apparatus used in the reaction is smaller and more economical. If the amount is 0.01 mol or more, the reaction sufficiently progresses.

In an operation method, the monomer is added to an aqueous catalyst solution to initiate a hydrolytic condensation reaction. An organic solvent may be added to the aqueous catalyst solution or the monomer may be diluted with an organic solvent, or both thereof may be performed. The reaction temperature is preferably 0 to 100° C., more preferably 5 to 80° C. A preferred method includes retaining the temperature to 5 to 80° C. during dropping of the monomer and then performing aging at 20 to 80° C.

The organic solvent which can be added to the aqueous catalyst solution or the organic solvent which can dilute the monomer is preferably any of methanol, ethanol, 1-propanol, 2-propanol, 1-butanol, 2-butanol, 2-methyl-1-propanol, ethylene glycol, propylene glycol, acetone, acetonitrile, tetrahydrofuran, toluene, hexane, ethyl acetate, methyl ethyl ketone, methyl isobutyl ketone, cyclohexanone, methyl amyl ketone, butanediol monomethyl ether, propylene glycol monomethyl ether, ethylene glycol monomethyl ether, butanediol monoethyl ether, propylene glycol monoethyl ether, ethylene glycol monoethyl ether, ethylene glycol monopropyl ether, propylene glycol dimethyl ether, diethylene glycol dimethyl ether, propylene glycol monomethyl ether acetate, propylene glycol monoethyl ether acetate, ethyl pyruvate, butyl acetate, methyl 3-methoxypropionate, ethyl 3-ethoxypropionate, tert-butyl acetate, t-butyl propionate, propylene glycol mono-t-butyl ether acetate, γ-butyrolactone, any mixture thereof, and the like.

Among these organic solvents, a water-soluble solvent is preferred. Examples can include alcohols such as methanol, ethanol, 1-propanol and 2-propanol, polyhydric alcohols such as ethylene glycol and propylene glycol, condensation derivatives of polyhydric alcohol such as butanediol monomethyl ether, propylene glycol monomethyl ether, ethylene glycol monomethyl ether, butanediol monoethyl ether, propylene glycol monoethyl ether, ethylene glycol monoethyl ether, butanediol monopropyl ether, propylene glycol monopropyl ether and ethylene glycol monopropyl ether, and acetone, acetonitrile, and tetrahydrofuran. Among them, one having a boiling point of 100° C. or less is particularly preferred.

The amount of the organic solvent used is preferably 0 to 1,000 ml, particularly 0 to 500 ml per 1 mol of the monomer. When the amount of the organic solvent used is smaller, a reaction container is smaller and more economical.

Thereafter, a neutralization reaction of the catalyst is, if necessary, performed, and thus an aqueous reaction mixture solution is obtained. The amount of an alkaline substance usable in neutralization is here preferably 0.1 to 2 equivalents relative to the acid used in the catalyst. The alkaline substance may be any substance as long as it exhibits alkalinity in water.

Subsequently, a by-product such as an alcohol generated in the hydrolytic condensation reaction is preferably removed from the aqueous reaction mixture solution by, for example, distillation under reduced pressure. The heating temperature of the aqueous reaction mixture solution here depends on the types of the organic solvent added, the alcohol generated in the reaction, and the like, and is preferably 0 to 100° C., more preferably 10 to 90° C., further preferably 15 to 80° C. The degree of pressure reduction here differs depending on the types of the organic solvent, the alcohol and the like to be removed, an air exhauster, a condenser, and the heating temperature, and is preferably atmospheric pressure or less, more preferably 80 kPa or less as the absolute pressure, further preferably 50 kPa or less as the absolute pressure. Although it is difficult to correctly know the amount of the alcohol removed here, about 80% by mass or more of the alcohol generated is desirably removed.

Next, the acid catalyst used in hydrolytic condensation may be removed from the aqueous reaction mixture solution. The method for removing the acid catalyst includes mixing water and a thermally crosslinkable polysiloxane solution and extracting the thermally crosslinkable polysiloxane with an organic solvent. The organic solvent used here is preferably an organic solvent which can dissolve the thermally crosslinkable polysiloxane and which is separated to two layers when it is mixed with water. Examples thereof can include methanol, ethanol, 1-propanol, 2-propanol, 1-butanol, 2-butanol, 2-methyl-1-propanol, acetone, tetrahydrofuran, toluene, hexane, ethyl acetate, cyclohexanone, methyl amyl ketone, butanediol monomethyl ether, propylene glycol monomethyl ether, ethylene glycol monomethyl ether, butanediol monoethyl ether, propylene glycol monoethyl ether, ethylene glycol monoethyl ether, butanediol monopropyl ether, propylene glycol monopropyl ether, ethylene glycol monopropyl ether, propylene glycol dimethyl ether, diethylene glycol dimethyl ether, propylene glycol monomethyl ether acetate, propylene glycol monoethyl ether acetate, ethyl pyruvate, butyl acetate, methyl 3-methoxypropionate, ethyl 3-ethoxypropionate, t-butyl acetate, t-butyl propionate, propylene glycol mono-t-butyl ether acetate, γ-butyrolactone, methyl isobutyl ketone, cyclopentyl methyl ether, and any mixture thereof.

Furthermore, a mixture of a water-soluble organic solvent and a poorly water-soluble organic solvent can also be used. For example, preferred are a methanol-ethyl acetate mixture, an ethanol-ethyl acetate mixture, a 1-propanol-ethyl acetate mixture, a 2-propanol-ethyl acetate mixture, a butanediol monomethyl ether-ethyl acetate mixture, a propylene glycol monomethyl ether-ethyl acetate mixture, an ethylene glycol monomethyl ether-ethyl acetate mixture, a butanediol monoethyl ether-ethyl acetate mixture, a propylene glycol monoethyl ether-ethyl acetate mixture, an ethylene glycol monoethyl ether-ethyl acetate mixture, a butanediol monopropyl ether-ethyl acetate mixture, a propylene glycol monopropyl ether-ethyl acetate mixture, an ethylene glycol monopropyl ether-ethyl acetate mixture, a methanol-methyl isobutyl ketone mixture, an ethanol-methyl isobutyl ketone mixture, a 1-propanol-methyl isobutyl ketone mixture, a 2-propanol-methyl isobutyl ketone mixture, a propylene glycol monomethyl ether-methyl isobutyl ketone mixture, an ethylene glycol monomethyl ether-methyl isobutyl ketone mixture, a propylene glycol monoethyl ether-methyl isobutyl ketone mixture, an ethylene glycol monoethyl ether-methyl isobutyl ketone mixture, a propylene glycol monopropyl ether-methyl isobutyl ketone mixture, an ethylene glycol monopropyl ether-methyl isobutyl ketone mixture, a methanol-cyclopentyl methyl ether mixture, an ethanol-cyclopentyl methyl ether mixture, a 1-propanol-cyclopentyl methyl ether mixture, a 2-propanol-cyclopentyl methyl ether mixture, a propylene glycol monomethyl ether-cyclopentyl methyl ether mixture, an ethylene glycol monomethyl ether-cyclopentyl methyl ether mixture, a propylene glycol monoethyl ether-cyclopentyl methyl ether mixture, an ethylene glycol monoethyl ether-cyclopentyl methyl ether mixture, a propylene glycol monopropyl ether-cyclopentyl methyl ether mixture, an ethylene glycol monopropyl ether-cyclopentyl methyl ether mixture, a methanol-propylene glycol methyl ether acetate mixture, an ethanol-propylene glycol methyl ether acetate mixture, a 1-propanol-propylene glycol methyl ether acetate mixture, a 2-propanol-propylene glycol methyl ether acetate mixture, a propylene glycol monomethyl ether-propylene glycol methyl ether acetate mixture, an ethylene glycol monomethyl ether-propylene glycol methyl ether acetate mixture, a propylene glycol monoethyl ether-propylene glycol methyl ether acetate mixture, an ethylene glycol monoethyl ether-propylene glycol methyl ether acetate mixture, a propylene glycol monopropyl ether-propylene glycol methyl ether acetate mixture, an ethylene glycol monopropyl ether-propylene glycol methyl ether acetate mixture, and the like, and a combination is not limited thereto.

The mixing ratio of the water-soluble organic solvent and the poorly water-soluble organic solvent is appropriately selected, and the proportion of the water-soluble organic solvent based on 100 parts by mass of the poorly water-soluble organic solvent is preferably 0.1 to 1,000 parts by mass, more preferably 1 to 500 parts by mass, further preferably 2 to 100 parts by mass.

Subsequently, washing with neutral water may be performed. This water used here may be usually one called deionized water or ultrapure water. The amount of this water is preferably 0.01 to 100 L, more preferably 0.05 to 50 L, further preferably 0.1 to 5 L based on 1 L of the thermally crosslinkable polysiloxane solution. This washing method may be performed by placing and stirring both the solvents in the same container, and then leaving them to stand to separate an aqueous layer. The number of washing times may be any number as long as it is one or more, and is preferably about 1 to 5 because, even if washing is performed 10 times or more, the effect corresponding to such washing is not obtained.

Examples of any other method for removing the acid catalyst can include a method with an ion-exchange resin, and a method involving removal after neutralization with an epoxy compound such as ethylene oxide or propylene oxide. These methods can be appropriately selected depending on the acid catalyst used in the reaction.

Such a water washing operation here may allow one portion of the thermally crosslinkable polysiloxane to be escaped to the aqueous layer, thereby substantially providing the effect comparable with a fractioning operation, and therefore the number of water washing times and the amount of washing water may be appropriately selected in view of the catalyst removal effect and the fractioning effect.

A final solvent is added to each of the thermally crosslinkable polysiloxane solution in which the acid catalyst remains and the thermally crosslinkable polysiloxane solution from which the acid catalyst is removed, to perform solvent exchange under reduced pressure, thereby providing a desired thermally crosslinkable polysiloxane solution. The temperature of the solvent exchange here depends on the types of the reaction solvent and the extraction solvent to be removed, and is preferably 0 to 100° C., more preferably 10 to 90° C., further preferably 15 to 80° C. The degree of pressure reduction here differs depending on the types of the extraction solvent to be removed, an air exhauster, a condenser, and the heating temperature, and is preferably atmospheric pressure or less, more preferably 80 kPa or less as the absolute pressure, further preferably 50 kPa or less as the absolute pressure.

If the solvent is here changed, the thermally crosslinkable polysiloxane may be destabilized. This destabilization is caused depending on the compatibility between the final solvent and the thermally crosslinkable polysiloxane, and in order to prevent this destabilization, a mono-, or di- or higher hydric alcohol having a cyclic ether described in paragraphs (0181) to (0182) in JP 2009-126940 A, as a substituent, may be added. The amount added is preferably 0 to 25 parts by mass, more preferably 0 to 15 parts by mass, further preferably 0 to 5 parts by mass based on 100 parts by mass of the thermally crosslinkable polysiloxane in the solution before solvent exchange, and, in the case of addition, the amount is preferably 0.5 parts by mass or more. Such a solvent exchange operation may be performed by addition of the mono-, or di- or higher hydric alcohol having a cyclic ether as a substituent, if necessary for the solution before solvent exchange.

The thermally crosslinkable polysiloxane is preferably in the state of a solution having a proper concentration. The concentration here is preferably 0.1 to 20% by mass. Such a concentration does not cause progression of a further condensation reaction, and therefore does not cause the change to a state in which re-dissolution in an organic solvent is impossible. Such a concentration is also economical and preferred because the amount of the solvent is decreased.

The final solvent added to the thermally crosslinkable polysiloxane solution is preferably an alcohol-based solvent, particularly preferably a monoalkyl ether derivative such as ethylene glycol, diethylene glycol, triethylene glycol, propylene glycol, dipropylene glycol, or butanediol. Specifically, preferred is, for example, butanediol monomethyl ether, propylene glycol monomethyl ether, ethylene glycol monomethyl ether, butanediol monoethyl ether, propylene glycol monoethyl ether, ethylene glycol monoethyl ether, butanediol monopropyl ether, propylene glycol monopropyl ether, ethylene glycol monopropyl ether, or diacetone alcohol.

If such a solvent is a main component, a non-alcohol-based solvent can also be added as an auxiliary solvent. Examples of the auxiliary solvent can include acetone, tetrahydrofuran, toluene, hexane, ethyl acetate, cyclohexanone, methyl amyl ketone, propylene glycol dimethyl ether, diethylene glycol dimethyl ether, propylene glycol monomethyl ether acetate, propylene glycol monoethyl ether acetate, ethyl pyruvate, butyl acetate, methyl 3-methoxypropionate, ethyl 3-ethoxypropionate, t-butyl acetate, t-butyl propionate, propylene glycol mono-t-butyl ether acetate, γ-butyrolactone, methyl isobutyl ketone, and cyclopentyl methyl ether.

Another reaction operation in which the acid catalyst is used includes adding water or a water-containing organic solvent to the monomer or an organic solution of the monomer, to initiate a hydrolysis reaction. The catalyst here may be added to the monomer or an organic solution of the monomer, or may be added to water or a water-containing organic solvent in advance. The reaction temperature is preferably 0 to 100° C., more preferably 10 to 80° C. A method is preferred which includes heating to 10 to 50° C. during dropping of water and thereafter aging with a temperature rise to 20 to 80° C.

When the organic solvent is used, a water-soluble organic solvent is preferred, and examples thereof can include methanol, ethanol, 1-propanol, 2-propanol, 1-butanol, 2-butanol, 2-methyl-1-propanol, acetone, tetrahydrofuran, acetonitrile, polyhydric alcohol condensate derivatives such as butanediol monomethyl ether, propylene glycol monomethyl ether, ethylene glycol monomethyl ether, butanediol monoethyl ether, propylene glycol monoethyl ether, ethylene glycol monoethyl ether, butanediol monopropyl ether, propylene glycol monopropyl ether, ethylene glycol monopropyl ether, propylene glycol dimethyl ether, diethylene glycol dimethyl ether, propylene glycol monomethyl ether acetate, propylene glycol monoethyl ether acetate and propylene glycol monopropyl ether acetate, and any mixture thereof.

The amount of the organic solvent used is preferably 0 to 1,000 ml, particularly 0 to 500 ml per 1 mol of the monomer. When the amount of the organic solvent used is smaller, a reaction container is smaller and more economical. The post-treatment of the aqueous reaction mixture solution obtained can be made by the same method as described above, to obtain the thermally crosslinkable polysiloxane.

(Synthesis method 2: alkali catalyst)

The thermally crosslinkable polysiloxane can be produced by hydrolytic condensation of one kind of the hydrolyzable monomer (Sm) or a mixture of two or more kinds thereof in the presence of an alkali catalyst. Examples of the alkali catalyst used here can include methylamine, ethylamine, propylamine, butylamine, ethylenediamine, hexamethylenediamine, dimethylamine, diethylamine, ethylmethylamine, trimethylamine, triethylamine, tripropylamine, tributylamine, cyclohexylamine, dicyclohexylamine, monoethanolamine, diethanolamine, dimethyl monoethanolamine, monomethyldiethanolamine, triethanolamine, diazabicyclooctane, diazabicyclocyclononene, diazabicycloundecene, hexamethylenetetramine, aniline, N,N-dimethylaniline, pyridine, N,N-dimethylaminopyridine, pyrrole, piperazine, pyrrolidine, piperidine, picolin, tetramethylammonium hydroxide, choline hydroxide, tetrapropylammonium hydroxide, tetrabutylammonium hydroxide, ammonia, lithium hydroxide, sodium hydroxide, potassium hydroxide, barium hydroxide, and calcium hydroxide. The amount of the catalyst used is preferably 1×10⁻⁶ mol to 10 mol, more preferably 1×10⁻⁵ mol to 5 mol, further preferably 1×10⁻⁴ mol to 1 mol per 1 mol of the monomer.

When the thermally crosslinkable polysiloxane is obtained from the monomer by hydrolytic condensation, the amount of water added is preferably 0.1 to 50 mol per 1 mol of a hydrolyzable substituent bound to the monomer. If the amount is 50 mol or less, an apparatus used in the reaction is smaller and more economical. If the amount is 0.1 mol or more, the reaction sufficiently progresses.

In an operation method, the monomer is added to an aqueous catalyst solution to initiate a hydrolytic condensation reaction. An organic solvent may be added to the aqueous catalyst solution or the monomer may be diluted with an organic solvent, or both thereof may be performed. The reaction temperature is preferably 0 to 100° C., more preferably 5 to 80° C. A preferred method includes retaining the temperature to 5 to 80° C. during dropping of the monomer and then performing aging at 20 to 80° C.

The organic solvent which can be added to such an aqueous alkali catalyst solution or which can dilute the monomer is preferably the same as any organic solvent exemplified as those which can be added to the aqueous acid catalyst solution. The amount of the organic solvent used is preferably 0 to 1,000 ml per 1 mol of the monomer because the reaction can be economically performed.

Thereafter, a neutralization reaction of the catalyst is, if necessary, performed, and thus an aqueous reaction mixture solution is obtained. The amount of an acidic substance here usable in neutralization is preferably 0.1 to 2 equivalents relative to the alkaline substance used in the catalyst. The acidic substance may be any substance as long as it exhibits acidity in water.

Subsequently, a by-product such as an alcohol generated in the hydrolytic condensation reaction is preferably removed from the aqueous reaction mixture solution by, for example, distillation under reduced pressure. The heating temperature of the aqueous reaction mixture solution here depends on the types of the organic solvent added and the alcohol generated in the reaction, and is preferably 0 to 100° C., more preferably 10 to 90° C., further preferably 15 to 80° C. The degree of pressure reduction here differs depending on the types of the organic solvent and the alcohol to be removed, an air exhauster, a condenser, and the heating temperature, and is preferably atmospheric pressure or less, more preferably 80 kPa or less as the absolute pressure, further preferably 50 kPa or less as the absolute pressure. Although it is difficult to correctly know the amount of the alcohol removed here, about 80% by mass or more of the alcohol generated is desirably removed.

Next, the thermally crosslinkable polysiloxane is extracted with an organic solvent in order to remove the catalyst used in hydrolytic condensation. The organic solvent used here is preferably an organic solvent which can dissolve the thermally crosslinkable polysiloxane and which is separated to two layers when it is mixed with water. Examples thereof can include methanol, ethanol, 1-propanol, 2-propanol, 1-butanol, 2-butanol, 2-methyl-1-propanol, acetone, tetrahydrofuran, toluene, hexane, ethyl acetate, cyclohexanone, methyl amyl ketone, propylene glycol monomethyl ether, ethylene glycol monomethyl ether, propylene glycol monoethyl ether, ethylene glycol monoethyl ether, propylene glycol monopropyl ether, ethylene glycol monopropyl ether, propylene glycol dimethyl ether, diethylene glycol dimethyl ether, propylene glycol monomethyl ether acetate, propylene glycol monoethyl ether acetate, ethyl pyruvate, butyl acetate, methyl 3-methoxypropionate, ethyl 3-ethoxypropionate, t-butyl acetate, t-butyl propionate, propylene glycol mono-t-butyl ether acetate, γ-butyrolactone, methyl isobutyl ketone, cyclopentyl methyl ether, and any mixture thereof.

Furthermore, a mixture of a water-soluble organic solvent and a poorly water-soluble organic solvent can also be used.

Specific examples of the organic solvent usable in removal of the alkali catalyst are the above-mentioned organic solvents specifically exemplified as those used in removal of the acid catalyst, and those that are the same as in the mixture of a water-soluble organic solvent and a poorly water-soluble organic solvent.

The mixing ratio of the water-soluble organic solvent and the poorly water-soluble organic solvent is appropriately selected, and the proportion of the water-soluble organic solvent based on 100 parts by mass of the poorly water-soluble organic solvent is preferably 0.1 to 1,000 parts by mass, more preferably 1 to 500 parts by mass, further preferably 2 to 100 parts by mass.

Subsequently, washing with neutral water is performed. This water used here may be usually one called deionized water or ultrapure water. The amount of this water is preferably 0.01 to 100 L, more preferably 0.05 to 50 L, further preferably 0.1 to 5 L based on 1 L of the thermally crosslinkable polysiloxane solution. This washing method may be performed by placing and stirring both the solvents in the same container, and then leaving them to stand to separate an aqueous layer. The number of washing times may be any number as long as it is one or more, and is preferably about 1 to 5 because, even if washing is performed 10 times or more, the effect corresponding to such washing is not obtained.

A final solvent is added to the thermally crosslinkable polysiloxane solution washed, to perform solvent exchange under reduced pressure, thereby providing a desired thermally crosslinkable polysiloxane solution. The temperature of the solvent exchange here depends on the type of the extraction solvent to be removed, and is preferably 0 to 100° C., more preferably 10 to 90° C., further preferably 15 to 80° C. The degree of pressure reduction here differs depending on the type of the extraction solvent to be removed, an air exhauster, a condenser, and the heating temperature, and is preferably atmospheric pressure or less, more preferably 80 kPa or less as the absolute pressure, further preferably 50 kPa or less as the absolute pressure.

The final solvent added to the thermally crosslinkable polysiloxane solution is preferably an alcohol-based solvent, particularly preferably a monoalkyl ether derivative such as ethylene glycol, diethylene glycol, triethylene glycol, propylene glycol, or dipropylene glycol. Specifically, preferred is, for example, propylene glycol monomethyl ether, ethylene glycol monomethyl ether, propylene glycol monoethyl ether, ethylene glycol monoethyl ether, propylene glycol monopropyl ether, ethylene glycol monopropyl ether, or diacetone alcohol.

Another reaction operation in which the alkali catalyst is used includes adding water or a water-containing organic solvent to the monomer or an organic solution of the monomer, to initiate a hydrolysis reaction. The catalyst here may be added to the monomer or an organic solution of the monomer, or may be added to water or a water-containing organic solvent in advance. The reaction temperature is preferably 0 to 100° C., more preferably 10 to 80° C. A method is preferred which includes heating to 10 to 50° C. during dropping of water and thereafter aging with a temperature rise to 20 to 80° C.

The organic solvent usable in the organic solution of the monomer or as the water-containing organic solvent is preferably water-soluble, and examples thereof can include methanol, ethanol, 1-propanol, 2-propanol, 1-butanol, 2-butanol, 2-methyl-1-propanol, acetone, tetrahydrofuran, acetonitrile, and polyhydric alcohol condensate derivatives such as propylene glycol monomethyl ether, ethylene glycol monomethyl ether, propylene glycol monoethyl ether, ethylene glycol monoethyl ether, propylene glycol monopropyl ether, ethylene glycol monopropyl ether, propylene glycol dimethyl ether, diethylene glycol dimethyl ether, propylene glycol monomethyl ether acetate, propylene glycol monoethyl ether acetate, and propylene glycol monopropyl ether acetate, as well as any mixture thereof.

The molecular weight of the thermally crosslinkable polysiloxane obtained by Synthesis method 1 or 2 can be adjusted by not only selection of the monomer, but also control of reaction conditions during polymerization, neither generation of any foreign substance, nor generation of any coating spot is caused as long as the weight average molecular weight is 100,000 or less, and therefore the molecular weight is preferably 100,000 or less, more preferably 200 to 50,000, further preferably 300 to 30,000. The data relating to the above weight average molecular weight is represented as the molecular weight in terms of polystyrene with polystyrene as a standard substance, as determined by gel permeation chromatography (GPC) with RI as a detector and tetrahydrofuran as an elution solvent.

Physical properties of the thermally crosslinkable polysiloxane used in the present invention are varied depending on the type of the acid or alkali catalyst used during hydrolytic condensation, and reaction conditions. Therefore, there can be appropriately selected according to the performance of an objective resist underlayer film.

Furthermore, a polysiloxane derivative produced from a mixture of one kind of the hydrolyzable monomer (Sm) or two or more kinds thereof with a hydrolyzable metal compound represented by the following general formula (Mm) in conditions in which the acid or alkali catalyst is used can be used as a component of a composition for resist underlayer film formation.

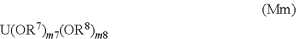

In the general formula (Mm), R⁷ and R⁸ are each independently an organic group having 1 to 30 carbon atoms, m7+m8 is the same number as the valence determined depending on the type of U, m7 and m8 are each an integer of 0 or more, and U is any element of Group III, Group IV, or Group V in the periodic table, except for carbon and silicon.

Examples of the hydrolyzable metal compound represented by the general formula (Mm), used here, can include the following. When U is boron, examples of the hydrolyzable metal compound represented by the general formula (Mm) can include boron methoxide, boron ethoxide, boron propoxide, boron butoxide, boron amiloxide, boron hexyloxide, boron cyclopentoxide, boron cyclohexyloxide, boron allyloxide, boron phenoxide, boron methoxyethoxide, boric acid, and boron oxide.

When U is aluminum, examples of the hydrolyzable metal compound represented by the general formula (Mm) can include aluminum methoxide, aluminum ethoxide, aluminum propoxide, aluminum butoxide, aluminum amiloxide, aluminum hexyloxide, aluminum cyclopentoxide, aluminum cyclohexyloxide, aluminum allyloxide, aluminum phenoxide, aluminum methoxyethoxide, aluminum ethoxyethoxide, aluminum dipropoxyethyl acetoacetate, aluminum dibutoxyethyl acetoacetate, aluminum propoxybisethyl acetoacetate, aluminum butoxybisethyl acetoacetate, aluminum 2,4-pentanedionate, and aluminum 2,2,6,6-tetramethyl-3,5-heptanedionate.

When U is gallium, examples of the hydrolyzable metal compound represented by the general formula (Mm) can include gallium methoxide, gallium ethoxide, gallium propoxide, gallium butoxide, gallium amiloxide, gallium hexyloxide, gallium cyclopentoxide, gallium cyclohexyloxide, gallium allyloxide, gallium phenoxide, gallium methoxyethoxide, gallium ethoxyethoxide, gallium dipropoxyethyl acetoacetate, gallium dibutoxyethyl acetoacetate, gallium propoxybisethyl acetoacetate, gallium butoxybisethyl acetoacetate, gallium 2,4-pentanedionate, and gallium 2,2,6,6-tetramethyl-3,5-heptanedionate.

When U is yttrium, examples of the hydrolyzable metal compound represented by the general formula (Mm) can include yttrium methoxide, yttrium ethoxide, yttrium propoxide, yttrium butoxide, yttrium amiloxide, yttrium hexyloxide, yttrium cyclopentoxide, yttrium cyclohexyloxide, yttrium allyloxide, yttrium phenoxide, yttrium methoxyethoxide, yttrium ethoxyethoxide, yttrium dipropoxyethyl acetoacetate, yttrium dibutoxyethyl acetoacetate, yttrium propoxybisethyl acetoacetate, yttrium butoxybisethyl acetoacetate, yttrium 2,4-pentanedionate, and yttrium 2,2,6,6-tetramethyl-3,5-heptanedionate.

When U is germanium, examples of the hydrolyzable metal compound represented by the general formula (Mm) can include germanium methoxide, germanium ethoxide, germanium propoxide, germanium butoxide, germanium amiloxide, germanium hexyloxide, germanium cyclopentoxide, germanium cyclohexyloxide, germanium allyloxide, germanium phenoxide, germanium methoxyethoxide, and germanium ethoxyethoxide.

When U is titanium, examples of the hydrolyzable metal compound represented by the general formula (Mm) can include titanium methoxide, titanium ethoxide, titanium propoxide, titanium butoxide, titanium amiloxide, titanium hexyloxide, titanium cyclopentoxide, titanium cyclohexyloxide, titanium allyloxide, titanium phenoxide, titanium methoxyethoxide, titanium ethoxyethoxide, titanium dipropoxybisethyl acetoacetate, titanium dibutoxybisethyl acetoacetate, titanium dipropoxybis2,4-pentanedionate, and titanium dibutoxybis2,4-pentanedionate.

When U is hafnium, examples of the hydrolyzable metal compound represented by the general formula (Mm) can include hafnium methoxide, hafnium ethoxide, hafnium propoxide, hafnium butoxide, hafnium amiloxide, hafnium hexyloxide, hafnium cyclopentoxide, hafnium cyclohexyloxide, hafnium allyloxide, hafnium phenoxide, hafnium methoxyethoxide, hafnium ethoxyethoxide, hafnium dipropoxybisethyl acetoacetate, hafnium dibutoxybisethyl acetoacetate, hafnium dipropoxybis2,4-pentanedionate, and hafnium dibutoxybis2,4-pentanedionate.

When U is tin, examples of the hydrolyzable metal compound represented by the general formula (Mm) can include methoxy tin, ethoxy tin, propoxy tin, butoxy tin, phenoxy tin, methoxyethoxy tin, ethoxyethoxy tin, tin 2,4-pentanedionate, and tin 2,2,6,6-tetramethyl-3,5-heptanedionate.

When U is arsenic, examples of the hydrolyzable metal compound represented by the general formula (Mm) can include methoxy arsenic, ethoxy arsenic, propoxy arsenic, butoxy arsenic, and phenoxy arsenic.

When U is antimony, examples of the hydrolyzable metal compound represented by the general formula (Mm) can include methoxy antimony, ethoxy antimony, propoxy antimony, butoxy antimony, phenoxy antimony, antimony acetate, and antimony propionate.

When U is niobium, examples of the hydrolyzable metal compound represented by the general formula (Mm) can include methoxy niobium, ethoxy niobium, propoxy niobium, butoxy niobium, and phenoxy niobium.

When U is tantalum, examples of the hydrolyzable metal compound represented by the general formula (Mm) can include methoxy tantalum, ethoxy tantalum, propoxy tantalum, butoxy tantalum, and phenoxy tantalum.

When U is bismuth, examples of the hydrolyzable metal compound represented by the general formula (Mm) can include methoxy bismuth, ethoxy bismuth, propoxy bismuth, butoxy bismuth, and phenoxy bismuth.

When U is phosphorus, examples of the hydrolyzable metal compound represented by the general formula (Mm) can include trimethyl phosphate, triethyl phosphate, tripropyl phosphate, trimethyl phosphite, triethyl phosphite, tripropyl phosphite, and phosphorus pentoxide.

When U is vanadium, examples of the hydrolyzable metal compound represented by the general formula (Mm) can include vanadium oxide bis(2,4-pentanedionate), vanadium 2,4-pentanedionate, vanadium tributoxide oxide, and vanadium tripropoxide oxide.

When U is zirconium, examples of the hydrolyzable metal compound represented by the general formula (Mm) can include methoxy zirconium, ethoxy zirconium, propoxy zirconium, butoxy zirconium, phenoxy zirconium, zirconium dibutoxidebis(2,4-pentanedionate), and zirconium dipropoxidebis(2,2,6,6-tetramethyl-3,5-heptanedionate).

[Amount of thermally crosslinkable polysiloxane added]

The amount of the thermally crosslinkable polysiloxane compounded in the silicon-containing resist underlayer film composition in the present invention is preferably, for example, 0.1 to 10% by mass relative to the solvent.

[Crosslinking catalyst for siloxane polymerization]

The silicon-containing resist underlayer film composition in the present invention includes a compound represented by the following general formula (Xc), in addition to the thermally crosslinkable polysiloxane. Hereinafter, the compound may also be referred to as “crosslinking catalyst for siloxane polymerization” or simply referred to as “crosslinking catalyst”.

In the present invention, the crosslinking catalyst for siloxane polymerization can be a sulfonium salt, an iodonium salt, a phosphonium salt, an ammonium salt or a polysiloxane having such a salt as one portion of a structure thereof, or an alkali metal salt.

Examples of the crosslinking catalyst for siloxane polymerization (Xc) can include a compound represented by the following general formula (Xc0):

LaHbA (Xc0)

wherein L is lithium, sodium, potassium, rubidium, cesium, sulfonium, iodonium, phosphonium or ammonium, A is a non-nucleophilic counter ion, “a” is an integer of 1 or more, “b” is an integer of 0 or 1 or more, and “a” +“b” is the valence of the non-nucleophilic counter ion.

Specific examples of (Xc0) include a sulfonium salt of the following general formula (Xc-1), an iodonium salt of the following general formula (Xc-2), a phosphonium salt of the following general formula (Xc-3), an ammonium salt of the following general formula (Xc-4), and an alkali metal salt.

Examples of the sulfonium salt (Xc-1), the iodonium salt (Xc-2), and the phosphonium salt (Xc-3) include the following:

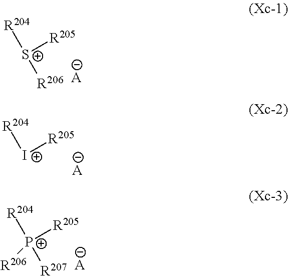

Examples of the ammonium salt (Xc-4) include the following:

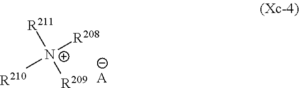

wherein R²⁰⁴, R²⁰⁵, R²⁰⁶, and R²⁰⁷ each represent a straight, branched or cyclic alkyl group, alkenyl group, oxoalkyl group or oxoalkenyl group having 1 to 12 carbon atoms, a substituted or unsubstituted aryl group having 6 to 20 carbon atoms, or an aralkyl group or aryloxoalkyl group having 7 to 12 carbon atoms, and some or all of hydrogen atoms in such a group are each optionally substituted by an alkoxy group or the like; R²⁰⁵ and R²⁰⁶ optionally form a ring, and when a ring is formed, R²⁰⁵ and R²⁰⁶ each represent an alkylene group having 1 to 6 carbon atoms; A- represents a non-nucleophilic counter ion; R²⁰⁸, R²⁰⁹, R²¹⁰, and R²¹1 are the same as R²⁰⁴, R²⁰⁵, R²⁰⁶, and R²⁰⁷, and are optionally hydrogen atoms; and R²⁰¹ and R²⁰⁹, and R²⁰⁸, R²⁰¹ and R²¹⁰ optionally form a ring, and when a ring is formed, R²⁰⁸ and R²⁰⁹, and R²⁰⁸, R²⁰⁹ and R²¹⁰ each represent an alkylene group having 3 to 10 carbon atoms.

R²⁰⁴, R²⁰⁵, R²⁰⁶, R²⁰⁷, R²⁰⁸, R²⁰⁹, R²¹, and R²¹¹ described above are the same as or different from each other, and specifically, examples of the alkyl group include a methyl group, an ethyl group, a propyl group, an isopropyl group, a n-butyl group, a sec-butyl group, a tert-butyl group, a pentyl group, a hexyl group, a heptyl group, an octyl group, a cyclopentyl group, a cyclohexyl group, a cycloheptyl group, a cyclopropylmethyl group, a 4-methylcyclohexyl group, a cyclohexylmethyl group, a norbornyl group, and an adamantyl group. Examples of the alkenyl group include a vinyl group, an allyl group, a propenyl group, a butenyl group, a hexenyl group, and a cyclohexenyl group. Examples of the oxoalkyl group include a 2-oxocyclopentyl group and a 2-oxocyclohexyl group, and can include a 2-oxopropyl group, a 2-cyclopentyl-2-oxoethyl group, a 2-cyclohexyl-2-oxoethyl group, and a 2-(4-methylcyclohexyl)-2-oxoethyl group. Examples of the aryl group include a phenyl group, a naphthyl group; alkoxyphenyl groups such as a p-methoxyphenyl group, a m-methoxyphenyl group, an o-methoxyphenyl group, an ethoxyphenyl group, a p-tert-butoxyphenyl group and a m-tert-butoxyphenyl group; alkylphenyl groups such as a 2-methylphenyl group, a 3-methylphenyl group, a 4-methylphenyl group, an ethylphenyl group, a 4-tert-butylphenyl group, a 4-butylphenyl group and a dimethylphenyl group; alkylnaphthyl groups such as a methylnaphthyl group and an ethylnaphthyl group; alkoxynaphthyl groups such as a methoxynaphthyl group and an ethoxynaphthyl group; dialkylnaphthyl groups such as a dimethylnaphthyl group and a diethylnaphthyl group; and dialkoxynaphthyl groups such as a dimethoxynaphthyl group and a diethoxynaphthyl group. Examples of the aralkyl group include a benzyl group, a 1-phenylethyl group, and a 2-phenylethyl group. Examples of the aryloxoalkyl group include 2-aryl-2-oxoethyl groups such as a 2-phenyl-2-oxoethyl group, a 2-(1-naphthyl)-2-oxoethyl group, and a 2-(2-naphthyl)-2-oxoethyl group.

Examples of the non-nucleophilic counter ion of A-include monovalent ions such as a hydroxy ion, a formate ion, an acetate ion, a propionate ion, a butanoate ion, a pentanoate ion, a hexanoate ion, a heptanoate ion, an octanoate ion, a nonanoate ion, a decanoate ion, an oleate ion, a stearate ion, a linoleate ion, a linolenate ion, a benzoate ion, a phthalate ion, an isophthalate ion, a terephthalate ion, a salicylate ion, a trifluoroacetate ion, a monochloroacetate ion, a dichloroacetate ion, a trichloroacetate ion, a fluorine ion, a chlorine ion, a bromine ion, an iodine ion, a nitrate ion, a nitrite ion, a chlorate ion, a bromate ion, a methanesulfonate ion, a para-toluenesulfonate ion and a monomethylsulfate ion; and monovalent or divalent ion such as oxalate ion, malonate ion, methylmalonate ion, ethylmalonate ion, propylmalonate ion, butylmalonate ion, dimethylmalonate ion, diethylmalonate ion, succinate ion, methylsuccinate ion, glutarate ion, adipate ion, itaconate ion, maleate ion, fumarate ion, citraconate ion, citrate ion, carbonate ion, and sulfate ion.

Examples of the alkali metal salt include lithium, sodium, potassium, and cesium salts: monovalent salts such as hydroxy salts, formic acid salts, acetic acid salts, propionic acid salts, butanoic acid salts, pentanoic acid salts, hexanoic acid salts, heptanoic acid salts, octanoic acid salts, nonanoic acid salts, decanoic acid salts, oleic acid salts, stearic acid salts, linolic acid salts, linolenic acid salts, benzoic acid salts, phthalic acid salts, isophthalic acid salts, terephthalic acid salts, salicylic acid salts, trifluoroacetic acid salts, monochloroacetic acid salts, dichloroacetic acid salts and trichloroacetic acid salts; and monovalent or divalent salts such as oxalic acid salts, malonic acid salts, methylmalonic acid salts, ethylmalonic acid salts, propylmalonic acid salts, butylmalonic acid salts, dimethylmalonic acid salts, diethylmalonic acid salts, succinic acid salts, methylsuccinic acid salts, glutaric acid salts, adipic acid salts, itaconic acid salts, maleic acid salts, fumaric acid salts, citraconic acid salts, citric acid salts, and carbonate.

(Sulfonium salt (Xc-1))

Specific examples of the sulfonium salt (Xc-1) include triphenylsulfonium formate, triphenylsulfonium acetate, triphenylsulfonium propionate, triphenylsulfonium butanoate, triphenylsulfonium benzoate, triphenylsulfonium phthalate, triphenylsulfonium isophthalate, triphenylsulfonium terephthalate, triphenylsulfonium salicylate, triphenylsulfonium trifluoromethanesulfonate, triphenylsulfonium trifluoroacetate, triphenylsulfonium monochloroacetate, triphenylsulfonium dichloroacetate, triphenylsulfonium trichloroacetate, triphenylsulfonium hydroxide, triphenylsulfonium nitrate, triphenylsulfonium chloride, triphenylsulfonium bromide, triphenylsulfonium oxalate, triphenylsulfonium malonate, triphenylsulfonium methylmalonate, triphenylsulfonium ethylmalonate, triphenylsulfonium propylmalonate, triphenylsulfonium butylmalonate, triphenylsulfonium dimethylmalonate, triphenylsulfonium diethylmalonate, triphenylsulfonium succinate, triphenylsulfonium methylsuccinate, triphenylsulfonium glutarate, triphenylsulfonium adipate, triphenylsulfonium itaconate, triphenylsulfonium maleate, triphenylsulfonium fumarate, triphenylsulfonium citraconate, triphenylsulfonium citrate, triphenylsulfonium carbonate, bistriphenylsulfonium oxalate, bistriphenylsulfonium maleate, bistriphenylsulfonium fumarate, bistriphenylsulfonium citraconate, bistriphenylsulfonium citrate, and bistriphenylsulfonium carbonate.

(Iodonium salt (Xc-2))

Specific examples of the iodonium salt (Xc-2) include diphenyliodonium formate, diphenyliodonium acetate, diphenyliodonium propionate, diphenyliodonium butanoate, diphenyliodonium benzoate, diphenyliodonium phthalate, diphenyliodonium isophthalate, diphenyliodonium terephthalate, diphenyliodonium salicylate, diphenyliodonium trifluoromethanesulfonate, diphenyliodonium trifluoroacetate, diphenyliodonium monochloroacetate, diphenyliodonium dichloroacetate, diphenyliodonium trichloroacetate, diphenyliodonium hydroxide, diphenyliodonium nitrate, diphenyliodonium chloride, diphenyliodonium bromide, diphenyliodonium iodide, diphenyliodonium oxalate, diphenyliodonium maleate, diphenyliodonium fumarate, diphenyliodonium citraconate, diphenyliodonium citrate, diphenyliodonium carbonate, bisdiphenyliodonium oxalate, bisdiphenyliodonium maleate, bisdiphenyliodonium fumarate, bisdiphenyliodonium citraconate, bisdiphenyliodonium citrate, and bisdiphenyliodonium carbonate.

(Phosphonium salt (Xc-3))

Specific examples of the phosphonium salt (Xc-3) include tetraethylphosphonium formate, tetraethylphosphonium acetate, tetraethylphosphonium propionate, tetraethylphosphonium butanoate, tetraethylphosphonium benzoate, tetraethylphosphonium phthalate, tetraethylphosphonium isophthalate, tetraethylphosphonium terephthalate, tetraethylphosphonium salicylate, tetraethylphosphonium trifluoromethanesulfonate, tetraethylphosphonium trifluoroacetate, tetraethylphosphonium monochloroacetate, tetraethylphosphonium dichloroacetate, tetraethylphosphonium trichloroacetate, tetraethylphosphonium hydroxide, tetraethylphosphonium nitrate, tetraethylphosphonium chloride, tetraethylphosphonium bromide, tetraethylphosphonium iodide, tetraethylphosphonium oxalate, tetraethylphosphonium maleate, tetraethylphosphonium fumarate, tetraethylphosphonium citraconate, tetraethylphosphonium citrate, tetraethylphosphonium carbonate, bistetraethylphosphonium oxalate, bistetraethylphosphonium maleate, bistetraethylphosphonium fumarate, bistetraethylphosphonium citraconate, bistetraethylphosphonium citrate, bistetraethylphosphonium carbonate, tetraphenylphosphonium formate, tetraphenylphosphonium acetate, tetraphenylphosphonium propionate, tetraphenylphosphonium butanoate, tetraphenylphosphonium benzoate, tetraphenylphosphonium phthalate, tetraphenylphosphonium isophthalate, tetraphenylphosphonium terephthalate, tetraphenylphosphonium salicylate, tetraphenylphosphonium trifluoromethanesulfonate, tetraphenylphosphonium trifluoroacetate, tetraphenylphosphonium monochloroacetate, tetraphenylphosphonium dichloroacetate, tetraphenylphosphonium trichloroacetate, tetraphenylphosphonium hydroxide, tetraphenylphosphonium nitrate, tetraphenylphosphonium chloride, tetraphenylphosphonium bromide, tetraphenylphosphonium iodide, tetraphenylphosphonium oxalate, tetraphenylphosphonium maleate, tetraphenylphosphonium fumarate, tetraphenylphosphonium citraconate, tetraphenylphosphonium citrate, tetraphenylphosphonium carbonate, bistetraphenylphosphonium oxalate, bistetraphenylphosphonium maleate, bistetraphenylphosphonium fumarate, bistetraphenylphosphonium citraconate, bistetraphenylphosphonium citrate, and bistetraphenylphosphonium carbonate.

(Ammonium salt (Xc-4))

Specific examples of the ammonium salt (Xc-4) can include tetramethylammonium formate, tetramethylammonium acetate, tetramethylammonium propionate, tetramethylammonium butanoate, tetramethylammonium benzoate, tetramethylammonium phthalate, tetramethylammonium isophthalate, tetramethylammonium terephthalate, tetramethylammonium salicylate, tetramethylammonium trifluoromethanesulfonate, tetramethylammonium trifluoroacetate, tetramethylammonium monochloroacetate, tetramethylammonium dichloroacetate, tetramethylammonium trichloroacetate, tetramethylammonium hydroxide, tetramethylammonium nitrate, tetramethylammonium chloride, tetramethylammonium bromide, tetramethylammonium iodide, tetramethylammonium monomethylsulfate, tetramethylammonium oxalate, tetramethylammonium malonate, tetramethylammonium maleate, tetramethylammonium fumarate, tetramethylammonium citraconate, tetramethylammonium citrate, tetramethylammonium carbonate, bistetramethylammonium oxalate, bistetramethylammonium malonate, bistetramethylammonium maleate, bistetramethylammonium fumarate, bistetramethylammonium citraconate, bistetramethylammonium citrate, bistetramethylammonium carbonate, tetraethylammonium formate, tetraethylammonium acetate, tetraethylammonium propionate, tetraethylammonium butanoate, tetraethylammonium benzoate, tetraethylammonium phthalate, tetraethylammonium isophthalate, tetraethylammonium terephthalate, tetraethylammonium salicylate, tetraethylammonium trifluoromethanesulfonate, tetraethylammonium trifluoroacetate, tetraethylammonium monochloroacetate, tetraethylammonium dichloroacetate, tetraethylammonium trichloroacetate, tetraethylammonium hydroxide, tetraethylammonium nitrate, tetraethylammonium chloride, tetraethylammonium bromide, tetraethylammonium iodide, tetraethylammonium monomethylsulfate, tetraethylammonium oxalate, tetraethylammonium malonate, tetraethylammonium maleate, tetraethylammonium fumarate, tetraethylammonium citraconate, tetraethylammonium citrate, tetraethylammonium carbonate, bistetraethylammonium oxalate, bistetraethylammonium malonate, bistetraethylammonium maleate, bistetraethylammonium fumarate, bistetraethylammonium citraconate, bistetraethylammonium citrate, bistetraethylammonium carbonate, tetrapropylammonium formate, tetrapropylammonium acetate, tetrapropylammonium propionate, tetrapropylammonium butanoate, tetrapropylammonium benzoate, tetrapropylammonium phthalate, tetrapropylammonium isophthalate, tetrapropylammonium terephthalate, tetrapropylammonium salicylate, tetrapropylammonium trifluoromethanesulfonate, tetrapropylammonium trifluoroacetate, tetrapropylammonium monochloroacetate, tetrapropylammonium dichloroacetate, tetrapropylammonium trichloroacetate, tetrapropylammonium hydroxide, tetrapropylammonium nitrate, tetrapropylammonium chloride, tetrapropylammonium bromide, tetrapropylammonium iodide, tetrapropylammonium monomethylsulfate, tetrapropylammonium oxalate, tetrapropylammonium malonate, tetrapropylammonium maleate, tetrapropylammonium fumarate, tetrapropylammonium citraconate, tetrapropylammonium citrate, tetrapropylammonium carbonate, bistetrapropylammonium oxalate, bistetrapropylammonium malonate, bistetrapropylammonium maleate, bistetrapropylammonium fumarate, bistetrapropylammonium citraconate, bistetrapropylammonium citrate, bistetrapropylammonium carbonate, tetrabutylammonium formate, tetrabutylammonium acetate, tetrabutylammonium propionate, tetrabutylammonium butanoate, tetrabutylammonium benzoate, tetrabutylammonium phthalate, tetrabutylammonium isophthalate, tetrabutylammonium terephthalate, tetrabutylammonium salicylate, tetrabutylammonium trifluoromethanesulfonate, tetrabutylammonium trifluoroacetate, tetrabutylammonium monochloroacetate, tetrabutylammonium dichloroacetate, tetrabutylammonium trichloroacetate, tetrabutylammonium hydroxide, tetrabutylammonium nitrate, tetrabutylammonium chloride, tetrabutylammonium bromide, tetrabutylammonium iodide, tetrabutylammonium methanesulfonate, tetrabutylammonium monomethylsulfate, tetrabutylammonium oxalate, tetrabutylammonium malonate, tetrabutylammonium maleate, tetrabutylammonium fumarate, tetrabutylammonium citraconate, tetrabutylammonium citrate, tetrabutylammonium carbonate, bistetrabutylammonium oxalate, bistetrabutylammonium malonate, bistetrabutylammonium maleate, bistetrabutylammonium fumarate, bistetrabutylammonium citraconate, bistetrabutylammonium citrate, bistetrabutylammonium carbonate, trimethylphenylammonium formate, trimethylphenylammonium acetate, trimethylphenylammonium propionate, trimethylphenylammonium butanoate, trimethylphenylammonium benzoate, trimethylphenylammonium phthalate, trimethylphenylammonium isophthalate, trimethylphenylammonium terephthalate, trimethylphenylammonium salicylate, trimethylphenylammonium trifluoromethanesulfonate, trimethylphenylammonium trifluoroacetate, trimethylphenylammonium monochloroacetate, trimethylphenylammonium dichloroacetate, trimethylphenylammonium trichloroacetate, trimethylphenylammonium hydroxide, trimethylphenylammonium nitrate, trimethylphenylammonium chloride, trimethylphenylammonium bromide, trimethylphenylammonium iodide, trimethylphenylammonium methanesulfonate, trimethylphenylammonium monomethylsulfate, trimethylphenylammonium oxalate, trimethylphenylammonium malonate, trimethylphenylammonium maleate, trimethylphenylammonium fumarate, trimethylphenylammonium citraconate, trimethylphenylammonium citrate, trimethylphenylammonium carbonate, bistrimethylphenylammonium oxalate, bistrimethylphenylammonium malonate, bistrimethylphenylammonium maleate, bistrimethylphenylammonium fumarate, bistrimethylphenylammonium citraconate, bistrimethylphenylammonium citrate, bistrimethylphenylammonium carbonate, triethylphenylammonium formate, triethylphenylammonium acetate, triethylphenylammonium propionate, triethylphenylammonium butanoate, triethylphenylammonium benzoate, triethylphenylammonium phthalate, triethylphenylammonium isophthalate, triethylphenylammonium terephthalate, triethylphenylammonium salicylate, triethylphenylammonium trifluoromethanesulfonate, triethylphenylammonium trifluoroacetate, triethylphenylammonium monochloroacetate, triethylphenylammonium dichloroacetate, triethylphenylammonium trichloroacetate, triethylphenylammonium hydroxide, triethylphenylammonium nitrate, triethylphenylammonium chloride, triethylphenylammonium bromide, triethylphenylammonium iodide, triethylphenylammonium methanesulfonate, triethylphenylammonium monomethylsulfate, triethylphenylammonium oxalate, triethylphenylammonium malonate, triethylphenylammonium maleate, triethylphenylammonium fumarate, triethylphenylammonium citraconate, triethylphenylammonium citrate, triethylphenylammonium carbonate, bistriethylphenylammonium oxalate, bistriethylphenylammonium malonate, bistriethylphenylammonium maleate, bistriethylphenylammonium fumarate, bistriethylphenylammonium citraconate, bistriethylphenylammonium citrate, bistriethylphenylammonium carbonate, benzyldimethylphenylammonium formate, benzyldimethylphenylammonium acetate, benzyldimethylphenylammonium propionate, benzyldimethylphenylammonium butanoate, benzyldimethylphenylammonium benzoate, benzyldimethylphenylammonium phthalate, benzyldimethylphenylammonium isophthalate, benzyldimethylphenylammonium terephthalate, benzyldimethylphenylammonium salicylate, benzyldimethylphenylammonium trifluoromethanesulfonate, benzyldimethylphenylammonium trifluoroacetate, benzyldimethylphenylammonium monochloroacetate, benzyldimethylphenylammonium dichloroacetate, benzyldimethylphenylammonium trichloroacetate, benzyldimethylphenylammonium hydroxide, benzyldimethylphenylammonium nitrate, benzyldimethylphenylammonium chloride, benzyldimethylphenylammonium bromide, benzyldimethylphenylammonium iodide, benzyldimethylphenylammonium methanesulfonate, benzyldimethylphenylammonium monomethylsulfate, benzyldimethylphenylammonium oxalate, benzyldimethylphenylammonium malonate, benzyldimethylphenylammonium maleate, benzyldimethylphenylammonium fumarate, benzyldimethylphenylammonium citraconate, benzyldimethylphenylammonium citrate, benzyldimethylphenylammonium carbonate, bisbenzyldimethylphenylammonium oxalate, bisbenzyldimethylphenylammonium malonate, bisbenzyldimethylphenylammonium maleate, bisbenzyldimethylphenylammonium fumarate, bisbenzyldimethylphenylammonium citraconate, bisbenzyldimethylphenylammonium citrate, and bisbenzyldimethylphenylammonium carbonate.

(Alkali metal salt)

Examples of the alkali metal salt can include lithium formate, lithium acetate, lithium propionate, lithium butanoate, lithium benzoate, lithium phthalate, lithium isophthalate, lithium terephthalate, lithium salicylate, lithium trifluoromethanesulfonate, lithium trifluoroacetate, lithium monochloroacetate, lithium dichloroacetate, lithium trichloroacetate, lithium hydroxide, lithium nitrate, lithium chloride, lithium bromide, lithium iodide, lithium methanesulfonate, lithium hydrogen oxalate, lithium hydrogen malonate, lithium hydrogen maleate, lithium hydrogen fumarate, lithium hydrogen citraconate, lithium hydrogen citrate, lithium hydrogen carbonate, lithium oxalate, lithium malonate, lithium maleate, lithium fumarate, lithium citraconate, lithium citrate, lithium carbonate, sodium formate, sodium acetate, sodium propionate, sodium butanoate, sodium benzoate, sodium phthalate, sodium isophthalate, sodium terephthalate, sodium salicylate, sodium trifluoromethanesulfonate, sodium trifluoroacetate, sodium monochloroacetate, sodium dichloroacetate, sodium trichloroacetate, sodium hydroxide, sodium nitrate, sodium chloride, sodium bromide, sodium iodide, sodium methanesulfonate, sodium hydrogen oxalate, sodium hydrogen malonate, sodium hydrogen maleate, sodium hydrogen fumarate, sodium hydrogen citraconate, sodium hydrogen citrate, sodium hydrogen carbonate, sodium oxalate, sodium malonate, sodium maleate, sodium fumarate, sodium citraconate, sodium citrate, sodium carbonate, potassium formate, potassium acetate, potassium propionate, potassium butanoate, potassium benzoate, potassium phthalate, potassium isophthalate, potassium terephthalate, potassium salicylate, potassium trifluoromethanesulfonate, potassium trifluoroacetate, potassium monochloroacetate, potassium dichloroacetate, potassium trichloroacetate, potassium hydroxide, potassium nitrate, potassium chloride, potassium bromide, potassium iodide, potassium methanesulfonate, potassium hydrogen oxalate, potassium hydrogen malonate, potassium hydrogen maleate, potassium hydrogen fumarate, potassium hydrogen citraconate, potassium hydrogen citrate, potassium hydrogen carbonate, potassium oxalate, potassium malonate, potassium maleate, potassium fumarate, potassium citraconate, potassium citrate, and potassium carbonate.

[Thermosetting polysiloxane having ammonium salt, sulfonium salt, phosphonium salt, or iodonium salt as one portion of structure, as curing catalyst (Xc)]

Examples of such a crosslinking catalyst (Xc) for polymerization in the present invention can include a thermosetting polysiloxane (Xc-10) having an ammonium salt, a sulfonium salt, a phosphonium salt, or an iodonium salt as one portion of the structure.

A compound represented by the following general formula (Xm) can be used as a raw material for production of (Xc-10) used here:

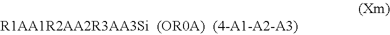

wherein R0A is a hydrocarbon group having 1 to 6 carbon atoms, at least one of R1A, R2A, and R3A is an organic group having an ammonium salt, a sulfonium salt, a phosphonium salt, or an iodonium salt, and the others are each a hydrogen atom or a monovalent organic group having 1 to 30 carbon atoms; and A1, A2, and A3 are each 0 or 1 and 1 A1+A2+A3≤3 is satisfied.

Examples of ROA can here include a methyl group, an ethyl group, a n-propyl group, an iso-propyl group, a n-butyl group, an iso-butyl group, a sec-butyl group, a tert-butyl group, a n-pentyl group, a cyclopentyl group, a n-hexyl group, a cyclohexyl group, and a phenyl group.

(Hydrolyzable silicon compound (Xm-1) having sulfonium salt as one portion of structure)

For example, the following general formula (Xm-1) can be exemplified as Xm in a hydrolyzable silicon compound having a sulfonium salt as one portion of the structure.

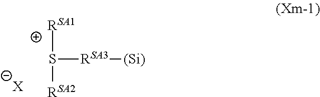

In the formula, R^{SA1} and R^{SA2} each represent a straight, branched or cyclic alkyl group, alkenyl group, oxoalkyl group or oxoalkenyl group having 1 to 20 carbon atoms, a substituted or unsubstituted aryl group having 6 to 20 carbon atoms, or an aralkyl group or aryloxyalkyl group having 7 to 20 carbon atoms, and some or all of hydrogen atoms in such a group are each optionally substituted by an alkoxy group, an amino group, an alkylamino group, a halogen atom or the like; R^{SA1} and R^{SA2} may form a ring together with a sulfur atom to which R^{SA1} and R^{SA2} bound, and when a ring is formed R^{SA1} and R^{SA2} each represent an alkylene group having 1 to 6 carbon atoms; R^{SA3} is a straight, branched or cyclic alkylene group or alkenylene group having 1 to 20 carbon atoms, or a substituted or unsubstituted arylene group or aralkylene group having 6 to 20 carbon atoms, and some or all of hydrogen atoms in such a group are each optionally substituted by an alkoxy group, an amino group, an alkylamino group or the like; and R^{SA1}, R^{SA2}, and R^{SA3} each optionally have an oxygen atom or a nitrogen atom in its chain or ring.

In the general formula (Xm-1), (Si) is designated for representing a binding position with Si.

Examples of X− include a hydroxy ion, a formate ion, an acetate ion, a propionate ion, a butanoate ion, a pentanoate ion, a hexanoate ion, a heptanoate ion, an octanoate ion, a nonanoate ion, a decanoate ion, an oleate ion, a stearate ion, a linoleate ion, a linolenate ion, a benzoate ion, a p-methylbenzoate ion, a p-t-butylbenzoate ion, a phthalate ion, an isophthalate ion, a terephthalate ion, a salicylate ion, a trifluoroacetate ion, a monochloroacetate ion, a dichloroacetate ion, a trichloroacetate ion, a nitrate ion, a chlorate ion, a perchlorate ion, a bromate ion, an iodate ion, an oxalate ion, a malonate ion, a methylmalonate ion, an ethylmalonate ion, a propylmalonate ion, a butylmalonate ion, a dimethylmalonate ion, a diethylmalonate ion, a succinate ion, a methylsuccinate ion, a glutarate ion, an adipate ion, an itaconate ion, a maleate ion, a fumarate ion, a citraconate ion, a citrate ion, and a carbonate ion.

Specific examples of a cation moiety of the compound represented by the general formula (Xm-1) include the following ions (X− is the same as described above).

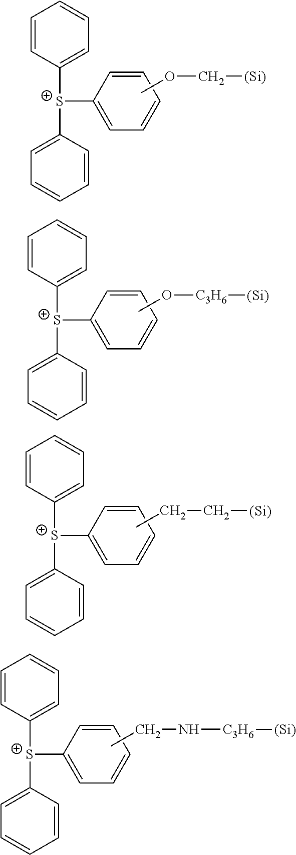

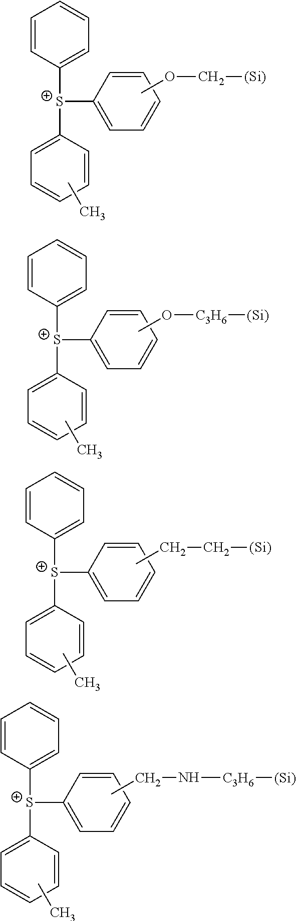

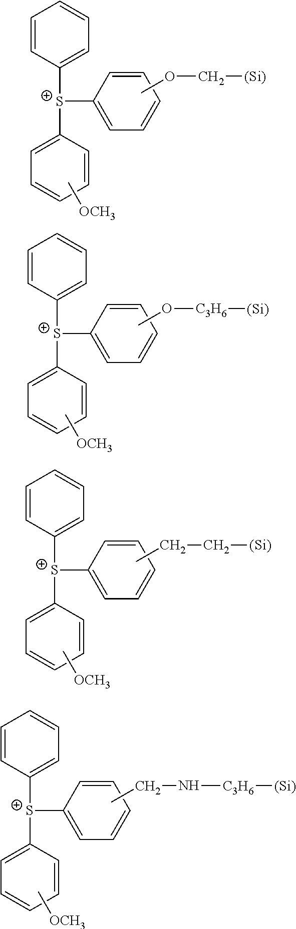

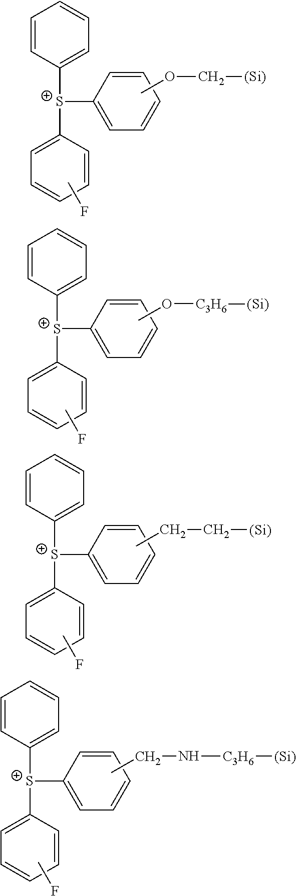

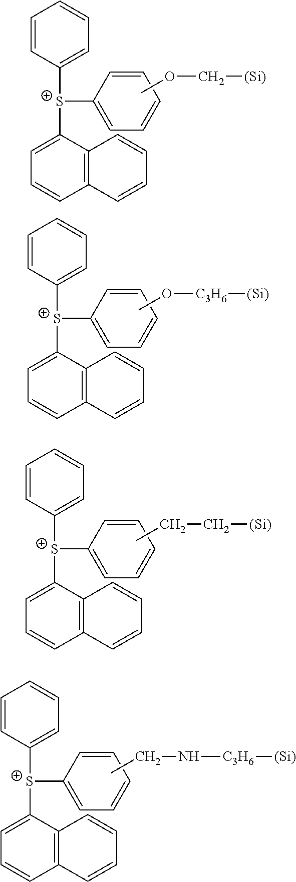

(Hydrolyzable silicon compound having iodonium salt as one portion of structure)

For example, the following general formula (Xm-2) can be exemplified as a hydrolyzable silicon compound having an iodonium salt as one portion of the structure.

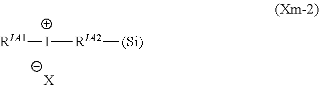

In the formula, R^{IA1} represents a straight, branched or cyclic alkyl group, alkenyl group, oxoalkyl group or oxoalkenyl group having 1 to 20 carbon atoms, a substituted or unsubstituted aryl group having 6 to 20 carbon atoms, or an aralkyl group or aryloxoalkyl group having 7 to 20 carbon atoms, and some or all of hydrogen atoms in this group are each optionally substituted by an alkoxy group, an amino group, an alkylamino group, a halogen atom, or the like; R^{IP1} and R^{IP2} may form a ring together with a nitrogen atom to which R^{IP1} and R^{IP2} bound, when a ring is formed R^{IP1} and R^{IP2} each represent an alkylene group having 1 to 6 carbon atoms; R^{IP2} is a straight, branched or cyclic alkylene group or alkenylene group having 1 to 20 carbon atoms, or a substituted or unsubstituted arylene group or aralkylene group having 6 to 20 carbon atoms, and some or all of hydrogen atoms in such a group are each optionally substituted by an alkoxy group, an amino group, an alkylamino group, or the like; and R^{IP1} to R^{IP2} each optionally have an oxygen atom or a nitrogen atom in its chain or ring.

In the general formula (Xm-2), (Si) is designated for representing a binding position with Si. X− is as described above.

Specific examples of a cation moiety of the compound represented by the general formula (Xm-2) include the following ions (X− is the same as described above).

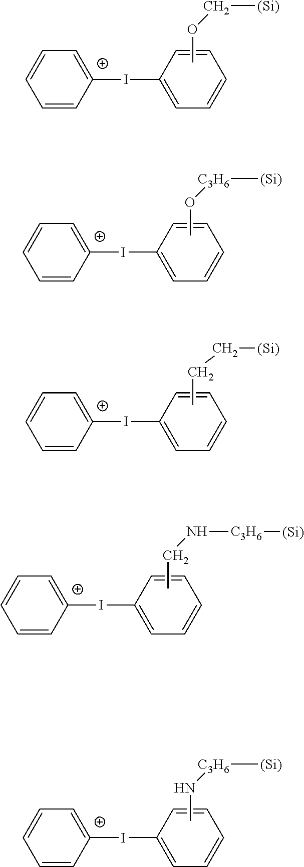

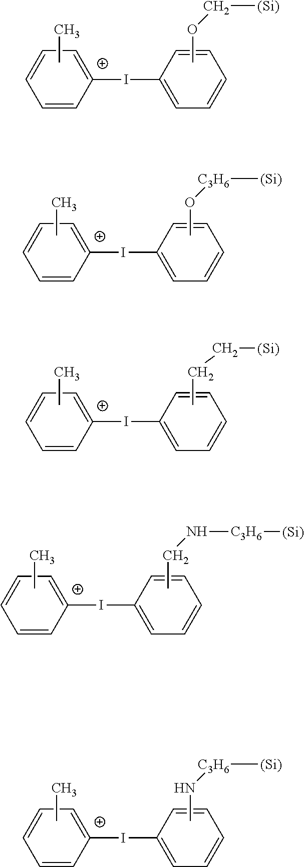

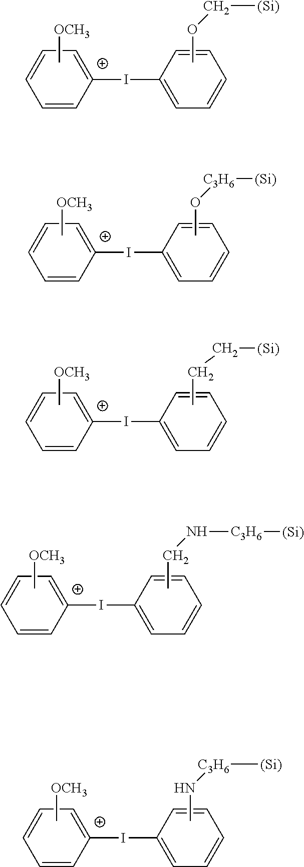

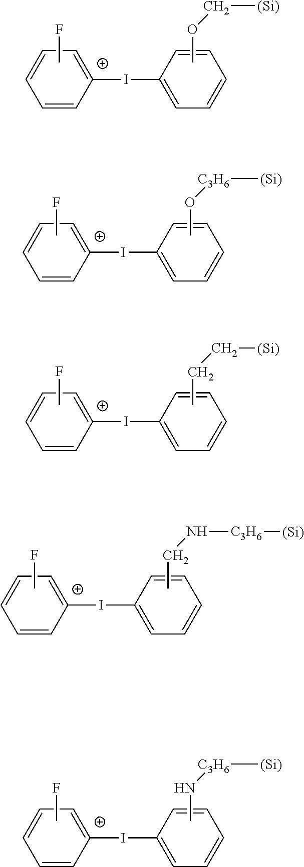

(Hydrolyzable silicon compound having phosphonium salt as one portion of structure)

For example, the following general formula (Xm-3) can be exemplified as a hydrolyzable silicon compound having a phosphonium salt as one portion of the structure.

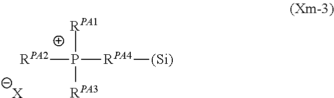

In the formula, R^{PA1}, R^{PA2}, and R^{PA3} each represent a straight, branched or cyclic alkyl group, alkenyl group, oxoalkyl group or oxoalkenyl group having 1 to 20 carbon atoms, a substituted or unsubstituted aryl group having 6 to 20 carbon atoms, or an aralkyl group or aryloxoalkyl group having 7 to 20 carbon atoms, and some or all of hydrogen atoms in such a group are each optionally substituted by an alkoxy group, an amino group, an alkylamino group, a halogen atom, or the like; R^{PA1} and R^{PA2} may form ring together with a phosphorus atom to which R^{PA1} and R^{PA2} bound, and when a ring is formed, R^{PA1} and R^{PA2} each represent an alkylene group having 1 to 6 carbon atoms; R^{PA4} is a straight, branched or cyclic alkylene group or alkenylene group having 1 to 20 carbon atoms, or a substituted or unsubstituted arylene group or aralkylene group having 6 to 20 carbon atoms, and some or all of hydrogen atoms in such a group are each optionally substituted by an alkoxy group, an amino group, an alkylamino group, or the like; and R^{PA1} to R^{PA4} each optionally have an oxygen atom or a nitrogen atom in its chain or ring.

In the general formula (Xm-3), (Si) is designated for representing a binding position with Si. X− is as described above.

Specific examples of a cation moiety of the compound represented by the general formula (Xm-3) include the following ions (X− is the same as described above).

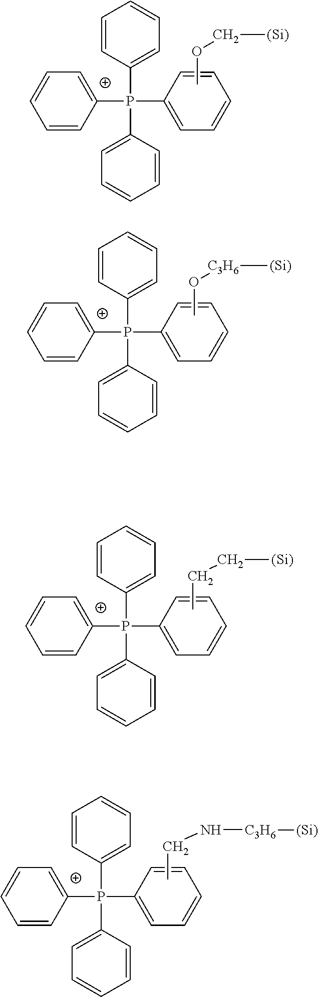

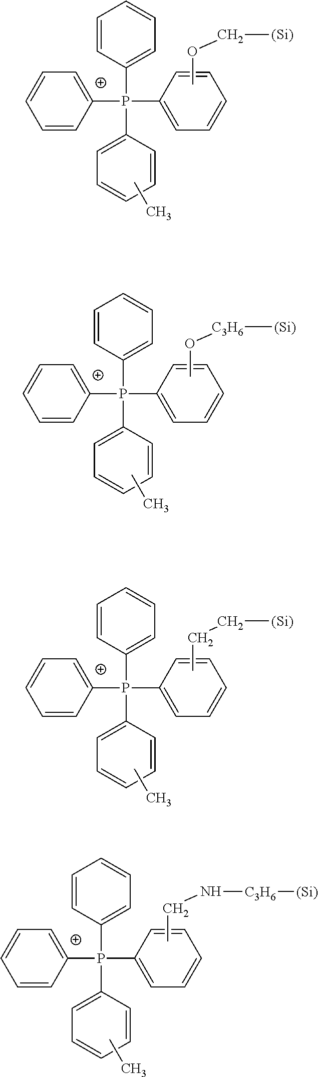

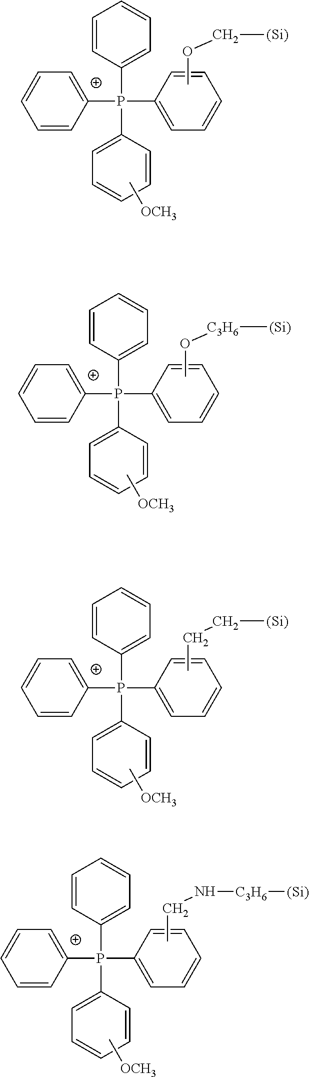

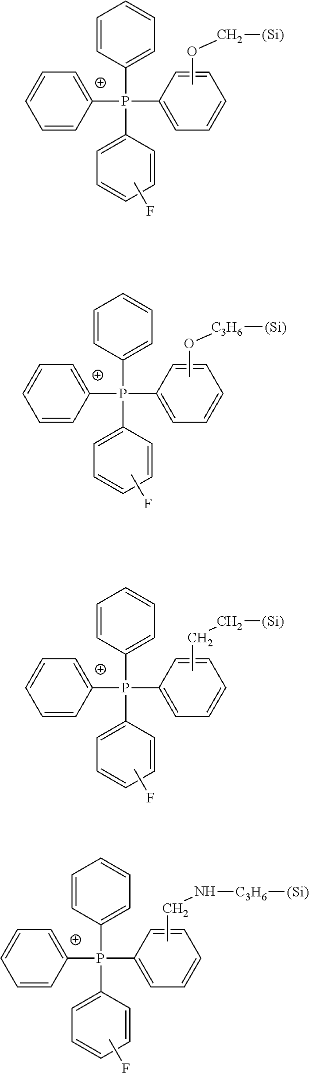

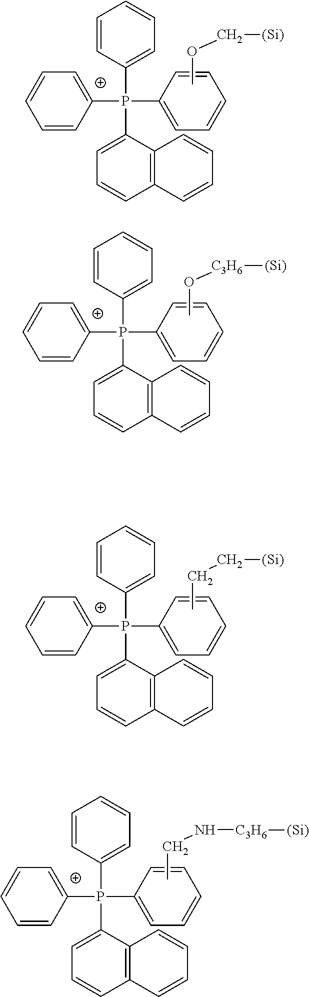

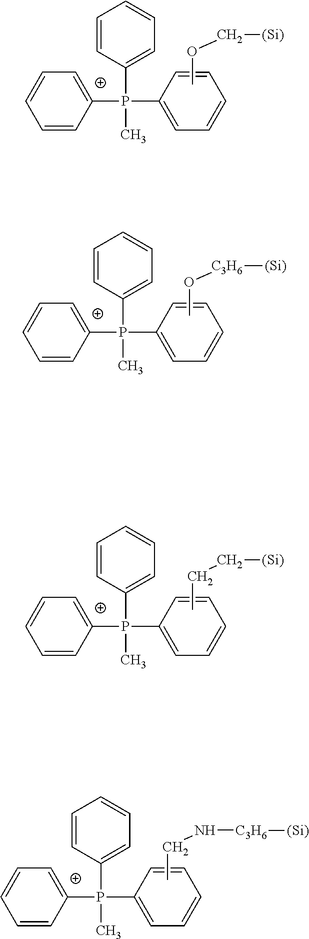

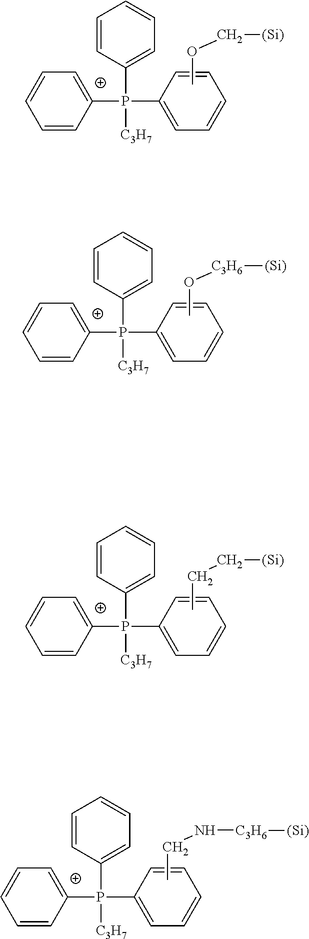

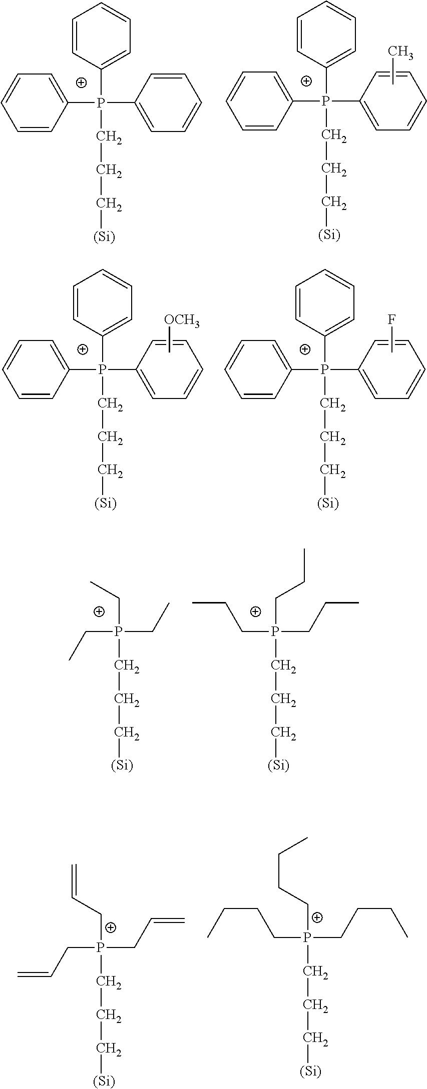

(Hydrolyzable silicon compound having ammonium salt as one portion of structure)

For example, the following general formula (Xm-4) can be exemplified as a hydrolyzable silicon compound having an ammonium salt as one portion of the structure.

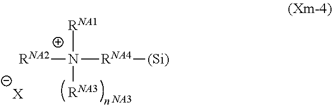

In the formula, R^{NA1}, R^{NA2}, and R^{NA3} each represent a hydrogen atom, a straight, branched or cyclic alkyl group, alkenyl group, oxoalkyl group or oxoalkenyl group having 1 to 20 carbon atoms, a substituted or unsubstituted aryl group having 6 to 20 carbon atoms, or an aralkyl group or aryloxyalkyl group having 7 to 20 carbon atoms, and some or all of hydrogen atoms in such a group are each a monovalent organic group optionally substituted by an alkoxy group, an amino group, an alkylamino group, or the like; R^{PA1} and R^{PA2} may form ring together with a nitrogen atom to which R^{PA1} and R^{PA2} bound, and when a ring is formed, R^{PA1} and R^{PA2} each represent an alkylene group having 1 to 6 carbon atoms, or a cyclic heterocycle or heteroaromatic ring containing nitrogen. R^{NA4} is a straight, branched or cyclic alkylene group or alkenylene group having 1 to 23 carbon atoms, a substituted or unsubstituted arylene group having 6 to 29 carbon atoms, or a divalent organic group in which some or all of hydrogen atoms in such a group are each optionally substituted by an alkoxy group, an amino group, an alkylamino group, or the like, and in a case where R^{NA1} and R^{NA2}, and R^{N}A1 and R^{N}A4 each form a cyclic structure and further contain unsaturated nitrogen, nNA3=0 is satisfied, or in any other case, nNA3=1 is satisfied.

In the general formula (Xm-4), (Si) is designated for representing a binding position with Si. X− is as described above.

Specific examples of a cation moiety of the compound represented by the general formula (Xm-4) include the following ions (X− is the same as described above).

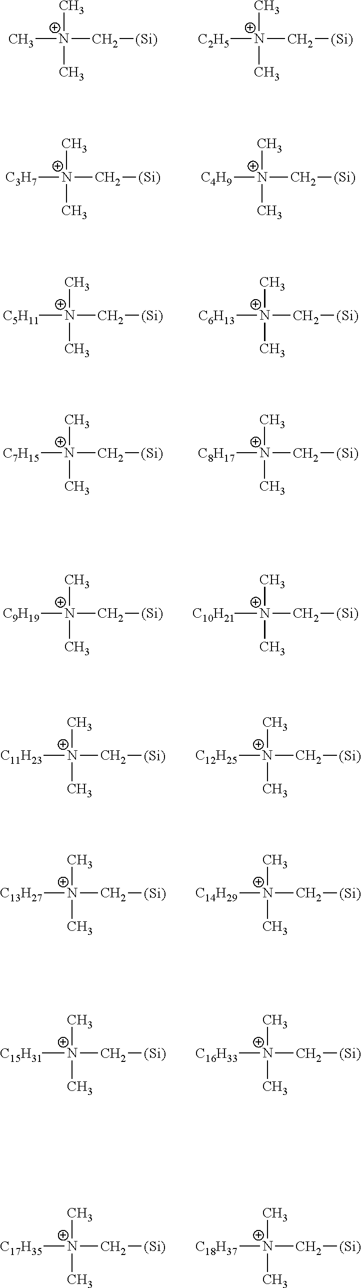

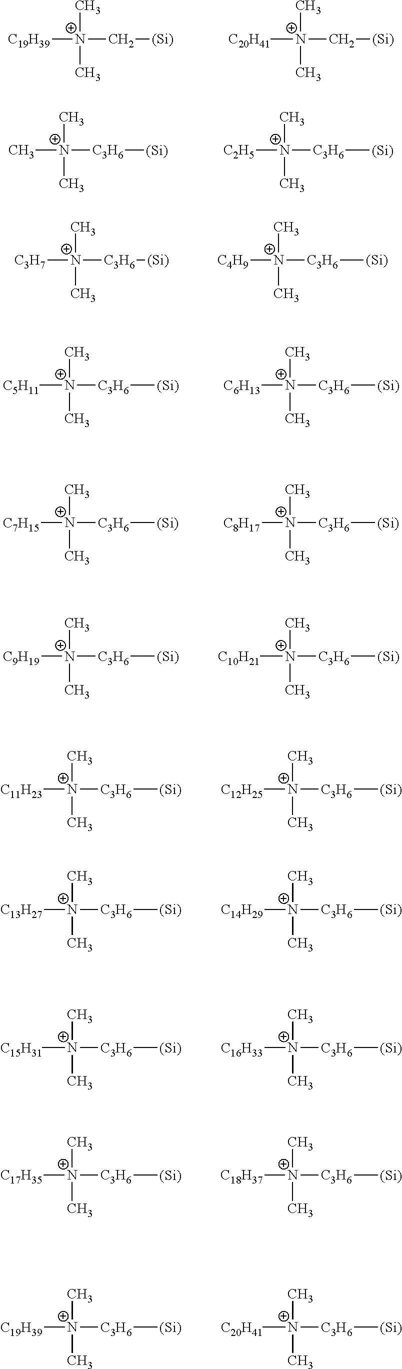

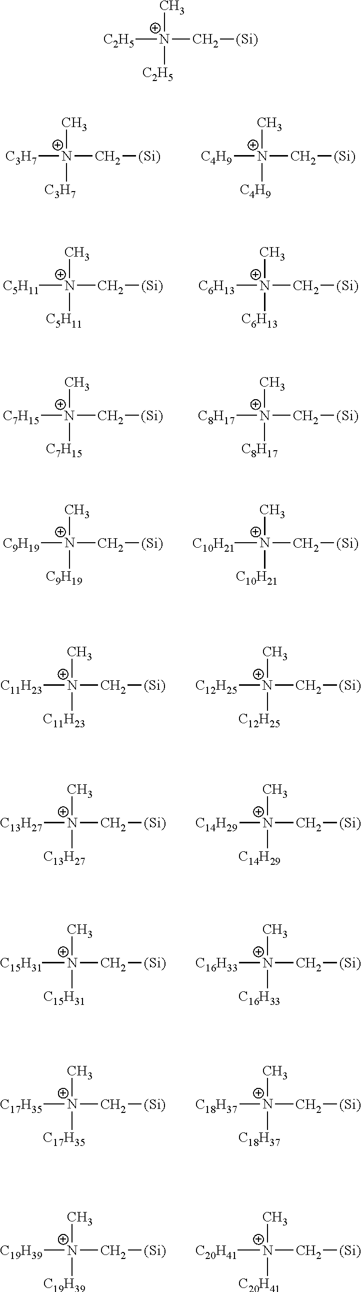

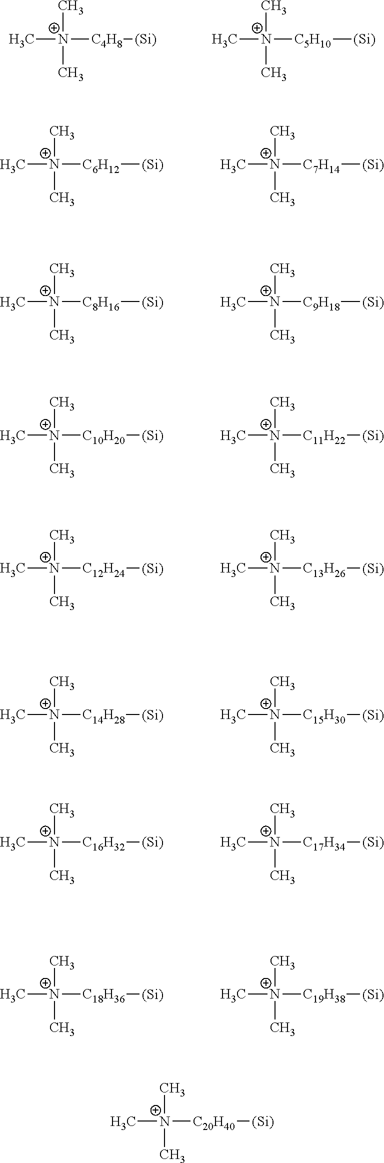

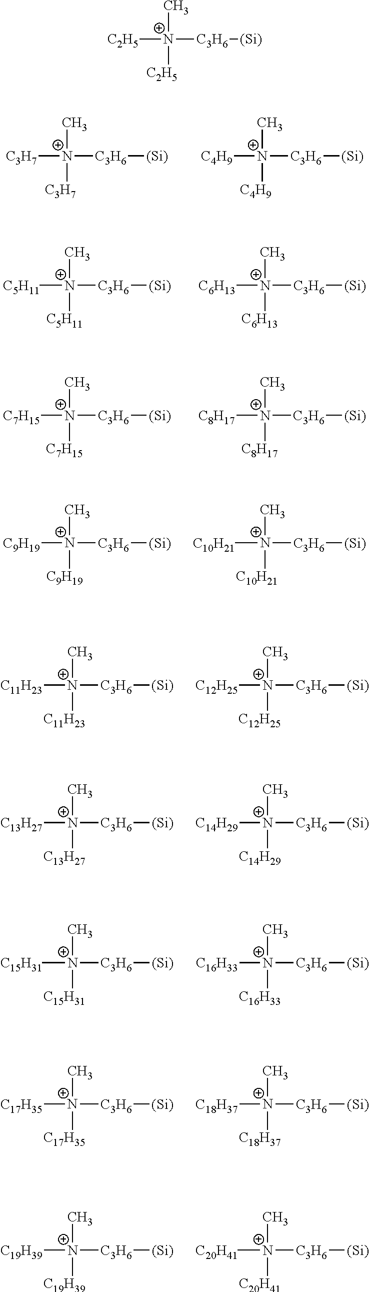

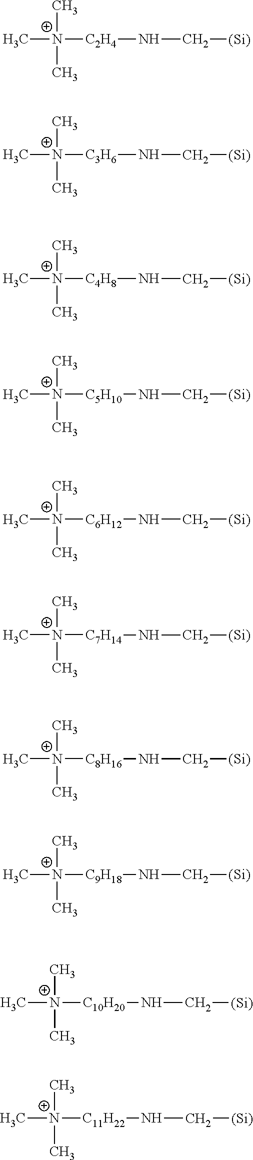

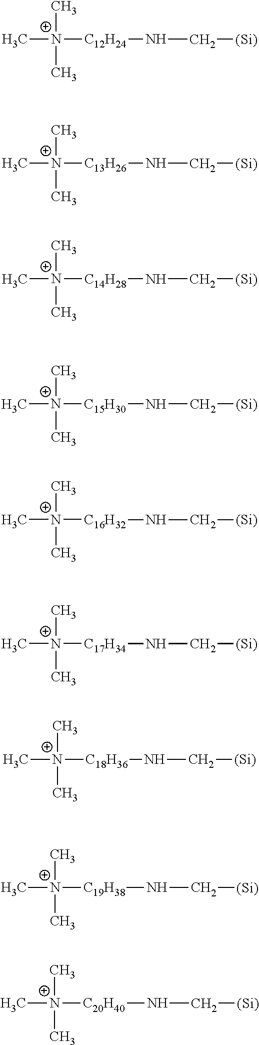

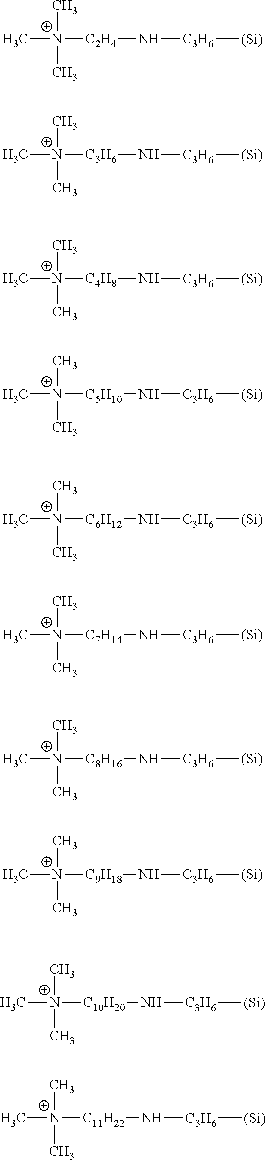

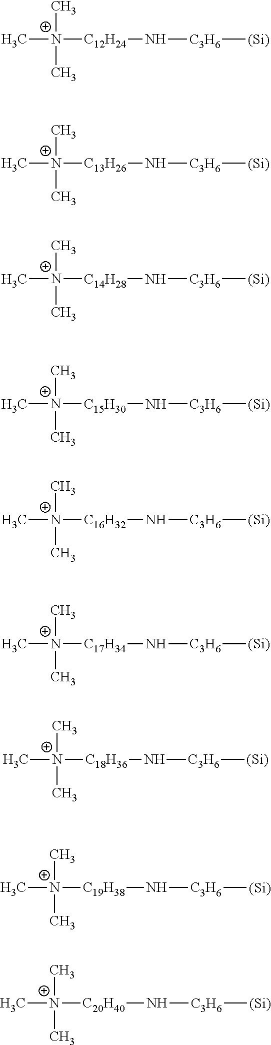

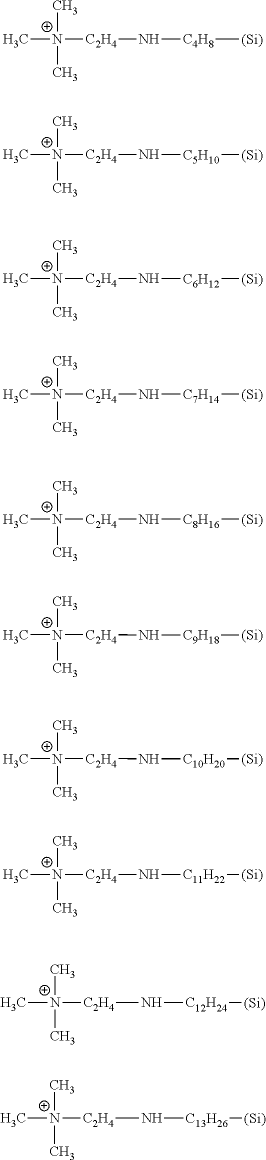

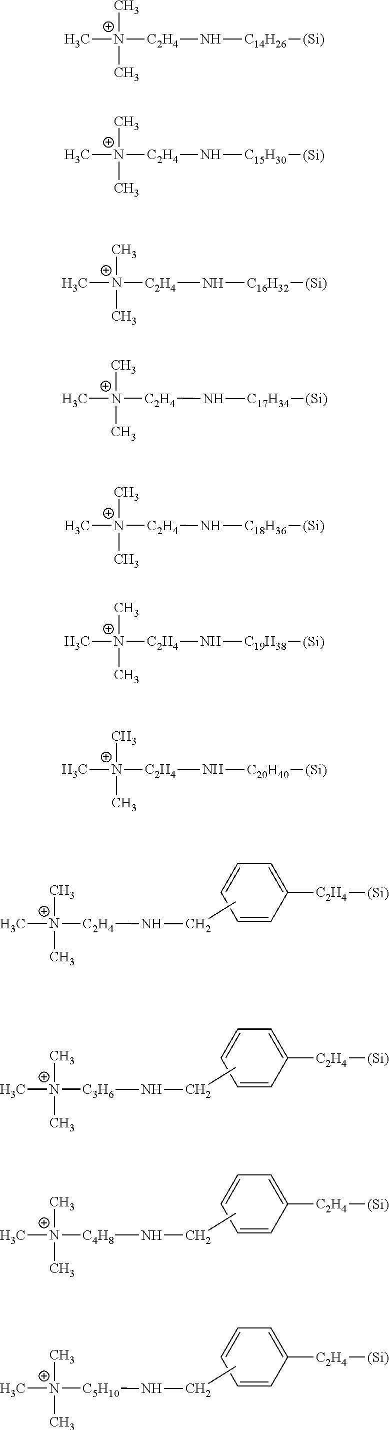

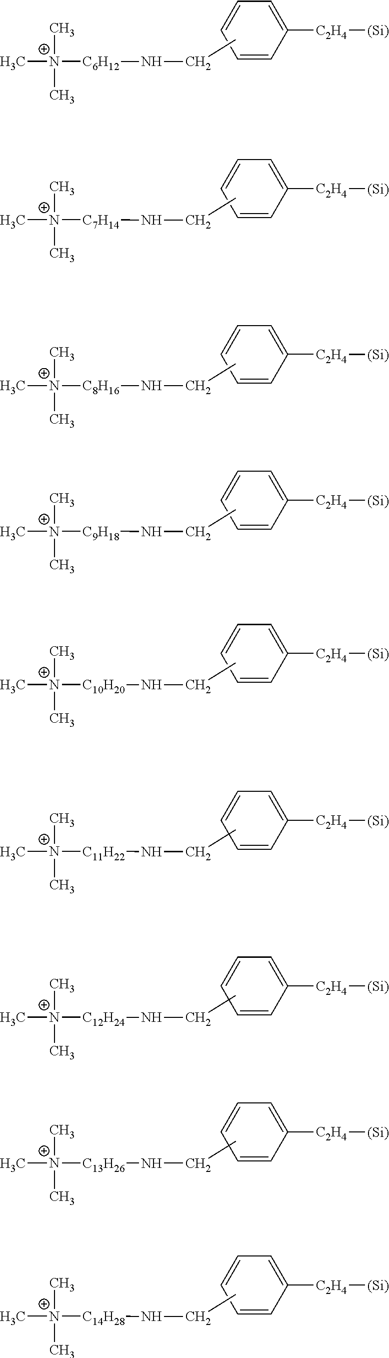

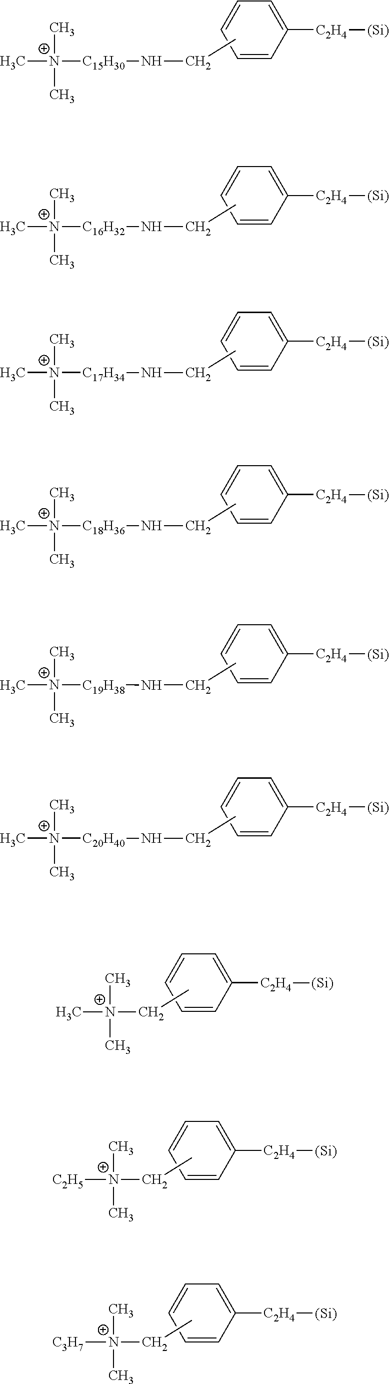

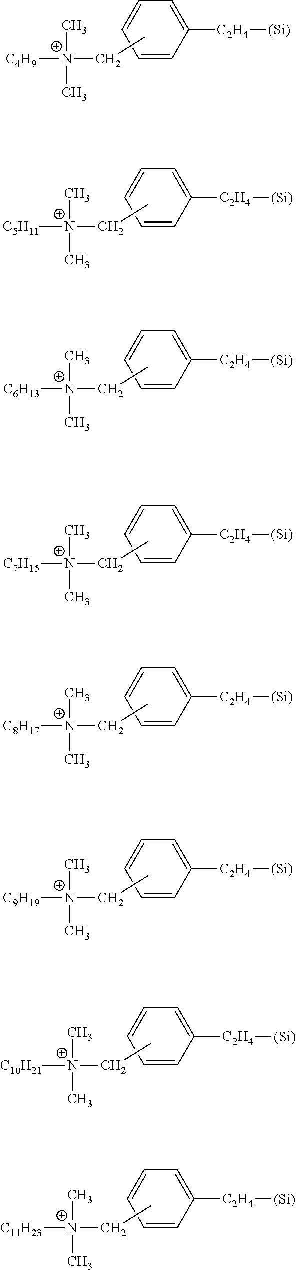

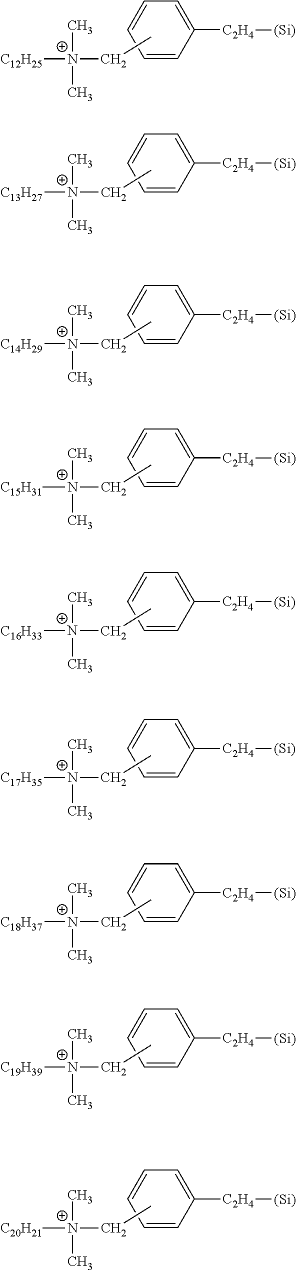

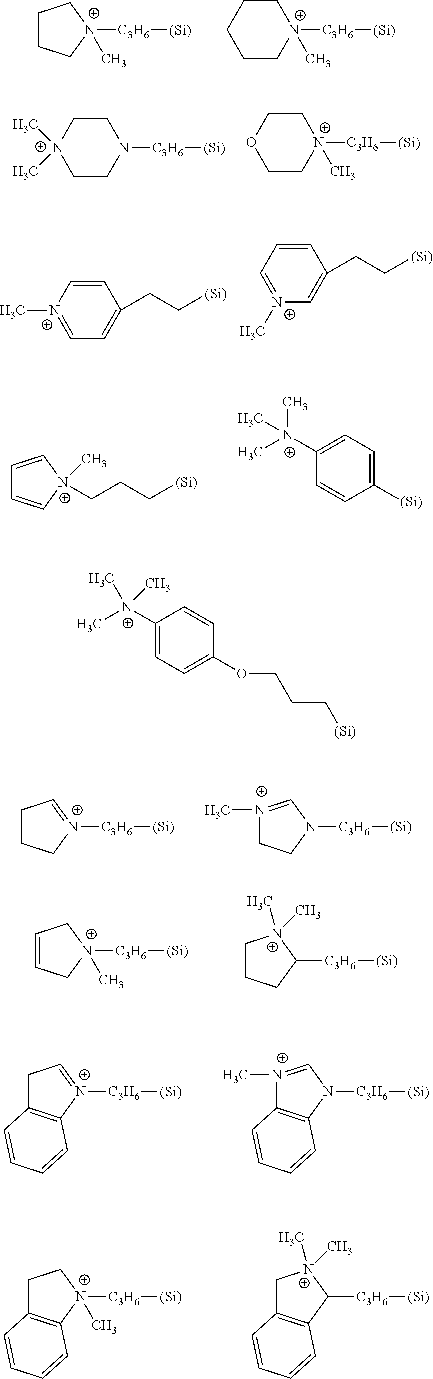

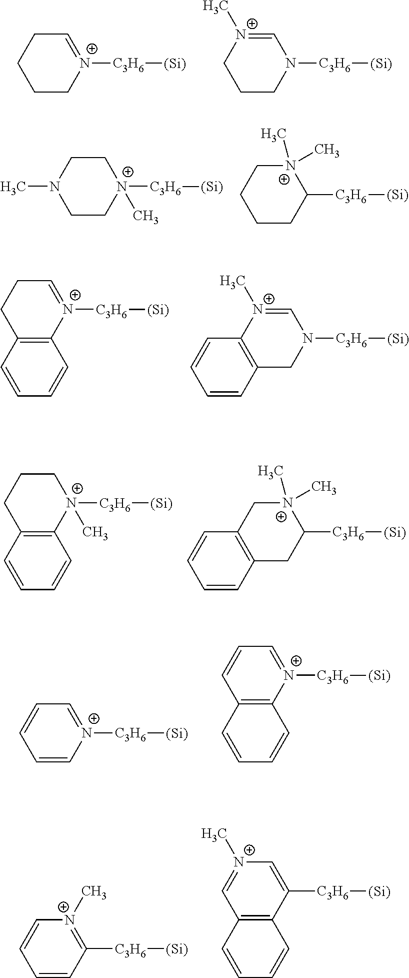

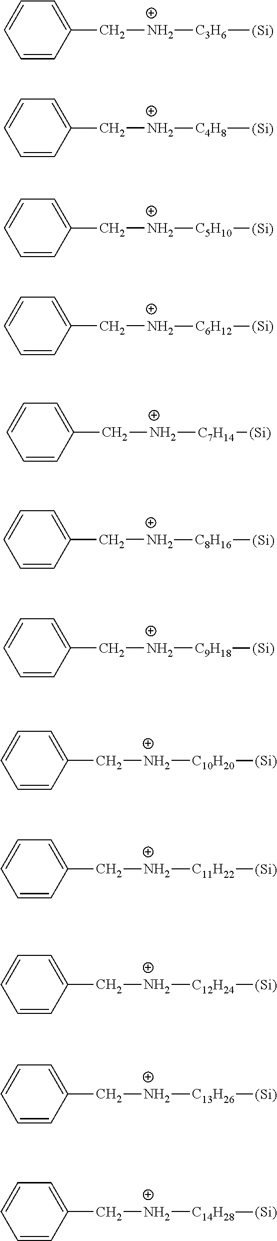

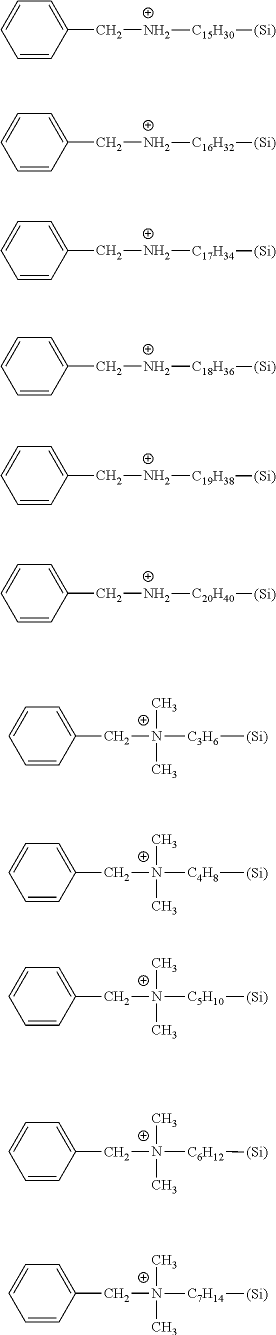

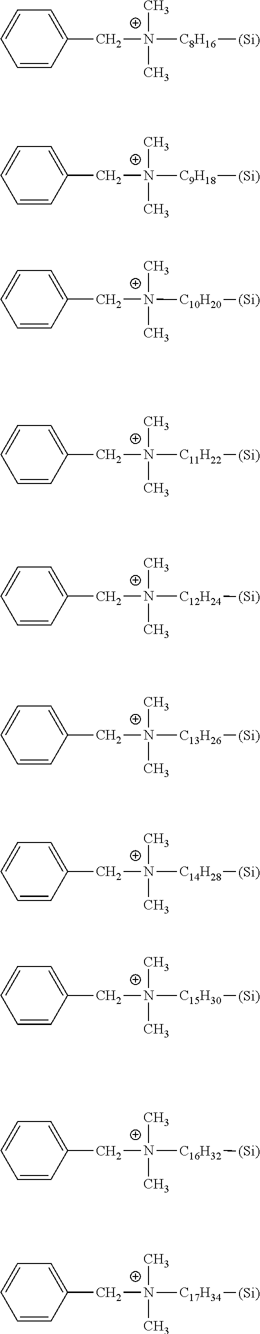

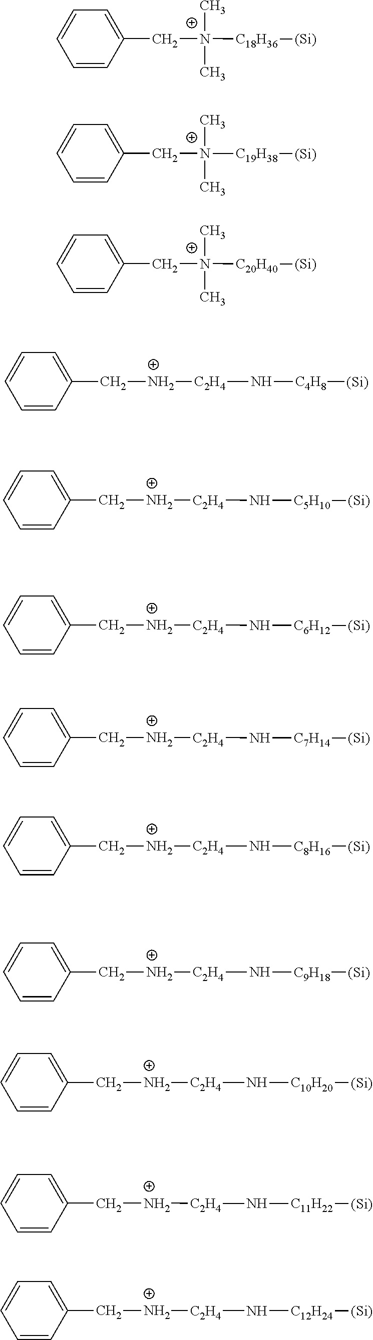

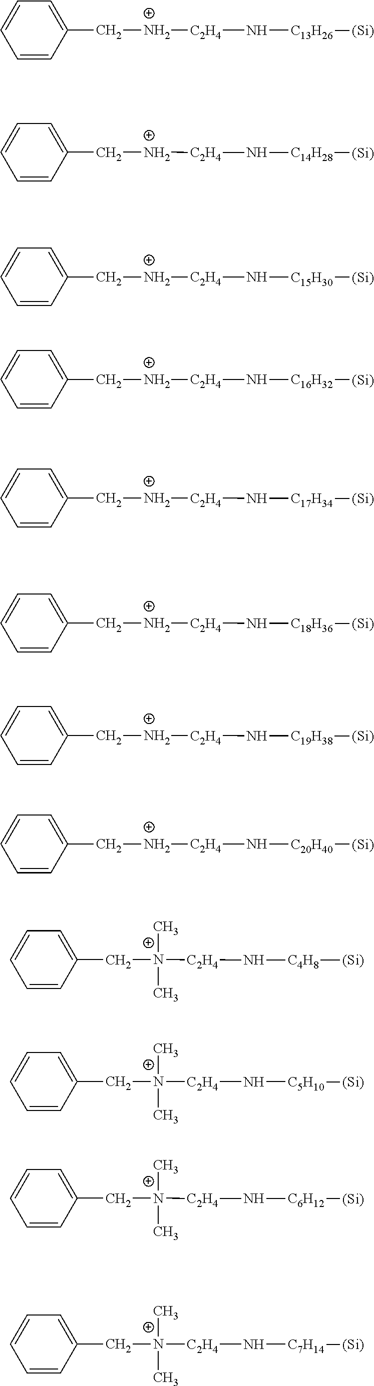

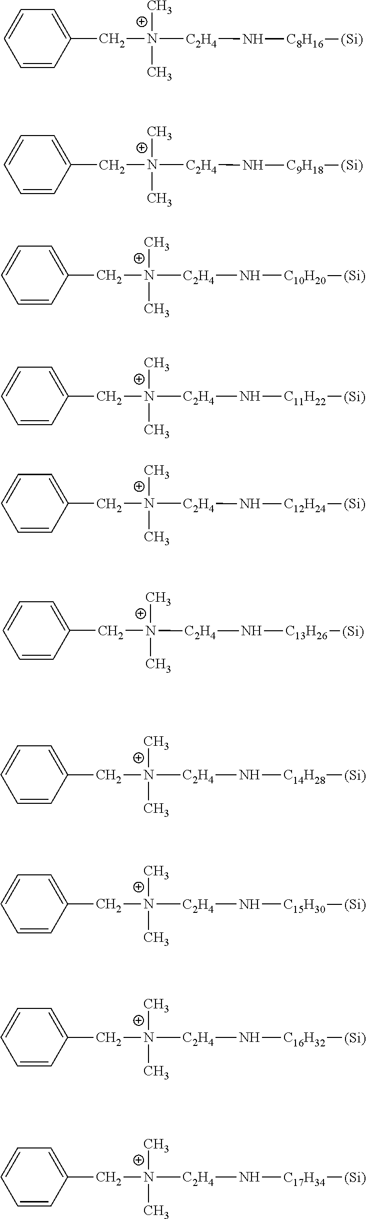

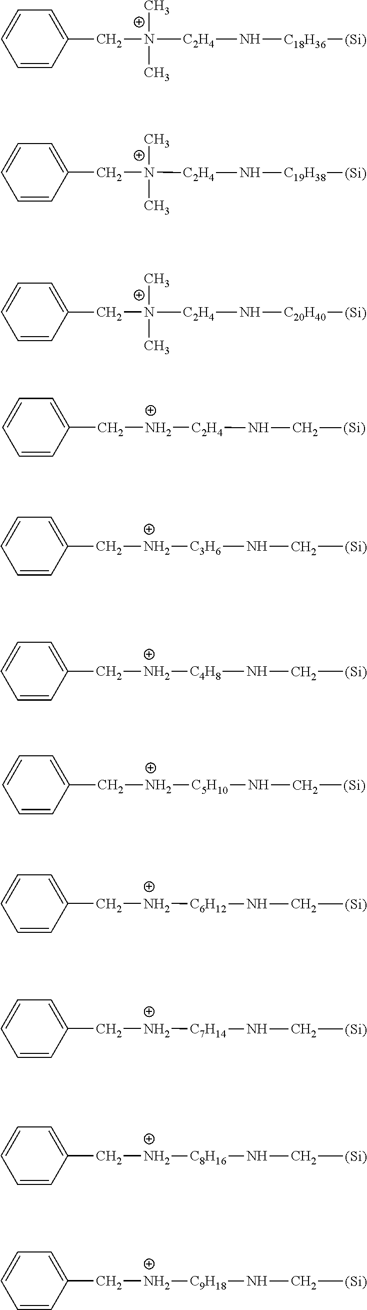

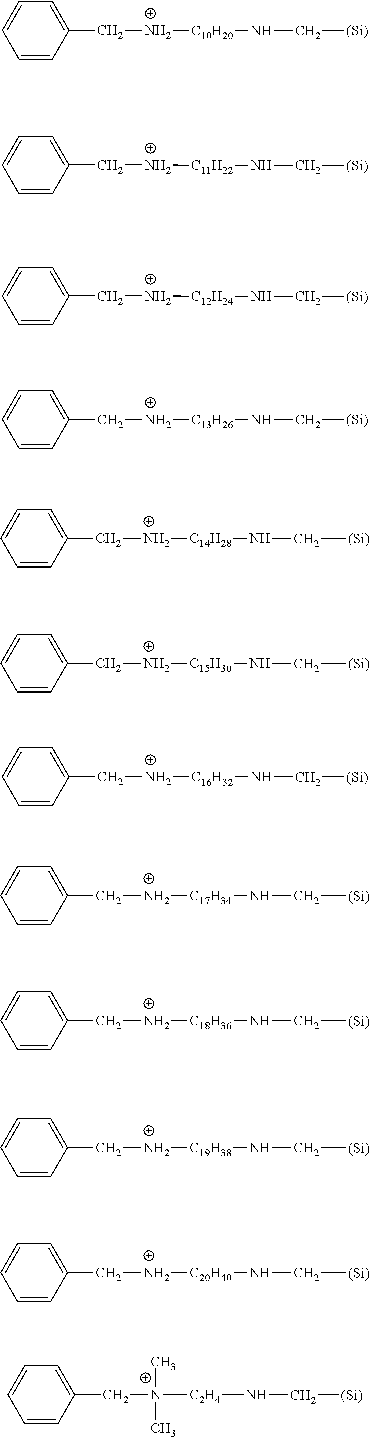

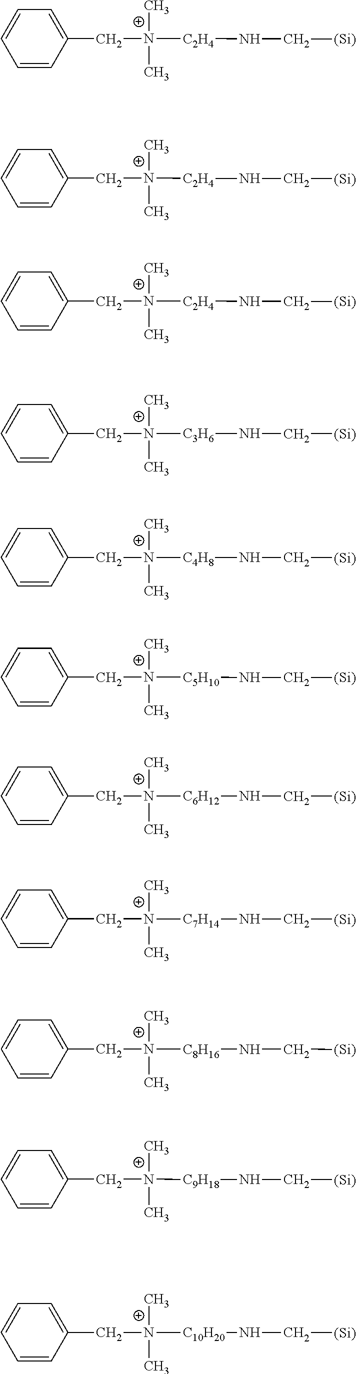

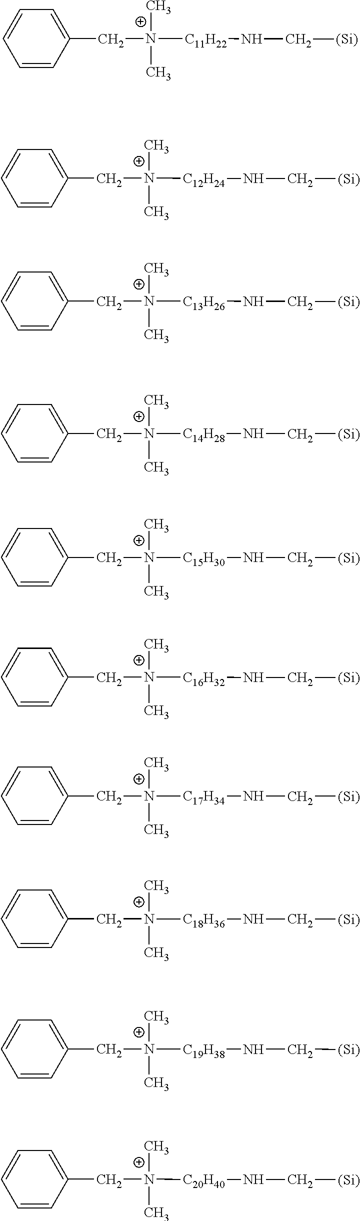

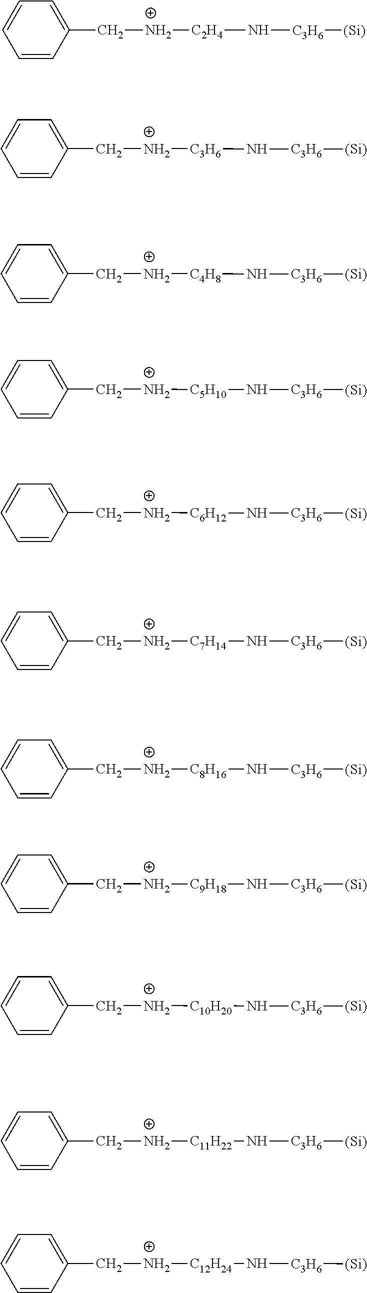

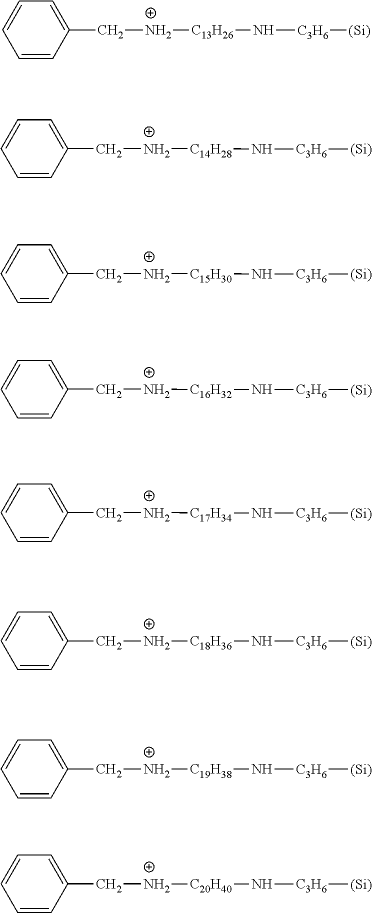

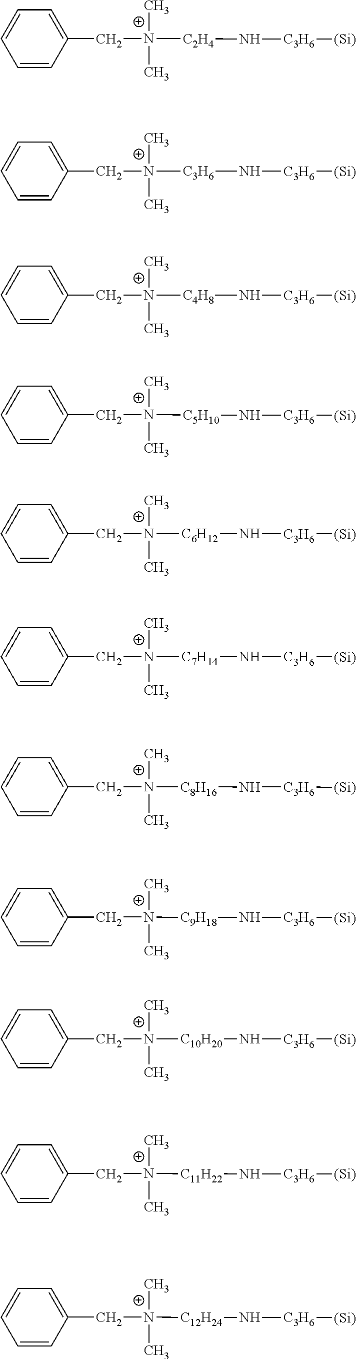

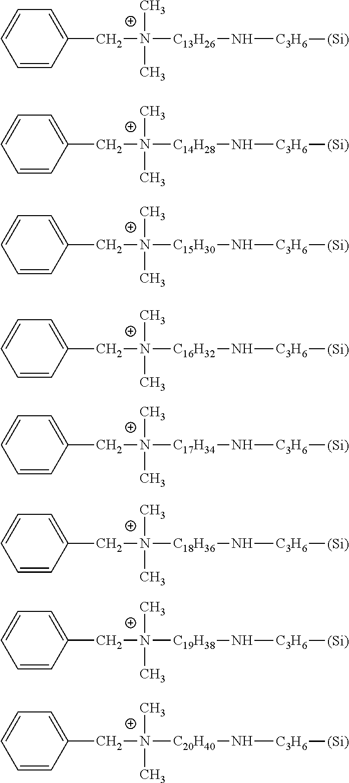

(Organic solvent)

The silicon-containing resist underlayer film composition in the present invention can contain a solvent. The solvent is preferably an alcohol-based organic solvent, more preferably a monoalkyl ether derivative derived from ethylene glycol, diethylene glycol, triethylene glycol, propylene glycol, dipropylene glycol, or butanediol. Specifically, preferred is, for example, butanediol monomethyl ether, propylene glycol monomethyl ether, ethylene glycol monomethyl ether, butanediol monoethyl ether, propylene glycol monoethyl ether, ethylene glycol monoethyl ether, butanediol monopropyl ether, propylene glycol monopropyl ether, or ethylene glycol monopropyl ether.

If such a solvent is a main component, a non-alcohol-based organic solvent can also be added as an auxiliary solvent. Examples of the auxiliary solvent can include acetone, tetrahydrofuran, toluene, hexane, ethyl acetate, cyclohexanone, methyl amyl ketone, propylene glycol dimethyl ether, diethylene glycol dimethyl ether, propylene glycol monomethyl ether acetate, propylene glycol monoethyl ether acetate, ethyl pyruvate, butyl acetate, methyl 3-methoxypropionate, ethyl 3-ethoxypropionate, t-butyl acetate, t-butyl propionate, propylene glycol mono-t-butyl ether acetate, γ-butyrolactone, methyl isobutyl ketone, and cyclopentyl methyl ether.

### (Water)

Water may be added to the silicon-containing resist underlayer film composition in the present invention. When water is added, the polysiloxane compound in the composition is hydrated to result in an enhancement in lithography performance. The content rate of water in the solvent component in the silicon-containing resist underlayer film composition in the present invention is preferably more than 0% by mass and less than 50% by mass, more preferably 0.3 to 30% by mass, further preferably 0.5 to 20% by mass. When the content rate of water is less than 50% by mass, a silicon-containing resist underlayer film is favorable in uniformity not to cause repelling.

The silicon-containing resist underlayer film composition preferably contains a crosslinking catalyst for siloxane polymerization (Xc), an alcohol-based organic solvent, and water.

(High-boiling point solvent)

A high-boiling point solvent having a boiling point of 180° C. or more can also be, if necessary, further added to the silicon-containing resist underlayer film composition in the present invention. Examples of the high-boiling point solvent can include 1-octanol, 2-ethylhexanol, 1-nonanol, 1-decanol, 1-undecanol, ethylene glycol, 1,2-propylene glycol, 1,3-butylene glycol, 2,4-pentanediol, 2-methyl-2,4-pentanediol, 2,5-hexanediol, 2,4-heptanediol, 2-ethyl-1,3-hexanediol, diethylene glycol, dipropylene glycol, triethylene glycol, tripropylene glycol, glycerin, gamma-butyrolactone, tripropylene glycol monomethyl ether, diacetone alcohol, n-nonyl acetate, ethylene glycol monoethyl ether acetate, 1,2-diacetoxyethane, 1-acetoxy-2-methoxyethane, 1,2-diacetoxypropane, diethylene glycol monomethyl ether acetate, diethylene glycol monoethyl ether acetate, diethylene glycol mono-n-butyl ether acetate, propylene glycol monomethyl ether acetate, propylene glycol monopropyl ether acetate, propylene glycol monobutyl ether acetate, dipropylene glycol monomethyl ether acetate, and dipropylene glycol monoethyl ether acetate. The amount of the high-boiling point solvent compounded is preferably 0 to 20% by mass, more preferably 0 to 10% by mass, in terms of the proportion in the solvent component.

The amount of the entire solvent used containing water is suitably 100 to 100,000 parts by mass, particularly 200 to 50,000 parts by mass based on 100 parts by mass of the polysiloxane compound as a base polymer.

[Other components]
(Organic acid)

A monobasic acid, or dibasic acid or higher basic organic acid having 1 to 30 carbon atoms is preferably added in order to enhance stability of the silicon-containing resist underlayer film composition in the present invention. Examples of the acid added here can include formic acid, acetic acid, propionic acid, butanoic acid, pentanoic acid, hexanoic acid, heptanoic acid, octanoic acid, nonane acid, decanoic acid, oleic acid, stearic acid, linolic acid, linolenic acid, benzoic acid, phthalic acid, isophthalic acid, terephthalic acid, salicylic acid, trifluoroacetic acid, monochloroacetic acid, dichloroacetic acid, trichloroacetic acid, oxalic acid, malonic acid, methylmalonic acid, ethylmalonic acid, propylmalonic acid, butylmalonic acid, dimethylmalonic acid, diethylmalonic acid, succinic acid, methylsuccinic acid, glutaric acid, adipic acid, itaconic acid, maleic acid, fumaric acid, citraconic acid, and citric acid. In particular, preferred is oxalic acid, maleic acid, formic acid, acetic acid, propionic acid, citric acid, or the like. Two or more of such acids may also be mixed and used in order that stability is kept. The amount added is 0.001 to 25 parts by mass, preferably 0.01 to 15 parts by mass, more preferably 0.1 to 5 parts by mass based on 100 parts by mass of silicon contained in the composition.

(Photo-acid generator)

A photo-acid generator may also be added to the silicon-containing resist underlayer film composition in the present invention. Specifically, any material described in paragraphs (0160) to (0179) in JP 2009-126940 A can be added as the photo-acid generator used in the present invention.

(Compound having anion moiety and cation moiety in one molecule (photo-acid generator (P-0))

In the present invention, one kind of a compound (photo-acid generator) having an anion moiety and a cation moiety, represented by the following general formula (P-0), or two or more kinds thereof may be additionally contained.

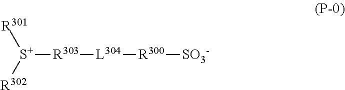

wherein R³⁰⁰ represents a divalent organic group substituted by one, or two or more fluorine atoms, and R³⁰¹ and R³⁰² each independently represent a straight, branched or cyclic monovalent hydrocarbon group having 1 to 20 carbon atoms, in which the group is optionally substituted by a heteroatom or optionally interposed by heteroatom; R³⁰³ represents a straight, branched or cyclic divalent hydrocarbon group having 1 to 20 carbon atoms, in which the group is optionally substituted by a heteroatom or optionally interposed by a heteroatom; R³⁰¹ and R³⁰², or R³⁰¹ and R³⁰³ are optionally bound to each other to form a ring together with a sulfur atom in the formula; and L304 is a single bond or a straight, branched or cyclic divalent hydrocarbon group having 1 to 20 carbon atoms, in which the group is optionally substituted by a heteroatom or optionally interposed by a heteroatom.

Such a compound (photo-acid generator) can be combined with a thermosetting silicon-containing material in the present invention, to obtain a resist underlayer film which not only retains LWR of an upper layer resist, but also can contribute to allowing a cross section shape to be rectangular.

In the general formula (P-0), R³⁰⁰ is a divalent organic group substituted by one, or two or more fluorine atoms. The divalent organic group represents, for example, a divalent hydrocarbon group such as a straight, branched or cyclic alkylene group or alkenylene group having 1 to 20 carbon atoms, or an arylene group. Specific examples of R³⁰⁰ can include the following structures.

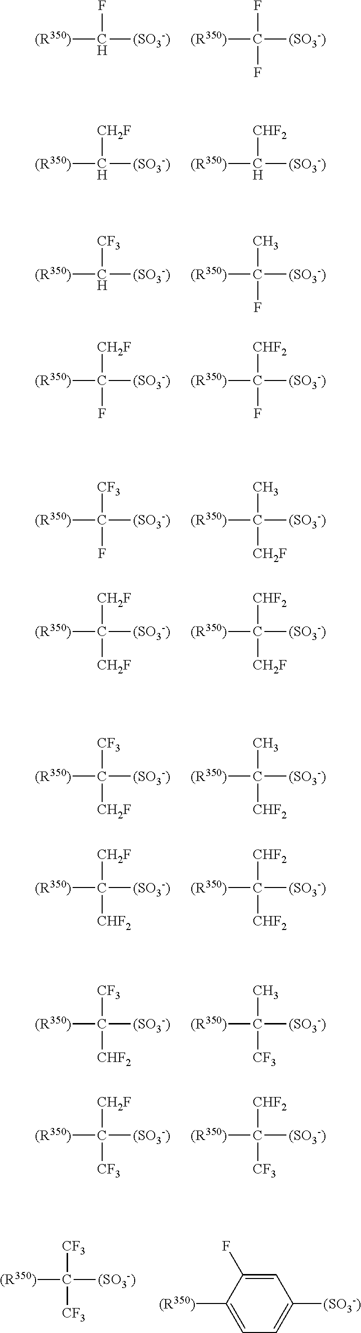

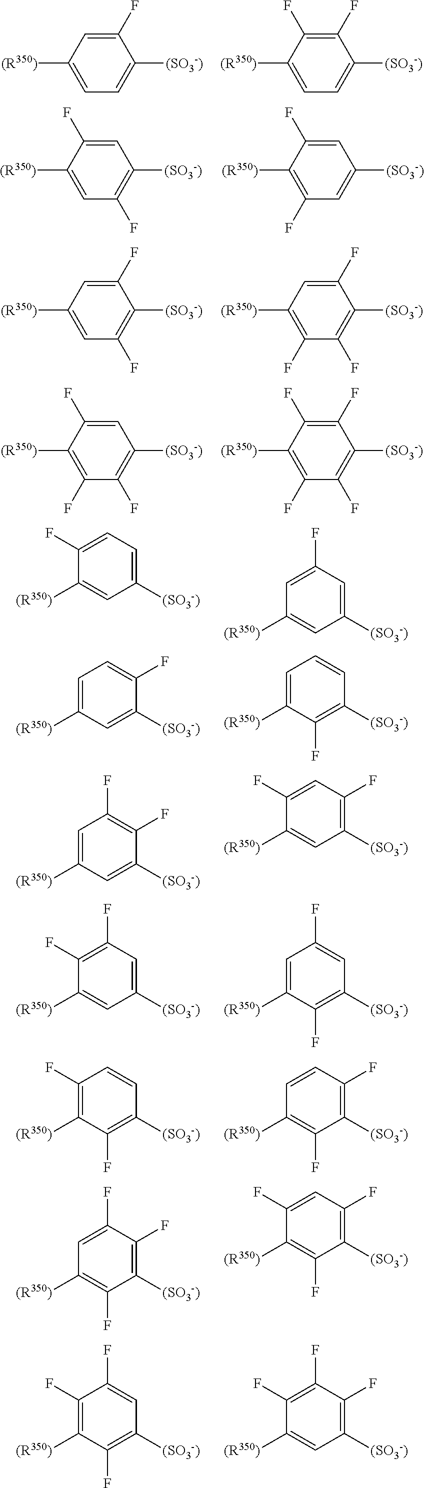

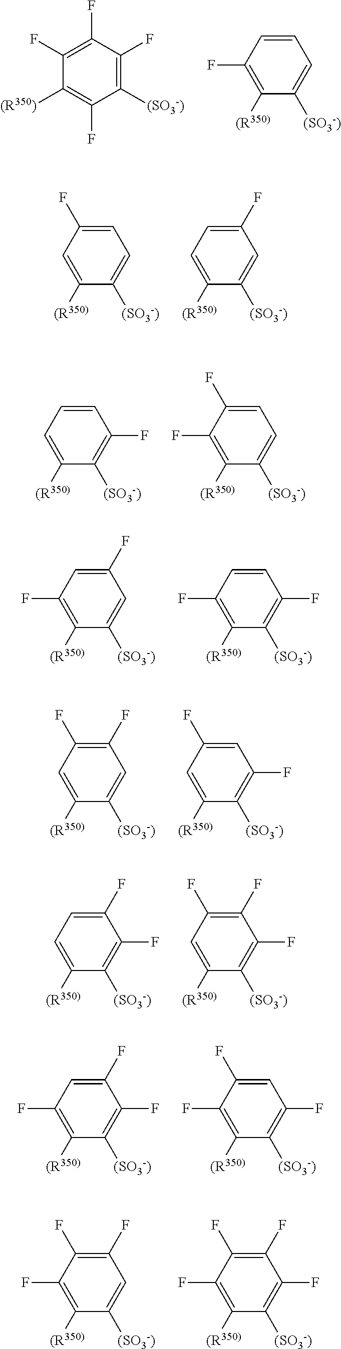

In the formulae, (SO₃—) is designated in order to indicate a binding position with a SO₃— group in the general formula (P-0). (R³⁵⁰) is designated in order to indicate a binding position with a portion at which the cation moiety in the general formula (P-0) is bound to R³⁰⁰ via L³⁰⁴.

R³⁰1 and R³⁰² each independently represent a straight, branched or cyclic monovalent hydrocarbon group having 1 to 20 carbon atoms, in which the group is optionally substituted by a heteroatom or optionally interposed by a heteroatom, for example, an alkyl group, an alkenyl group, an aryl group, or an aralkyl group. Examples of the alkyl group include a methyl group, an ethyl group, a propyl group, an isopropyl group, a n-butyl group, a sec-butyl group, a tert-butyl group, a pentyl group, a hexyl group, a heptyl group, an octyl group, a cyclopentyl group, a cyclohexyl group, a cycloheptyl group, a cyclopropylmethyl group, a 4-methylcyclohexyl group, a cyclohexylmethyl group, a norbornyl group, and an adamantyl group. Examples of the alkenyl group include a vinyl group, an allyl group, a propenyl group, a butenyl group, a hexenyl group, and a cyclohexenyl group. Examples of the oxoalkyl group include a 2-oxocyclopentyl group, a 2-oxocyclohexyl group, a 2-oxopropyl group, a 2-oxoethyl group, a 2-cyclopentyl-2-oxoethyl group, a 2-cyclohexyl-2-oxoethyl group, and a 2-(4-methylcyclohexyl)-2-oxoethyl group. Examples of the aryl group include a phenyl group, a naphthyl group and a thienyl group, as well as alkoxyphenyl groups such as a 4-hydroxyphenyl group, a 4-methoxyphenyl group, a 3-methoxyphenyl group, a 2-methoxyphenyl group, a 4-ethoxyphenyl group, a 4-tert-butoxyphenyl group and a 3-tert-butoxyphenyl group; alkylphenyl groups such as a 2-methylphenyl group, a 3-methylphenyl group, a 4-methylphenyl group, a 4-ethylphenyl group, a 4-tert-butylphenyl group, a 4-n-butylphenyl group and a 2,4-dimethylphenyl group; alkylnaphthyl groups such as a methylnaphthyl group and an ethylnaphthyl group; alkoxynaphthyl groups such as a methoxynaphthyl group, an ethoxynaphthyl group, a n-propoxynaphthyl group and a n-butoxynaphthyl group; dialkylnaphthyl groups such as a dimethylnaphthyl group and a diethylnaphthyl group; and dialkoxynaphthyl groups such as a dimethoxynaphthyl group and a diethoxynaphthyl group. Examples of the aralkyl group include a benzyl group, a 1-phenylethyl group, and a 2-phenylethyl group. Examples of the aryloxoalkyl group include 2-aryl-2-oxoethyl groups such as a 2-phenyl-2-oxoethyl group, a 2-(1-naphthyl)-2-oxoethyl group and a 2-(2-naphthyl)-2-oxoethyl group. R³⁰1 and R³⁰² are optionally bound to each other to form a ring together with a sulfur atom in the formula, and in this case, examples thereof include groups represented by the following formulae.

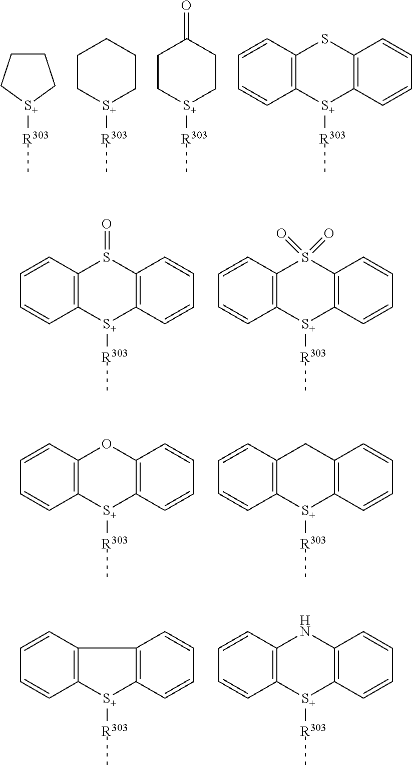

(a dotted line represents a bond.)

In the general formula (P-0), R³⁰³ represents a straight, branched or cyclic divalent hydrocarbon group having 1 to 20 carbon atoms, in which the group is optionally substituted by a heteroatom or optionally interposed by a heteroatom. Specific examples of R³⁰³ include straight alkanediyl groups such as a methylene group, an ethylene group, a propan-1,3-diyl group, a butan-1,4-diyl group, a pentan-1,5-diyl group, a hexan-1,6-diyl group, a heptan-1,7-diyl group, an octan-1,8-diyl group, a nonan-1,9-diyl group, a decan-1,10-diyl group, an undecan-1,11-diyl group, a dodecan-1,12-diyl group, a tridecan-1,13-diyl group, a tetradecan-1,14-diyl group, a pentadecan-1,15-diyl group, a hexadecan-1,16-diyl group and a heptadecan-1,17-diyl group; saturated cyclic hydrocarbon groups such as a cyclopentanediyl group, a cyclohexanediyl group, a norbornanediyl group and an adamantanediyl group, and unsaturated cyclic hydrocarbon groups such as a phenylene group and a naphthylene group. Some of hydrogen atoms in these groups are each optionally substituted by an alkyl group such as a methyl group, an ethyl group, a propyl group, a n-butyl group, or a tert-butyl group. Alternatively, such hydrogen atoms are each optionally substituted with a heteroatom such as an oxygen atom, a sulfur atom, a nitrogen atom, or a halogen atom, and as a result, a hydroxy group, a cyano group, a carbonyl group, an ether bond, an ester bond, a sulfonic acid ester bond, a carbonate bond, a lactone ring, a sultone ring, a carboxylic anhydride, a haloalkyl group, or the like is optionally formed. R³⁰1 and R³⁰³ are optionally bound to each other to form a ring together with a sulfur atom in the formula, and in this case, examples thereof include groups represented by the following formulae.

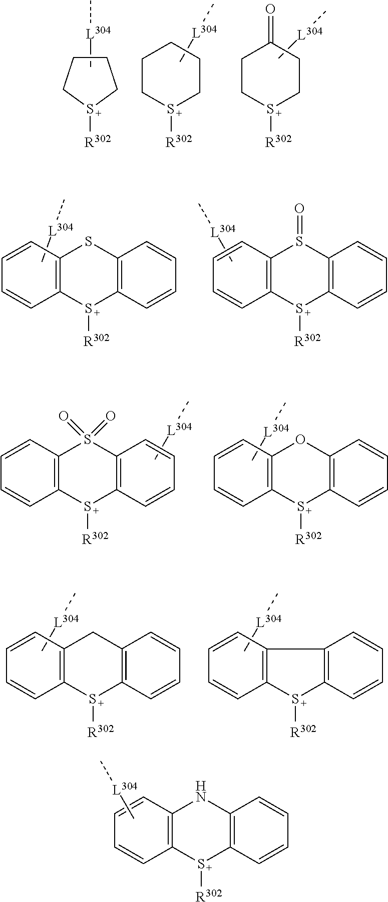

(a broken line represents a bond.)

In the general formula (P-0), L³⁰⁴ represents a single bond, or a straight, branched or cyclic divalent hydrocarbon group having 1 to 20 carbon atoms, in which the group is optionally substituted by a heteroatom or a heteroatom is optionally interposed. Specific examples of L³⁰⁴ include straight alkanediyl groups such as a methylene group, an ethylene group, a propan-1,3-diyl group, a butan-1,4-diyl group, a pentan-1,5-diyl group, a hexan-1,6-diyl group, a heptan-1,7-diyl group, an octan-1,8-diyl group, a nonan-1,9-diyl group, a decan-1,10-diyl group, an undecan-1,11-diyl group, a dodecan-1,12-diyl group, a tridecan-1,13-diyl group, a tetradecan-1,14-diyl group, a pentadecan-1,15-diyl group, a hexadecan-1,16-diyl group and a heptadecan-1,17-diyl group; saturated cyclic hydrocarbon groups such as a cyclopentanediyl group, a cyclohexanediyl group, a norbornanediyl group; and an adamantanediyl group, and unsaturated cyclic hydrocarbon groups such as a phenylene group and a naphthylene group. Some of hydrogen atoms in these groups are each optionally substituted by an alkyl group such as a methyl group, an ethyl group, a propyl group, a n-butyl group, or a tert-butyl group. Alternatively, such hydrogen atoms are each optionally substituted with a heteroatom such as an oxygen atom, a sulfur atom, a nitrogen atom, or a halogen atom, and as a result, a hydroxy group, a cyano group, a carbonyl group, an ether bond, an ester bond, a sulfonic acid ester bond, a carbonate bond, a lactone ring, a sultone ring, a carboxylic anhydride, a haloalkyl group, or the like is optionally formed.

The compound (photo-acid generator) represented by the general formula (P-0) is preferably represented by the following general formula (P-1).

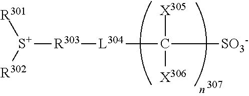

In the general formula (P-1), X³⁰⁵ and X³⁰⁶ each independently represent any of a hydrogen atom, a fluorine atom, and a trifluoromethyl group, but all thereof are not simultaneously hydrogen atoms; n³⁰⁷ represents an integer of 1 to 4; and R³⁰¹, R³⁰², R³⁰³ and L³⁰⁴ are as described above.

The photo-acid generator represented by the general formula (P-0) is more preferably represented by the following general formula (P-1-1).

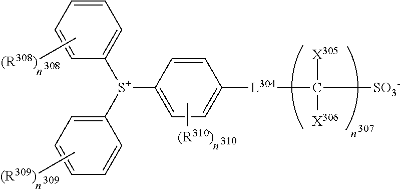

In the general formula (P-1-1), R³⁰⁰, R³⁰⁹ and R³¹⁰ each independently represent a hydrogen atom, or a straight, branched or cyclic monovalent hydrocarbon group having 1 to 20 carbon atoms, in which the group is optionally substituted by a heteroatom or optionally interposed by a heteroatom. Specifically, examples thereof include a methyl group, an ethyl group, a propyl group, an isopropyl group, a n-butyl group, a sec-butyl group, a tert-butyl group, a tert-amyl group, a n-pentyl group, a n-hexyl group, a n-octyl group, a n-nonyl group, a n-decyl group, a cyclopentyl group, a cyclohexyl group, a 2-ethylhexyl group, a cyclopentylmethyl group, a cyclopentylethyl group, a cyclopentylbutyl group, a cyclohexylmethyl group, a cyclohexylethyl group, a cyclohexylbutyl group, a norbornyl group, an oxanorbornyl group, a tricyclo[5.2.1.0^{2,6}]decanyl group, and an adamantyl group. Some of hydrogen atoms in these groups are each optionally substituted with a heteroatom such as an oxygen atom, a sulfur atom, a nitrogen atom, or a halogen atom; and optionally interposed by a heteroatom such as an oxygen atom, a sulfur atom, or a nitrogen atom, and as a result, a hydroxy group, a cyano group, a carbonyl group, an ether bond, an ester bond, a sulfonic acid ester bond, a carbonate bond, a lactone ring, a sultone ring, a carboxylic anhydride, a haloalkyl group, or the like is optionally formed or interposed. Preferred is a methyl group, a methoxy group, a tert-butyl group, or a tert-butoxy group.

In the general formula (P-1-1), n³⁰⁰ and n³⁰⁹ each represent an integer of 0 to 5, preferably 0 or 1. n³¹⁰ represents an integer of 0 to 4, preferably 0 or 2; and L³⁰⁴, X³⁰⁵, X³⁰⁶, and n³⁰⁷ are as described above.

The compound (photo-acid generator) represented by the general formula (P-0) is further preferably represented by the following general formula (P-1-2).

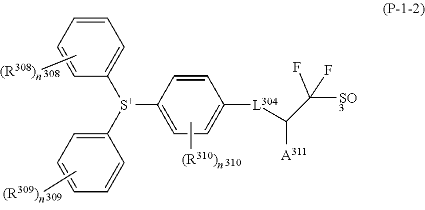

In the general formula (P-1-2), A³¹¹ is a hydrogen atom or a trifluoromethyl group; and R³⁰⁸, R³⁰⁹, R³¹⁰, n³⁰⁸, n³⁰⁹, n³¹⁰, and L³⁰⁴ are as described above.

Examples of the photo-acid generator represented by each of the general formulae (P-0), (P-1), (P-1-1) and (P-1-2) more specifically include the following structures. The photo-acid generator is not limited thereto.

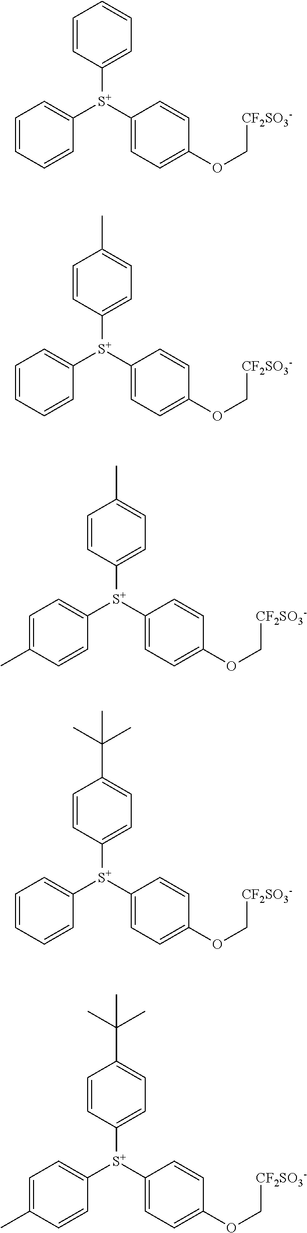

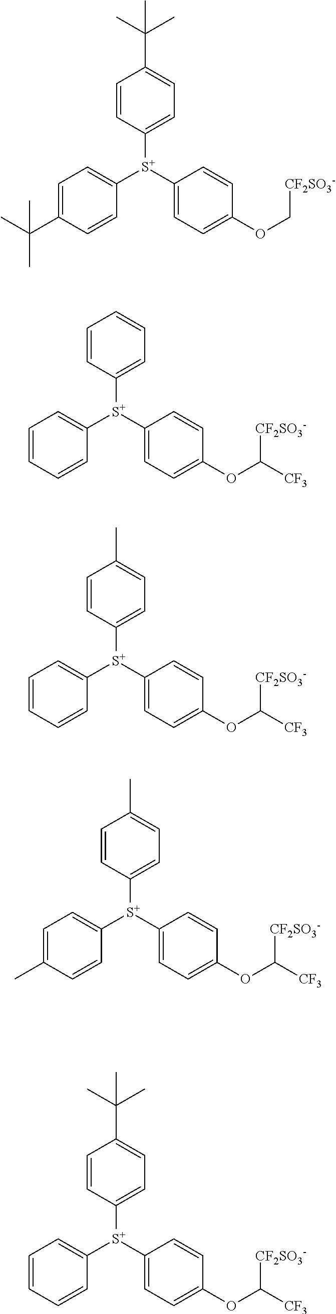

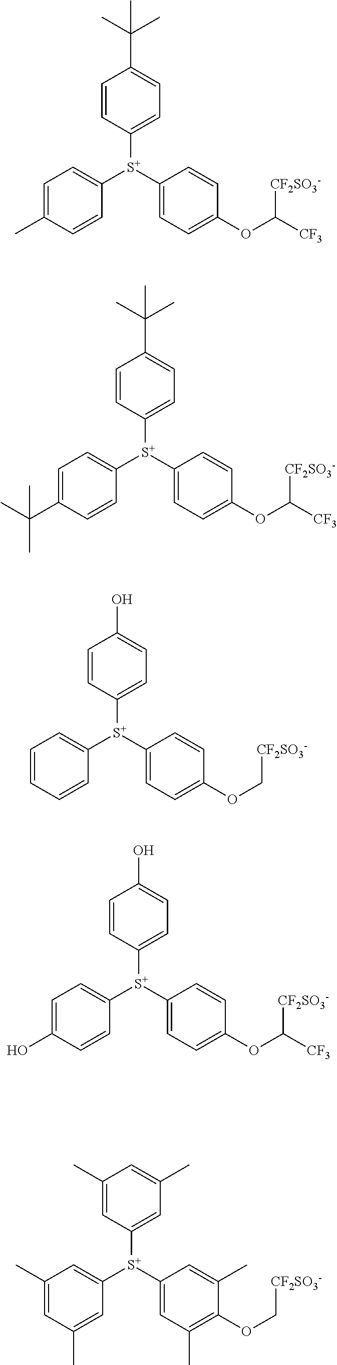

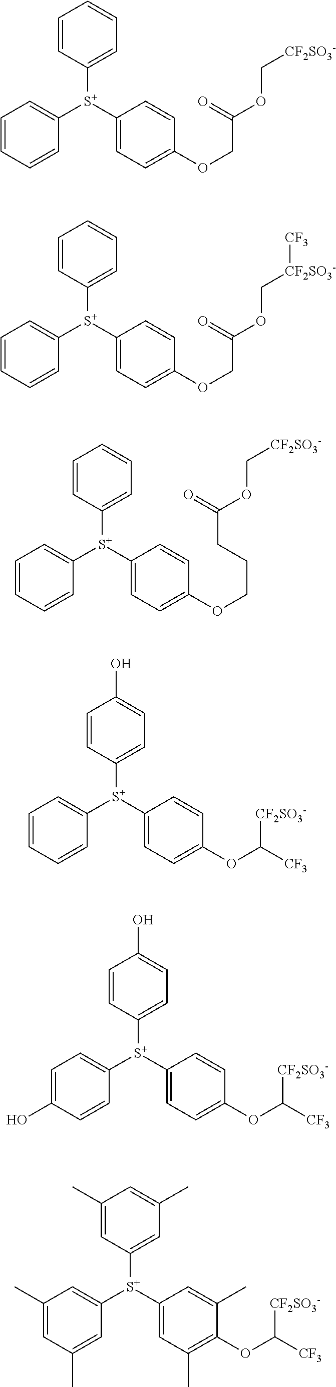

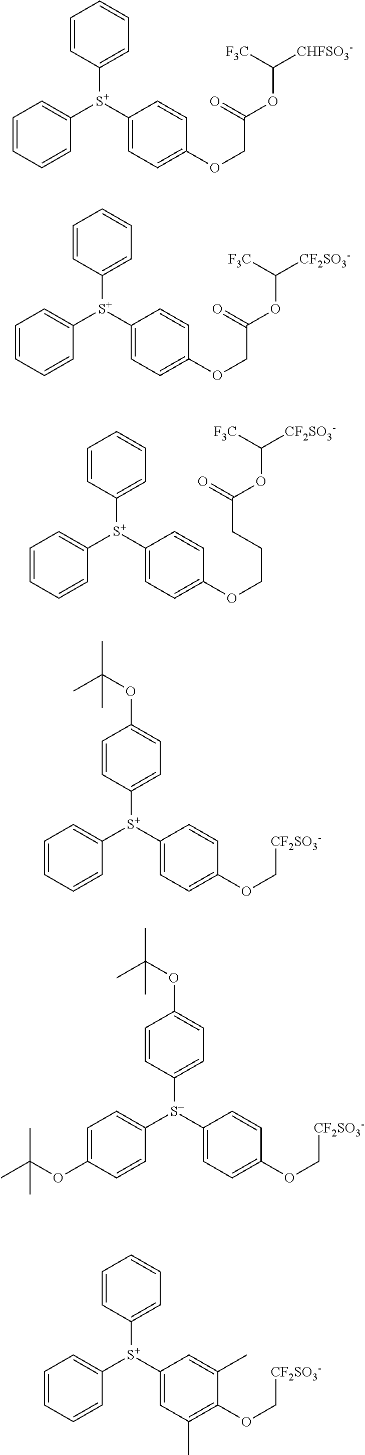

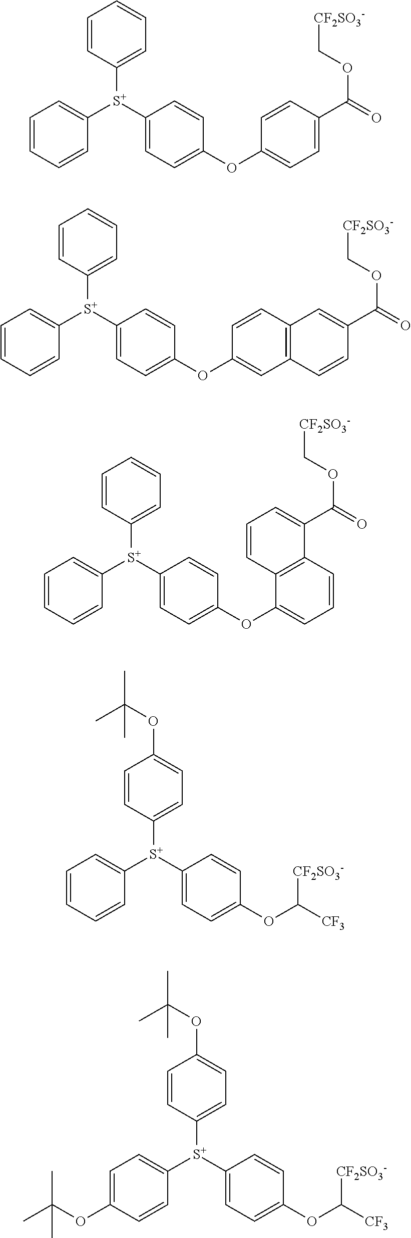

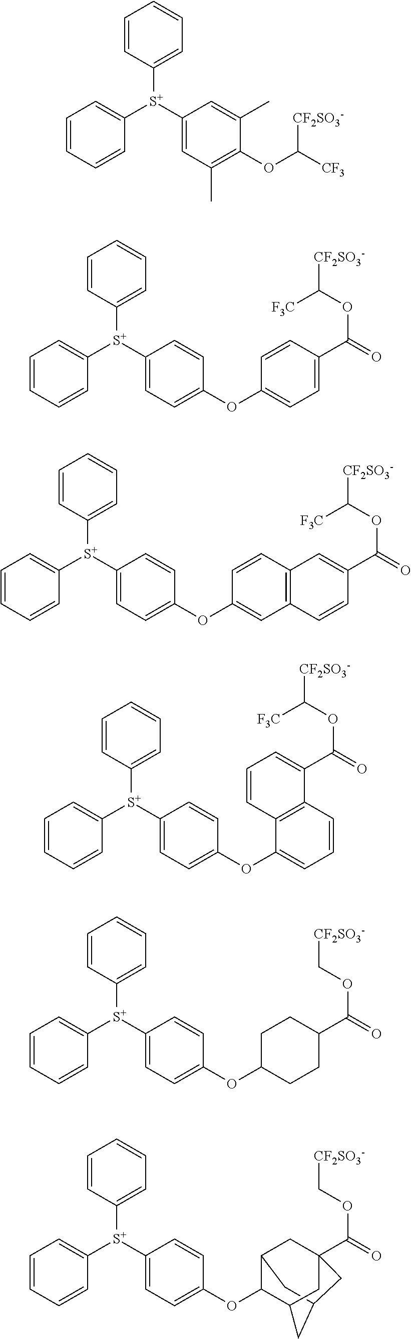

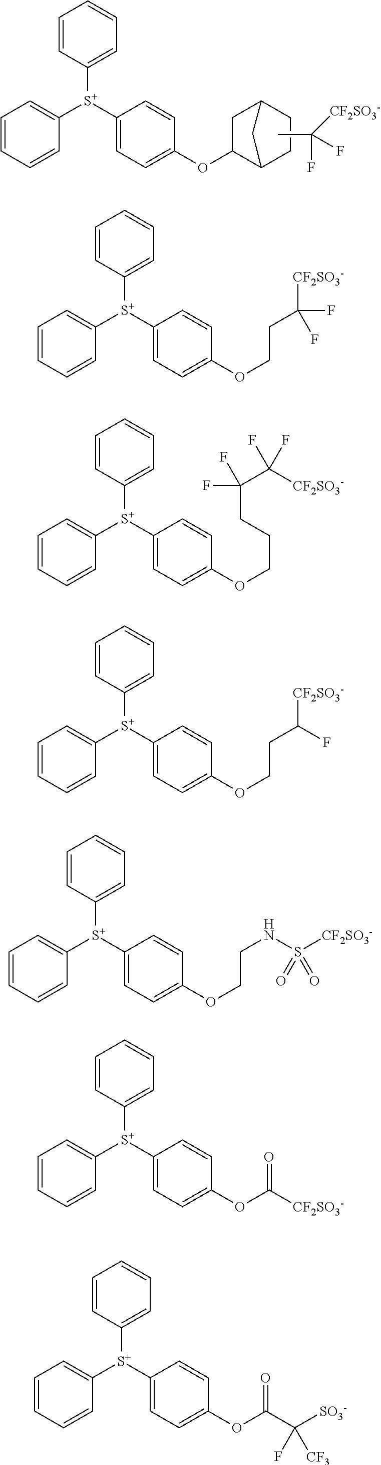

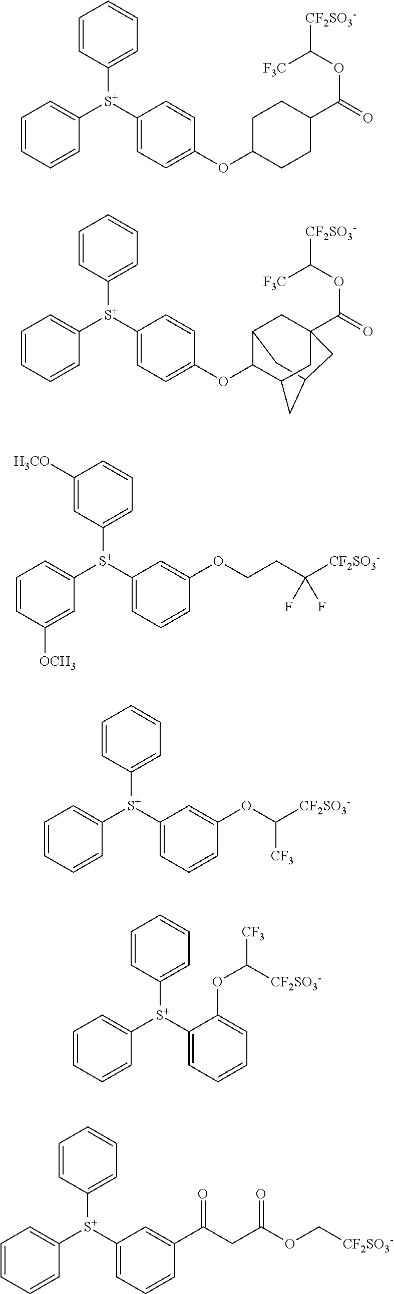

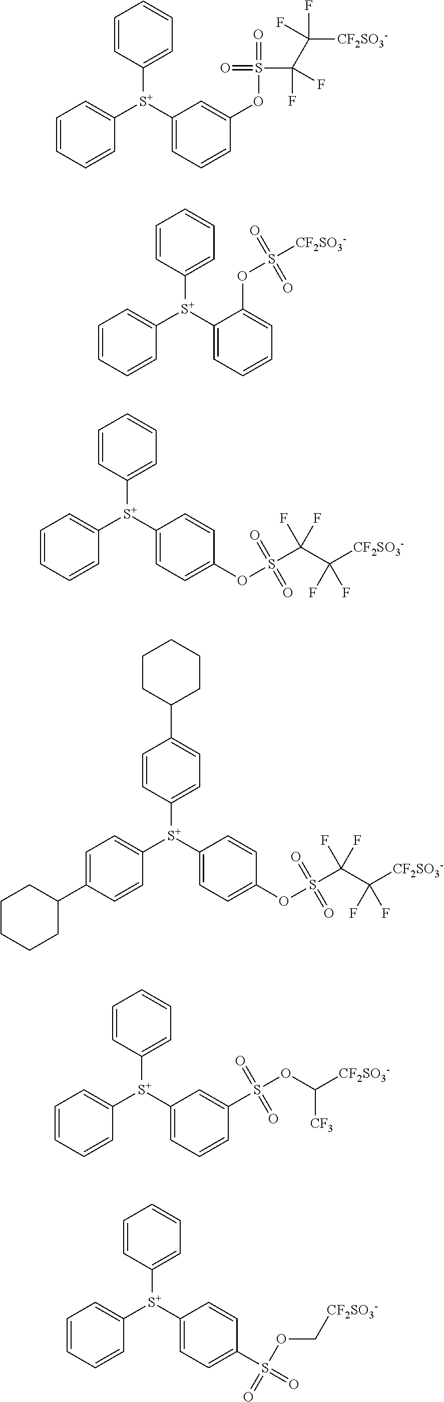

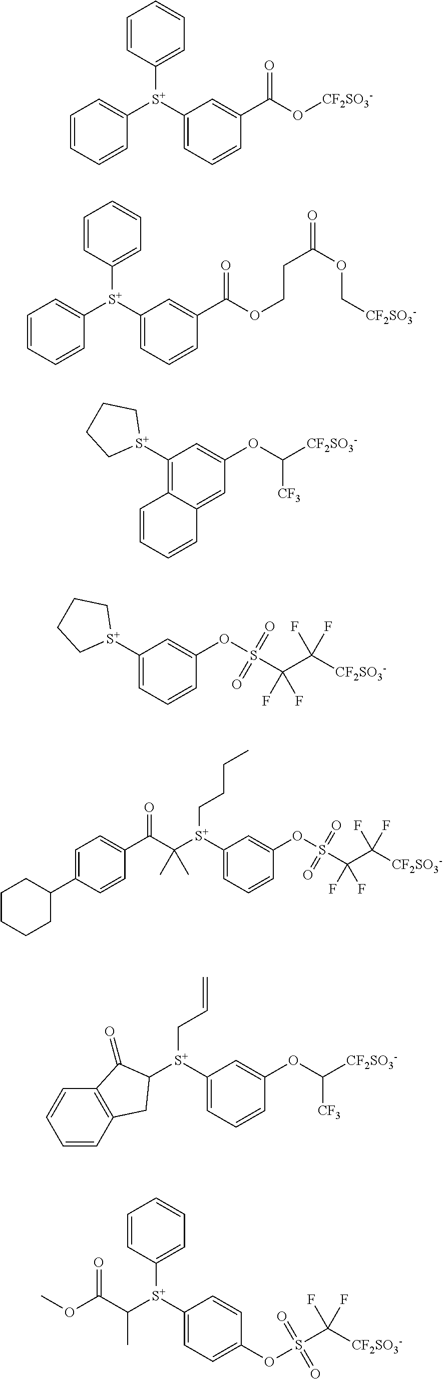

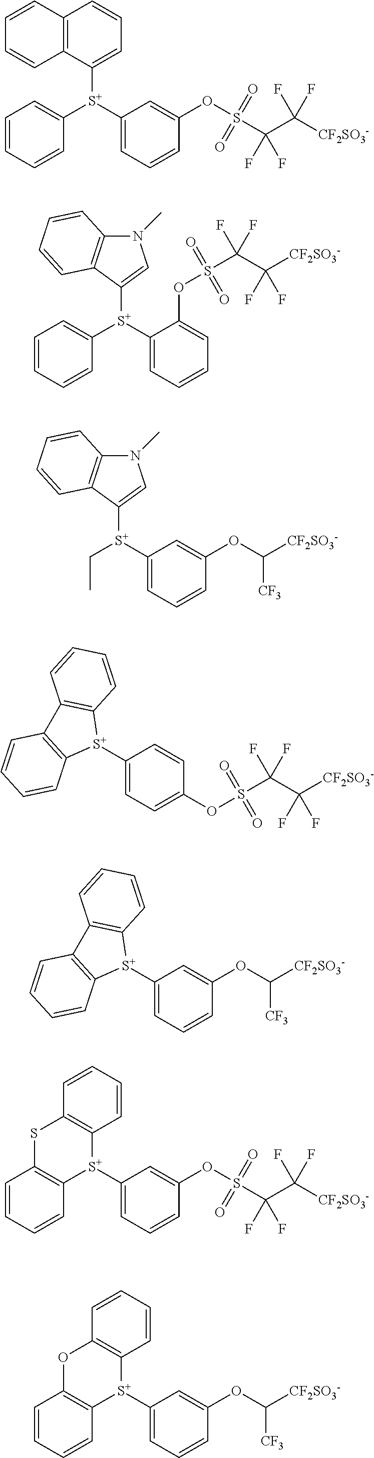

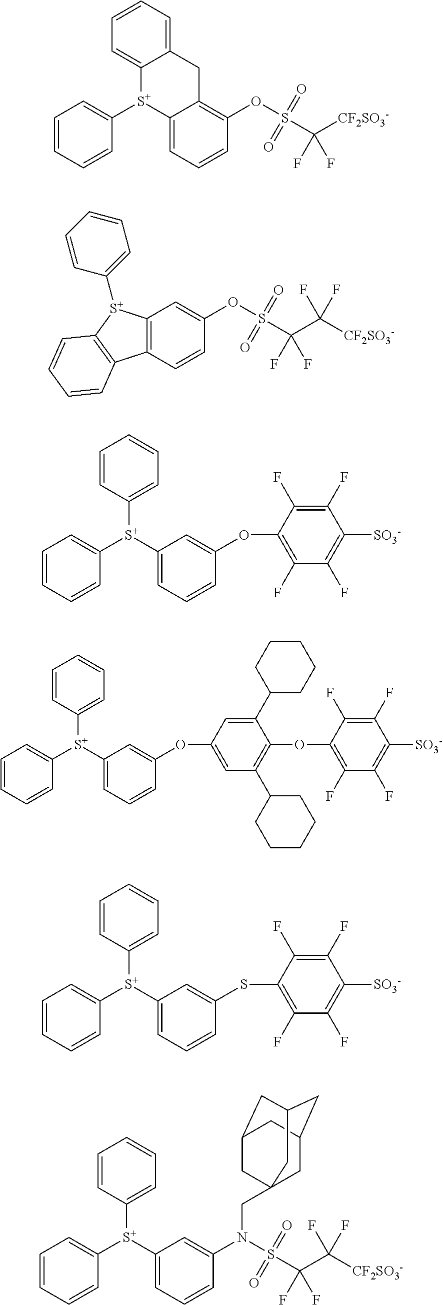

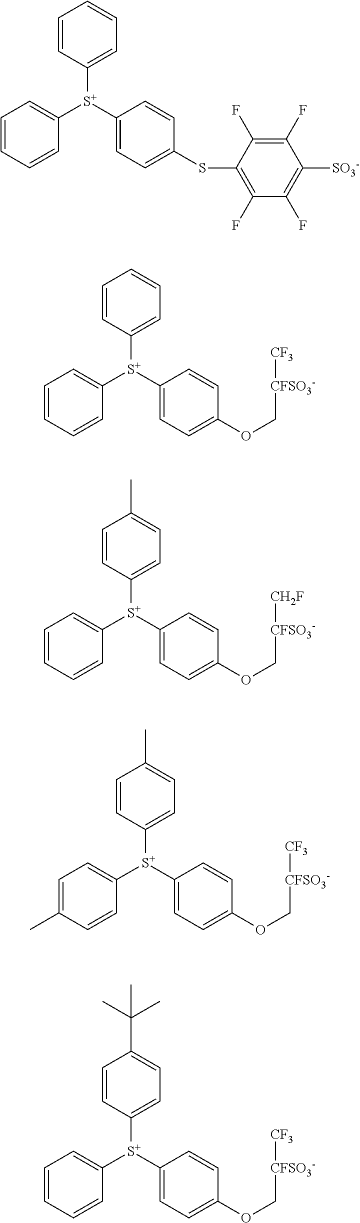

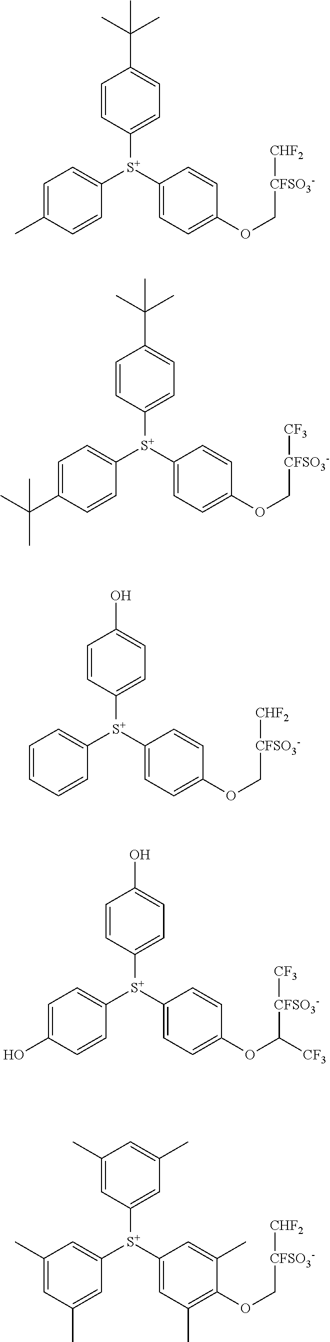

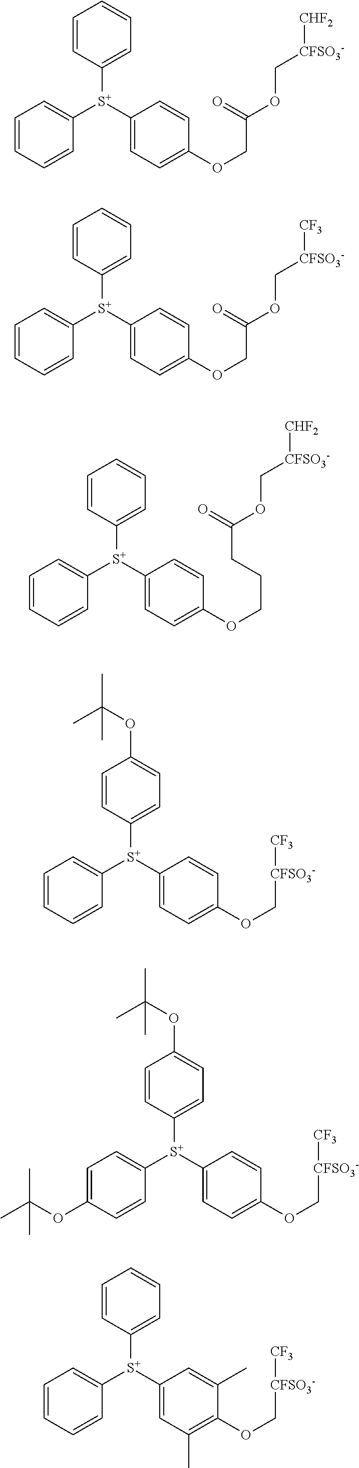

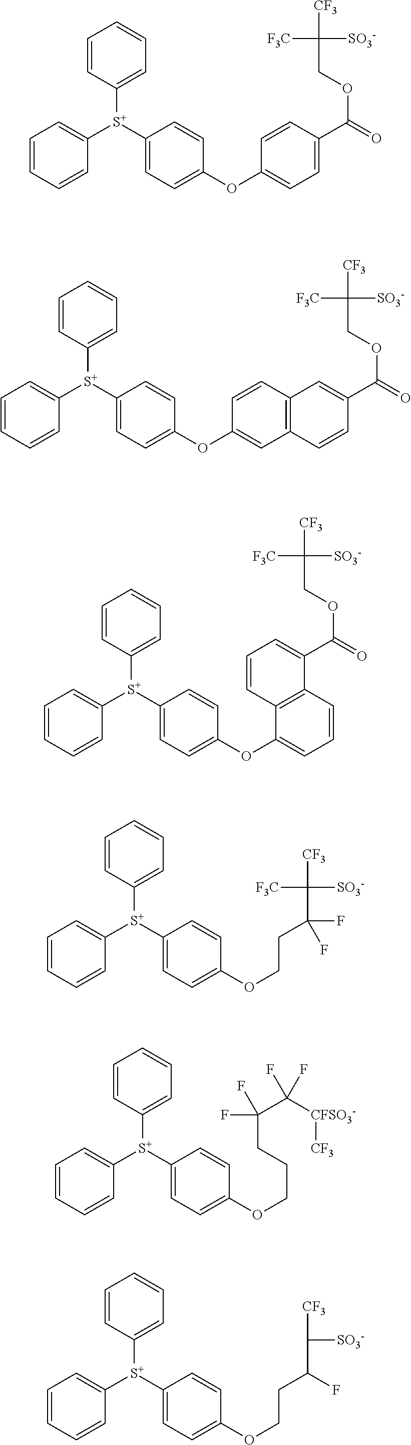

The amount of the compound represented by the general formula (P-0), added here, is 0.001 to 40 parts by mass, preferably 0.1 to 40 parts by mass, further preferably 0.1 to 20 parts by mass based on 100 parts by mass of the thermally crosslinkable polysiloxane. Such a photo-acid generator can be added to decrease the residue of an exposed section of the upper layer resist and form a pattern small in LWR.

### (Stabilizer)

Furthermore, in the present invention, a stabilizer can be added to the silicon-containing resist underlayer film composition. The stabilizer added here can be a mono-, or di- or higher hydric alcohol having a cyclic ether as a substituent. In particular, if any stabilizer described in paragraphs (0181) to (0182) in JP 2009-126940 A is added, a composition for silicon-containing resist underlayer film formation can be enhanced in stability. The amount of the stabilizer added can be preferably 0.001 to 50 parts by mass, more preferably 0.01 to 40 parts by mass based on 100 parts by mass of the thermally crosslinkable polysiloxane.

### (Surfactant)

A surfactant can be, if necessary, further compounded to the composition in the present invention. Specifically, any material described in paragraph (0185) in JP 2009-126940 A can be added as such a surfactant. The amount of the surfactant added is preferably 0 to 10 parts by mass, particularly preferably 0 to 5 parts by mass based on 100 parts by mass of the thermally crosslinkable polysiloxane.

The silicon-containing resist underlayer film has the effect of collapse suppression of a fine pattern in line-and-space patterning and the effect of allowing for formation of a pattern excellent in CDU in contact hole patterning, in a fine patterning process with a multilayer resist process in a semiconductor device manufacturing process.

When the silicon-containing resist underlayer film has a carboxyl group protected with an acid-labile group, the acid-labile group can be thermally decomposed to allow the carboxyl group to be exposed on a silicon-containing resist underlayer film surface in a baking step during silicon-containing resist underlayer film formation.

When the silicon-containing resist underlayer film has a carboxyl group protected with an acid-labile group, a thermal acid generator can be contained in the silicon-containing resist underlayer film composition, to lower the pyrolysis temperature of the acid-labile group and allow for a process at a lower temperature.

High adhesiveness between the silicon-containing resist underlayer film and the resist film is doe to the fact that the silicon-containing resist underlayer film has a carboxy group after a baking step of the silicon-containing resist underlayer film. By using a resist composition described below, crosslinking is formed between a carboxy group on the silicon-containing resist underlayer film surface and a carboxy group of the carboxy group-containing compound contained in the resist composition via the hypervalent iodine compound by baking after resist composition application. A resist composition described below is a positive type, and therefore crosslinking of a pattern on an unexposed section and a surface of an adhesion film imparts strong resistance to stress or the like during development, can allow for suppression of collapse of a line-and-space pattern, and provides usefulness for production of a resist pattern having a high aspect ratio. In this regard, in the case of a contact hole pattern, high adhesiveness between the resist film and the silicon-containing resist underlayer film prevents from penetrating of a developer between the resist film and the resist underlayer film and causing swelling, thereby enabling a contact hole pattern excellent in CDU to be formed.

[Resist film]

The resist film used in the present invention is described.

The resist film is obtained from a resist composition containing specific hypervalent iodine compound, carboxy group-containing compound and solvent.

[Hypervalent iodine compound]

The hypervalent iodine compound is a three-coordinate hypervalent iodine compound represented by the following formula (7), (8) or (9).

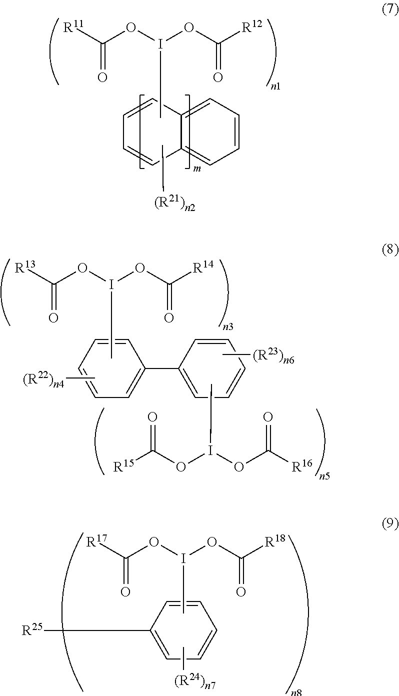

In the formulae (7) to (9), m is 0, 1 or 2; When “m” is 0, n1 is 1, 2 or 3, n2 is 0, 1, 2, 3, 4 or 5, and 1≤n1+n2≤6 is satisfied; when “m” is 1, n1 is 1, 2 or 3, n2 is 0, 1, 2, 3, 4, 5, 6 or 7, and 1≤n1+n2≤8 is satisfied; when m is 2, n1 is 1, 2 or 3, n2 is 0, 1, 2, 3, 4, 5, 6, 7, 8 or 9, and 1≤n1+n2≤10 is satisfied; n3 is 1 or 2; n4 is 0, 1, 2, 3 or 4; Herein, 1≤n3+n4≤5 is satisfied; n5 is 1 or 2; n6 is 0, 1, 2, 3 or 4; Herein, 1≤n5+n6≤5 is satisfied; n7 is 0, 1, 2, 3 or 4; and n8 is 1, 2, 3 or 4.

In the formulae (7) to (9), R¹¹ to R¹⁸ are each independently a halogen atom, or a hydrocarbyl group having 1 to 10 carbon atoms and optionally containing a heteroatom; R¹¹ and R¹², R¹³ and R¹⁴, R¹⁵ and R¹⁶, or R¹⁷ and R¹⁸ are optionally bound to each other to form a ring together with carbon atoms to which these are bound and an atom between the carbon atoms.

Examples of the halogen atom represented by R¹¹ to R¹⁸ include a fluorine atom, a chlorine atom, a bromine atom, and an iodine atom. The hydrocarbyl group having 1 to 10 carbon atoms, represented by R¹¹ to R¹⁸, may be saturated or unsaturated, and may be any of straight, branched or cyclic. Specific examples thereof include alkyl groups each having 1 to 10 carbon atoms, such as a methyl group, an ethyl group, a propyl group, an isopropyl group, a n-butyl group, an isobutyl group, a sec-butyl group, a tert-butyl group, a n-pentyl group, a tert-pentyl group, a n-hexyl group, a n-octyl group, a 2-ethylhexyl group, a n-nonyl group and a n-decyl group; cyclic saturated hydrocarbyl groups each having 3 to 10 carbon atoms, such as a cyclopentyl group, a cyclohexyl group, a cyclopentylmethyl group, a cyclopentylethyl group, a cyclopentylbutyl group, a cyclohexylmethyl group, a cyclohexylethyl group, a cyclohexylbutyl group, a norbornyl group, tricyclo[5.2.1.0^{2,6}]decanyl group and an adamantyl group; alkenyl groups such as a vinyl group and an allyl group; aryl groups each having 6 to 10 carbon atoms, such as a phenyl group and a naphthyl group; and any group obtained by combination thereof. Some or all of hydrogen atoms in the hydrocarbyl group are each optionally substituted by a group containing a heteroatom such as an oxygen atom, a sulfur atom, a nitrogen atom, or a halogen atom, some of —CH₂— in the hydrocarbyl group are each optionally substituted by a group containing a heteroatom such as an oxygen atom, a sulfur atom, or a nitrogen atom, and as a result, a hydroxy group, a cyano group, a halogen atom, a carbonyl group, an ether bond, a thioether bond, an ester bond, a sulfonic acid ester bond, a carbonate bond, a carbamate bond, a lactone ring, a sultone ring, a carboxylic anhydride (—C(═O)—O—C(═O)—), or the like is optionally contained. R¹¹ to R¹⁸ are each preferably a hydrocarbyl group having 1 to 4 carbon atoms.

In the formulae (7) to (9), R²¹ to R²⁴ are each independently a halogen atom, or a hydrocarbyl group having 1 to 40 carbon atoms and optionally containing a heteroatom; when n2 is 2 or more, R²¹s are the same as or different from each other, and plural R²¹s are optionally bound to each other to form a ring together with carbon atoms in an aromatic ring to which these are bound; when n4 is 2 or more, R²²s are the same as or different from each other, and plural R²²s are optionally bound to each other to form a ring together with carbon atoms in an aromatic ring to which these are bound; when n6 is 2 or more, R²³s are the same as or different from each other, and plural R²³s are optionally bound to each other to form a ring together with carbon atoms in an aromatic ring to which these are bound; when n7 is 2 or more, R²⁴s are the same as or different from each other, and plural R²⁴s are optionally bound to each other to form a ring together with carbon atoms in an aromatic ring to which these are bound.

Specific examples of the halogen atom represented by R²¹ to R²⁴ include a fluorine atom, a chlorine atom, a bromine atom, and an iodine atom. The hydrocarbyl group having 1 to 40 carbon atoms, represented by R²¹ to R²⁴, may be saturated or unsaturated, and may be any of straight, branched or cyclic. Specific examples thereof include alkyl groups each having 1 to 40 carbon atoms, such as a methyl group, an ethyl group, a propyl group, an isopropyl group, a n-butyl group, an isobutyl group, a sec-butyl group, a tert-butyl group, a n-pentyl group, a tert-pentyl group, a n-hexyl group, a n-octyl group, a 2-ethylhexyl group, a n-nonyl group and a n-decyl group; cyclic saturated hydrocarbyl groups each having 3 to 40 carbon atoms, such as a cyclopentyl group, a cyclohexyl group, a cyclopentylmethyl group, a cyclopentylethyl group, a cyclopentylbutyl group, a cyclohexylmethyl group, a cyclohexylethyl group, a cyclohexylbutyl group, a norbornyl group, a tricyclo[5.2.1.0^{2,6}]decanyl group, an adamantyl group and an adamantylmethyl group; and aryl groups each having 6 to 40 carbon atoms, such as a phenyl group, a naphthyl group and an anthracenyl group. Some or all of hydrogen atoms in the hydrocarbyl group are each optionally substituted by a group containing a heteroatom such as an oxygen atom, a sulfur atom, a nitrogen atom, or a halogen atom, some of —CH₂— in the hydrocarbyl group are each optionally substituted by a group containing a heteroatom such as an oxygen atom, a sulfur atom, or a nitrogen atom, and as a result, a hydroxy group, a cyano group, a halogen atom, a carbonyl group, an ether bond, a thioether bond, an ester bond, a sulfonic acid ester bond, a carbonate bond, a carbamate bond, a lactone ring, a sultone ring, a carboxylic anhydride (—C(═O)—O—C(═O)—), or the like is optionally contained.

In the formula (9), R²⁵ is an (n8)-valent hydrocarbon group having 1 to 40 carbon atoms or an (n8)-valent heterocyclic group having 2 to 40 carbon atoms, and when n8 is 2, R²⁵ is optionally an ether bond, a carbonyl group, an azo group, a thioether bond, a carbonate bond, a carbamate bond, a sulfinyl group, a sulfonyl group or a thioketone bond. Some or all of hydrogen atoms in the (n8)-valent hydrocarbon group or the (n8)-valent heterocyclic group are each optionally substituted by a group containing a heteroatom, some of —CH₂— in the (n8)-valent hydrocarbon group are each optionally substituted by a group containing a heteroatom, and R²⁴ and R²⁵ are optionally bound to each other to form a ring together with carbon atoms to which these are bound and an atom between the carbon atoms.

The (n8)-valent hydrocarbon group represented by R²⁵ may be saturated or unsaturated, and may be any of straight, branched or cyclic. The (n8)-valent hydrocarbon group is a group obtained by detachment of (n8) hydrogen atoms from hydrocarbon. Examples of the hydrocarbon include alkane having 1 to 40 carbon atoms, alkene having 2 to 40 carbon atoms, alkyne having 2 to 40 carbon atoms, cyclic saturated hydrocarbon having 3 to 40 carbon atoms, cyclic unsaturated hydrocarbon having 3 to 40 carbon atoms, and aromatic hydrocarbon having 6 to 40 carbon atoms.

Specific examples of the alkane having 1 to 40 carbon atoms include methane, ethane, propane, butane, pentane, hexane, heptane, octane, nonane, decane, and any structural isomer thereof.

Specific examples of the alkene having 2 to 40 carbon atoms include ethylene, propylene, butene, pentene, hexene, heptene, octene, nonene, decene, and any structural isomer thereof.

Specific examples of the alkyne having 2 to 40 carbon atoms include acetylene, propyne, butyne, pentyne, hexyne, heptyne, octyne, nonyne, decyne, and any structural isomer thereof.

Specific examples of the cyclic saturated hydrocarbon having 3 to 40 carbon atoms include cyclopropane, cyclobutane, cyclohexane, cycloheptane, cyclooctane, adamantane, and norbornane.

Specific examples of the cyclic unsaturated hydrocarbon having 3 to 40 carbon atoms include cyclopropene, cyclobutene, cyclopentene, cyclohexene, cycloheptene, cyclooctene, and norbornene.

Specific examples of the aromatic hydrocarbon having 6 to 40 carbon atoms include benzene, naphthalene, and biphenyl.

The (n8)-valent heterocyclic group represented by R²⁵ is a group obtained by detachment of (n8) hydrogen atoms from a heterocyclic compound. Specific examples of the heterocyclic compound include furan, pyridine, pyrazole, and thiazolidine.

Some or all of hydrogen atoms in the (n8)-valent hydrocarbon group or (n8)-valent heterocyclic group are each optionally substituted by a group containing a heteroatom such as an oxygen atom, a sulfur atom, a nitrogen atom, or a halogen atom, and as a result, a hydroxy group, a cyano group, a fluorine atom, a chlorine atom, a bromine atom, an iodine atom, or the like is optionally contained. Some of —CH₂-constituting the (n8)-valent hydrocarbon group are each optionally substituted by a group containing a heteroatom such as an oxygen atom, a sulfur atom, or a nitrogen atom, and as a result, a carbonyl group, an ether bond, a thioether bond, an ester bond, a sulfonic acid ester bond, a carbonate bond, a carbamate bond, a lactone ring, a sultone ring, a carboxylic anhydride (—C(═O)—O—C(═O)—), or the like is optionally contained.

Specific examples of the hypervalent iodine compound represented by the formula (7) include the following hypervalent iodine compounds, but not limited thereto.

[chemical structure]

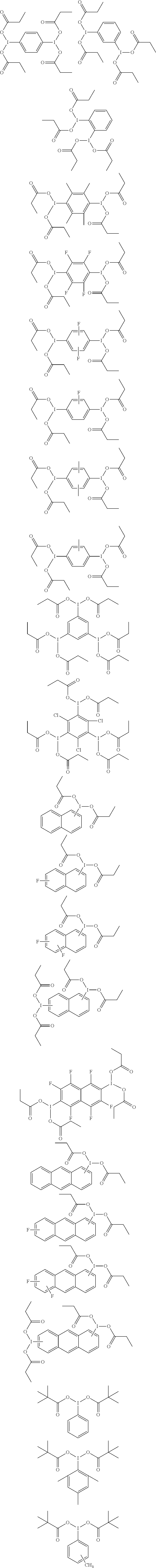

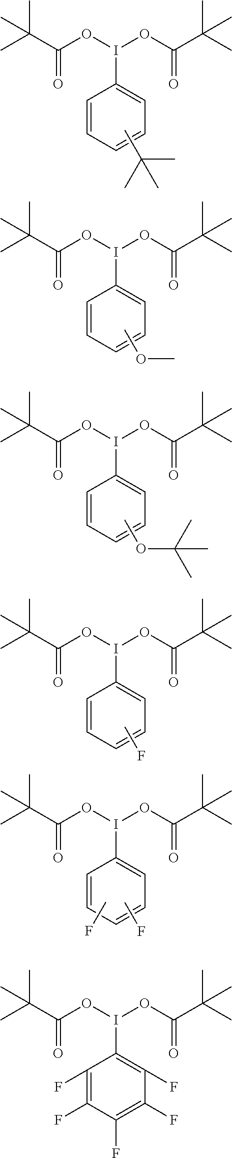

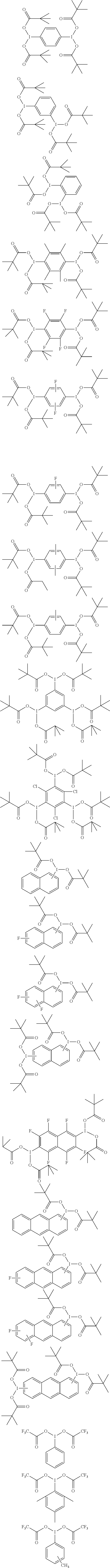

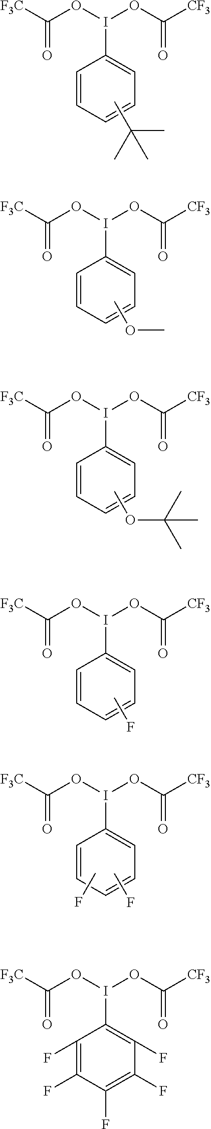

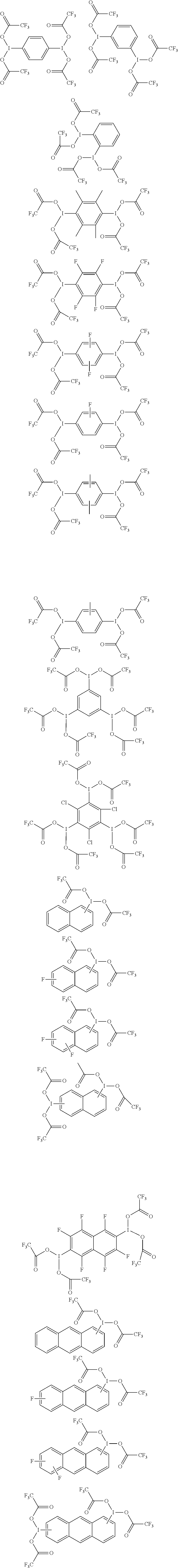

Specific examples of the hypervalent iodine compound represented by the formula (8) include the following hypervalent iodine compounds, but not limited thereto.

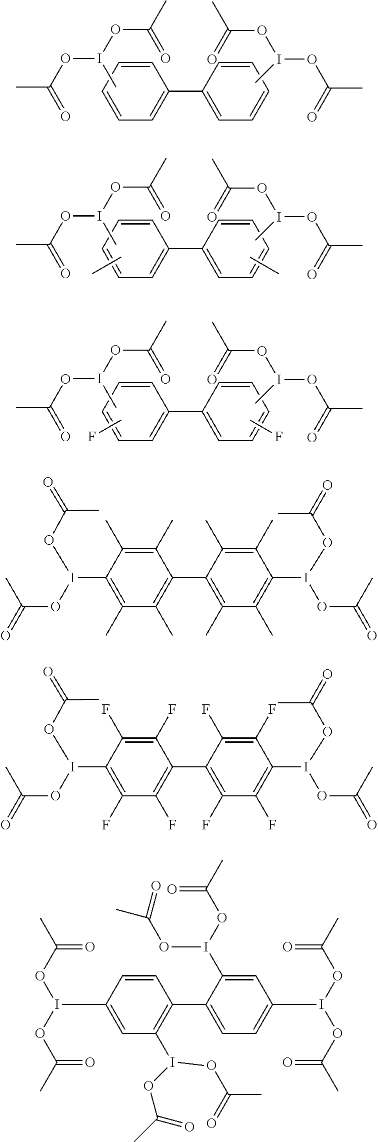

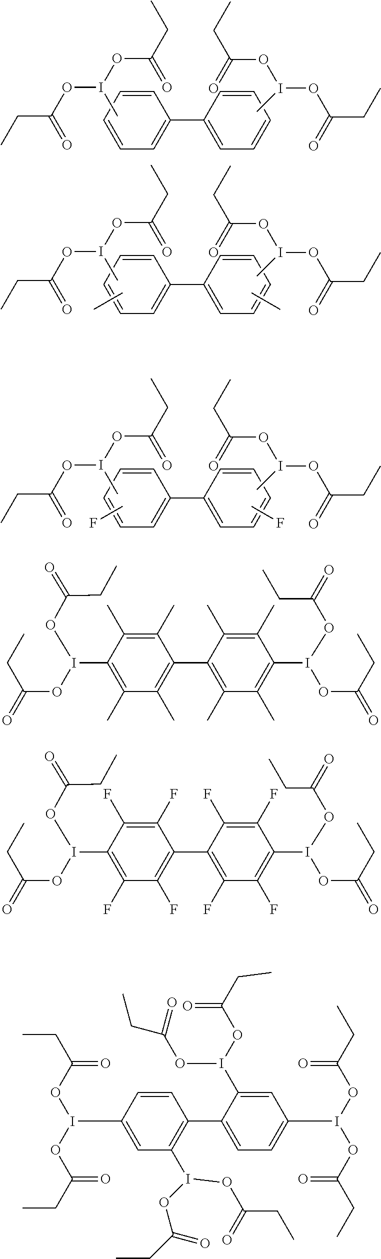

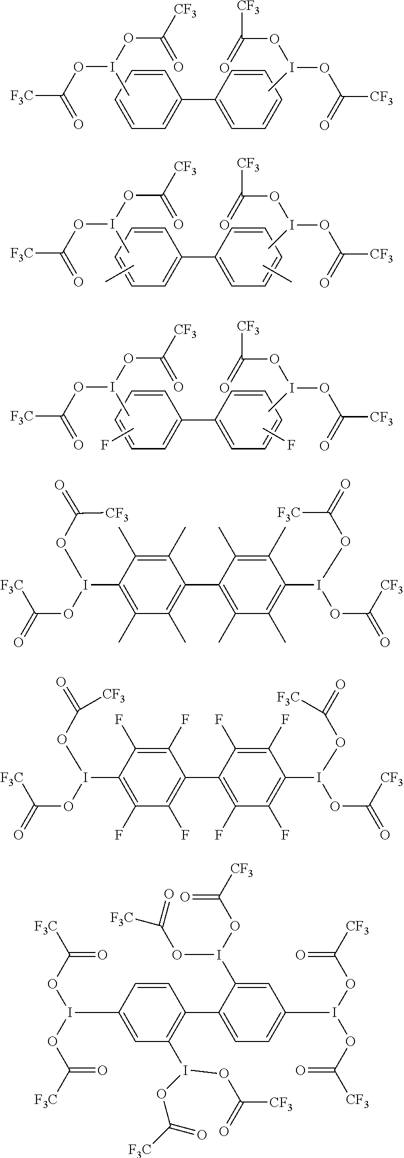

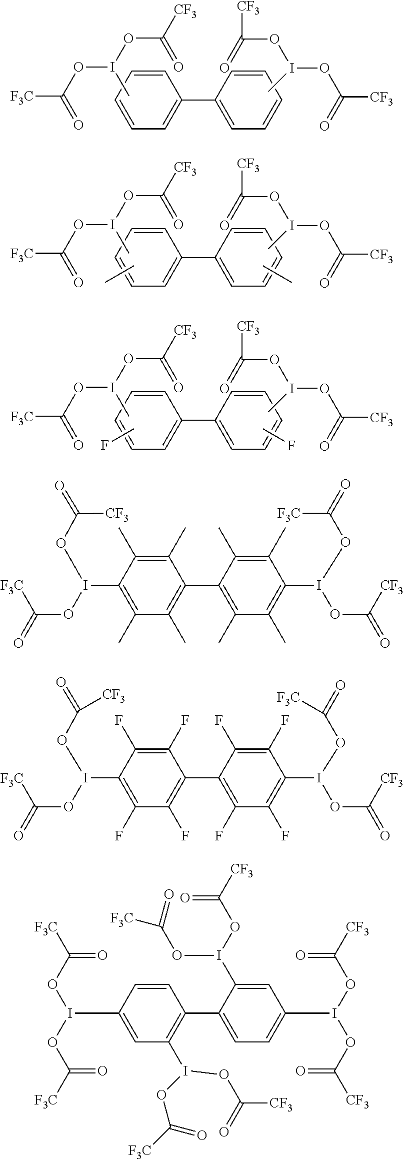

Specific examples of the hypervalent iodine compound represented by the formula (9) include the following hypervalent iodine compounds, but not limited thereto.

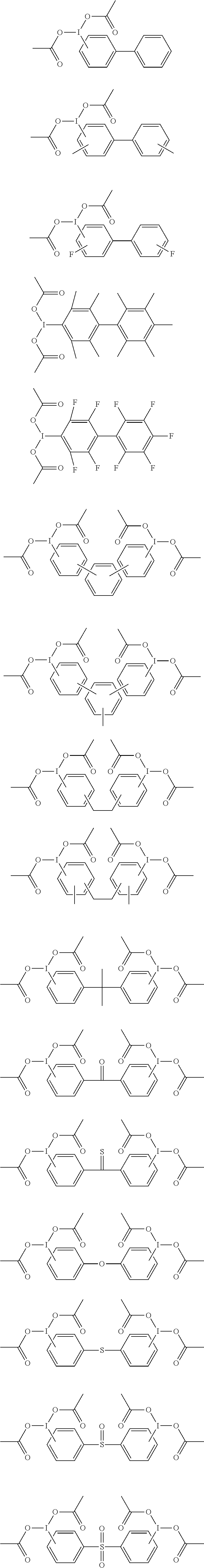

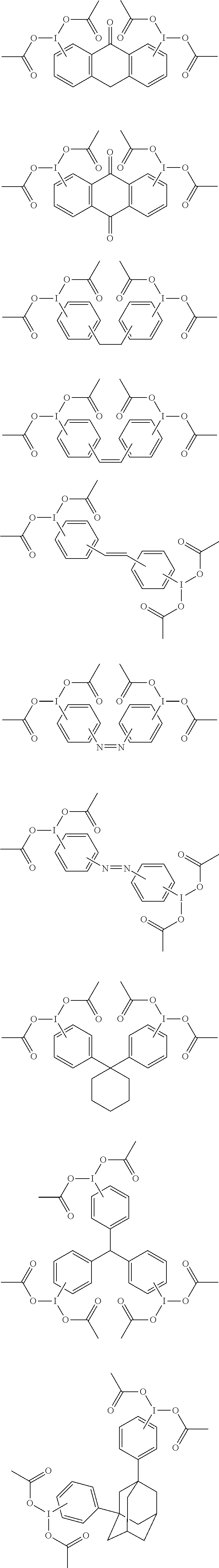

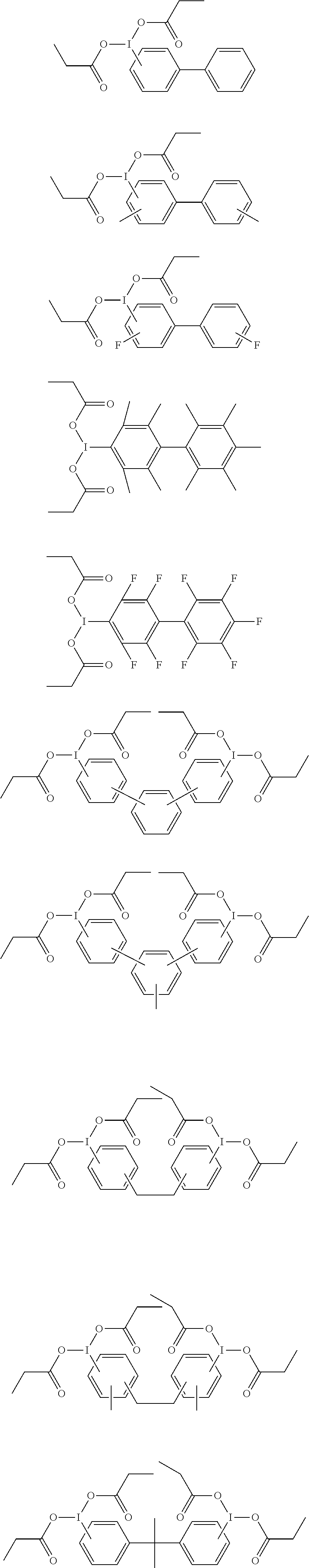

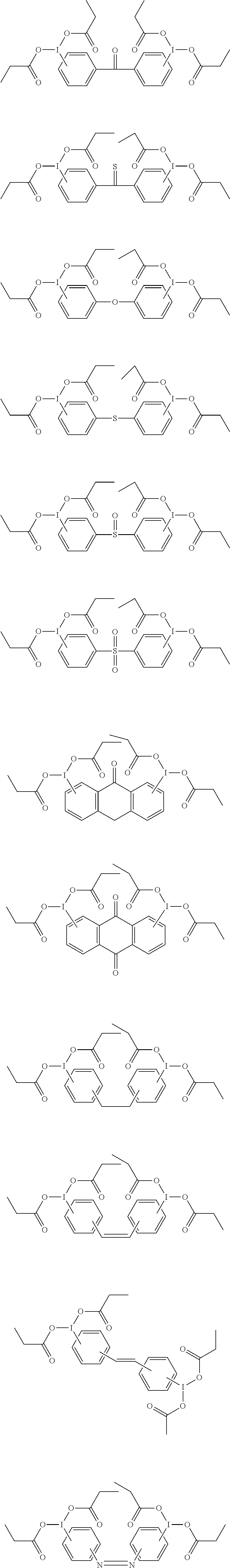

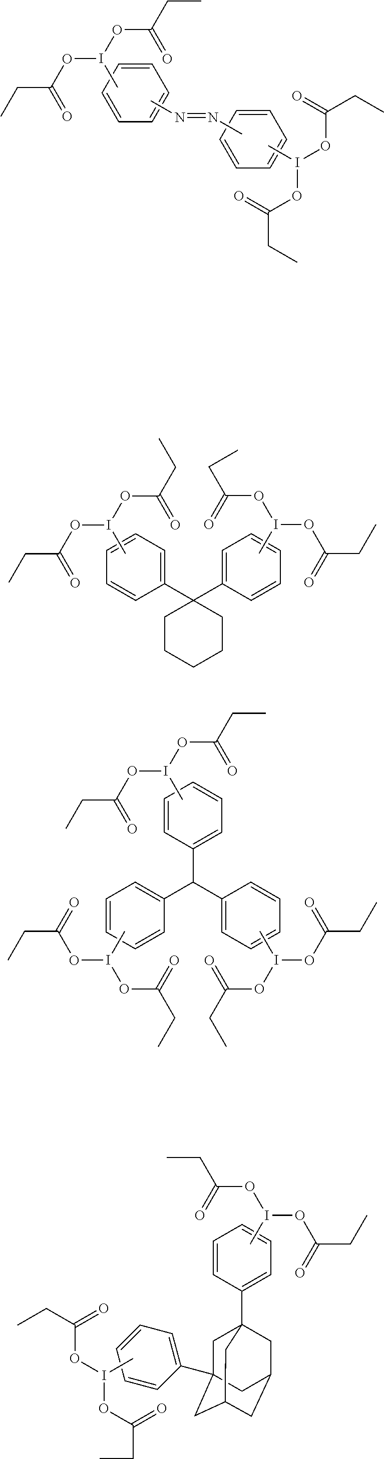

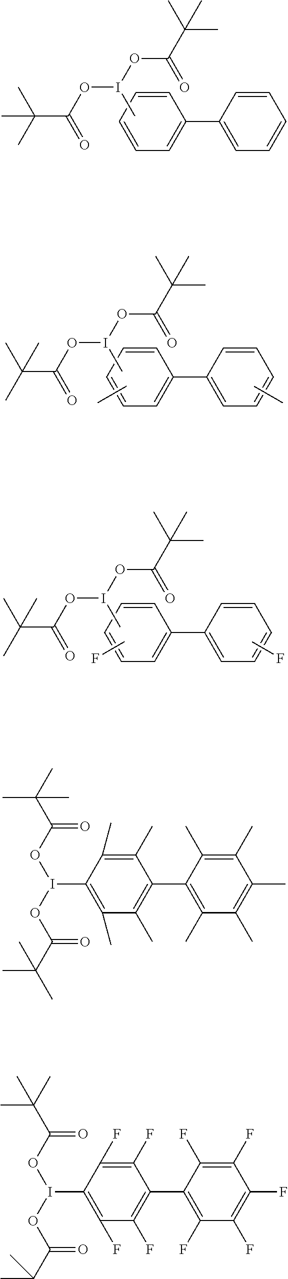

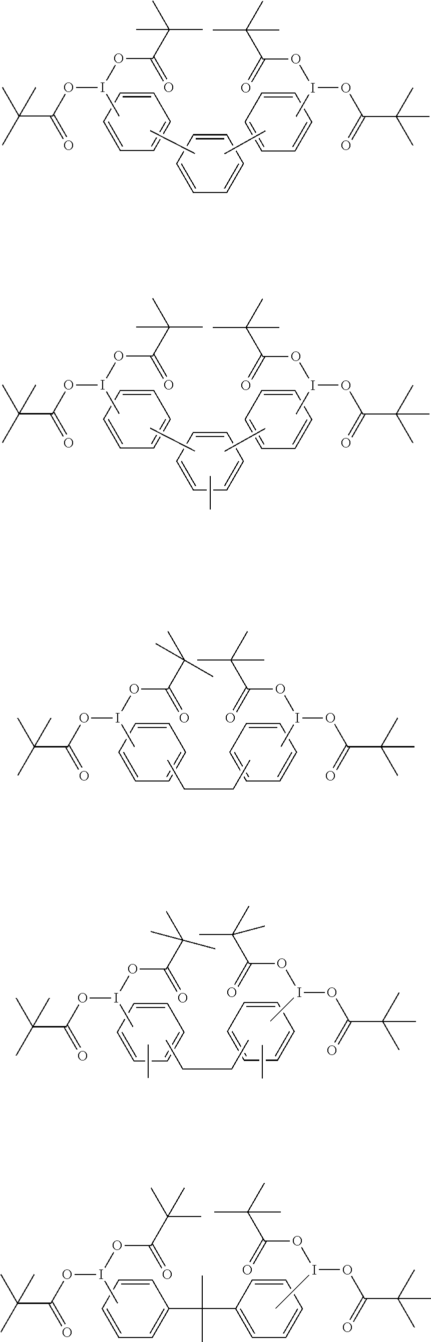

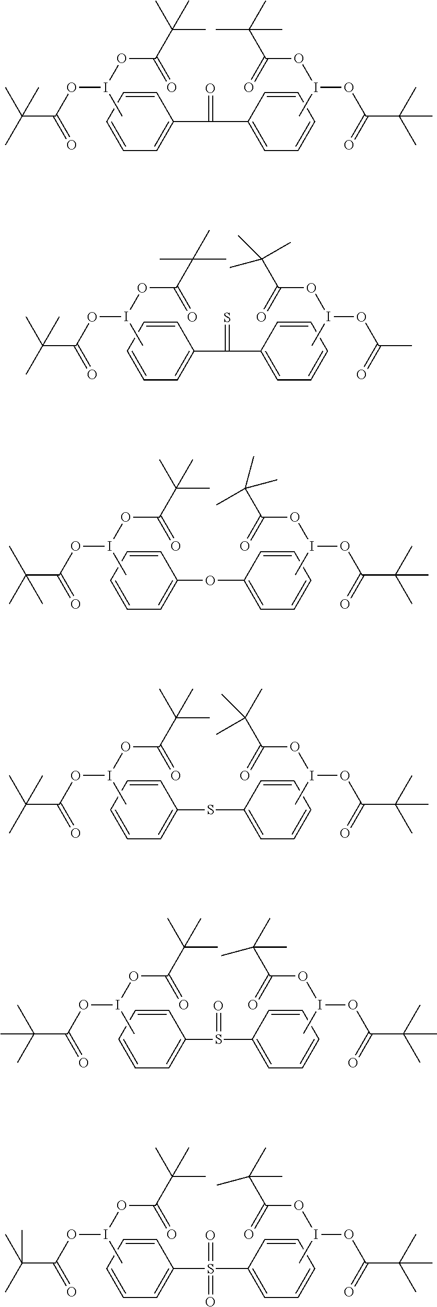

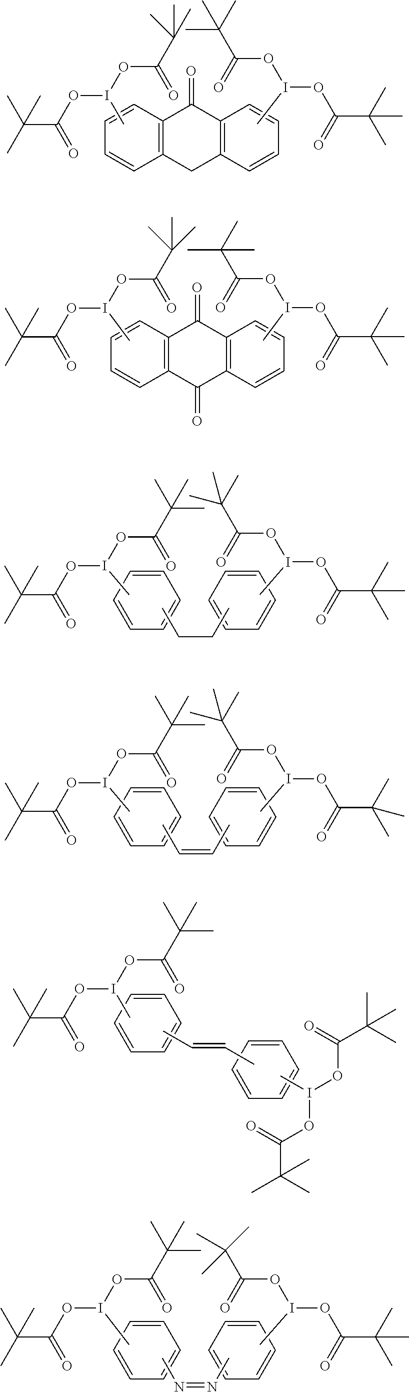

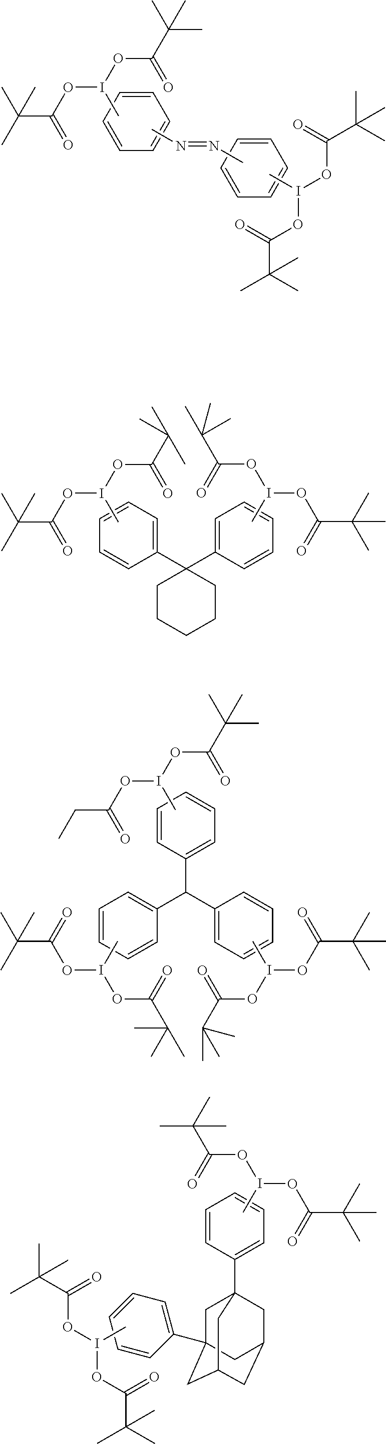

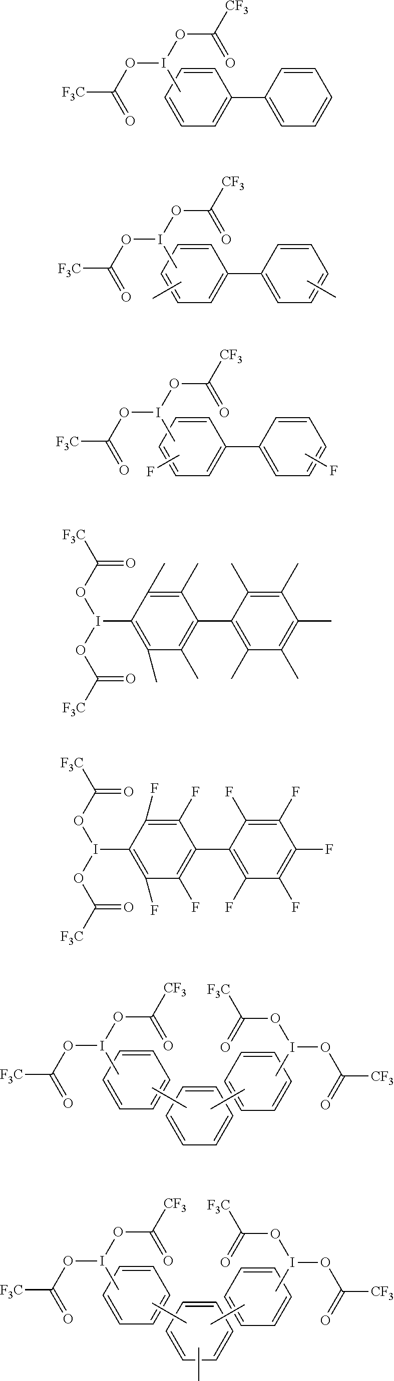

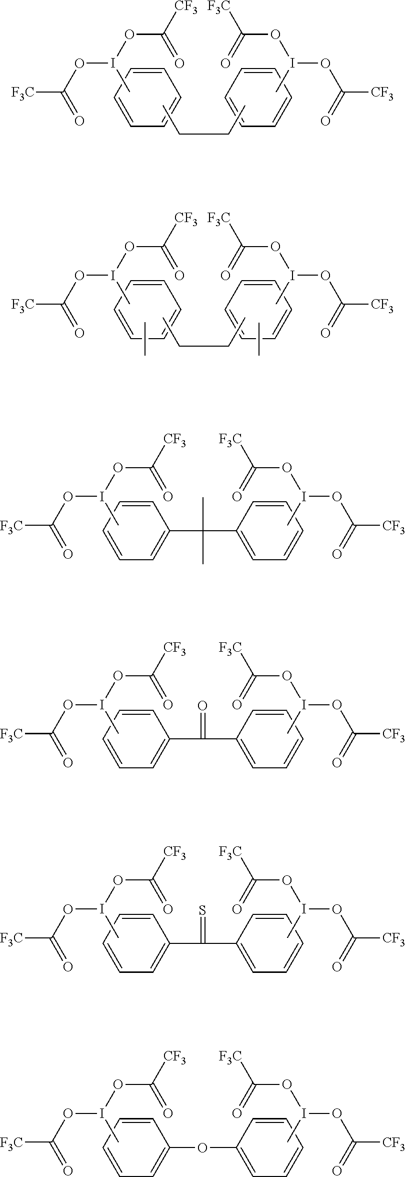

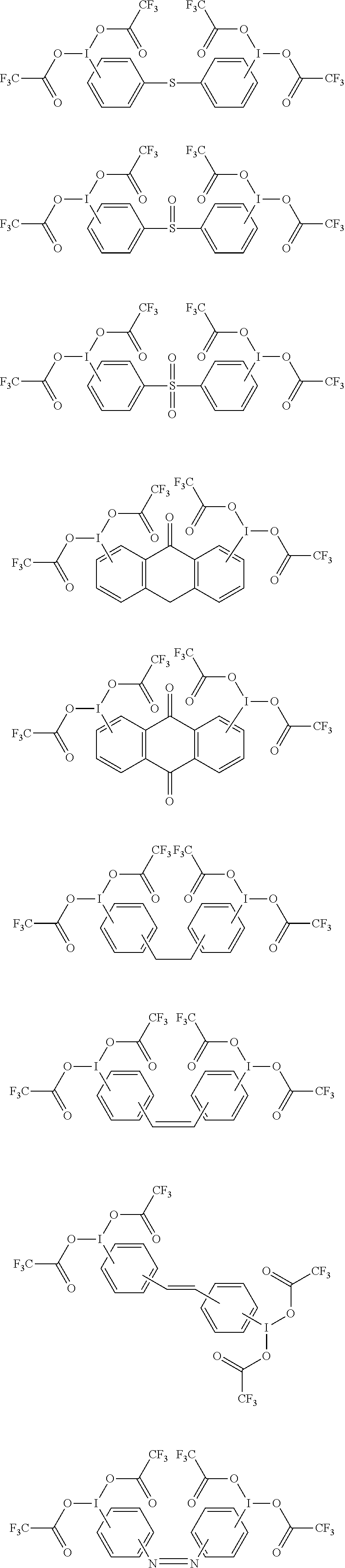

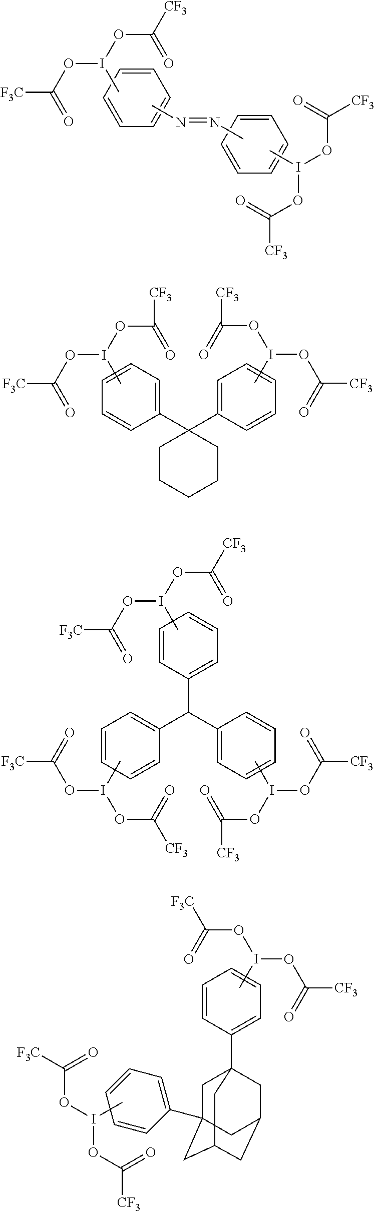

The carboxy group-containing compound is preferably a polymer containing a repeating unit represented by the following formula (10) or a compound represented by the following formula (11).

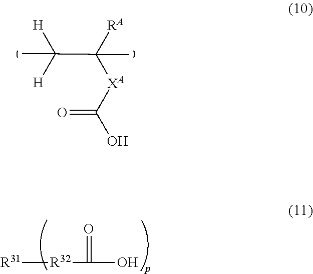

In the formula (10), R^{A} is a hydrogen atom, a halogen atom, a methyl group or a trifluoromethyl group; X^{A} is a single bond, a phenylene group, a naphthylene group or *—C(═O)—O—X^{A1}—; X^{A1} is a saturated hydrocarbylene group having 1 to 10 carbon atoms, a phenylene group or a naphthylene group, and the saturated hydrocarbylene group optionally contains a hydroxy group, an ether bond, an ester bond or a lactone ring; and * represents a point of attachment to a carbon atom in a backbone.

In the formula (11), p is 1, 2, 3 or 4.

In the formula (11), R³¹ is a p-valent hydrocarbon group having 1 to 40 carbon atoms or a p-valent heterocyclic group having 2 to 40 carbon atoms, and when “p” is 2, R³¹ is optionally an ether bond, a carbonyl group, an azo group, a thioether bond, a carbonate bond, a carbamate bond, a sulfinyl group or a sulfonyl group; and some or all of hydrogen atoms in the p-valent hydrocarbon group or the p-valent heterocyclic group are each optionally substituted by a group containing a heteroatom, and some of —CH₂— in the p-valent hydrocarbon group are each optionally substituted by a group containing a heteroatom.

In the formula (11), R³² is a single bond or a hydrocarbylene group having 1 to 10 carbon atoms, some or all of hydrogen atoms in the hydrocarbylene group are each optionally substituted by a group containing a heteroatom, and some of —CH₂— in the hydrocarbylene group are each optionally substituted by a group containing a heteroatom; and when “p” is 2, 3 or 4, R³²S are the same as or different from each other.

The p-valent hydrocarbon group represented by R³¹ may be saturated or unsaturated, and may be any of straight, branched or cyclic. The p-valent hydrocarbon group is a group obtained by detaching “p” hydrogen atoms from hydrocarbon. Examples of the hydrocarbon include alkane having 1 to 40 carbon atoms, alkene having 2 to 40 carbon atoms, alkyne having 2 to 40 carbon atoms, cyclic saturated hydrocarbon having 3 to 40 carbon atoms, cyclic unsaturated hydrocarbon having 3 to 40 carbon atoms, and aromatic hydrocarbon having 6 to 40 carbon atoms.

Examples of the alkane having 1 to 40 carbon atoms include methane, ethane, propane, butane, pentane, hexane, heptane, octane, nonane, decane, and any structural isomer thereof.

Examples of the alkene having 2 to 40 carbon atoms include ethylene, propylene, butene, pentene, hexene, heptene, octene, nonene, decene, and any structural isomer thereof.

Examples of the alkyne having 2 to 40 carbon atoms include acetylene, propyne, butyne, pentyne, hexyne, heptyne, octyne, nonyne, decyne, and any structural isomer thereof.

Examples of the cyclic saturated hydrocarbon having 3 to 40 carbon atoms include cyclopropane, cyclobutane, cyclohexane, cycloheptane, cyclooctane, adamantane, and norbornane.

Examples of the cyclic unsaturated hydrocarbon having 3 to 40 carbon atoms include cyclopropene, cyclobutene, cyclopentene, cyclohexene, cycloheptene, cyclooctene, and norbornene.

Examples of the aromatic hydrocarbon having 6 to 40 carbon atoms include benzene, naphthalene, and biphenyl.

The p-valent heterocyclic group represented by R³¹ is a group obtained by detaching “p” hydrogen atoms from a heterocyclic compound. Examples of the heterocyclic compound include furan, pyridine, pyrazole, and thiazolidine.

Some or all of hydrogen atoms in the p-valent hydrocarbon group or p-valent heterocyclic group are each optionally substituted by a group containing a heteroatom such as an oxygen atom, a sulfur atom, a nitrogen atom, or a halogen atom, and as a result, a hydroxy group, a cyano group, a fluorine atom, a chlorine atom, a bromine atom, an iodine atom, or the like is optionally contained. Some of —CH₂-constituting the p-valent hydrocarbon group are each optionally substituted by a group containing a heteroatom such as an oxygen atom, a sulfur atom, or a nitrogen atom, and as a result, a carbonyl group, an ether bond, a thioether bond, an ester bond, a sulfonic acid ester bond, a carbonate bond, a carbamate bond, a lactone ring, a sultone ring, a carboxylic anhydride (—C(═O)—O—C(═O)—), or the like is optionally contained.

The hydrocarbylene group represented by R³² may be saturated or unsaturated, and may be any of straight, branched or cyclic. Specific examples thereof include alkanediyl groups each having 1 to 20 carbon atoms, such as a methanediyl group, an ethan-1,1-diyl group, an ethan-1,2-diyl group, a propan-1,2-diyl group, a propan-1,3-diyl group, a butan-1,4-diyl group, a pentan-1,5-diyl group, a hexan-1,6-diyl group, a heptan-1,7-diyl group, an octan-1,8-diyl group, a nonan-1,9-diyl group, a decan-1,10-diyl group, an undecan-1,11-diyl group and a dodecan-1,12-diyl group; cyclic saturated hydrocarbylene groups each having 3 to 20 carbon atoms, such as a cyclopentanediyl group, a cyclohexanediyl group, a norbornanediyl group and an adamantanediyl group; unsaturated aliphatic hydrocarbylene groups each having 2 to 20 carbon atoms, such as a vinylene group and a propene-1,3-diyl group; arylene groups each having 6 to 20 carbon atoms, such as a phenylene group and a naphthylene group; and any group obtained by combination thereof. Some or all of hydrogen atoms in the hydrocarbylene group are each optionally substituted by a group containing a heteroatom such as an oxygen atom, a sulfur atom, a nitrogen atom, or a halogen atom, some of —CH₂— in the hydrocarbylene group are each optionally substituted by a group containing a heteroatom such as an oxygen atom, a sulfur atom, or a nitrogen atom, and as a result, a hydroxy group, a cyano group, a fluorine atom, a chlorine atom, a bromine atom, an iodine atom, a carbonyl group, an ether bond, a thioether bond, an ester bond, a sulfonic acid ester bond, a carbonate bond, a carbamate bond, a lactone ring, a sultone ring, a carboxylic anhydride, or the like is optionally contained.

The carboxylic acid compound represented by the formula (11) is preferably such a compound in which “p” is 2, 3 or 4. This case is preferred from the viewpoints of etching resistance and developer resistance because a stiff resist film in which the molecular weight is high is easily formed during mixing with the hypervalent iodine compound.

Specific examples of the carboxy group-containing repeating unit represented by the formula (10), in the carboxy group-containing polymer represented by the formula (10), include those represented below, but are not limited thereto. In the following formulae, R^{A} is the same as described above.

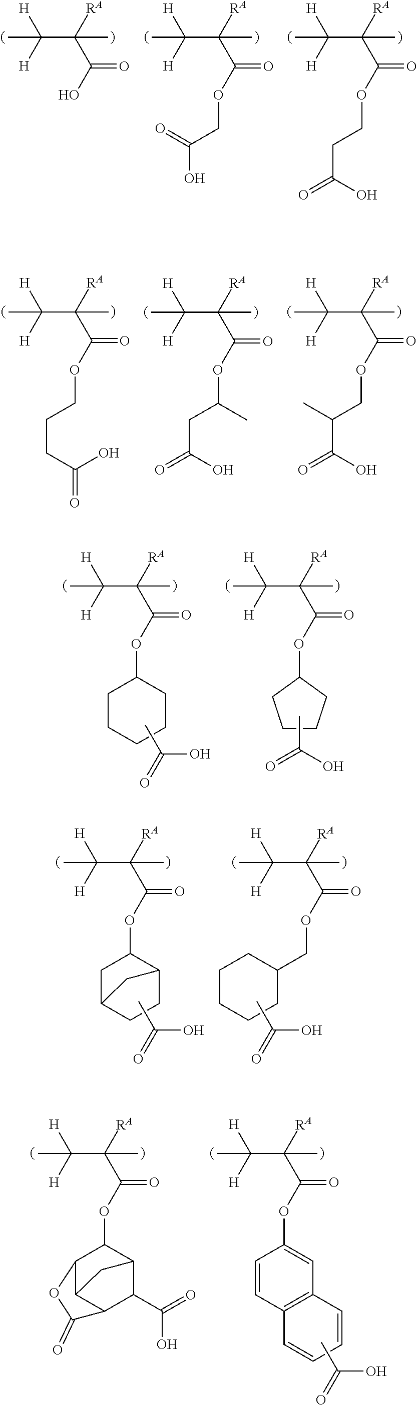

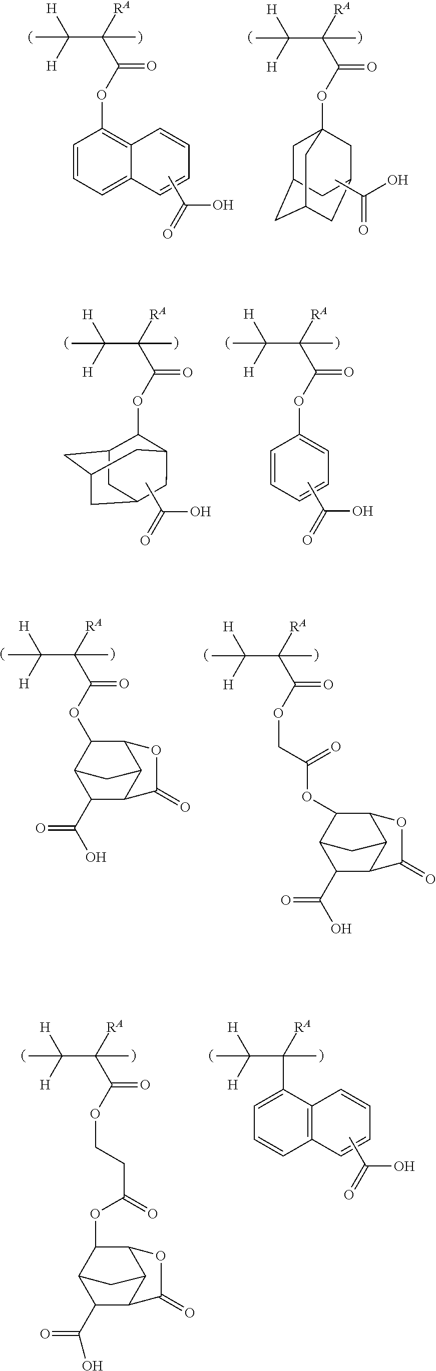

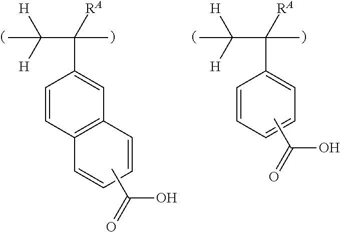

Examples of the carboxylic acid compound represented by the formula (11) include those represented below, but are not limited thereto.

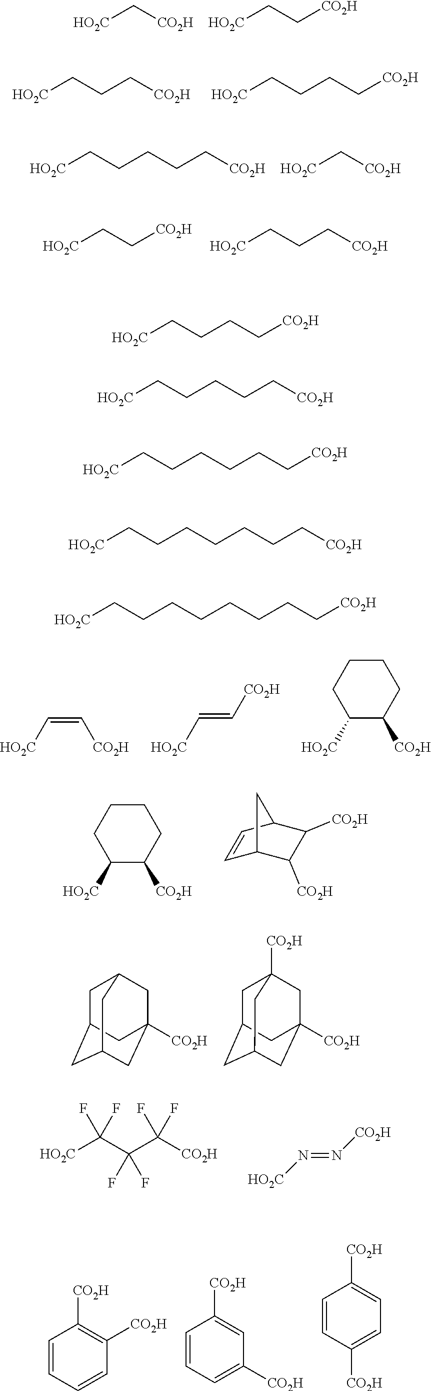

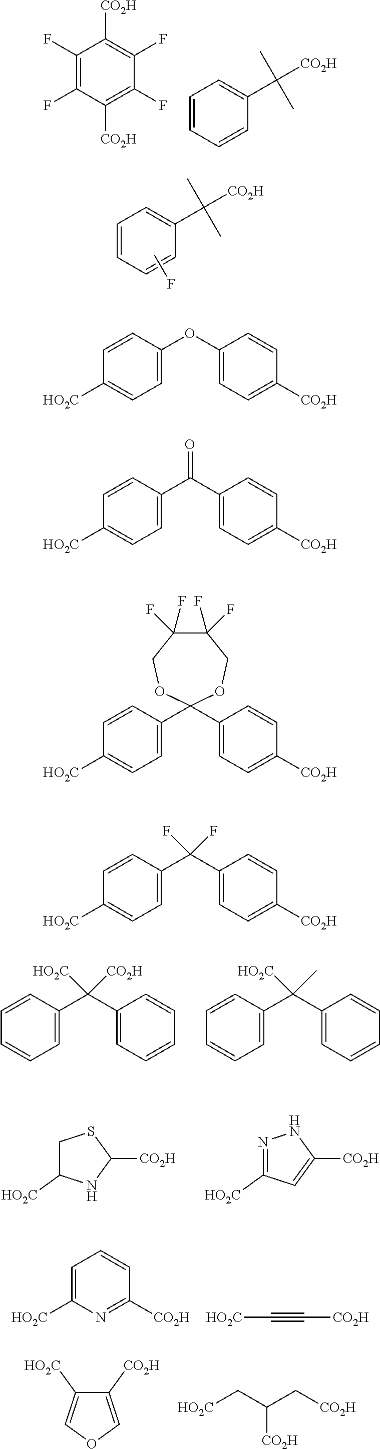

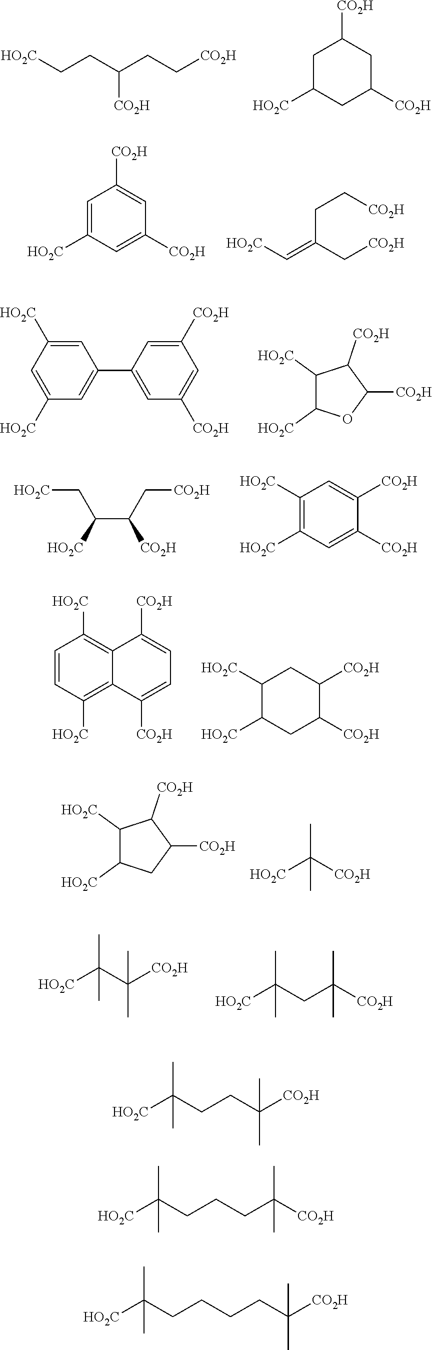

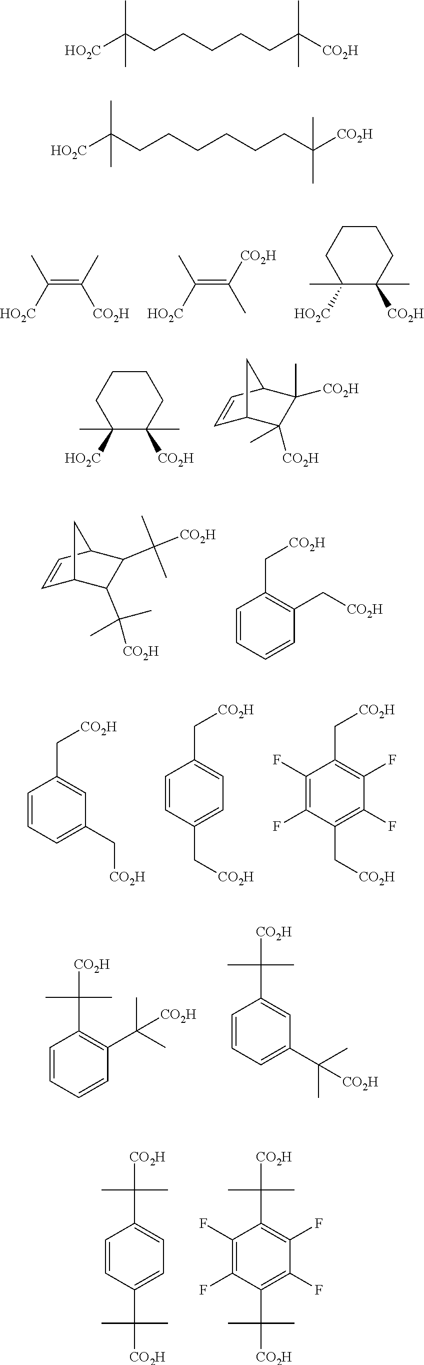

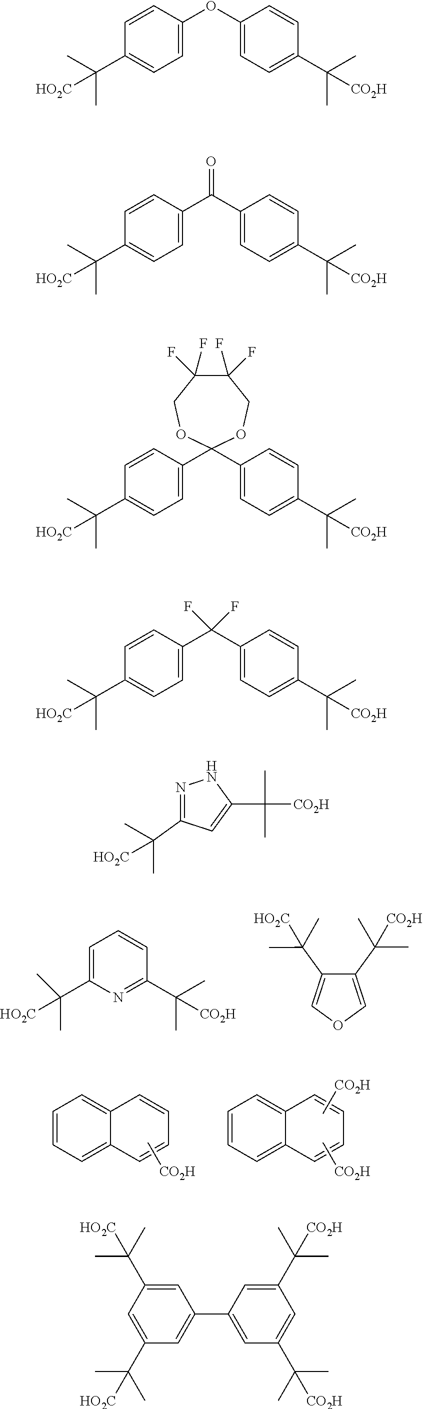

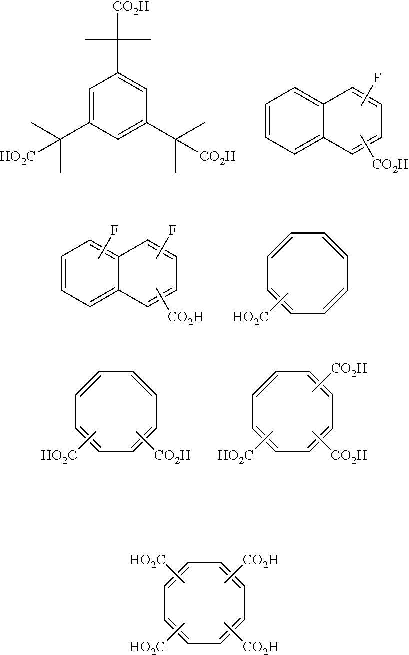

The carboxy group-containing polymer containing the repeating unit represented by the formula (10) further optionally contains any other repeating unit (hereinafter, also referred to as any other repeating unit.) besides the repeating unit represented by the formula (10). Such any other repeating unit is not particularly limited, and is preferably a unit capable of enhancing the solubility of a polymer which is difficult to dissolve only by a repeating unit having a carboxy group, in a solvent. Such any other repeating unit is preferably a repeating unit having a rigid skeleton and having a cyclic structure expected to impart high etching resistance, or a repeating unit having a styrene skeleton.

Specific examples of such any other repeating unit described above include those represented below, but are not limited thereto. In the following formulae, R^{A} is the same as described above, and each X^{B} is independently —CH₂— or —O—.

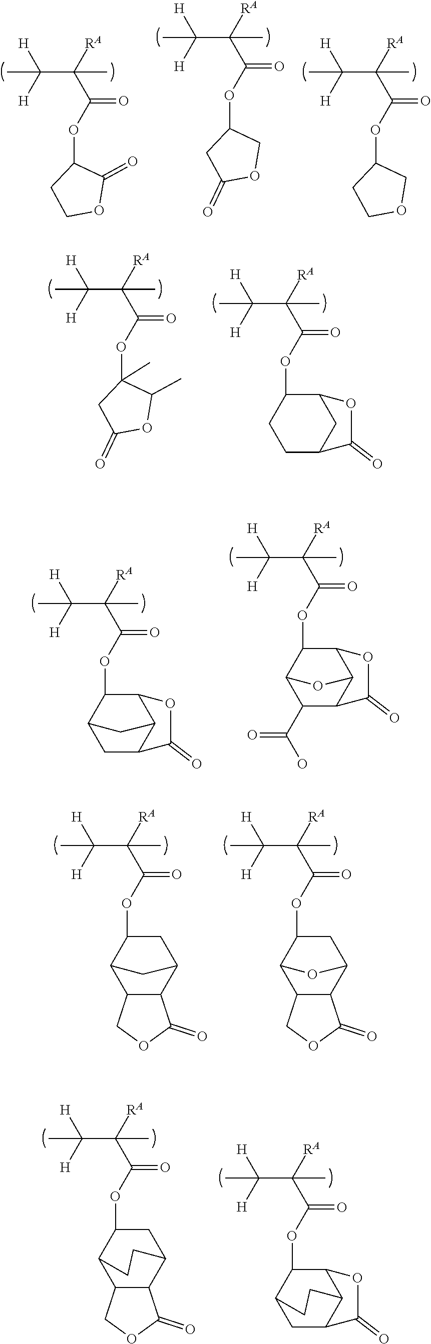

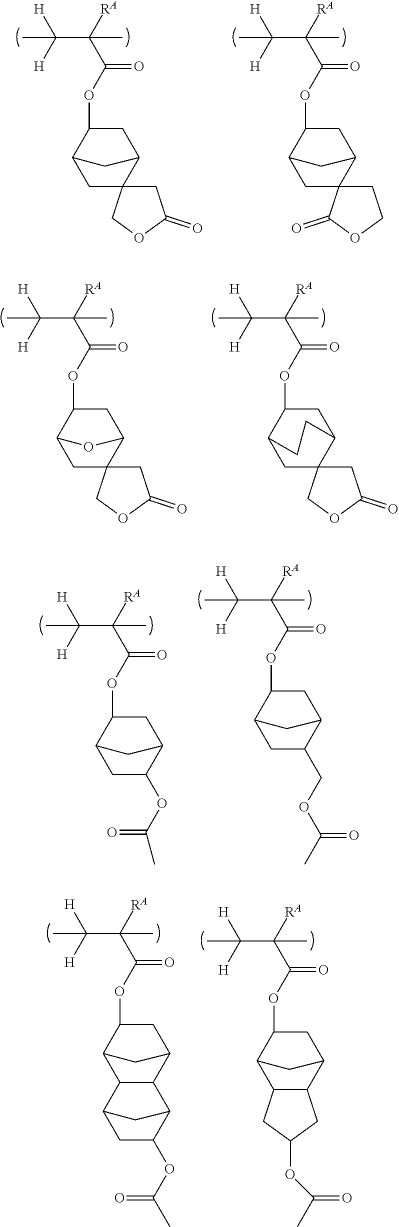

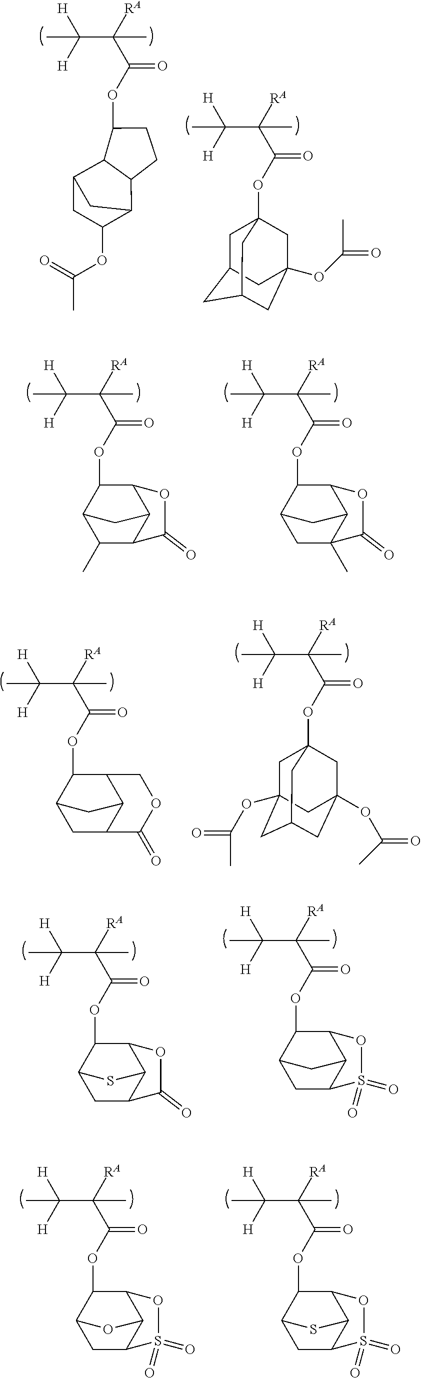

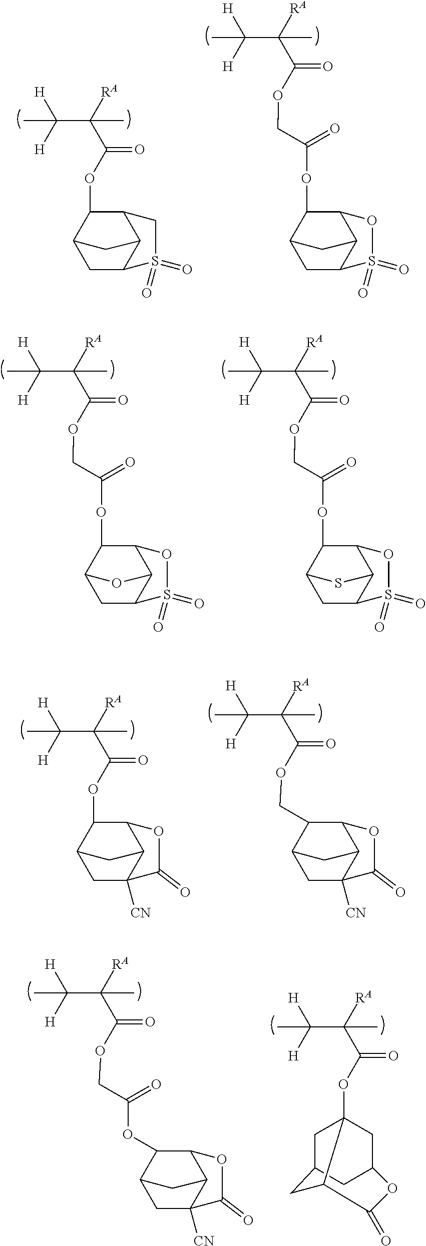

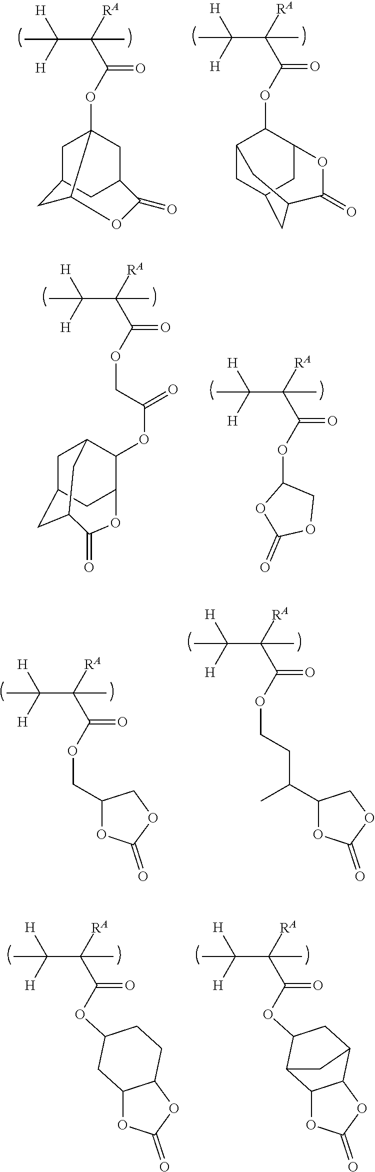

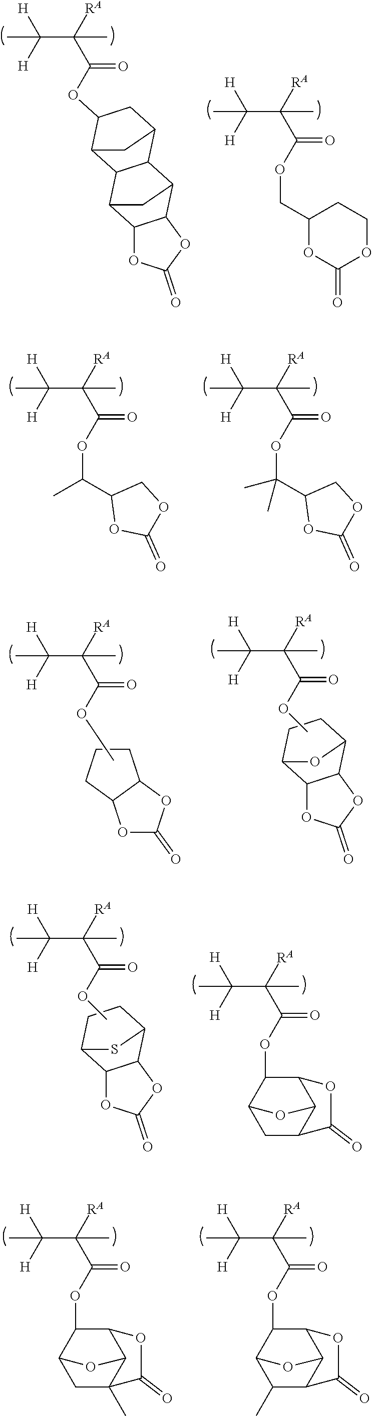

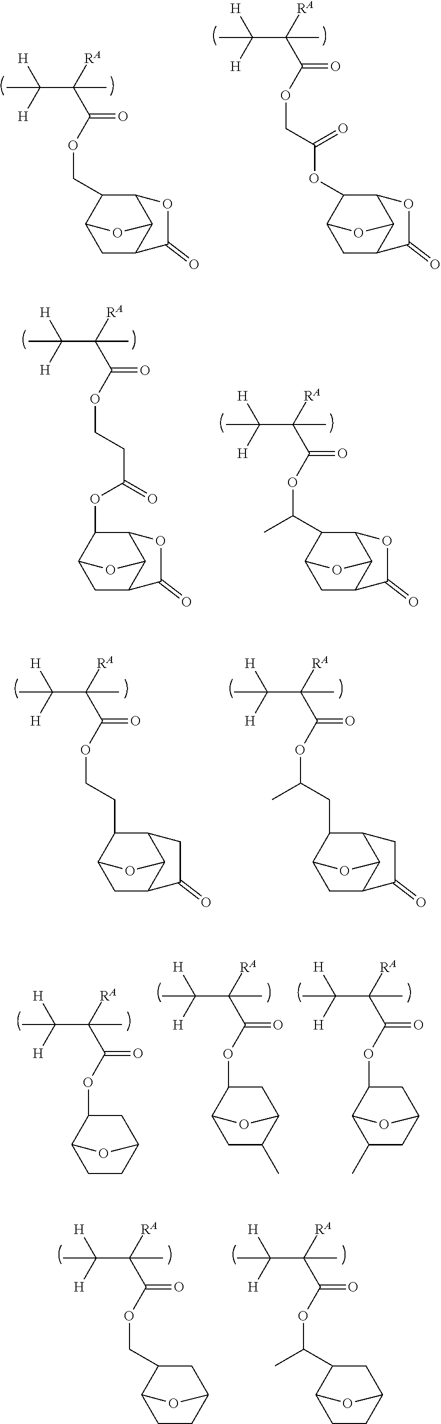

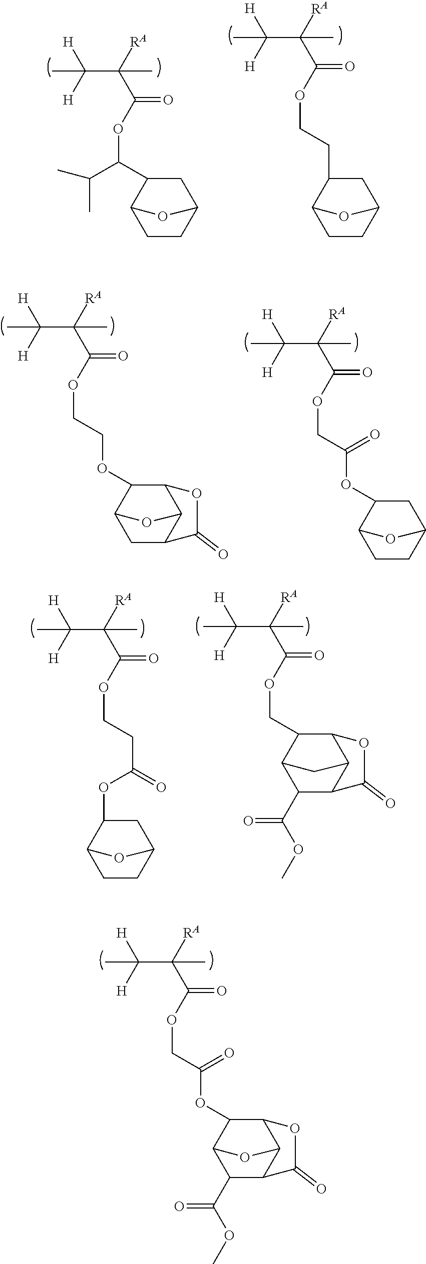

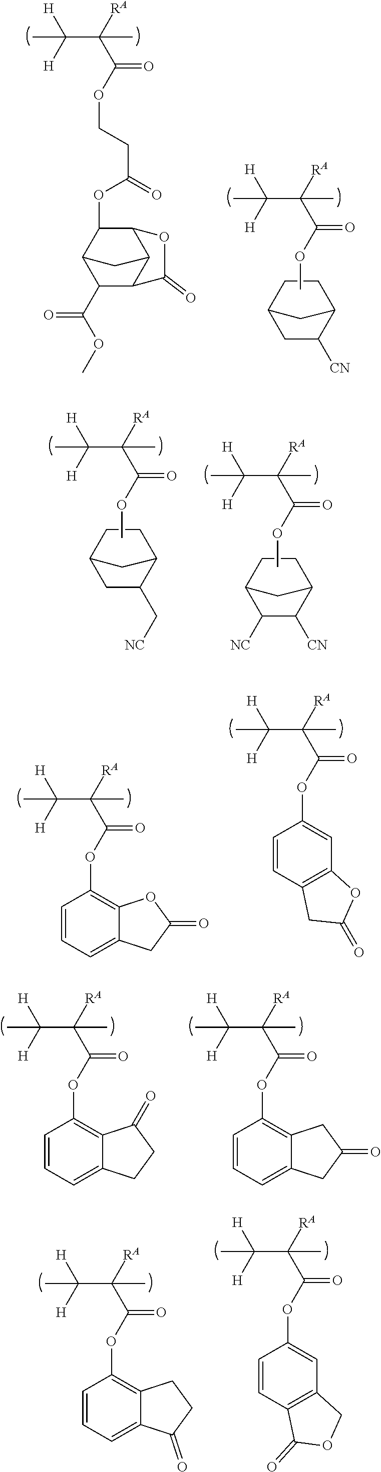

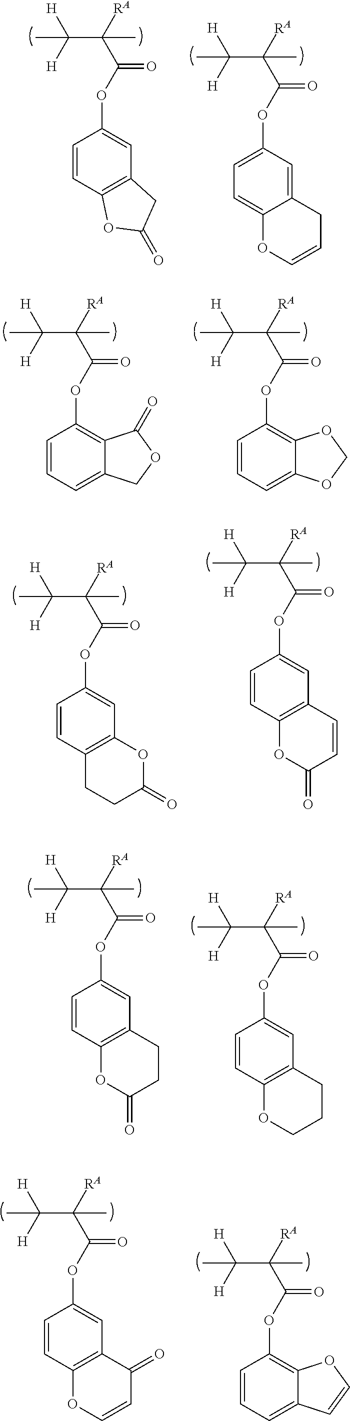

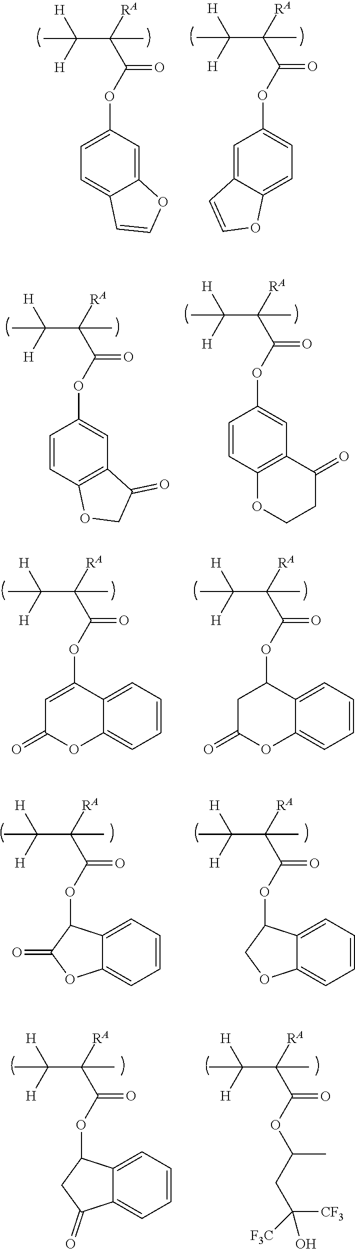

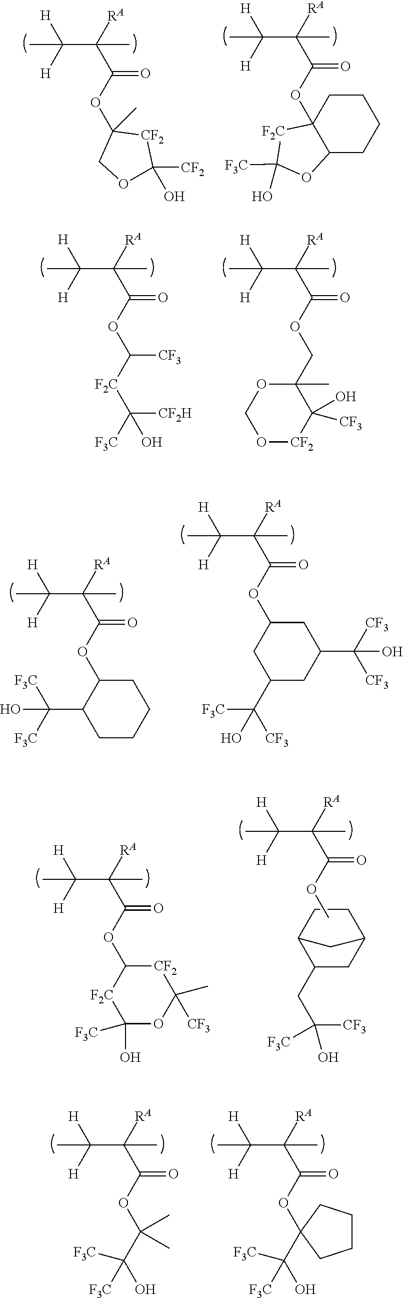

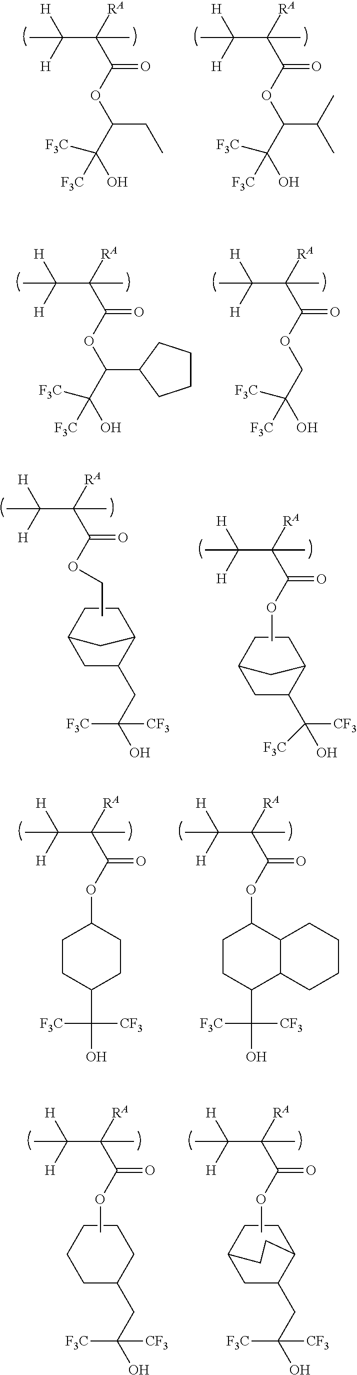

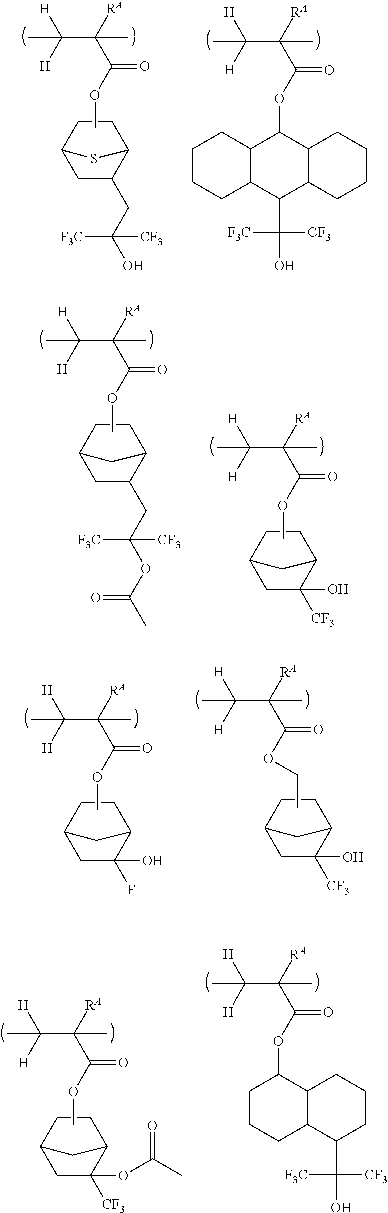

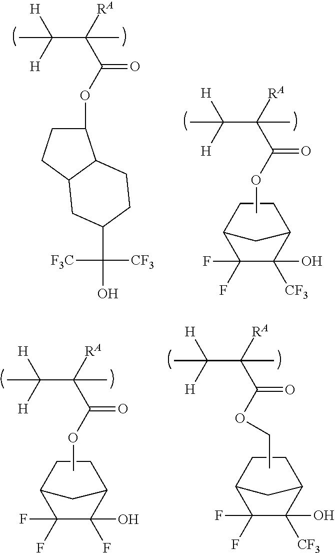

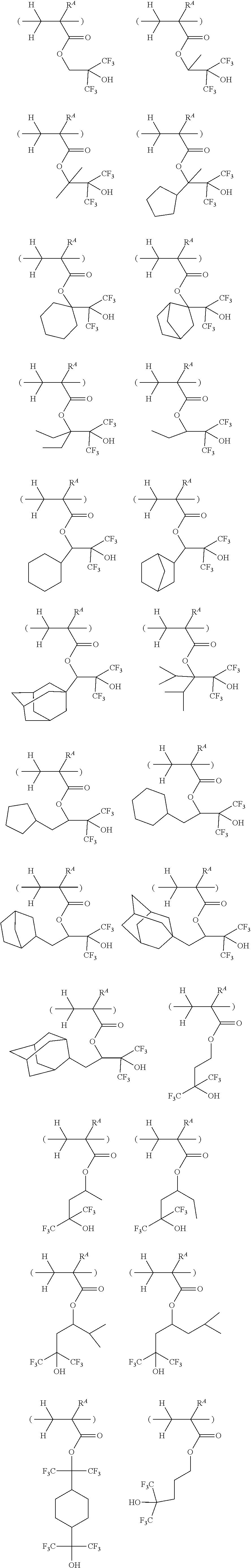

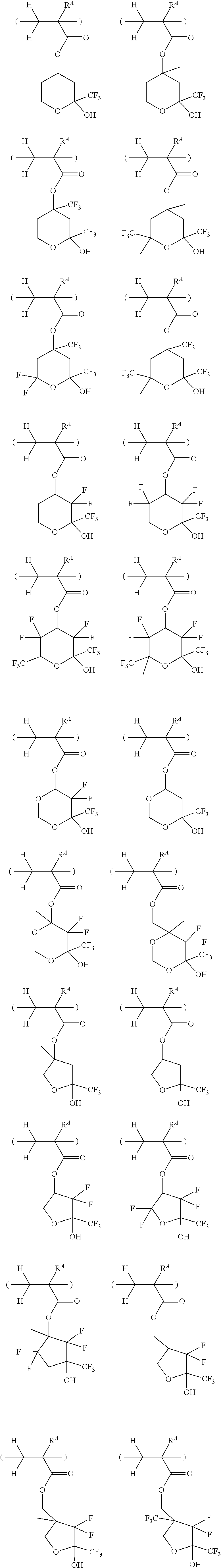

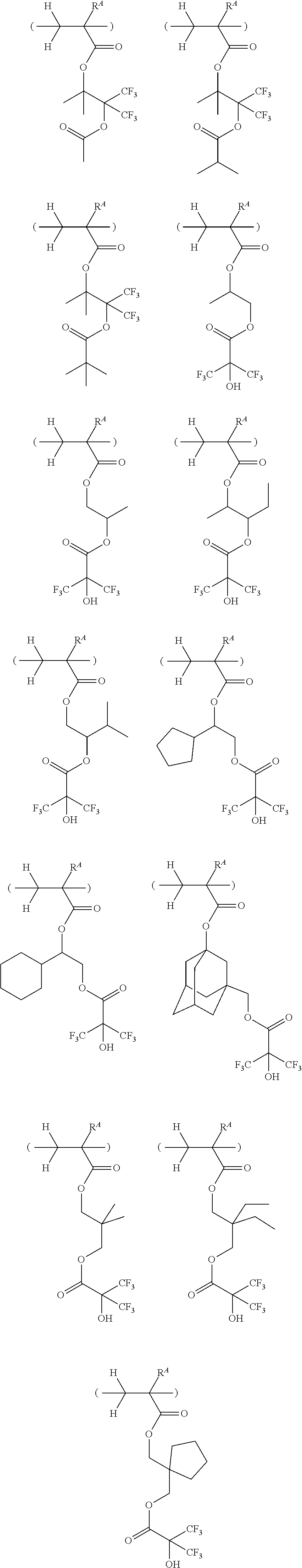

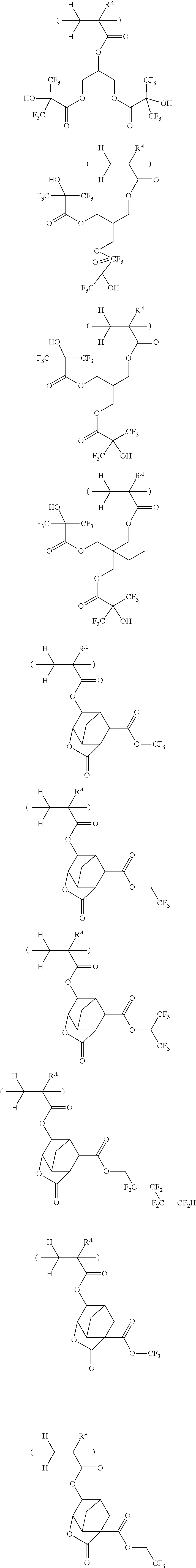

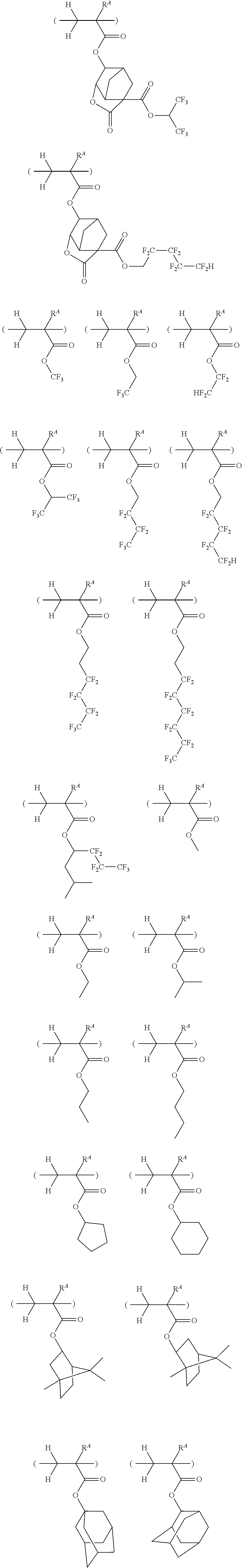

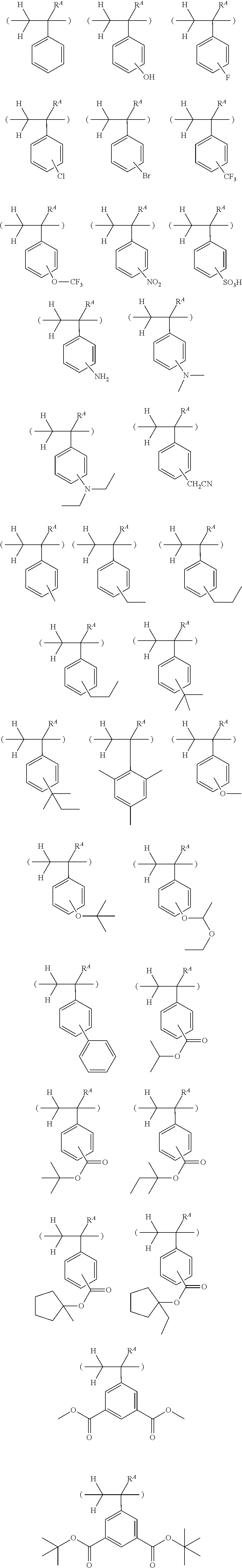

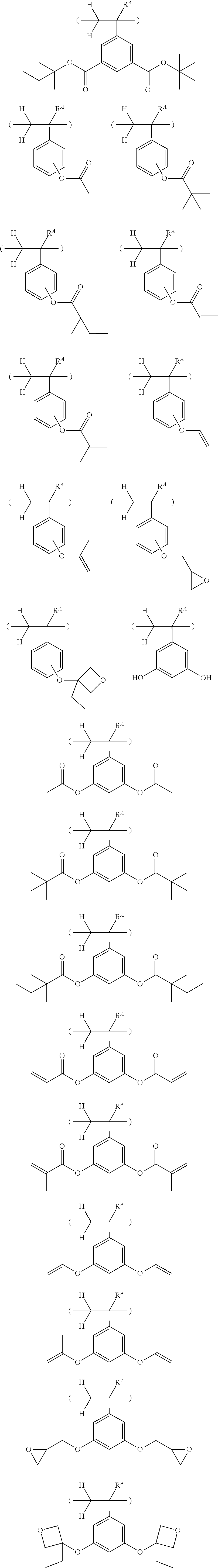

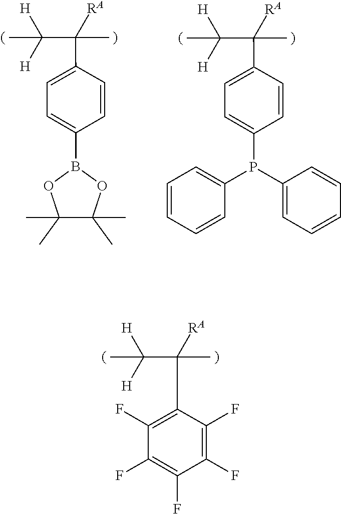

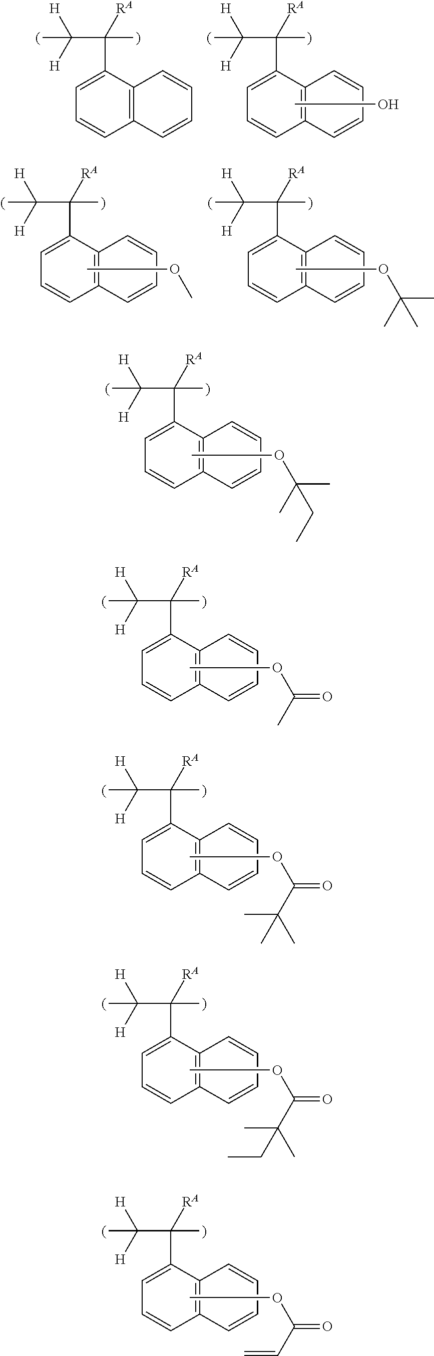

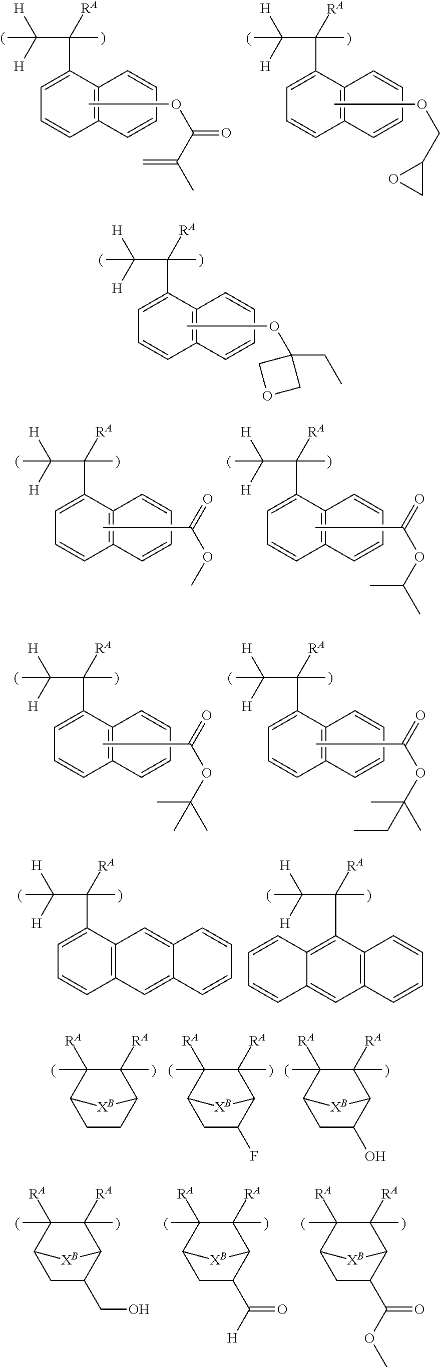

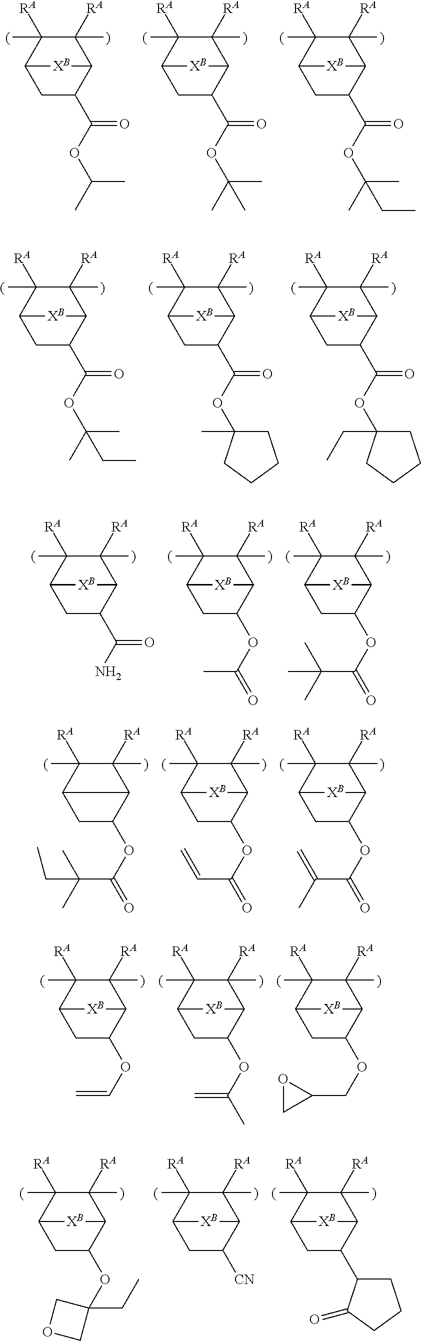

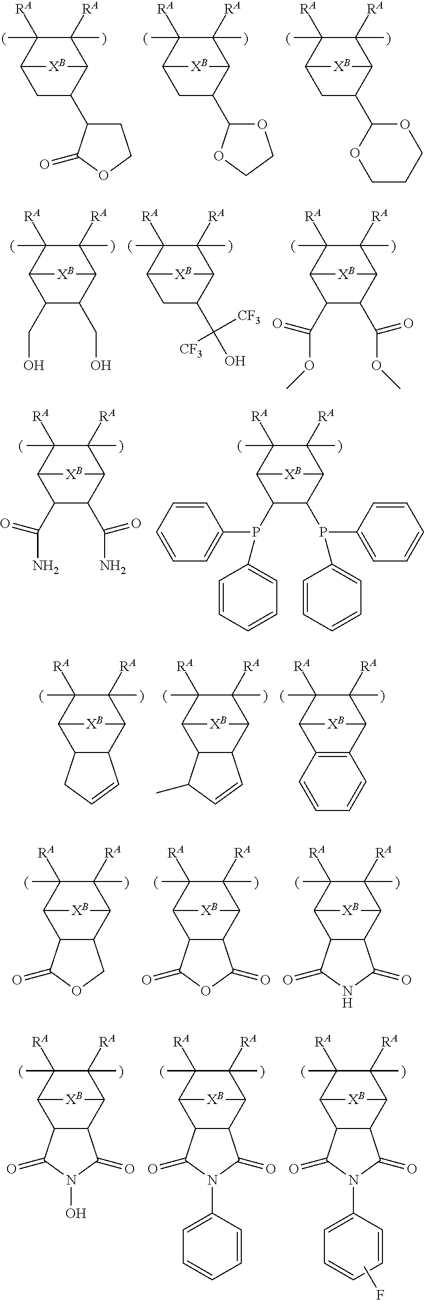

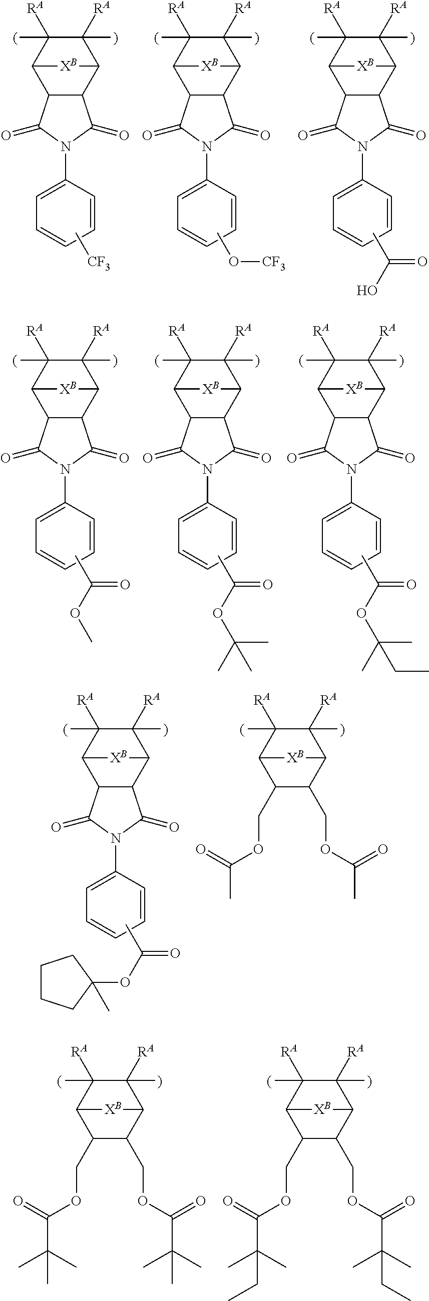

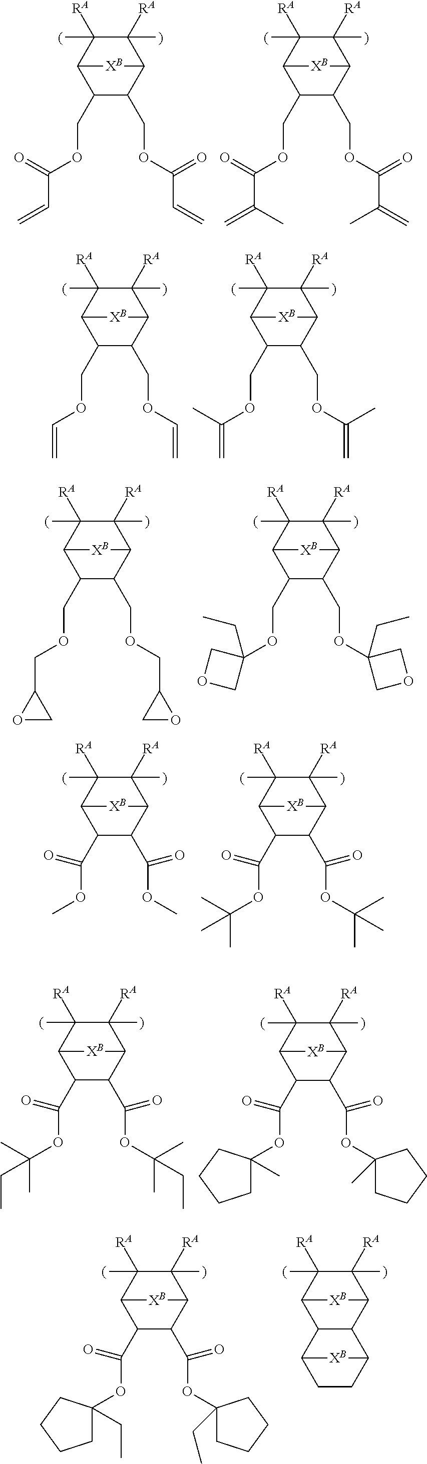

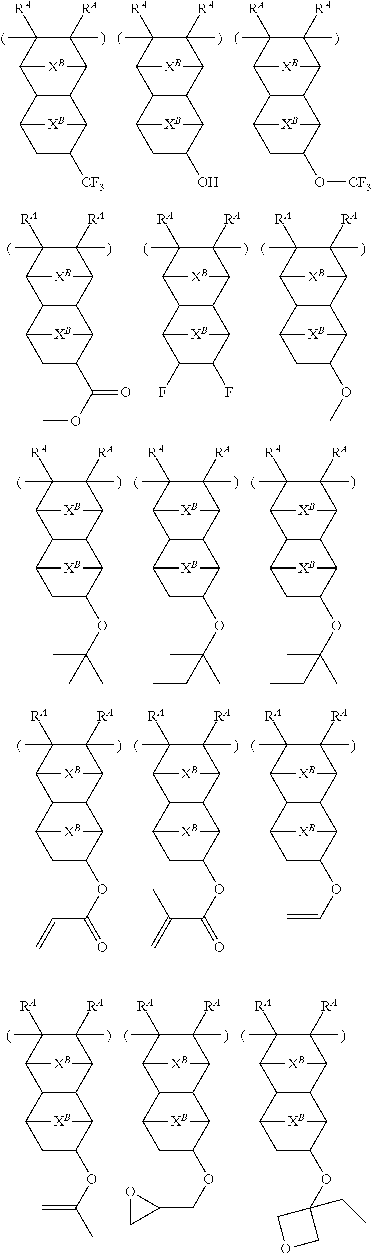

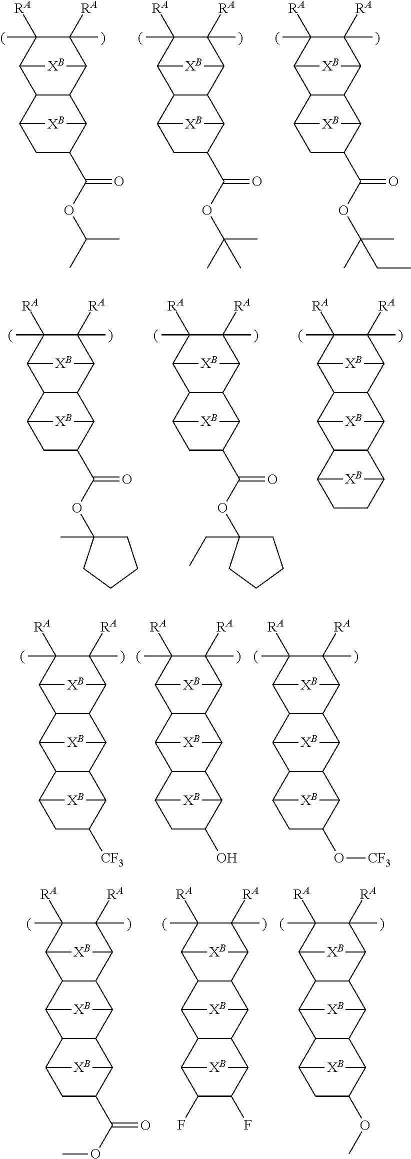

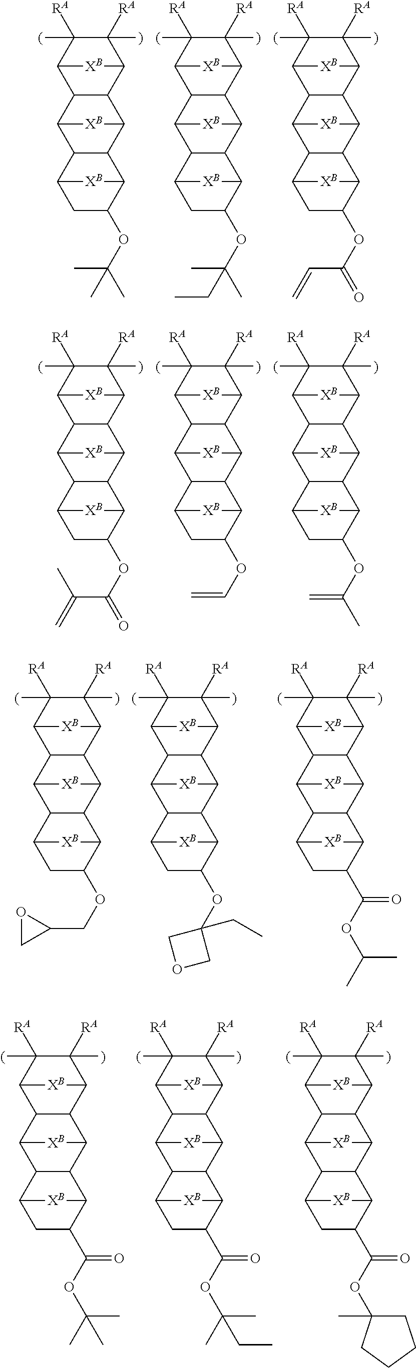

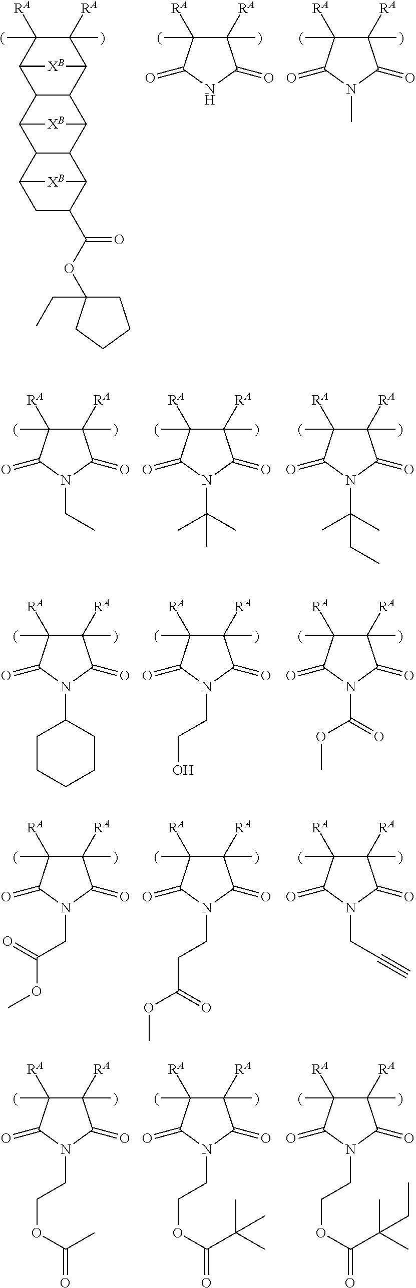

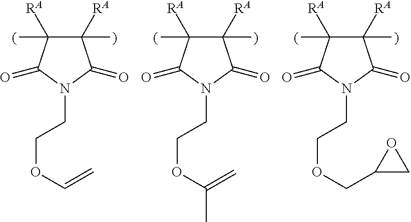

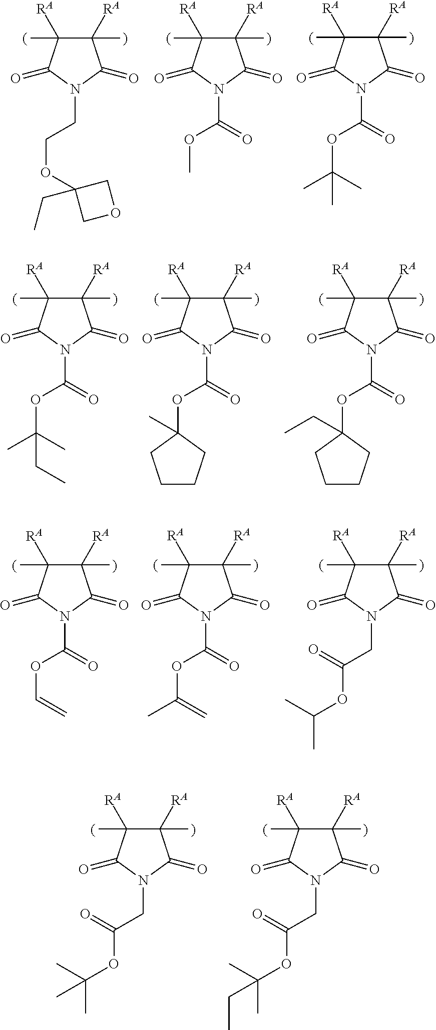

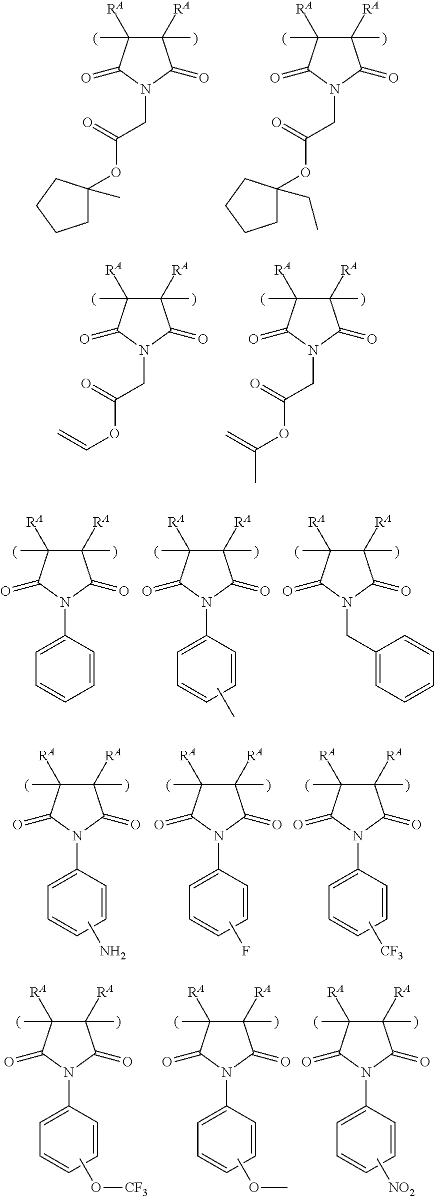

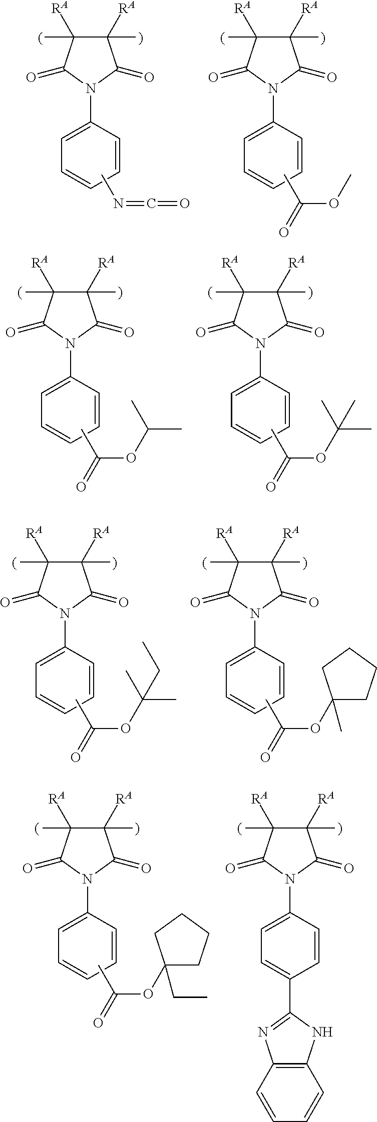

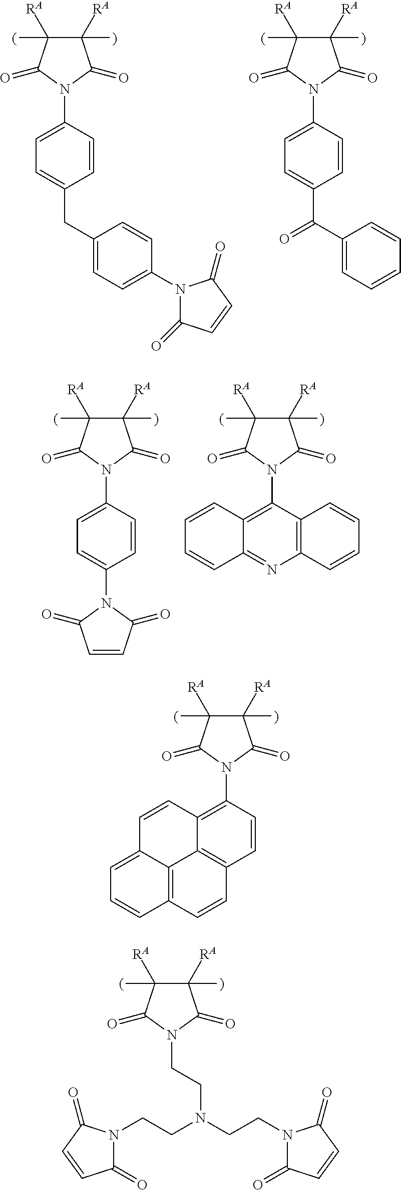

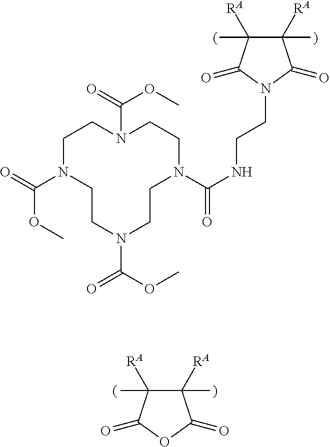

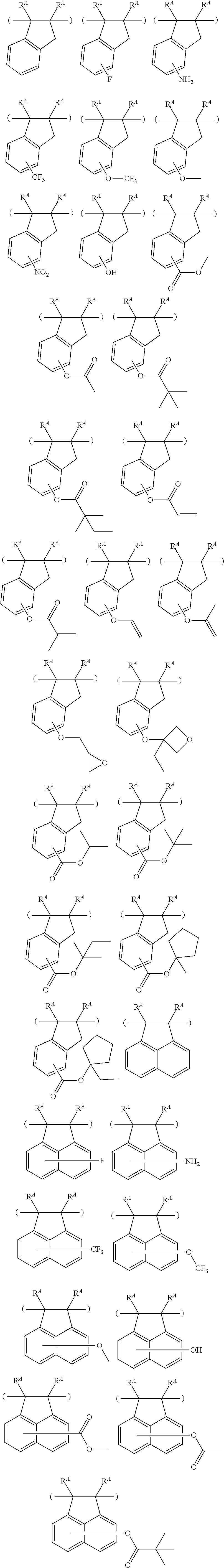

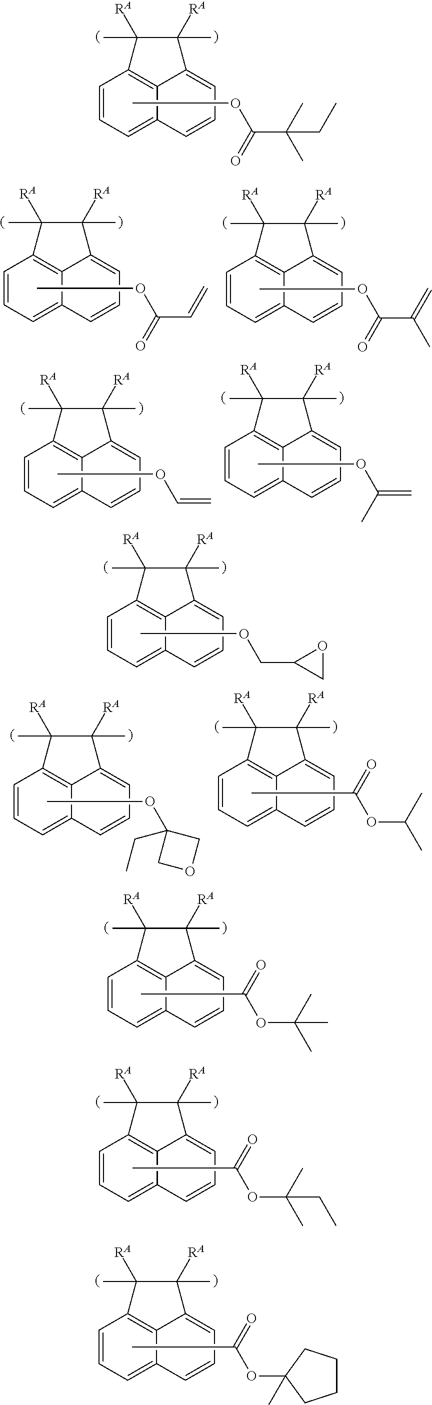

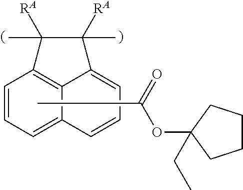

The content ratio of the hypervalent iodine compound to the carboxy group-containing compound in the resist composition (when the carboxy group-containing compound is a carboxy group-containing polymer, the content ratio of the hypervalent iodine compound to a carboxylic acid-containing repeating unit in the polymer is meant) is preferably 10:90 to 90:10, more preferably 20:80 to 80:20, further preferably 30:70 to 70:30 in terms of the molar ratio of hypervalent iodine compound:carboxy group-containing compound. The hypervalent iodine compound may be used singly or in combinations of two or more kinds of such compounds different in compositional ratio, Mw and/or Mw/Mn. The carboxy group-containing polymer may be used singly or in combinations of two or more kinds of such compounds different in compositional ratio, Mw and/or Mw/Mn.

The content ratio (molar ratio) of the carboxy group-containing repeating unit and any other repeating unit in the carboxy group-containing polymer is preferably 10:90 to 90:10, more preferably 15:85 to 85:15, further preferably 20:80 to 80:20 in terms of carboxy group-containing repeating unit:any other repeating unit.

The weight average molecular weight (Mw) of the carboxy group-containing polymer is preferably 1000 to 500000, more preferably 3000 to 100000. Herein, Mw in the present invention is a value measured in terms of polystyrene by gel permeation chromatography (GPC) with tetrahydrofuran (THF) as a solvent.

When the molecular weight distribution (Mw/Mn) of the carboxy group-containing polymer is broad, a low-molecular-weight polymer and a high-molecular-weight polymer are present and therefore foreign substances may be found on a pattern after exposure and/or the shape of the pattern may deteriorate. Therefore, the influences by Mw and Mw/Mn are easily increased according to miniaturization of a pattern rule, and thus the Mw/Mn of the carboxy group-containing polymer is preferably 1.0 to 2.0 which corresponds to a narrow distribution, in order to obtain a resist composition suitably used for a fine pattern dimension.

Examples of the process for synthesizing the carboxy group-containing polymer include a process consisting steps of adding a radical polymerization initiator to a monomer imparting the repeating unit in an organic solvent and heating for polymerizing.

Specific examples of the organic solvent used in the polymerization reaction include toluene, benzene, THF, diethyl ether, dioxane, cyclohexane, cyclopentane, cyclopentanone, cyclohexanone, methyl ethyl ketone (MEK) propylene glycol monomethyl ether (PGME), propylene glycol monomethyl ether acetate (PGMEA), and γ-butyrolactone (GBL). Specific examples of the polymerization initiator include 2,2-azobisisobutyronitrile (AIBN), 2,2-azobis(2,4-dimethylvaleronitrile), dimethyl-2,2-azobis(2-methylpropionate), 1,1-azobis(1-acetoxy-1-phenylethane), benzoyl peroxide, and lauroyl peroxide. The amount of the polymerization initiator added is preferably 0.01 to 25% by mol relative to the total monomer to be polymerized. The reaction temperature is preferably 50 to 150° C., more preferably 60 to 100° C. The reaction time is preferably 2 to 24 hours, and is more preferably 2 to 12 hours from the viewpoint of production efficiency.

The polymerization initiator may be added to the monomer solution and these may be supplied to a reaction oven, or an initiator solution may be prepared separately from the monomer solution and these may be each independently supplied to a reaction oven. Since the polymerization reaction can progress due to radical generated from the initiator during a waiting time to generate an ultra-high molecular weight polymer, the monomer solution and the initiator solution are preferably each independently prepared and dropped from the viewpoint of quality control. A known chain transfer agent such as dodecylmercaptan or 2-mercaptoethanol may be used in combination for adjustment of the molecular weight. In this case, the amount of the chain transfer agent added is preferably 0.01 to 20% by mol based on the total monomer to be polymerized.

The amount of each monomer in the monomer solution may be appropriately set, for example, so that a preferred proportion of the repeating unit contained is achieved.

### (Solvent)

The resist composition contains a solvent. The solvent is not particularly limited as long as it can dissolve the hypervalent iodine compound, the carboxy group-containing compound and any other component described below and thus can form a film. Such a solvent is preferably an organic solvent, and specific examples thereof include ketones such as cyclohexanone, methyl-2-n-pentyl ketone and methyl isoamyl ketone; alcohols such as 3-methoxybutanol, 3-methyl-3-methoxybutanol, 1-methoxy-2-propanol, 1-ethoxy-2-propanol, diacetone alcohol, 4-methyl-2-pentanol and methyl 2-hydroxyisobutyrate; ethers such as propylene glycol monomethyl ether, ethylene glycol monomethyl ether, propylene glycol monoethyl ether, ethylene glycol monoethyl ether, propylene glycol dimethyl ether and diethylene glycol dimethyl ether; esters such as propylene glycol monomethyl ether acetate, propylene glycol monoethyl ether acetate, ethyl lactate, ethyl pyruvate, butyl acetate, methyl 3-methoxypropionate, ethyl 3-ethoxypropionate, tert-butyl acetate, tert-butyl propionate and propylene glycol mono-tert-butyl ether acetate; carboxylic acids such as formic acid, acetic acid and propionic acid; lactones such as γ-butyrolactone; and any mixed solvent thereof.

The content of the solvent in the resist composition is preferably an amount so that the solid content concentration in the resist composition is 0.1 to 20% by mass, more preferably an amount so that the concentration is 0.1 to 15% by mass, further preferably an amount so that the concentration is 0.1 to 10% by mass. In the present invention, the term of solid content refers to all components of the resist composition excluding the solvent. The solvent may be used singly or as a mixture of two or more kinds thereof.

### (Surfactant)

The resist composition may further contain a surfactant. The surfactant is preferably fluorine-based and/or silicone-based surfactant(s). Examples of such surfactant(s) include any surfactant described in paragraph [0276] in US 2008/0248425 A. Surfactants other than the fluorine-based and/or silicone-based surfactants described in paragraph [0280] in US 2008/0248425 A can also be further used.

When the resist composition contains the above surfactant, the content is preferably 0.0001 to 2% by mass in the total solid content. The surfactant may be used singly or in combinations of two or more kinds thereof.

(Radical scavenger)

The resist composition may further contain a radical scavenger. A radical scavenger can be added to control an optical reaction in photolithography and adjust the sensitivity.

Examples of the radical scavenger include hindered phenols, quinones, hindered amines, and a thiol compound. Specifically, examples of the hindered phenols include dibutylhydroxytoluene (BHT) and 2,2-methylenebis(4-methyl-6-tert-butylphenol). Examples of the quinones include 4-methoxyphenol (metoquinone) and hydroquinone. Examples of the hindered amines include 2,2,6,6-tetramethylpiperidine and 2,2,6,6-tetramethylpiperidine-N-oxy radical. Examples of the thiols include dodecanethiol and hexadecanethiol.

When the resist composition contains the radical scavenger, the content is preferably 0.01 to 10% by mass in the total solid content. The radical scavenger may be used singly or in combinations of two or more kinds thereof.

(Crosslinking agent)

The resist composition may further contain a crosslinking agent. A crosslinking agent can be added to promote a crosslinking reaction in photolithography and increasing the glass transition temperature of a pattern, thereby obtaining a pattern excellent in fine-line resolvability.

Examples of the crosslinking agent include a compound having a carbon-carbon unsaturated bond such as a vinyl group, a (meth)acrylate group, an allyl group, an alkynyl group, or an aromatic ring, as a functional group. Specifically, examples of the compound having a vinyl group include linear alkene, branched alkene, and cyclic alkene each optionally having a substituent. Examples of the compound having a (meth)acrylate group include acrylic acid, methacrylic acid, acrylic acid ester and methacrylic acid ester each optionally having a substituent. Examples of the compound having an allyl group include allyl alcohol, allyl ether, allyl ester, allylamide, allylamine and allyl group-containing isocyanurate each optionally having a substituent. Examples of the compound having an alkynyl group include linear alkyne, branched alkyne, cyclic alkyne, alkynyl alcohol, alkynyl ether, alkynyl ester, alkynylamide, alkynylamine and alkynyl group-containing isocyanurates each optionally having a substituent. Examples of the compound having an aromatic ring include arenes, heteroarenes, styrene, stilbene, phenylacetylene, acenaphthylene and chalcone each optionally having a substituent. The crosslinking agent may have only any one of the above functional groups, or may have a plurality thereof. The number of the above functional groups contained in the crosslinking agent is preferably 1 or more and 10 or less, more preferably 2 or more and 8 or less.

When the resist composition contains the crosslinking agent, the content is preferably 0.01 to 50% by mass in the total solid content. The crosslinking agent may be used singly or in combinations of two or more kinds thereof.

(Photopolymerization initiator)

The resist composition, when contains the crosslinking agent, may further contain a photopolymerization initiator. A photopolymerization initiator can generate a radical by irradiation with a high energy line, thereby promoting crosslinking of the crosslinking agent.

Specific examples of the photopolymerization initiator include benzophenone derivatives such as benzophenone, methyl 0-benzoylbenzoate, 4-benzoyl-4-methyl diphenyl ketone, dibenzyl ketone and fluorenone; acetophenone derivatives such as 2,2-diethoxyacetophenone, 2-hydroxy-2-methylpropiophenone, 2,2-dimethoxy-1,2-diphenylethan-1-one, 1-hydroxycyclohexylphenyl ketone, 2-methyl-1-[4-(methylthio)phenyl]-2-morpholinopropan-1-one, 2-hydroxy-1-{4-[4-(2-hydroxy-2-methylpropionyl)-benzyl]-phenyl}-2-methylpropan-1-one and methyl phenylglyoxylate; thioxanthone derivatives such as thioxanthone, 2-methylthioxanthone, 2-isopropylthioxanthone, 4-isopropylthioxanthone, 2-chlorothioxanthone and diethylthioxanthone; benzil derivatives such as benzil, benzil dimethyl ketal and benzil-β-methoxyethylacetal; benzoin derivatives such as benzoin, benzoin methyl ether and 2-hydroxy-2-methyl-1-phenylpropan-1-one; oxime-based compounds such as 1-phenyl-1,2-butanedione-2-(O-methoxycarbonyl)oxime, 1-phenyl-1,2-propanedione-2-(O-methoxycarbonyl)oxime, 1-phenyl-1,2-propanedione-2-(O-ethoxycarbonyl)oxime, 1-phenyl-1,2-propanedione-2-(O-benzoyl)oxime, 1,3-diphenylpropanetrione-2-(O-ethoxycarbonyl)oxime, 1-phenyl-3-ethoxypropanetrione-2-(O-benzoyl)oxime 1,2-octanedione, 1-[4-(phenylthio)-2-(O-benzoyl oxime)]ethanone and 1-[9-ethyl-6-(2-methylbenzoyl)-9H-carbazol-3-yl]-1-(O-acetyloxime); α-hydroxyketone-based compounds such as 2-hydroxy-2-methyl-1-phenylpropan-1-one, 1-[4-(2-hydroxyethoxy)phenyl]-2-hydroxy-2-methyl-1-propan-1-one and 2-hydroxy-1-{4-[4-(2-hydroxy-2-methylpropionyl)-benzyl]phenyl}-2-methylpropane; α-aminoalkylphenone-based compounds such as 2-benzyl-2-dimethylamino-1-(4-morpholinophenyl)-butanone-1 and 2-dimethylamino-2-(4-methylbenzyl)-1-(4-morpholin-4-yl-phenyl)butan-1-one; phosphine oxide-based compounds such as bis(2,4,6-trimethylbenzoyl)-phenylphosphine oxide, bis(2,6-dimethoxybenzoyl)-2,4,4-trimethyl-pentylphosphine oxide and 2,4,6-trimethylbenzoyldiphenylphosphine oxide; and titanocene compounds such as bis(η5-2,4-cyclopentadien-1-yl)-bis(2,6-difluoro-3-(1H-pyrrol-1-yl)phenyl)titanium.

When the resist composition contains the photopolymerization initiator, the content is preferably 0.1 to 10% by mass, more preferably 0.1 to 5% by mass, most preferably 0.1 to 1% by mass in the total solid content. A content of 0.1% by mass or more allows the compounding effect to be sufficiently obtained.

The resist composition contains the hypervalent iodine compound and the carboxy group-containing compound as main components as described above, but does not contain any acid-labile group-containing polymer and photo-acid generator contained in a conventional chemically amplified resist composition. However, the resist composition of the present invention can form a positive type pattern whose exposed section is made soluble in a developer particularly by EB or EUV exposure. The mechanism, although not completely clear, is presumed as follows, for example.

The hypervalent iodine compound represented by the formula (7), (8) or (9) is a three-coordinate compound having an aryl group and a carboxylate ligand. It is considered that such a three-coordinate iodine compound is mixed with the carboxy group-containing compound to result in exchange of a carboxylate ligand in an equilibrium reaction. If the original carboxylate ligand can be here removed by any process, a hypervalent iodine compound having a new ligand is generated. For example, if acetic acid having a low boiling point generated by mixing 1-iodonaphthylene diacetate as the hypervalent iodine compound and the carboxy group-containing compound is removed, ligand exchange is completed. Here, a polymer is provided in which the carboxy group-containing compound is crosslinked by the hypervalent iodine compound.

The polymer crosslinked with the hypervalent iodine compound is generated during film formation. The reason is that such a crosslinked polymer, even if synthesized in advance, is not dissolved in most organic solvents and therefore a solution cannot be prepared. It is presumed that this is caused, because the hypervalent iodine compound which is originally polarized and therefore is low in solvent solubility much further deteriorates in solubility due to use of the carboxy group-containing compound as a ligand. It is here desirable to provide a step of removing the original low-molecular-weight carboxylic acid component in film formation and in a subsequent baking step, thereby not only completing a ligand exchange reaction, but also forming a resist film.

A resist film obtained from the resist composition is changed in polarity due to decomposition of the hypervalent iodine compound as a main component by light, and a pattern is formed in a development step. The mechanism, although not completely clear, is presumed as follows, for example.

The resist film obtained from the resist composition contains a polymer in which the hypervalent iodine compound is bound during film formation. However, this compound is decomposed by light and formed into a monovalent iodine compound, and at the same time the binding between the carboxy group-containing compound and the hypervalent iodine compound is released and the molecular weight is also decreased. As a result, a positive type pattern in which an exposed section is removed by an organic solvent is formed.

It can be said from the above presumptions that the resist composition is a non-chemically amplified resist composition. The resist composition does not require any acid-labile group-containing polymer and photo-acid generator unlike a conventional chemically amplified resist composition. Therefore, an adverse effect due to acid diffusion (for example, image blurs) is not caused and a fine pattern can be resolved.

The resist composition is extremely effective particularly for EUV lithography. The reason for this is that the composition has an iodine atom with high absorbability of EUV light. In other words, shot noise can be reduced and higher resolvability and lower LWR can be achieved.

As an EUV resist composition capable of forming a fine pattern, a metal resist is proposed, it contains as a main component, a compound of tin as a metal having high ability to absorb EUV light as in an iodine atom (for example, Patent Document 2). However, as described above, such a metal resist has many problems, for example, insufficient solubility in a solvent, storage stability, and defects by the residue after etching due to inclusion of a metal element. In this regard, the resist composition of the present invention, in which no metal element is used, thus is more advantageous than a metal resist in terms of defects, and does not have the problem about solubility in a solvent. Furthermore, the resist composition of the present invention can be applied to a positive type, and therefore can be widely used in a variety of applications. For example, a metal resist adopted in negative type development in a contact hole forming step requires a reverse process step after pillar patterning, but such a reverse process step is not necessary about a positive type. Accordingly, it can be said that the resist composition of the present invention is more useful than a metal resist also from the viewpoint of process simplicity.

The thickness of the resist film is preferably 10 to 70 nm, more preferably 20 to 50 nm.

[Resist underlayer film]

The laminate of the present invention is provided as a laminate including a resist underlayer film between the substrate and the silicon-containing resist underlayer film.

The resist underlayer film used here can be a known film used in a fine patterning process in a multilayer resist process. Specific examples of the resist underlayer film include Spin-on Carbon ODL-301 (carbon content 88% by mass) manufactured by Shin-Etsu Chemical Co., Ltd.

The thickness of the resist underlayer film is preferably 40 to 200 nm, more preferably 40 to 150 nm.

The resist underlayer film is preferably a resist underlayer film obtained with a solution-type composition for resist underlayer film formation, or a resist underlayer film formed by a CVD process or an ALD process.

[Process for manufacturing laminate]

The present invention provides the following process for manufacturing a laminate.

A process for manufacturing a laminate, including the steps of:
forming a resist underlayer film on a substrate;
forming a silicon-containing resist underlayer film from a silicon-containing resist underlayer film composition that contains a thermally crosslinkable polysiloxane containing any one or more from the repeating units represented by the general formulae (1) to (3) and any one or more from the repeating units represented by the general formulae (4) to (6), on the resist underlayer film; and
applying a resist composition containing at least one hypervalent iodine compound selected from the hypervalent iodine compound represented by the formula (7) above, the hypervalent iodine compound represented by the formula (8) above and the hypervalent iodine compound represented by the formula (9) above, a carboxy group-containing compound, and a solvent, to the silicon-containing resist underlayer film, and performing a heating treatment, to form a resist film.

The process for manufacturing a laminate of the present invention, used in a two-layer resist process, includes a step of applying the silicon-containing resist underlayer film composition, to a substrate, and performing a heating treatment, to form an adhesion film, and a step of applying the resist composition to the silicon-containing resist underlayer film, and performing a heating treatment, to form a resist film.

The present invention provides the process for manufacturing a laminate, wherein the resist underlayer film is formed by applying an underlayer film-forming material to the substrate and performing a heating treatment.

Examples of the process for forming the silicon-containing resist underlayer film include a process including applying the silicon-containing resist underlayer film composition, to a substrate, by a spin coating process or the like, evaporating the solvent, and performing baking for promotion of a crosslinking reaction. The baking temperature is preferably 100 to 400° C., more preferably 150 to 300° C. The baking time is preferably 10 to 600 seconds, more preferably 10 to 300 seconds.

The silicon-containing resist underlayer film can also be formed by applying the silicon-containing resist underlayer film composition, to a substrate, by a spin coating process or the like in the same manner as described above, and baking and curing the silicon-containing resist underlayer film composition in an atmosphere at an oxygen concentration of 0.1 to 21%. The silicon-containing resist underlayer film composition can be thus baked in such an oxygen atmosphere, thereby obtaining a sufficiently cured film. The baking temperature and time can be here the same as described above.

The atmosphere during baking may be an atmosphere in which not only air, but also any inert gas such as N₂, Ar, or He is inserted. Here, an atmosphere can be adopted in which the oxygen concentration is less than 0.1%. The baking temperature and time can be here the same as described above. Even in the case of a substrate containing a material unstable to heating under an oxygen atmosphere, a crosslinking reaction during silicon-containing resist underlayer film formation can be promoted without the occurrence of degradation of such a substrate.

The resist film can be formed by application to the silicon-containing resist underlayer film by an appropriate application process such as spin coating, roll coating, flow coating, dip coating, spray coating, or doctor coating, and pre-baking on a hot plate preferably at 60 to 200° C. for 10 seconds to 30 minutes, more preferably at 80 to 180° C. for 30 seconds to 20 minutes.

The process for manufacturing a laminate of the present invention, used in a three-layer resist process, includes a step of applying a resist underlayer film-forming material to a substrate, and performing a heating treatment, to form a resist underlayer film, a step of applying the silicon-containing resist underlayer film composition to the resist underlayer film, and performing a heating treatment, to form a silicon-containing resist underlayer film, and a step of applying the resist composition to the silicon-containing resist underlayer film, and performing a heating treatment, to form a resist film.

Examples of the process for forming the resist underlayer film include a process including applying the composition for resist underlayer film formation, to a substrate, by a spin coating process or the like, evaporating the solvent, and performing baking. The baking temperature may be appropriately set depending on the type of the resist underlayer film to be formed, and is usually about 100 to 400° C. and is preferably about 150 to 300° C. The baking time may be appropriately set depending on the type of the resist underlayer film to be formed, and is usually about 10 to 600 seconds and is preferably about 10 to 300 seconds.

The resist underlayer film is preferably formed by a CVD process or an ALD process.

In the three-layer resist process, the silicon-containing resist underlayer film can be formed by applying the silicon-containing resist underlayer film composition, to the resist underlayer film, by a spin coating process or the like, evaporating the solvent, and performing baking for promotion of a crosslinking reaction. The baking time and temperature are here the same as the time and temperature in the process for forming the silicon-containing resist underlayer film in the two-layer resist process.

In the three-layer resist process, the resist film can be formed by the same process as the process for forming the resist film in the two-layer resist process.

[Patterning process]

The present invention provides a patterning process including the steps of: exposing the resist film of the laminate, to an i-line, a KrF excimer laser, an ArF excimer laser, an electron beam or an extreme-ultraviolet ray; and developing the exposed resist film with a developer.

In the case of exposure with an i-line, a KrF excimer laser light, an ArF excimer laser light or EUV, irradiation is performed directly or with a mask for formation of an objective pattern so that the amount of exposure is preferably about 1 to 300 mJ/cm², more preferably about 10 to 200 mJ/cm². In the case of exposure with EB, lithography is performed directly or with a mask for formation of an objective pattern so that the amount of exposure is preferably about 0.1 to 8000 μC/cm², more preferably about 0.5 to 5000 μC/cm². The patterning process of the present invention is suitable particularly for fine patterning with EB or EUV among high energy lines.

After exposure, PEB is, if necessary, performed. It is here preferable to perform PEB on a hot plate or in an oven in conditions of 30 to 200° C. for 10 seconds to 30 minutes, more preferably of 60 to 120° C. for 30 seconds to 20 minutes, after exposure.

After exposure or after PEB, patterning is performed, if necessary, by development with a developer.

The developer used here is preferably an organic solvent.

After exposure or after PEB, patterning is performed, if necessary, by development with a developer. Examples of the developer used here include organic solvents such as 2-octanone, 2-nonanone, 2-heptanone, 3-heptanone, 4-heptanone, 2-hexanone, 3-hexanone, diisobutyl ketone, 5-methyl-2-hexanone, methylcyclohexanone, acetophenone, methylacetophenone, isopropyl alcohol, isoamyl alcohol, n-butanol, tert-butyl alcohol, tert-pentyl alcohol, n-pentanol, cyclohexanol, formic acid, acetic acid, propionic acid, propyl acetate, butyl acetate, isobutyl acetate, pentyl acetate, butenyl acetate, isopentyl acetate, cyclohexyl acetate, 4-tert-butylcyclohexyl acetate, octyl acetate, isobornyl acetate, propyl formate, butyl formate, isobutyl formate, pentyl formate, isopentyl formate, methyl valerate, methyl pentenoate, methyl crotonate, ethyl crotonate, methyl propionate, ethyl propionate, ethyl 3-ethoxypropionate, methyl lactate, ethyl lactate, propyl lactate, butyl lactate, isobutyl lactate, pentyl lactate, isopentyl lactate, methyl 2-hydroxyisobutyrate, ethyl 2-hydroxyisobutyrate, methyl benzoate, ethyl benzoate, phenyl acetate, benzyl acetate, methyl phenylacetate, ethyl phenylacetate, benzyl formate, phenylethyl formate, 3-methyl phenylpropionate, benzyl propionate, 2-phenylethyl acetate, 2-propanol, 3-methoxybutanol, 3-methyl-3-methoxybutanol, 1-methoxy-2-propanol, 1-ethoxy-2-propanol, 3-methyl-1-butanol, diacetone alcohol, 4-methyl-2-pentanol, 3-methylcyclohexanol, 3,5,5-trimethylhexyl alcohol, 2,6-dimethyl-4-heptanol, toluene, anisole and ε-caprolactone. Such a developer may be used singly or as a mixture of two or more kinds thereof.

After development, rinse is, if necessary, performed. A rinse liquid is preferably a solvent which is mixed with a developer to dissolve the developer and not to dissolve the resist film. As such a solvent, an alcohol having 3 to 10 carbon atoms, an ether compound having 8 to 12 carbon atoms, or an alkane, alkene, alkyne or aromatic solvent having 6 to 12 carbon atoms is preferably used.

Such rinse can be performed to reduce the occurrence of collapse and/or defects of a resist pattern. Such rinse is not necessarily essential, and the amount of a solvent used can be reduced by not performing such rinse.

### EXAMPLES

Hereinafter, the present invention is specifically described with reference to Synthesis Examples, Comparative Synthesis Examples, Preparation Examples, Examples and Comparative Examples, but the present invention is not limited to the following Examples. Here, measurement of the molecular weight was carried out by gel permeation chromatography (GPC) with tetrahydrofuran (THF) or N,N-dimethylformamide (DMF) as an eluent, the weight average molecular weight (Mw) and the number average molecular weight (Mn) in terms of polystyrene were determined, and the dispersity (Mw/Mn) was determined therefrom.

[1] Synthesis of polymer for silicon-containing resist underlayer film composition

### Synthesis Example 1-1

A mixture of 30.6 g of compound (101), 11.4 g of compound (102), and 4.3 g of compound (103) (molar ratio: 67/28/5) was added to a mixture of 75 g of deionized water and 0.5 g of 7% nitric acid, and retained at 25° C. for 24 hours, to perform hydrolytic condensation. After the completion of reaction, 450 g of propylene glycol monoethyl ether (PGEE) and 1.1 g of an aqueous 24% maleic acid solution were added, and the water content subjected to hydrolytic condensation and an alcohol as a by-product were distilled off under reduced pressure, thereby obtaining 240 g of a PGEE solution of polysiloxane compound 1 (compound concentration 10%). The molecular weight in terms of polystyrene of polysiloxane compound 1 was measured, and thus the Mw was 2,750.

### Synthesis Example 1-2

A mixture of 30.6 g of compound (101), 9.4 g of compound (102), and 8.5 g of compound (103) (molar ratio: 67/23/10) was added to a mixture of 75 g of deionized water and 0.5 g of 7% nitric acid, and retained at 25° C. for 24 hours, to perform hydrolytic condensation. After the completion of reaction, 450 g of propylene glycol monoethyl ether (PGEE) and 1.1 g of an aqueous 24% maleic acid solution were added, and the water content subjected to hydrolytic condensation and an alcohol as a by-product were distilled off under reduced pressure, thereby obtaining 270 g of a PGEE solution of polysiloxane compound 2 (compound concentration 10%). The molecular weight in terms of polystyrene of polysiloxane compound 2 was measured, and thus the Mw was 2,650.

### Synthesis Example 1-3

A mixture of 30.6 g of compound (101), 5.3 g of compound (102), and 17.1 g of compound (103) (molar ratio: 67/13/20) was added to a mixture of 75 g of deionized water and 0.5 g of 7% nitric acid, and retained at 25° C. for 24 hours, to perform hydrolytic condensation. After the completion of reaction, 450 g of propylene glycol monoethyl ether (PGEE) and 1.4 g of an aqueous 24% maleic acid solution were added, and the water content subjected to hydrolytic condensation and an alcohol as a by-product were distilled off under reduced pressure, thereby obtaining 280 g of a PGEE solution of polysiloxane compound 3 (compound concentration 10%). The molecular weight in terms of polystyrene of polysiloxane compound 3 was measured, and thus the Mw was 2,700.

### Synthesis Example 1-4

A mixture of 30.6 g of compound (101), 1.2 g of compound (102), and 25.6 g of compound (103) (molar ratio: 67/3/30) was added to a mixture of 75 g of deionized water and 0.5 g of 7% nitric acid, and retained at 25° C. for 24 hours, to perform hydrolytic condensation. After the completion of reaction, 450 g of propylene glycol monoethyl ether (PGEE) and 1.6 g of an aqueous 24% maleic acid solution were added, and the water content subjected to hydrolytic condensation and an alcohol as a by-product were distilled off under reduced pressure, thereby obtaining 280 g of a PGEE solution of polysiloxane compound 4 (compound concentration 10%). The molecular weight in terms of polystyrene of polysiloxane compound 4 was measured, and thus the Mw was 2,700.

### Synthesis Example 1-5

A mixture of 22.8 g of compound (101) and 42.7 g of compound (103) (molar ratio: 50/50) was added to a mixture of 75 g of deionized water and 0.5 g of 7% nitric acid, and retained at 25° C. for 24 hours, to perform hydrolytic condensation. After the completion of reaction, 450 g of propylene glycol monoethyl ether (PGEE) and 2.0 g of an aqueous 24% maleic acid solution were added, and the water content subjected to hydrolytic condensation and an alcohol as a by-product were distilled off under reduced pressure, thereby obtaining 300 g of a PGEE solution of polysiloxane compound 5 (compound concentration 10%). The molecular weight in terms of polystyrene of polysiloxane compound 5 was measured, and thus the Mw was 2,650.

### Synthesis Example 1-6

A mixture of 30.6 g of compound (101), 9.4 g of compound (102), and 9.1 g of compound (104) (molar ratio: 67/23/10) was added to a mixture of 75 g of deionized water and 0.5 g of 7% nitric acid, and retained at 25° C. for 24 hours, to perform hydrolytic condensation. After the completion of reaction, 450 g of propylene glycol monoethyl ether (PGEE) and 1.2 g of an aqueous 24% maleic acid solution were added, and the water content subjected to hydrolytic condensation and an alcohol as a by-product were distilled off under reduced pressure, thereby obtaining 240 g of a PGEE solution of polysiloxane compound 6 (compound concentration 10%). The molecular weight in terms of polystyrene of polysiloxane compound 6 was measured, and thus the Mw was 2,650.

### Synthesis Example 1-7

A mixture of 30.6 g of compound (101), 9.4 g of compound (102), and 9.8 g of compound (105) (molar ratio: 67/23/10) was added to a mixture of 75 g of deionized water and 0.5 g of 7% nitric acid, and retained at 25° C. for 24 hours, to perform hydrolytic condensation. After the completion of reaction, 450 g of propylene glycol monoethyl ether (PGEE) and 1.2 g of an aqueous 24% maleic acid solution were added, and the water content subjected to hydrolytic condensation and an alcohol as a by-product were distilled off under reduced pressure, thereby obtaining 250 g of a PGEE solution of polysiloxane compound 7 (compound concentration 10%). The molecular weight in terms of polystyrene of polysiloxane compound 7 was measured, and thus the Mw was 2,700.

### Synthesis Example 1-8

A mixture of 30.6 g of compound (101), 9.4 g of compound (102), and 9.8 g of compound (106) (molar ratio: 67/23/10) was added to a mixture of 75 g of deionized water and 0.5 g of 7% nitric acid, and retained at 25° C. for 24 hours, to perform hydrolytic condensation. After the completion of reaction, 450 g of propylene glycol monoethyl ether (PGEE) and 1.2 g of an aqueous 24% maleic acid solution were added, and the water content subjected to hydrolytic condensation and an alcohol as a by-product were distilled off under reduced pressure, thereby obtaining 255 g of a PGEE solution of polysiloxane compound 8 (compound concentration 10%). The molecular weight in terms of polystyrene of polysiloxane compound 8 was measured, and thus the Mw was 2,730.

### Synthesis Example 1-9

A mixture of 30.6 g of compound (101), 9.4 g of compound (102), and 6.3 g of compound (107) (molar ratio: 67/23/10) was added to a mixture of 75 g of deionized water and 0.5 g of 7% nitric acid, and retained at 25° C. for 24 hours, to perform hydrolytic condensation. After the completion of reaction, 450 g of propylene glycol monoethyl ether (PGEE) and 1.0 g of an aqueous 24% maleic acid solution were added, and the water content subjected to hydrolytic condensation and an alcohol as a by-product were distilled off under reduced pressure, thereby obtaining 220 g of a PGEE solution of polysiloxane compound 9 (compound concentration 10%). The molecular weight in terms of polystyrene of polysiloxane compound 9 was measured, and thus the Mw was 2,550.

### Synthesis Example 1-10

A mixture of 30.6 g of compound (101), 9.4 g of compound (102), and 6.9 g of compound (108) (molar ratio: 67/23/10) was added to a mixture of 75 g of deionized water and 0.5 g of 7% nitric acid, and retained at 25° C. for 24 hours, to perform hydrolytic condensation. After the completion of reaction, 450 g of propylene glycol monoethyl ether (PGEE) and 1.1 g of an aqueous 24% maleic acid solution were added, and the water content subjected to hydrolytic condensation and an alcohol as a by-product were distilled off under reduced pressure, thereby obtaining 255 g of a PGEE solution of polysiloxane compound 10 (compound concentration 10%). The molecular weight in terms of polystyrene of polysiloxane compound 10 was measured, and thus the Mw was 3,600.

### Synthesis Example 1-11

A mixture of 30.6 g of compound (101), 5.3 g of compound (102), and 13.8 g of compound (108) (molar ratio: 67/13/20) was added to a mixture of 75 g of deionized water and 0.5 g of 7% nitric acid, and retained at 25° C. for 24 hours, to perform hydrolytic condensation. After the completion of reaction, 450 g of propylene glycol monoethyl ether (PGEE) and 1.1 g of an aqueous 24% maleic acid solution were added, and the water content subjected to hydrolytic condensation and an alcohol as a by-product were distilled off under reduced pressure, thereby obtaining 270 g of a PGEE solution of polysiloxane compound 11 (compound concentration 10%). The molecular weight in terms of polystyrene of polysiloxane compound 11 was measured, and thus the Mw was 3,600.

### Synthesis Example 1-12

A mixture of 30.6 g of compound (101), 1.2 g of compound (102), and 20.7 g of compound (108) (molar ratio: 67/3/30) was added to a mixture of 75 g of deionized water and 0.5 g of 7% nitric acid, and retained at 25° C. for 24 hours, to perform hydrolytic condensation. After the completion of reaction, 450 g of propylene glycol monoethyl ether (PGEE) and 1.2 g of an aqueous 24% maleic acid solution were added, and the water content subjected to hydrolytic condensation and an alcohol as a by-product were distilled off under reduced pressure, thereby obtaining 310 g of a PGEE solution of polysiloxane compound 12 (compound concentration 10%). The molecular weight in terms of polystyrene of polysiloxane compound 12 was measured, and thus the Mw was 7,000.

### Comparative Synthesis Example 1-13

A mixture of 30.6 g of compound (101), 9.4 g of compound (102), and 5.9 g of compound (109) (molar ratio: 67/23/10) was added to a mixture of 75 g of deionized water and 0.5 g of 7% nitric acid, and retained at 25° C. for 24 hours, to perform hydrolytic condensation. After the completion of reaction, 450 g of propylene glycol monoethyl ether (PGEE) and 1.0 g of an aqueous 24% maleic acid solution were added, and the water content subjected to hydrolytic condensation and an alcohol as a by-product were distilled off under reduced pressure, thereby obtaining 210 g of a PGEE solution of polysiloxane compound 13 (compound concentration 10%). The molecular weight in terms of polystyrene of polysiloxane compound 13 was measured, and thus the Mw was 2,600.

Respective objective products were obtained as polysiloxane compounds 1 to 13 according to processes of [Synthesis Example 1-1] to [Synthesis Example 1-12], and [Comparative Synthesis Example 1-13] in which monomers shown in Table 1 were used.

TABLE 1

| | Amount of each monomer loaded (% by mol) | | | | | | | | | |
|---|---|---|---|---|---|---|---|---|---|---|
| | 101 | 102 | 103 | 104 | 105 | 106 | 107 | 108 | 109 | Mw |
| Compound 1 | 67 | 28 | 5 | — | — | — | — | — | — | 2750 |
| Compound 2 | 67 | 23 | 10 | — | — | — | — | — | — | 2650 |
| Compound 3 | 67 | 13 | 20 | — | — | — | — | — | — | 2700 |
| Compound 4 | 67 | 3 | 30 | — | — | — | — | — | — | 2700 |
| Compound 5 | 50 | — | 50 | — | — | — | — | — | — | 2650 |
| Compound 6 | 67 | 23 | — | 10 | — | — | — | — | — | 2650 |
| Compound 7 | 67 | 23 | — | — | 10 | — | — | — | — | 2700 |
| Compound 8 | 67 | 23 | — | — | — | 10 | — | — | — | 2730 |
| Compound 9 | 67 | 23 | — | — | — | — | 10 | — | — | 2550 |
| Compound 10 | 67 | 23 | — | — | — | — | — | 10 | — | 3600 |
| Compound 11 | 67 | 13 | — | — | — | — | — | 20 | — | 3600 |
| Compound 12 | 67 | 3 | — | — | — | — | — | 30 | — | 7000 |
| Compound 13 | 67 | 23 | — | — | — | — | — | — | 10 | 2600 |

Si(OMe)₄
Compound 101 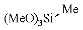
Compound 102 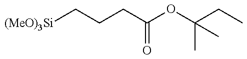
Compound 103 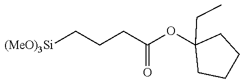
Compound 104 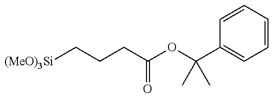
Compound 105 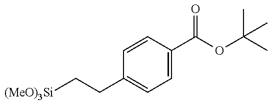
Compound 106 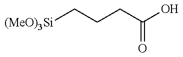
Compound 107 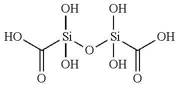 [SMILES: O=C(O)[Si](O)(O)O[Si](O)(O)C(=O)O]
Compound 108 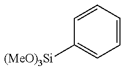
Compound 109

[2] Preparation of silicon-containing resist underlayer film composition

Each of polysiloxane compounds 1 to 13 obtained in Synthesis Examples 1-1 to 1-13 described above, a crosslinking catalyst, an acid, a solvent, and water were mixed at proportions shown in Table 2, and filtrated by a 0.1-μm fluororesin filter, thereby preparing each polysiloxane underlayer film composition solution, and such solutions were respectively defined as Sols. 1 to 13.

TABLE 2

| | | Crosslinking | | | |
|---|---|---|---|---|---|
| | Polysiloxane | catalyst | Acid | Solvent | Water |
| | (parts | (parts | (parts | (parts | (parts |
| | by mass) | by mass) | by mass) | by mass) | by mass) |
| Sol. | Compound | QBANO3 | Maleic acid | PGEE | Water |
| 1 | 1(1) | (0.03) | (0.01) | (100) | (10) |
| Sol. | Compound | QBANO3 | Maleic acid | PGEE | Water |
| 2 | 2(1) | (0.03) | (0.01) | (100) | (10) |
| Sol. | Compound | QBANO3 | Maleic acid | PGEE | Water |
| 3 | 3(1) | (0.03) | (0.01) | (100) | (10) |
| Sol. | Compound | QBANO3 | Maleic acid | PGEE | Water |
| 4 | 4(1) | (0.03) | (0.01) | (100) | (10) |
| Sol. | Compound | QBANO3 | Maleic acid | PGEE | Water |
| 5 | 5(1) | (0.03) | (0.01) | (100) | (10 |
| Sol. | Compound | TPSNO3 | Maleic acid | PGEE | Water |
| 6 | 6(1) | (0.03) | (0.01) | (100) | (10) |
| Sol. | Compound | TPSNO3 | Maleic acid | PGEE | Water |
| 7 | 7(1) | (0.03) | (0.01) | (100) | (10) |
| Sol. | Compound | TPSNO3 | Maleic acid | PGEE | Water |
| 8 | 8(1) | (0.03) | (0.01) | (100) | (10) |
| Sol. | Compound | TPSNO3 | Maleic acid | PGEE | Water |
| 9 | 9(1) | (0.03) | (0.01) | (100) | (10 |
| Sol. | Compound | QBANO3 | Maleic acid | PGEE | Water |
| 10 | 10(1) | (0.03) | (0.01) | (100) | (10) |
| Sol. | Compound | QBANO3 | Maleic acid | PGEE | Water |
| 11 | 11(1) | (0.03) | (0.01) | (100) | (10) |
| Sol. | Compound | QBANO3 | Maleic acid | PGEE | Water |
| 12 | 12(1) | (0.03) | (0.01) | (100) | (10) |
| Sol. | Compound | QBANO3 | Maleic acid | PGEE | Water |
| 13 | 13(1) | (0.03) | (0.01) | (100) | (10) |

TPSNO₃: triphenylsulfonium nitrate
QBANO₃: tetrabutylammonium nitrate
PGEE: propylene glycol monoethyl ether

[3] Synthesis of polymer for resist composition

Compounds shown below were used for synthesis of polymers P-1 to P-5 for resist compositions.

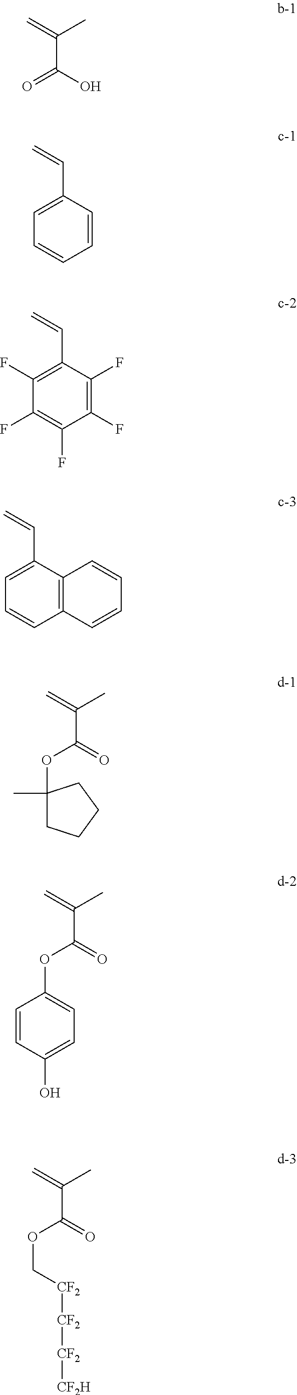

### [Synthesis Example 2-1] Synthesis of Polymer P-1

Under a nitrogen atmosphere, monomer b-1 (56 g), monomer c-1 (36 g), 5.4 g of V-601 (manufactured by FUJIFILM Wako Pure Chemical Corporation) and 180 g of MEK were taken in a flask, to prepare a monomer-polymerization initiator solution. After 55 g of MEK was taken in another flask whose atmosphere was a nitrogen atmosphere, and heated to 80° C. with stirring, the monomer-polymerization initiator solution was dropped over 4 hours. After the completion of dropping, the polymerization liquid was continuously stirred for 2 hours with the temperature thereof being kept at 80° C., and then cooled to room temperature. The resulting polymerization liquid was dropped to 4000 g of hexane vigorously stirred, and a polymer precipitated was separated by filtration. The resulting polymer was washed with hexane (1200 g) twice, and thereafter dried in vacuum at 50° C. for 20 hours, thereby obtaining polymer P-1 as a white powder (yield: 90 g, yield percentage: 98%). The Mw and the Mw/Mn of polymer P-1 were respectively 8000 and 1.42. Herein, the Mw is a value measured in terms of polystyrene by GPC with THF as a solvent.

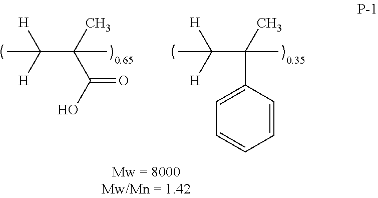

### [Synthesis Examples 2-2 to 2-5] Synthesis of Polymers P-2 to P-5

Each polymer shown in Table 3 was synthesized by the same process as in Synthesis Example 2-1 except that the types of monomers and the compounding ratio thereof were changed.

TABLE 3

| | | Introduction | | Introduction | | |
|---|---|---|---|---|---|---|
| | | ratio | | ratio | | |
| Polymer | Unit 1 | (% by mol) | Unit 2 | (% by mol) | Mw | Mw/Mn |
| P-1 | b-1 | 65 | c-1 | 35 | 8000 | 1.42 |
| P-2 | b-1 | 50 | c-2 | 50 | 8400 | 1.51 |
| P-3 | b-1 | 60 | c-3 | 40 | 8100 | 1.42 |
| P-4 | b-1 | 60 | d-3 | 40 | 8100 | 1.42 |
| P-5 | d-1 | 65 | d-2 | 35 | 8000 | 1.44 |

[4] Preparation of resist composition

### Preparation Examples 2-1 to 2-10 and Comparative Preparation Examples 1-1 to 1-2

Resist compositions (R-01 to R-10) were each prepared by dissolving the hypervalent iodine compound and the carboxy group-containing compound in a solvent containing a 0.01% by mass of surfactant (PF-636, manufactured by OMNOVA Solutions Inc.) at a compositional ratio shown in Table 4, and filtrating the resulting solution with a 0.2-μm Teflon (registered trademark) filter. Resist compositions (CR-01 and CR-02) were each prepared by dissolving a polymer, a photo-acid generator and a sensitivity modifier in a solvent containing a 0.01% by mass surfactant (PF-636, manufactured by OMNOVA Solutions Inc.) at a compositional ratio shown in Table 5, and filtrating the resulting solution with a 0.2-μm Teflon (registered trademark) filter.

TABLE 4

| | | Hypervalent | Hypervalent | Carboxy group- | | |
|---|---|---|---|---|---|---|
| | | iodine | iodine | containing | | |
| | | compound 1 | compound 2 | compound | Solvent 1 | Solvent 2 |
| | Resist | (parts | (parts | (parts | (parts | (parts |
| | composition | by mass) | by mass) | by mass) | by mass) | by mass) |
| Preparation | R-01 | I-1 | — | P-1 | PGMEA | AcOH |
| Example 2-1 | | (12) | | (9) | (800) | (200) |
| Preparation | R-02 | I-2 | — | P-1 | PGMEA | AcOH |
| Example 2-2 | | (10) | | (9) | (800) | (200) |
| Preparation | R-03 | I-3 | — | P-1 | PGMEA | AcOH |
| Example 2-3 | | (10) | | (9) | (800) | (200) |
| Preparation | R-04 | I-1 | I-2 | P-1 | PGMEA | AcOH |
| Example 2-4 | | (6) | (5) | (9) | (800) | (200) |
| Preparation | R-05 | I-1 | — | P-2 | PGMEA | AcOH |
| Example 2-5 | | (12) | | (17) | (800) | (200) |
| Preparation | R-06 | I-1 | — | P-3 | PGMEA | AcOH |
| Example 2-6 | | (12) | | (11) | (800) | (200) |
| Preparation | R-07 | I-1 | — | P-4 | PGMEA | AcOH |
| Example 2-7 | | (12) | | (17) | (800) | (200) |
| Preparation | R-08 | I-1 | — | m-1 | PGMEA | AcOH |
| Example 2-8 | | (12) | | (7) | (800) | (200) |
| Preparation | R-09 | I-1 | — | m-2 | PGMEA | AcOH |
| Example 2-9 | | (12) | | (4) | (800) | (200) |
| Preparation | R-10 | I-1 | — | m-3 | PGMEA | AcOH |
| Example 2-10 | | (12) | | (7) | (800) | (200) |

TABLE 5

| | | | Photo-acid | Sensitivity | | |
|---|---|---|---|---|---|---|
| | | Polymer | generator | modifier | Solvent 1 | Solvent 2 |
| | Resist | (parts | (parts | (parts | (parts | (parts |
| | composition | by mass) | by mass) | by mass) | by mass) | by mass) |
| Comparative | CR-01 | P-5 | PAG-1 | Q-1 | PGMEA | GBL |
| Preparation | | (80) | (19) | (6) | (1890) | (210) |
| Example 1-1 | | | | | | |
| Comparative | CR-02 | P-5 | PAG-1 | I-1 | PGMEA | GBL |
| Preparation | | (80) | (19) | (5) | (1890) | (210) |
| Example 1-2 | | | | | | |

In Tables 4 and 5, hypervalent iodine compounds I-1 to I-3, carboxy group-containing compounds m-1 to m-3, photo-acid generators PAG-1, sensitivity modifiers Q-1 and solvents are as follows.

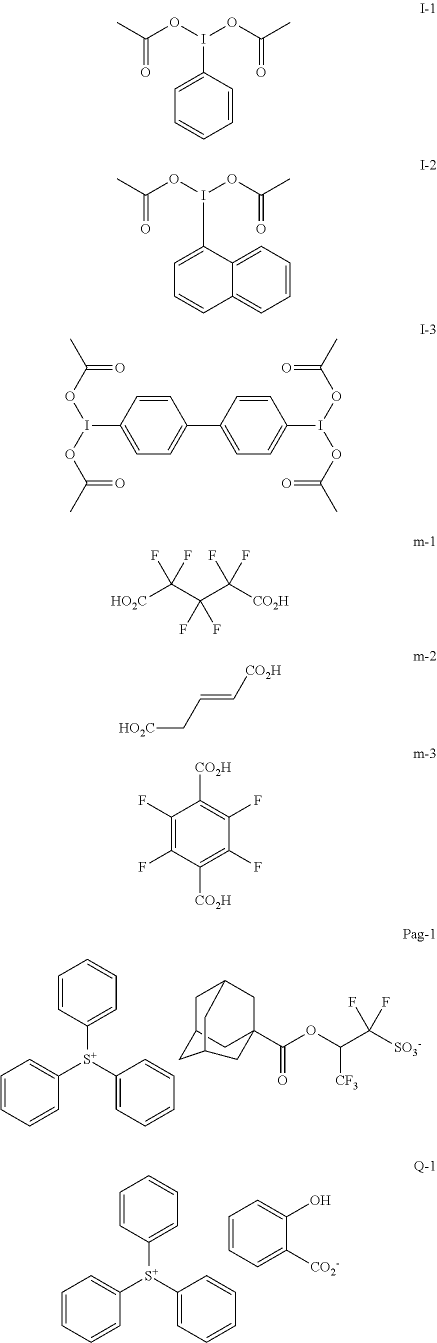

Solvent: AcOH (acetic acid)
GBL (γ-butyrolactone)
   [5] Manufacturing of laminate and EUV lithography evaluation (two-layer resist process, line-and-space pattern)

### Examples 1-1 to 1-21 and Comparative Examples 1-1 to 1-4

Each silicon-containing resist underlayer film composition (Sol.1 to Sol.13) was applied to a silicon substrate by spin coating, and baked with a hot plate at a temperature shown in Table 6 for 60 seconds, then a silicon-containing resist underlayer film having a thickness of 40 nm was formed.

Subsequently, each resist composition (R-01 to R-10, CR-01 to CR-02) was applied to the film by spin coating, and pre-baked (PAB) with a hot plate at a temperature shown in Table 6 for 60 seconds, then a resist film having a thickness of 40 nm was producted. The resist film was subjected to exposure of a 36 nm line-and-space (LS) (1:1) pattern with an EUV scanner NXE3400 manufactured by ASML Holding N.V. (NA 0.33, σ 0.9, 90° dipole illumination), and thereafter PEB on a hot plate at a temperature shown in Table 6 for 60 seconds and then development with a developer shown in Table 6 for 30 seconds, thereby forming an LS pattern having a space width of 18 nm and a pitch of 36 nm.

The resist pattern obtained was evaluated as follows. The results are shown in Table 6.

[Evaluation of sensitivity]

The LS pattern was observed with a length measurement SEM (CG-6300) manufactured by Hitachi High-Tech Corporation, the optimal amount of exposure Eop (mJ/cm²), in which an LS pattern having a space width of 18 nm and a pitch of 36 nm was obtained, was determined, and this amount was defined as sensitivity.

### [Evaluation of LWR]

The dimensions at 10 positions in the longitudinal direction of the space width of the LS pattern obtained by irradiation in the optimal amount of exposure were measured with a length measurement SEM (CG-6300) manufactured by Hitachi High-Tech Corporation, and a value three times (3σ) the standard deviation (a) was determined as LWR, from the above results. As this value is smaller, a pattern small in roughness and uniform in space width is obtained.

[Evaluation of limit resolvability]

The line width (nm) at a limit of resolving during formation of a pattern with an increase in amount of exposure little by little from the optimal amount of exposure in which the LS pattern was formed was determined with a length measurement SEM (CG-6300) manufactured by Hitachi High-Tech Corporation, and this line width was defined as the limit resolution (nm). It is indicated that, as this value is smaller, a finer pattern having excellent limit resolvability can be formed.

TABLE 6

| | Silicon- | Silicon- | | | | | | |
|---|---|---|---|---|---|---|---|---|
| | containing | containing | | | | | | |
| | resist | resist | | | | | | |
| | underlayer | underlayer | | | | | | |
| | film-forming | film | | PAB/ | | EoP | | Limit |
| | material | Bake | Resist | PEB | | (mJ/ | LWR | resolution |
| | composition | (° C.) | composition | (° C.) | Developer | cm²) | (nm) | (nm) |
| Evaluation Example 1 -1 | Sol. 1 | 240 | R-01 | 110/90 | nBA | 40 | 3.5 | 15 |
| Evaluation Example 1 -2 | Sol. 2 | 240 | R-01 | 110/90 | nBA | 40 | 3.5 | 15 |
| Evaluation Example 1 -3 | Sol. 3 | 240 | R-01 | 110/90 | nBA | 40 | 3.6 | 13 |
| Evaluation Example 1 -4 | Sol. 4 | 240 | R-01 | 110/90 | nBA | 40 | 3.5 | 13 |
| Evaluation Example 1 -5 | Sol. 5 | 240 | R-01 | 110/90 | nBA | 40 | 3.4 | 13 |
| Evaluation Example 1 -6 | Sol. 6 | 240 | R-01 | 110/90 | nBA | 40 | 3.5 | 15 |
| Evaluation Example 1 -7 | Sol. 7 | 240 | R-01 | 110/90 | nBA | 40 | 3.6 | 15 |
| Evaluation Example 1 -8 | Sol. 8 | 240 | R-01 | 110/90 | nBA | 40 | 3.5 | 15 |
| Evaluation Example 1 -9 | Sol. 9 | 240 | R-01 | 110/90 | nBA | 40 | 3.6 | 15 |
| Evaluation Example 1 -10 | Sol. 10 | 240 | R-01 | 110/90 | nBA | 40 | 3.5 | 15 |
| Evaluation Example 1 -11 | Sol. 11 | 240 | R-01 | 110/90 | nBA | 40 | 3.6 | 13 |
| Evaluation Example 1 -12 | Sol. 12 | 240 | R-01 | 110/90 | nBA | 40 | 3.5 | 13 |
| Evaluation Example 1 -13 | Sol. 11 | 240 | R-02 | 110/90 | nBA | 43 | 3.5 | 13 |
| Evaluation Example 1 -14 | Sol. 11 | 240 | R-03 | 110/90 | nBA | 45 | 3.5 | 13 |
| Evaluation Example 1 -15 | Sol. 11 | 240 | R-04 | 110/90 | nBA | 42 | 3.6 | 13 |
| Evaluation Example 1 -16 | Sol. 11 | 240 | R-05 | 110/90 | nBA | 39 | 3.5 | 13 |
| Evaluation Example 1 -17 | Sol. 11 | 240 | R-06 | 110/90 | nBA | 42 | 3.6 | 13 |
| Evaluation Example 1 -18 | Sol. 11 | 240 | R-07 | 110/90 | nBA | 38 | 3.5 | 13 |
| Evaluation Example 1 -19 | Sol. 11 | 240 | R-08 | 110/90 | nBA | 44 | 3.6 | 13 |
| Evaluation Example 1 -20 | Sol. 11 | 240 | R-09 | 110/90 | nBA | 44 | 3.5 | 13 |
| Evaluation Example 1 -21 | Sol. 11 | 240 | R-10 | 110/90 | nBA | 46 | 3.5 | 13 |
| Comparative Evaluation | Sol. 13 | 240 | R-01 | 110/90 | nBA | 40 | 3.5 | 16 |
| Example 1 -1 | | | | | | | | |
| Comparative Evaluation | Sol. 13 | 240 | R-10 | 110/90 | nBA | 40 | 3.5 | 16 |
| Example 1 -2 | | | | | | | | |
| Comparative Evaluation | Sol. 11 | 240 | CR-01 | 105/90 | TMAH | 85 | 5.0 | 18 |
| Example 1 -3 | | | | | | | | |
| Comparative Evaluation | Sol. 11 | 240 | CR-02 | 105/90 | TMAH | 85 | 5.0 | 18 |
| Example 1 -4 | | | | | | | | |

Developer: nBA (butyl acetate)

TMAH (aqueous 2.38% by mass tetramethylammonium hydroxide solution)

It was found from the results shown in Table 6 that Examples, compared with Comparative Examples 1-1 and 1-2, exhibited excellent resolvability by use of the silicon-containing resist underlayer film composition in a two-layer resist process. It was also found that, even in comparison with Comparative Examples 1-3 and 1-4 in which a chemically amplified resist composition with an acid catalyst reaction was used, sensitivity, resolvability and LWR were excellent. Accordingly, it has been found that resolvability is excellent in LS patterning by EUV exposure in a two-layer resist process in which the laminate of the present invention is used.

[6] Manufacturing of laminate and EUV lithography evaluation (three-layer resist process, contact hole pattern)

### Examples 2-1 to 2-21 and Comparative Examples 2-1 to 2-4

Spin-on Carbon ODL-301 (carbon content 88% by mass) manufactured by Shin-Etsu Chemical Co., Ltd. was applied to a silicon substrate, and baked at 350° C. for 60 seconds, then a resist underlayer film having a thickness of 200 nm was formed. Each silicon-containing resist underlayer film composition (Sol.1 to Sol.13) was applied thereto by spin coating, and baked with a hot plate at a temperature shown in Table 7 for 60 seconds, then a silicon-containing resist underlayer film having a thickness of 40 nm was formed.

Subsequently, each resist composition (R-01 to R-10 and CR-01 to CR-02) was applied to the film by spin coating, and pre-baked (PAB) with a hot plate at a temperature shown in Table 7 for 60 seconds, thereby producing a resist film having a thickness of 50 nm. Next, the resist film was exposed with an EUV scanner NXE3400 manufactured by ASML Holding N.V. (NA 0.33, σ 0.9/0.6, quadrupole illumination, mask of a hole pattern with a pitch of 64 nm and a bias of +20% as dimensions on a wafer), subjected to PEB on a hot plate at a temperature shown in Table 6 for 60 seconds, and developed with a developer shown in Table 7 for 30 seconds, then a hole pattern having a dimension of 32 nm was obtained.

The resist pattern obtained was evaluated as follows. The results are shown in Table 7.

[Evaluation of sensitivity]

The contact hole pattern was observed with a length measurement SEM (CG-6300) manufactured by Hitachi High-Tech Corporation, the optimal amount of exposure Eop (mJ/cm²), in which a hole pattern having a dimension of 22 nm was obtained, was determined, and this amount was defined as sensitivity.

### [Evaluation of CDU]

The dimensions at 50 positions of the hole pattern obtained by irradiation in the optimal amount of exposure were measured, and a value three times (3σ) the standard deviation (a) calculated from the above results was defined as CDU. As this value is smaller, a pattern uniform in hole diameter is obtained.

### [Evaluation of Limit Resolvability]

The hole diameter (nm) at a limit of resolving during formation of a pattern with a decrease in amount of exposure little by little from the optimal amount of exposure in which the hole pattern was formed was determined with a length measurement SEM (CG-6300) manufactured by Hitachi High-Tech Corporation, and this hole diameter was defined as the limit resolution (nm). It is indicated that, as this value is smaller, a pattern having excellent limit resolvability and a finer hole diameter can be formed.

TABLE 7

| | Silicon- | Silicon- | | | | | | |
|---|---|---|---|---|---|---|---|---|
| | containing | containing | | | | | | |
| | resist | resist | | | | | | |
| | underlayer | underlayer | | | | | | |
| | film-forming | film | | PAB/ | | EoP | | Limit |
| | material | Bake | Resist | PEB | | (mJ/ | CDU | resolution |
| | composition | (° C.) | composition | (° C.) | Developer | cm²) | (nm) | (nm) |
| Evaluation Example 2-1 | Sol. 1 | 240 | R-01 | 110/90 | nBA | 44 | 2.5 | 25 |
| Evaluation Example 2-2 | Sol. 2 | 240 | R-01 | 110/90 | nBA | 44 | 2.5 | 25 |
| Evaluation Example 2-3 | Sol. 3 | 240 | R-01 | 110/90 | nBA | 44 | 2.2 | 25 |
| Evaluation Example 2-4 | Sol. 4 | 240 | R-01 | 110/90 | nBA | 44 | 2.3 | 25 |
| Evaluation Example 2-5 | Sol. 5 | 240 | R-01 | 110/90 | nBA | 44 | 2.2 | 25 |
| Evaluation Example 2-6 | Sol. 6 | 240 | R-01 | 110/90 | nBA | 44 | 2.4 | 25 |
| Evaluation Example 2-7 | Sol. 7 | 240 | R-01 | 110/90 | nBA | 44 | 2.4 | 25 |
| Evaluation Example 2-8 | Sol. 8 | 240 | R-01 | 110/90 | nBA | 44 | 2.5 | 25 |
| Evaluation Example 2-9 | Sol. 9 | 240 | R-01 | 110/90 | nBA | 44 | 2.5 | 25 |
| Evaluation Example 2-10 | Sol. 10 | 240 | R-01 | 110/90 | nBA | 44 | 2.4 | 25 |
| Evaluation Example 2-11 | Sol. 11 | 240 | R-01 | 110/90 | nBA | 44 | 2.3 | 25 |
| Evaluation Example 2-12 | Sol. 12 | 240 | R-01 | 110/90 | nBA | 44 | 2.3 | 25 |
| Evaluation Example 2-13 | Sol. 11 | 240 | R-02 | 110/90 | nBA | 46 | 2.2 | 25 |
| Evaluation Example 2-14 | Sol. 11 | 240 | R-03 | 110/90 | nBA | 48 | 2.2 | 25 |
| Evaluation Example 2-15 | Sol. 11 | 240 | R-04 | 110/90 | nBA | 45 | 2.3 | 25 |
| Evaluation Example 2-16 | Sol. 11 | 240 | R-05 | 110/90 | nBA | 42 | 2.3 | 25 |
| Evaluation Example 2-17 | Sol. 11 | 240 | R-06 | 110/90 | nBA | 45 | 2.3 | 25 |
| Evaluation Example 2-18 | Sol. 11 | 240 | R-07 | 110/90 | nBA | 42 | 2.3 | 25 |
| Evaluation Example 2-19 | Sol. 11 | 240 | R-08 | 110/90 | nBA | 48 | 2.3 | 25 |
| Evaluation Example 2-20 | Sol. 11 | 240 | R-09 | 110/90 | nBA | 48 | 2.2 | 25 |
| Evaluation Example 2-21 | Sol. 11 | 240 | R-10 | 110/90 | nBA | 48 | 2.3 | 25 |
| Comparative Evaluation | Sol. 13 | 240 | R-01 | 110/90 | nBA | 44 | 2.8 | 25 |
| Example 2-1 | | | | | | | | |
| Comparative Evaluation | Sol. 13 | 240 | R-10 | 110/90 | nBA | 46 | 2.8 | 25 |
| Example 2-2 | | | | | | | | |
| Comparative Evaluation | Sol. 11 | 240 | CR-01 | 105/90 | TMAH | 50 | 4.2 | 27 |
| Example 2-3 | | | | | | | | |
| Comparative Evaluation | Sol. 11 | 240 | CR-02 | 105/90 | TMAH | 50 | 4.2 | 27 |
| Example 2-4 | | | | | | | | |

It was found from the results shown in Table 7 that Examples, compared with Comparative Examples 2-1 and 2-2, provided a pattern exhibiting excellent CDU by use of the silicon-containing resist underlayer film composition in a three-layer resist process. It was also found that, even in comparison with Comparative Examples 2-3 and 2-4 in which a chemically amplified resist composition with an acid catalyst reaction was used, sensitivity, resolvability and LWR were excellent. Accordingly, it has been found that CDU is excellent in contact hole patterning by EUV exposure in a three-layer resist process in which the laminate of the present invention is used.

The present description includes the following embodiments.

[1]A laminate comprising:
a substrate;
a silicon-containing resist underlayer film obtained from a silicon-containing resist underlayer film composition that contains a thermally crosslinkable polysiloxane containing any one or more from repeating units represented by the following general formulae (1) to (3) and any one or more from repeating units represented by the following general formulae (4) to (6); and
a resist film obtained from a resist composition that contains at least one hypervalent iodine compound selected from a hypervalent iodine compound represented by the following formula (7), a hypervalent iodine compound represented by the following formula (8) and a hypervalent iodine compound represented by the following formula (9), a carboxy group-containing compound, and a solvent;
in the listed order:

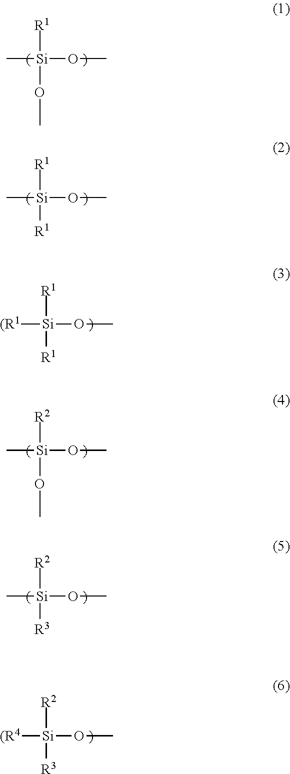

wherein R¹ is an organic group having a carboxy group or an organic group having a carboxyl group substituted with an acid-labile group, and R², R³ and R⁴ are the same as or different from each other, and are each a monovalent organic group having 1 to 30 carbon atoms;

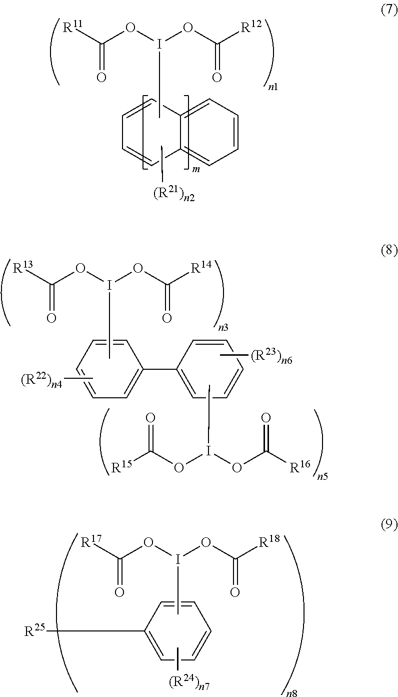

wherein “m” is 0, 1 or 2; when “m” is 0, n1 is 1, 2 or 3, n2 is 0, 1, 2, 3, 4 or 5, and 1≤n1+n2≤6 is satisfied; when “m” is 1, n1 is 1, 2 or 3, n2 is 0, 1, 2, 3, 4, 5, 6 or 7, and 1≤n1+n2≤8 is satisfied; when m is 2, n1 is 1, 2 or 3, n2 is 0, 1, 2, 3, 4, 5, 6, 7, 8 or 9, and 1≤n1+n2≤10 is satisfied; n3 is 1 or 2; n4 is 0, 1, 2, 3 or 4; provided that 1≤n3+n4≤5 is satisfied; n5 is 1 or 2; n6 is 0, 1, 2, 3 or 4; provided that 1≤n5+n6≤5 is satisfied; n7 is 0, 1, 2, 3 or 4; and n8 is 1, 2, 3 or 4;
R¹¹ to R¹⁸ are each independently a halogen atom, or a hydrocarbyl group having 1 to 10 carbon atoms and optionally containing a heteroatom; and R¹¹ and R¹², R¹³ and R¹⁴, R¹⁵ and R¹⁶, or R¹⁷ and R¹⁸ are optionally bound to each other to form a ring together with carbon atoms to which these are bound and an atom between the carbon atoms;
R²¹ to R²⁴ are each independently a halogen atom, or a hydrocarbyl group having 1 to 40 carbon atoms and optionally containing a heteroatom; when n2 is 2 or more, R²¹s are the same as or different from each other, and plural R²¹s are optionally bound to each other to form a ring together with carbon atoms in an aromatic ring to which these are bound; when n4 is 2 or more, R²²s are the same as or different from each other, and plural R²²s are optionally bound to each other to form a ring together with carbon atoms in an aromatic ring to which these are bound; when n6 is 2 or more, R²³s are the same as or different from each other, and plural R²³s are optionally bound to each other to form a ring together with carbon atoms in an aromatic ring to which these are bound; and when n7 is 2 or more, R²⁴s are the same as or different from each other, and plural R²⁴s are optionally bound to each other to form a ring together with carbon atoms in an aromatic ring to which these are bound; and
R²⁵ is an (n8)-valent hydrocarbon group having 1 to 40 carbon atoms or an (n8)-valent heterocyclic group having 2 to 40 carbon atoms, and when n8 is 2, R²⁵ is optionally an ether bond, a carbonyl group, an azo group, a thioether bond, a carbonate bond, a carbamate bond, a sulfinyl group, a sulfonyl group or a thioketone bond; and some or all of hydrogen atoms in the (n8)-valent hydrocarbon group or the (n8)-valent heterocyclic group are each optionally substituted by a group containing a heteroatom, some of —CH₂— in the (n8)-valent hydrocarbon group are each optionally substituted by a group containing a heteroatom, and R²⁴ and R²⁵ are optionally bound to each other to form a ring together with carbon atoms to which these are bound and an atom between the carbon atoms.

[2] The laminate according to [1], comprising a resist underlayer film between the substrate and the silicon-containing resist underlayer film.

[3] The laminate according to [1] or [2], wherein the silicon-containing resist underlayer film composition contains a crosslinking catalyst for siloxane polymerization (Xc), an alcohol-based organic solvent, and water.

[4] The laminate according to any one [1] or [3], wherein the carboxy group-containing compound in the resist composition is a polymer containing a repeating unit represented by the following formula (10) or a compound represented by the following formula (11):

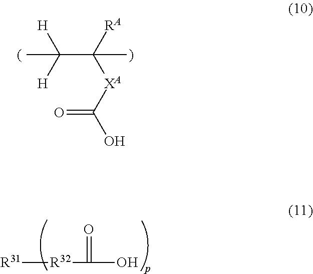

wherein R^{A} is a hydrogen atom, a halogen atom, a methyl group or a trifluoromethyl group;
X^{A} is a single bond, a phenylene group, a naphthylene group or *—C(═O)—O—X^{A1}—; X^{A1} is a saturated hydrocarbylene group having 1 to 10 carbon atoms, a phenylene group or a naphthylene group, and the saturated hydrocarbylene group optionally contains a hydroxy group, an ether bond, an ester bond or a lactone ring; and * represents a point of attachment to a carbon atom in a backbone;
p is 1, 2, 3 or 4;
R³¹ is a p-valent hydrocarbon group having 1 to 40 carbon atoms or a p-valent heterocyclic group having 2 to 40 carbon atoms, and when p is 2, R³¹ is optionally an ether bond, a carbonyl group, an azo group, a thioether bond, a carbonate bond, a carbamate bond, a sulfinyl group or a sulfonyl group; and some or all of hydrogen atoms in the p-valent hydrocarbon group or the p-valent heterocyclic group are each optionally substituted by a group containing a heteroatom, and some of —CH₂— in the p-valent hydrocarbon group are each optionally substituted by a group containing a heteroatom; and
R³² is a single bond or a hydrocarbylene group having 1 to 10 carbon atoms, some or all of hydrogen atoms in the hydrocarbylene group are each optionally substituted by a group containing a heteroatom, and some of —CH₂— in the hydrocarbylene group are each optionally substituted by a group containing a heteroatom; and when p is 2 to 4, R³²s are the same as or different from each other.

[5]A process for manufacturing a laminate, comprising the steps of:
forming a resist underlayer film on a substrate;
forming a silicon-containing resist underlayer film from a silicon-containing resist underlayer film composition that contains a thermally crosslinkable polysiloxane containing any one or more from repeating units represented by the following general formulae (1) to (3) and any one or more from repeating units represented by the following general formulae (4) to (6) on the resist underlayer film; and
applying a resist composition containing at least one hypervalent iodine compound selected from a hypervalent iodine compound represented by the following formula (7), a hypervalent iodine compound represented by the following formula (8) and a hypervalent iodine compound represented by the following formula (9), a carboxy group-containing compound, and a solvent, to the silicon-containing resist underlayer film, and performing a heating treatment, to form a resist film:

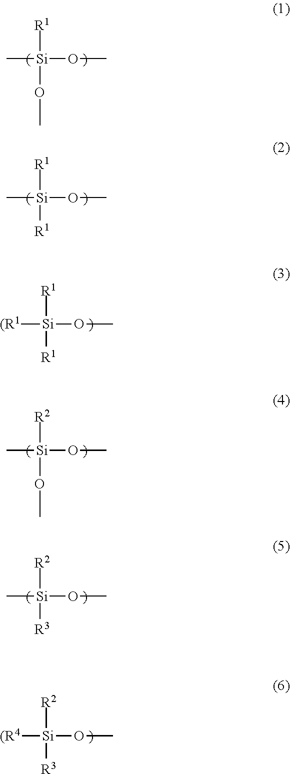

wherein R¹ is an organic group having a carboxy group or an organic group having a carboxyl group substituted with an acid-labile group, and R², R³ and R⁴ are the same as or different from each other, and are each a monovalent organic group having 1 to 30 carbon atoms;

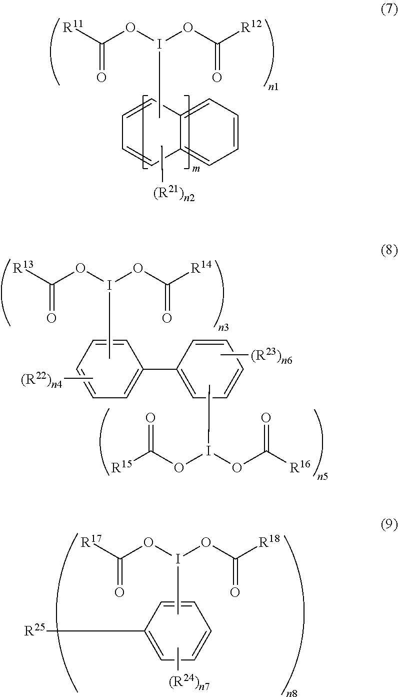

wherein “m” is 0, 1 or 2; when “m” is 0, n1 is 1, 2 or 3, n2 is 0, 1, 2, 3, 4 or 5, and 1≤n1+n2≤6 is satisfied; when “m” is 1, n1 is 1, 2 or 3, n2 is 0, 1, 2, 3, 4, 5, 6 or 7, and 1≤n1+n2≤8 is satisfied; when “m” is 2, n1 is 1, 2 or 3, n2 is 0, 1, 2, 3, 4, 5, 6, 7, 8 or 9, and 1≤n1+n2≤10 is satisfied; n3 is 1 or 2; n4 is 0, 1, 2, 3 or 4; provided that 1≤n3+n4≤5 is satisfied; n5 is 1 or 2; n6 is 0, 1, 2, 3 or 4; provided that 1≤n5+n6≤5 is satisfied; n7 is 0, 1, 2, 3 or 4; and n8 is 1, 2, 3 or 4;
R¹¹ to R¹⁸ are each independently a halogen atom, or a hydrocarbyl group having 1 to 10 carbon atoms and optionally containing a heteroatom; and R¹¹ and R¹², R¹³ and R¹⁴, R¹⁵ and R¹⁶, or R¹⁷ and R¹⁸ are optionally bound to each other to form a ring together with carbon atoms to which these are bound and an atom between the carbon atoms;
R²¹ to R²⁴ are each independently a halogen atom, or a hydrocarbyl group having 1 to 40 carbon atoms and optionally containing a heteroatom; when n2 is 2 or more, R²¹s are the same as or different from each other, and plural R²¹s are optionally bound to each other to form a ring together with carbon atoms in an aromatic ring to which these are bound; when n4 is 2 or more, R²²s are the same as or different from each other, and plural R²²s are optionally bound to each other to form a ring together with carbon atoms in an aromatic ring to which these are bound; when n6 is 2 or more, R²³s are the same as or different from each other, and plural R²³s are optionally bound to each other to form a ring together with carbon atoms in an aromatic ring to which these are bound; and when n7 is 2 or more, R²⁴s are the same as or different from each other, and plural R²⁴s are optionally bound to each other to form a ring together with carbon atoms in an aromatic ring to which these are bound; and
R²⁵ is an (n8)-valent hydrocarbon group having 1 to 40 carbon atoms or an (n8)-valent heterocyclic group having 2 to 40 carbon atoms, and when n8 is 2, R²⁵ is optionally an ether bond, a carbonyl group, an azo group, a thioether bond, a carbonate bond, a carbamate bond, a sulfinyl group, a sulfonyl group or a thioketone bond; and some or all of hydrogen atoms in the (n8)-valent hydrocarbon group or the (n8)-valent heterocyclic group are each optionally substituted by a group containing a heteroatom, some of —CH₂— in the (n8)-valent hydrocarbon group are each optionally substituted by a group containing a heteroatom, and R²⁴ and R²⁵ are optionally bound to each other to form a ring together with carbon atoms to which these are bound and an atom between the carbon atoms.

[6] The process for manufacturing a laminate according to [5], wherein the resist underlayer film is formed by applying an underlayer film-forming material to the substrate and performing a heating treatment.

[7] The process for manufacturing a laminate according to [5], wherein the resist underlayer film is formed by a CVD process or an ALD process.

[8] The process for manufacturing a laminate according to any one of [5] or [7], wherein the carboxy group-containing compound is a polymer containing a repeating unit represented by the following formula (10) or a compound represented by the following formula (11):

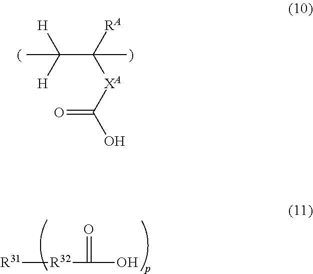

wherein R^{A} is a hydrogen atom, a halogen atom, a methyl group or a trifluoromethyl group;
X^{A} is a single bond, a phenylene group, a naphthylene group or *—C(═O)—O—X^{A1}—; X^{A1} is a saturated hydrocarbylene group having 1 to 10 carbon atoms, a phenylene group or a naphthylene group, and the saturated hydrocarbylene group optionally contains a hydroxy group, an ether bond, an ester bond or a lactone ring; and * represents a point of attachment to a carbon atom in a backbone;
p is 1, 2, 3 or 4;
R³¹ is a p-valent hydrocarbon group having 1 to 40 carbon atoms or a p-valent heterocyclic group having 2 to 40 carbon atoms, and when p is 2, R³¹ is optionally an ether bond, a carbonyl group, an azo group, a thioether bond, a carbonate bond, a carbamate bond, a sulfinyl group or a sulfonyl group; and some or all of hydrogen atoms in the p-valent hydrocarbon group or the p-valent heterocyclic group are each optionally substituted by a group containing a heteroatom, and some of —CH₂— in the p-valent hydrocarbon group are each optionally substituted by a group containing a heteroatom; and
R³² is a single bond or a hydrocarbylene group having 1 to 10 carbon atoms, some or all of hydrogen atoms in the hydrocarbylene group are each optionally substituted by a group containing a heteroatom, and some of —CH₂— in the hydrocarbylene group are each optionally substituted by a group containing a heteroatom; and when p is 2 to 4, R³²s are the same as or different from each other.

[9]A patterning process comprising the steps of: exposing the resist film of the laminate according to any one of [1] or [4], to an i-line, a KrF excimer laser, an ArF excimer laser, an electron beam or an extreme-ultraviolet ray; and developing the exposed resist film with a developer.

[10] The patterning process according to [9], wherein the developer is an organic solvent.

It should be noted that the present invention is not limited to the above-described embodiments. The embodiments are just examples, and any examples that substantially have the same feature and demonstrate the same functions and effects as those in the technical concept disclosed in claims of the present invention are included in the technical scope of the present invention.

1. A laminate comprising:
a substrate;
a silicon-containing resist underlayer film obtained from a silicon-containing resist underlayer film composition that contains a thermally crosslinkable polysiloxane containing any one or more from repeating units represented by the following general formulae (1) to (3) and any one or more from repeating units represented by the following general formulae (4) to (6); and
a resist film obtained from a resist composition that contains at least one hypervalent iodine compound selected from a hypervalent iodine compound represented by the following formula (7), a hypervalent iodine compound represented by the following formula (8) and a hypervalent iodine compound represented by the following formula (9), a carboxy group-containing compound, and a solvent;
in the listed order: 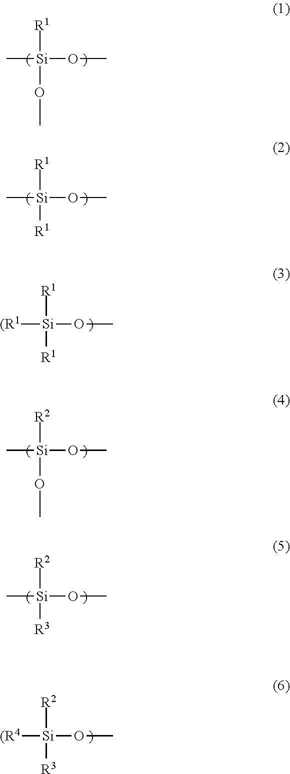
wherein R¹ is an organic group having a carboxy group or an organic group having a carboxyl group substituted with an acid-labile group, and R², R³ and R⁴ are the same as or different from each other, and are each a monovalent organic group having 1 to 30 carbon atoms; 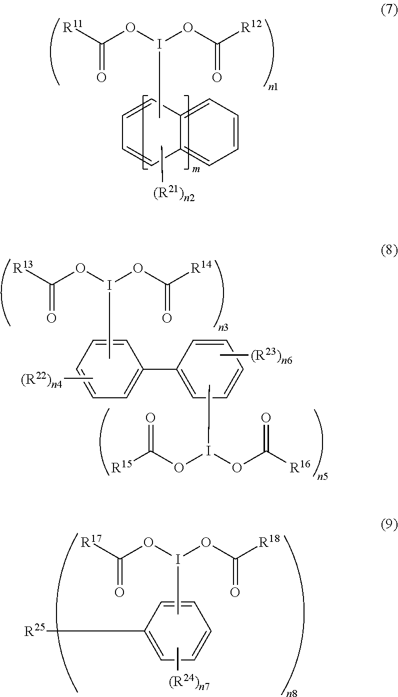
wherein “m” is 0, 1 or 2; when “m” is 0, n1 is 1, 2 or 3, n2 is 0, 1, 2, 3, 4 or 5, and 1≤n1+n2≤6 is satisfied; when “m” is 1, n1 is 1, 2 or 3, n2 is 0, 1, 2, 3, 4, 5, 6 or 7, and 1≤n1+n2≤8 is satisfied; when m is 2, n1 is 1, 2 or 3, n2 is 0, 1, 2, 3, 4, 5, 6, 7, 8 or 9, and 1≤n1+n2≤10 is satisfied; n3 is 1 or 2; n4 is 0, 1, 2, 3 or 4; provided that 1≤n3+n4≤5 is satisfied; n5 is 1 or 2; n6 is 0, 1, 2, 3 or 4; provided that 1≤n5+n6≤5 is satisfied; n7 is 0, 1, 2, 3 or 4; and n8 is 1, 2, 3 or 4;
R¹¹ to R¹⁸ are each independently a halogen atom, or a hydrocarbyl group having 1 to 10 carbon atoms and optionally containing a heteroatom; and R¹¹ and R¹², R¹³ and R¹⁴, R¹⁵ and R¹⁶, or R¹⁷ and R¹⁸ are optionally bound to each other to form a ring together with carbon atoms to which these are bound and an atom between the carbon atoms;
R²¹ to R²⁴ are each independently a halogen atom, or a hydrocarbyl group having 1 to 40 carbon atoms and optionally containing a heteroatom; when n2 is 2 or more, R²¹s are the same as or different from each other, and plural R²¹s are optionally bound to each other to form a ring together with carbon atoms in an aromatic ring to which these are bound; when n4 is 2 or more, R²²s are the same as or different from each other, and plural R²²s are optionally bound to each other to form a ring together with carbon atoms in an aromatic ring to which these are bound; when n6 is 2 or more, R²³s are the same as or different from each other, and plural R²³s are optionally bound to each other to form a ring together with carbon atoms in an aromatic ring to which these are bound; and when n7 is 2 or more, R²⁴s are the same as or different from each other, and plural R²⁴s are optionally bound to each other to form a ring together with carbon atoms in an aromatic ring to which these are bound; and
R²⁵ is an (n8)-valent hydrocarbon group having 1 to 40 carbon atoms or an (n8)-valent heterocyclic group having 2 to 40 carbon atoms, and when n8 is 2, R²⁵ is optionally an ether bond, a carbonyl group, an azo group, a thioether bond, a carbonate bond, a carbamate bond, a sulfinyl group, a sulfonyl group or a thioketone bond; and some or all of hydrogen atoms in the (n8)-valent hydrocarbon group or the (n8)-valent heterocyclic group are each optionally substituted by a group containing a heteroatom, some of —CH₂— in the (n8)-valent hydrocarbon group are each optionally substituted by a group containing a heteroatom, and R²⁴ and R²⁵ are optionally bound to each other to form a ring together with carbon atoms to which these are bound and an atom between the carbon atoms.

2. The laminate according to claim 1, comprising a resist underlayer film between the substrate and the silicon-containing resist underlayer film.

3. The laminate according to claim 1, wherein the silicon-containing resist underlayer film composition contains a crosslinking catalyst for siloxane polymerization (Xc), an alcohol-based organic solvent, and water.

4. The laminate according to claim 2, wherein the silicon-containing resist underlayer film composition contains a crosslinking catalyst for siloxane polymerization (Xc), an alcohol-based organic solvent, and water.

5. The laminate according to claim 1, wherein the carboxy group-containing compound in the resist composition is a polymer containing a repeating unit represented by the following formula (10) or a compound represented by the following formula (11): 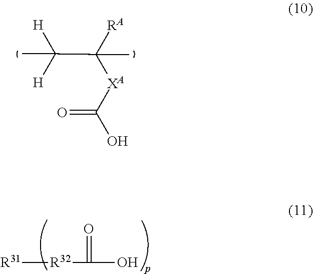
wherein R^{A} is a hydrogen atom, a halogen atom, a methyl group or a trifluoromethyl group;
X^{A} is a single bond, a phenylene group, a naphthylene group or *—C(═O)—O—X^{A1}—; X^{A1} is a saturated hydrocarbylene group having 1 to 10 carbon atoms, a phenylene group or a naphthylene group, and the saturated hydrocarbylene group optionally contains a hydroxy group, an ether bond, an ester bond or a lactone ring; and * represents a point of attachment to a carbon atom in a backbone;
“p” is 1, 2, 3 or 4;
R³¹ is a p-valent hydrocarbon group having 1 to 40 carbon atoms or a p-valent heterocyclic group having 2 to 40 carbon atoms, and when “p” is 2, R³¹ is optionally an ether bond, a carbonyl group, an azo group, a thioether bond, a carbonate bond, a carbamate bond, a sulfinyl group or a sulfonyl group; and some or all of hydrogen atoms in the p-valent hydrocarbon group or the p-valent heterocyclic group are each optionally substituted by a group containing a heteroatom, and some of —CH₂— in the p-valent hydrocarbon group are each optionally substituted by a group containing a heteroatom; and
R³² is a single bond or a hydrocarbylene group having 1 to 10 carbon atoms, some or all of hydrogen atoms in the hydrocarbylene group are each optionally substituted by a group containing a heteroatom, and some of —CH₂— in the hydrocarbylene group are each optionally substituted by a group containing a heteroatom; and when p is 2 to 4, R³²s are the same as or different from each other.

6. The laminate according to claim 2, wherein the carboxy group-containing compound in the resist composition is a polymer containing a repeating unit represented by the following formula (10) or a compound represented by the following formula (11): 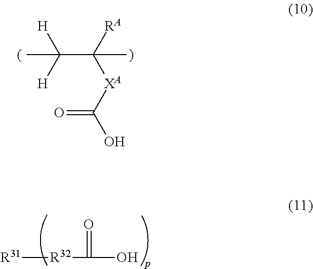
wherein R^{A} is a hydrogen atom, a halogen atom, a methyl group or a trifluoromethyl group;
X^{A} is a single bond, a phenylene group, a naphthylene group or *—C(═O)—O—X^{A}1-; X^{A1} is a saturated hydrocarbylene group having 1 to 10 carbon atoms, a phenylene group or a naphthylene group, and the saturated hydrocarbylene group optionally contains a hydroxy group, an ether bond, an ester bond or a lactone ring; and * represents a point of attachment to a carbon atom in a backbone;
“p” is 1, 2, 3 or 4;
R³¹ is a p-valent hydrocarbon group having 1 to 40 carbon atoms or a p-valent heterocyclic group having 2 to 40 carbon atoms, and when “p” is 2, R³¹ is optionally an ether bond, a carbonyl group, an azo group, a thioether bond, a carbonate bond, a carbamate bond, a sulfinyl group or a sulfonyl group; and some or all of hydrogen atoms in the p-valent hydrocarbon group or the p-valent heterocyclic group are each optionally substituted by a group containing a heteroatom, and some of —CH₂— in the p-valent hydrocarbon group are each optionally substituted by a group containing a heteroatom; and
R³² is a single bond or a hydrocarbylene group having 1 to 10 carbon atoms, some or all of hydrogen atoms in the hydrocarbylene group are each optionally substituted by a group containing a heteroatom, and some of —CH₂— in the hydrocarbylene group are each optionally substituted by a group containing a heteroatom; and when p is 2 to 4, R³²s are the same as or different from each other.

7. The laminate according to claim 3, wherein the carboxy group-containing compound in the resist composition is a polymer containing a repeating unit represented by the following formula (10) or a compound represented by the following formula (11): 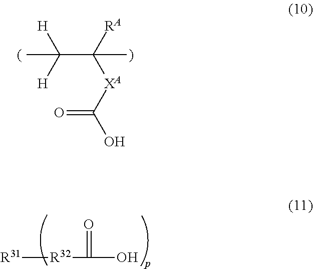
wherein R^{A} is a hydrogen atom, a halogen atom, a methyl group or a trifluoromethyl group;
X^{A} is a single bond, a phenylene group, a naphthylene group or *—C(═O)—O—X^{A1}—; X^{A1} is a saturated hydrocarbylene group having 1 to 10 carbon atoms, a phenylene group or a naphthylene group, and the saturated hydrocarbylene group optionally contains a hydroxy group, an ether bond, an ester bond or a lactone ring; and * represents a point of attachment to a carbon atom in a backbone;
“p” is 1, 2, 3 or 4;
R³¹ is a p-valent hydrocarbon group having 1 to 40 carbon atoms or a p-valent heterocyclic group having 2 to 40 carbon atoms, and when “p” is 2, R³¹ is optionally an ether bond, a carbonyl group, an azo group, a thioether bond, a carbonate bond, a carbamate bond, a sulfinyl group or a sulfonyl group; and some or all of hydrogen atoms in the p-valent hydrocarbon group or the p-valent heterocyclic group are each optionally substituted by a group containing a heteroatom, and some of —CH₂— in the p-valent hydrocarbon group are each optionally substituted by a group containing a heteroatom; and
R³² is a single bond or a hydrocarbylene group having 1 to 10 carbon atoms, some or all of hydrogen atoms in the hydrocarbylene group are each optionally substituted by a group containing a heteroatom, and some of —CH₂— in the hydrocarbylene group are each optionally substituted by a group containing a heteroatom; and when p is 2 to 4, R³²s are the same as or different from each other.

8. A process for manufacturing a laminate, comprising the steps of:
forming a resist underlayer film on a substrate;
forming a silicon-containing resist underlayer film from a silicon-containing resist underlayer film composition that contains a thermally crosslinkable polysiloxane containing any one or more from repeating units represented by the following general formulae (1) to (3) and any one or more from repeating units represented by the following general formulae (4) to (6) on the resist underlayer film; and
applying a resist composition containing at least one hypervalent iodine compound selected from a hypervalent iodine compound represented by the following formula (7), a hypervalent iodine compound represented by the following formula (8) and a hypervalent iodine compound represented by the following formula (9), a carboxy group-containing compound, and a solvent, to the silicon-containing resist underlayer film, and
performing a heating treatment, to form a resist film: 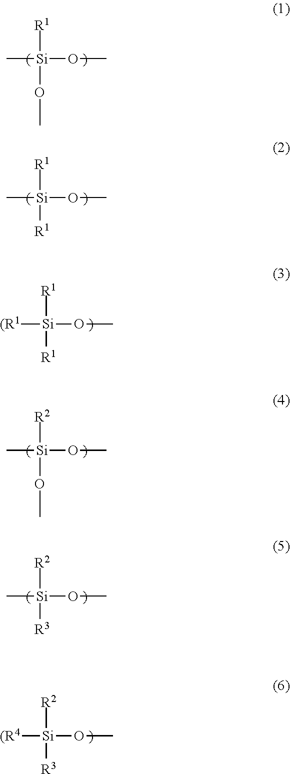
wherein R¹ is an organic group having a carboxy group or an organic group having a carboxyl group substituted with an acid-labile group, and R², R³ and R⁴ are the same as or different from each other, and are each a monovalent organic group having 1 to 30 carbon atoms; 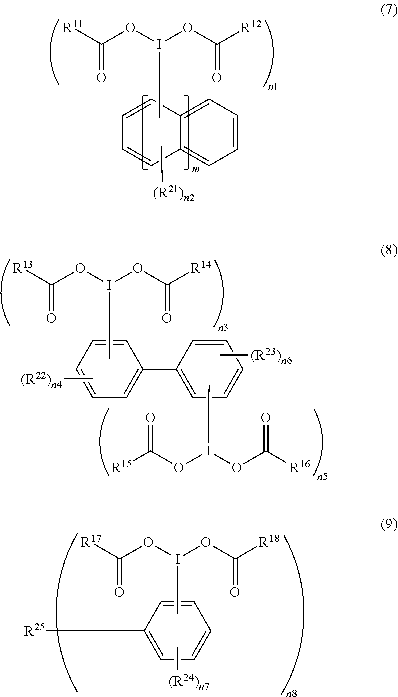
wherein “m” is 0, 1 or 2; when “m” is 0, n1 is 1, 2 or 3, n2 is 0, 1, 2, 3, 4 or 5, and 1≤n1+n2≤6 is satisfied; when m is 1, n1 is 1, 2 or 3, n2 is 0, 1, 2, 3, 4, 5, 6 or 7, and 1≤n1+n2≤8 is satisfied; when m is 2, n1 is 1, 2 or 3, n2 is 0, 1, 2, 3, 4, 5, 6, 7, 8 or 9, and 1≤n1+n2≤10 is satisfied; n3 is 1 or 2; n4 is 0, 1, 2, 3 or 4; provided that 1≤n3+n4≤5 is satisfied; n5 is 1 or 2; n6 is 0, 1, 2, 3 or 4; provided that 1≤n5+n6≤5 is satisfied; n7 is 0, 1, 2, 3 or 4; and n8 is 1, 2, 3 or 4;
R¹¹ to R¹⁸ are each independently a halogen atom, or a hydrocarbyl group having 1 to 10 carbon atoms and optionally containing a heteroatom; and R¹¹ and R¹², R¹³ and R¹⁴, R¹⁵ and R¹⁶, or R¹⁷ and R¹⁸ are optionally bound to each other to form a ring together with carbon atoms to which these are bound and an atom between the carbon atoms;
R²¹ to R²⁴ are each independently a halogen atom, or a hydrocarbyl group having 1 to 40 carbon atoms and optionally containing a heteroatom; when n2 is 2 or more, R²¹s are the same as or different from each other, and plural R²¹s are optionally bound to each other to form a ring together with carbon atoms in an aromatic ring to which these are bound; when n4 is 2 or more, R²²s are the same as or different from each other, and plural R²²s are optionally bound to each other to form a ring together with carbon atoms in an aromatic ring to which these are bound; when n6 is 2 or more, R²³s are the same as or different from each other, and plural R²³s are optionally bound to each other to form a ring together with carbon atoms in an aromatic ring to which these are bound; and when n7 is 2 or more, R²⁴s are the same as or different from each other, and plural R²⁴s are optionally bound to each other to form a ring together with carbon atoms in an aromatic ring to which these are bound; and
R²⁵ is an (n8)-valent hydrocarbon group having 1 to 40 carbon atoms or an (n8)-valent heterocyclic group having 2 to 40 carbon atoms, and when n8 is 2, R²⁵ is optionally an ether bond, a carbonyl group, an azo group, a thioether bond, a carbonate bond, a carbamate bond, a sulfinyl group, a sulfonyl group or a thioketone bond; and some or all of hydrogen atoms in the (n8)-valent hydrocarbon group or the (n8)-valent heterocyclic group are each optionally substituted by a group containing a heteroatom, some of —CH₂— in the (n8)-valent hydrocarbon group are each optionally substituted by a group containing a heteroatom, and R²⁴ and R²⁵ are optionally bound to each other to form a ring together with carbon atoms to which these are bound and an atom between the carbon atoms.

9. The process for manufacturing a laminate according to claim 8, wherein the resist underlayer film is formed by applying an underlayer film-forming material to the substrate and performing a heating treatment.

10. The process for manufacturing a laminate according to claim 8, wherein the resist underlayer film is formed by a CVD process or an ALD process.

11. The process for manufacturing a laminate according to claim 8, wherein the carboxy group-containing compound is a polymer containing a repeating unit represented by the following formula (10) or a compound represented by the following formula (11): 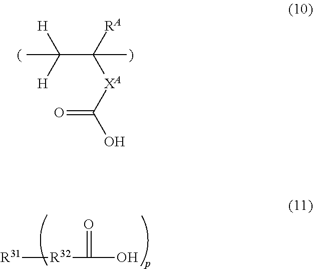
wherein R^{A} is a hydrogen atom, a halogen atom, a methyl group or a trifluoromethyl group;
X^{A} is a single bond, a phenylene group, a naphthylene group or *—C(═O)—O—X^{A1}—; X^{A1} is a saturated hydrocarbylene group having 1 to 10 carbon atoms, a phenylene group or a naphthylene group, and the saturated hydrocarbylene group optionally contains a hydroxy group, an ether bond, an ester bond or a lactone ring; and * represents a point of attachment to a carbon atom in a backbone;
p is 1, 2, 3 or 4;
R³¹ is a p-valent hydrocarbon group having 1 to 40 carbon atoms or a p-valent heterocyclic group having 2 to 40 carbon atoms, and when p is 2, R³¹ is optionally an ether bond, a carbonyl group, an azo group, a thioether bond, a carbonate bond, a carbamate bond, a sulfinyl group or a sulfonyl group; and some or all of hydrogen atoms in the p-valent hydrocarbon group or the p-valent heterocyclic group are each optionally substituted by a group containing a heteroatom, and some of —CH₂— in the p-valent hydrocarbon group are each optionally substituted by a group containing a heteroatom; and
R³² is a single bond or a hydrocarbylene group having 1 to 10 carbon atoms, some or all of hydrogen atoms in the hydrocarbylene group are each optionally substituted by a group containing a heteroatom, and some of —CH₂— in the hydrocarbylene group are each optionally substituted by a group containing a heteroatom; and when p is 2 to 4, R³²s are the same as or different from each other.

12. The process for manufacturing a laminate according to claim 9, wherein the carboxy group-containing compound is a polymer containing a repeating unit represented by the following formula (10) or a compound represented by the following formula (11): 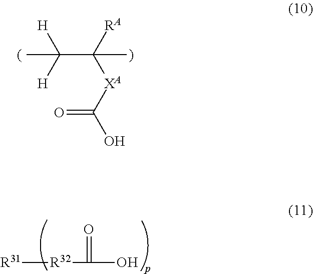
wherein R^{A} is a hydrogen atom, a halogen atom, a methyl group or a trifluoromethyl group;
X^{A} is a single bond, a phenylene group, a naphthylene group or *—C(═O)—O—X^{A1}—; X^{A1} is a saturated hydrocarbylene group having 1 to 10 carbon atoms, a phenylene group or a naphthylene group, and the saturated hydrocarbylene group optionally contains a hydroxy group, an ether bond, an ester bond or a lactone ring; and * represents a point of attachment to a carbon atom in a backbone;
p is 1, 2, 3 or 4;
R³¹ is a p-valent hydrocarbon group having 1 to 40 carbon atoms or a p-valent heterocyclic group having 2 to 40 carbon atoms, and when p is 2, R³¹ is optionally an ether bond, a carbonyl group, an azo group, a thioether bond, a carbonate bond, a carbamate bond, a sulfinyl group or a sulfonyl group; and some or all of hydrogen atoms in the p-valent hydrocarbon group or the p-valent heterocyclic group are each optionally substituted by a group containing a heteroatom, and some of —CH₂— in the p-valent hydrocarbon group are each optionally substituted by a group containing a heteroatom; and
R³² is a single bond or a hydrocarbylene group having 1 to 10 carbon atoms, some or all of hydrogen atoms in the hydrocarbylene group are each optionally substituted by a group containing a heteroatom, and some of —CH₂— in the hydrocarbylene group are each optionally substituted by a group containing a heteroatom; and when p is 2 to 4, R³²s are the same as or different from each other.

13. The process for manufacturing a laminate according to claim 10, wherein the carboxy group-containing compound is a polymer containing a repeating unit represented by the following formula (10) or a compound represented by the following formula (11): 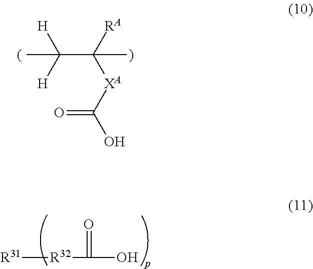
wherein R^{A} is a hydrogen atom, a halogen atom, a methyl group or a trifluoromethyl group;
X^{A} is a single bond, a phenylene group, a naphthylene group or *—C(═O)—O—X^{A1}—; X^{A1} is a saturated hydrocarbylene group having 1 to 10 carbon atoms, a phenylene group or a naphthylene group, and the saturated hydrocarbylene group optionally contains a hydroxy group, an ether bond, an ester bond or a lactone ring; and * represents a point of attachment to a carbon atom in a backbone;
p is 1, 2, 3 or 4;
R³¹ is a p-valent hydrocarbon group having 1 to 40 carbon atoms or a p-valent heterocyclic group having 2 to 40 carbon atoms, and when p is 2, R³¹ is optionally an ether bond, a carbonyl group, an azo group, a thioether bond, a carbonate bond, a carbamate bond, a sulfinyl group or a sulfonyl group; and some or all of hydrogen atoms in the p-valent hydrocarbon group or the p-valent heterocyclic group are each optionally substituted by a group containing a heteroatom, and some of —CH₂— in the p-valent hydrocarbon group are each optionally substituted by a group containing a heteroatom; and
R³² is a single bond or a hydrocarbylene group having 1 to 10 carbon atoms, some or all of hydrogen atoms in the hydrocarbylene group are each optionally substituted by a group containing a heteroatom, and some of —CH₂— in the hydrocarbylene group are each optionally substituted by a group containing a heteroatom; and when p is 2 to 4, R³²s are the same as or different from each other.

14. A patterning process comprising the steps of: exposing the resist film of the laminate according to claim 1, to an i-line, a KrF excimer laser, an ArF excimer laser, an electron beam or an extreme-ultraviolet ray; and developing the exposed resist film with a developer.

15. A patterning process comprising the steps of: exposing the resist film of the laminate according to claim 2, to an i-line, a KrF excimer laser, an ArF excimer laser, an electron beam or an extreme-ultraviolet ray; and developing the exposed resist film with a developer.

16. A patterning process comprising the steps of: exposing the resist film of the laminate according to claim 3, to an i-line, a KrF excimer laser, an ArF excimer laser, an electron beam or an extreme-ultraviolet ray; and developing the exposed resist film with a developer.

17. A patterning process comprising the steps of: exposing the resist film of the laminate according to claim 4, to an i-line, a KrF excimer laser, an ArF excimer laser, an electron beam or an extreme-ultraviolet ray; and developing the exposed resist film with a developer.

18. The patterning process according to claim 14, wherein the developer is an organic solvent.

19. The patterning process according to claim 15, wherein the developer is an organic solvent.

20. The patterning process according to claim 16, wherein the developer is an organic solvent.
